(19) United States
(12) Patent Application Publication
(10) Pub. No.: US 2025/0338772 A1
(43) Pub. Date: Oct. 30, 2025

(54) LIGHT EMITTING ELEMENT, FUSED POLYCYCLIC COMPOUND FOR THE LIGHT EMITTING ELEMENT, AND DISPLAY DEVICE INCLUDING THE LIGHT EMITTING ELEMENT

(71) Applicant: Samsung Display Co., Ltd., Yongin-si (KR)

(72) Inventors: MinJae SUNG, Yongin-si (KR); Hirokazu MIYASHITA, Yongin-si (KR); TAEIL KIM, Yongin-si (KR); JUNHA PARK, Yongin-si (KR); MUN-KI SIM, Yongin-si (KR); MINJUNG JUNG, Yongin-si (KR)

(21) Appl. No.: 19/098,206

(22) Filed: Apr. 2, 2025

(30) Foreign Application Priority Data
Apr. 24, 2024 (KR) 10-2024-0054779

(51) Int. Cl. H10K 85/60; C07F 5/02; C09K 11/02; C09K 11/06; H10K 50/12; H10K 85/30; H10K 85/40

(52) U.S. Cl. CPC H10K 85/658; C07F 5/027; C09K 11/02; C09K 11/06; H10K 85/346; H10K 85/40; H10K 85/654; H10K 85/6572; C09K 2211/1007; C09K 2211/1018; H10K 50/12

(57) ABSTRACT

A light emitting element includes a first electrode, a second electrode arranged on the first electrode, and an emission layer arranged between the first electrode and the second electrode and including a first compound represented by Formula 1.

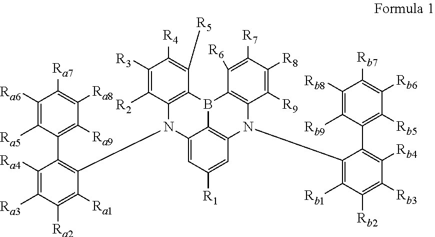

### CROSS-REFERENCE TO RELATED APPLICATIONS

The present application claims priority to and the benefit of Korean Patent Application No. 10-2024-0054779, filed on Apr. 24, 2024, in the Korean Intellectual Property Office, the entire disclosure of which is incorporated herein by reference.

### BACKGROUND

### 1. Field

One or more embodiments of the present disclosure relate to a light emitting element, a fused polycyclic compound used for the light emitting element, and a display device including the light emitting element.

### 2. Description of the Related Art

Recently, organic electroluminescence display devices and/or the like have been garnered significant attention as image display devices, leading to active research and development. An organic electroluminescence display device or the like is a display device that includes a self-luminescence light emitting element that displays images by recombining holes and electrons injected separately from a first electrode and a second electrode within an emission layer. This recombination causes a light emitting material in the emission layer to emits light, thereby enabling image display (e.g., display of images).

When applying a light emitting element to a display device, high light efficiency and/or the like are desired or required. Consequently, ongoing research and development efforts are focused on materials for light emitting elements that may stably achieve such desired characteristics.

### SUMMARY

One or more aspects of embodiments of the present disclosure are directed toward a light emitting element with improved luminous efficiency and a display device including the light emitting element.

One or more aspects of embodiments of the present disclosure are directed toward a fused polycyclic compound, which is a material for a light emitting element capable of improving luminous efficiency of the light emitting element.

Additional aspects will be set forth in part in the description which follows and, in part, will be apparent from the description, or may be learned by practice of the presented embodiments.

According to one or more embodiments of the present disclosure, a light emitting element includes a first electrode, a second electrode on the first electrode, and an emission layer between the first electrode and the second electrode and including a first compound represented by Formula 1.

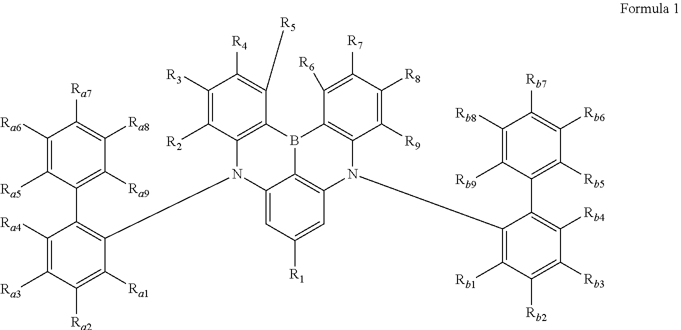

In Formula 1, at least one selected from among R₁ to R₉, Rₐ₁ to Rₐ₉, and R_{b1} to R_{b9} may be represented by Formula 2, and the rest thereof may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group.

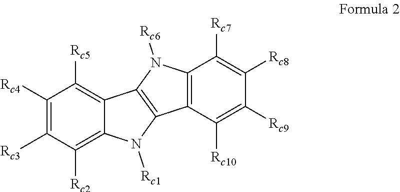

In Formula 2, any one selected from among R_{c1} to R_{c10} may be a position bonded to Formula 1, and the rest thereof may each independently be hydrogen, deuterium, or a substituted or unsubstituted aryl group having 6 to 30 ring-forming carbon atoms.

In one or more embodiments, the emission layer may further include at least one selected from among a second compound represented by Formula HT-1, a third compound represented by Formula ET-1, and a fourth compound represented by Formula D-1.

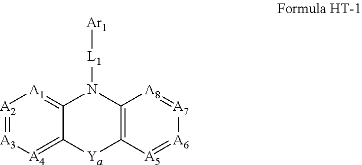

In Formula HT-1, A₁ to A₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Ar₁ may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or may form a ring by being bonded to an adjacent group.

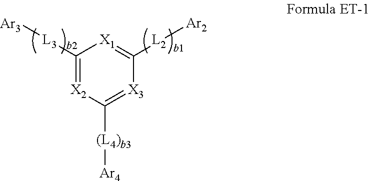

In Formula ET-1, at least one selected from among X₁ to X₃ may be N, and the rest thereof may be CR₅₆, R₅₆ may be hydrogen, deuterium, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar₂ to Ar₄ may each independently be hydrogen, deuterium, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

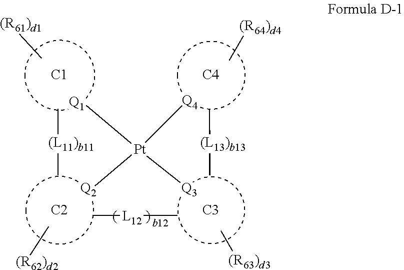

In Formula D-1, Q₁ to Q₄ may each independently be C or N, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted hetero ring having 2 to 30 ring-forming carbon atoms, L₁₁ to L₁₃ may each independently be a direct linkage, *—O—*, *—S—*,

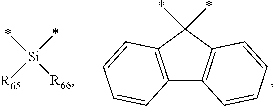

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, Formula 2 may be represented by Formula 2-A.

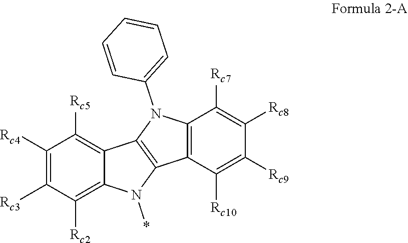

In Formula 2-A, R_{c2} to R_{c5} and R_{c7} to R_{c10} may each be the same as defined in Formula 2.

In one or more embodiments, the first compound represented by Formula 1 may be represented by Formula 1-A or Formula 1-B.

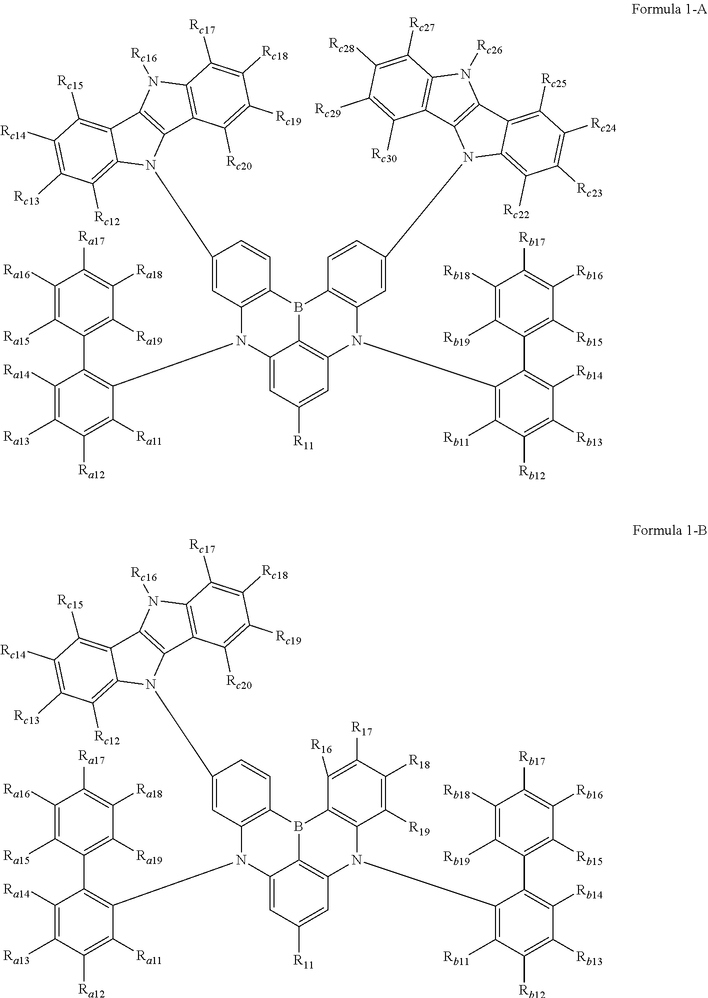

Formula 1-A, R_{c22} to R_{c30} may each independently be hydrogen, deuterium, or a substituted or unsubstituted aryl group having 6 to 30 ring-forming carbon atoms, in Formula 1-B, R₁₆ to R₁₉ may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group, and in Formula 1-A and Formula 1-B, R₁₁, Rₐ₁₁ to Rₐ₁₉, and R_{b11} to R_{b19} may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group, and R_{c12} to R_{c20} may each independently be hydrogen, deuterium, or a substituted or unsubstituted aryl group having 6 to 30 ring-forming carbon atoms.

In one or more embodiments, the first compound represented by Formula 1-A may be represented by Formula 1-A1.

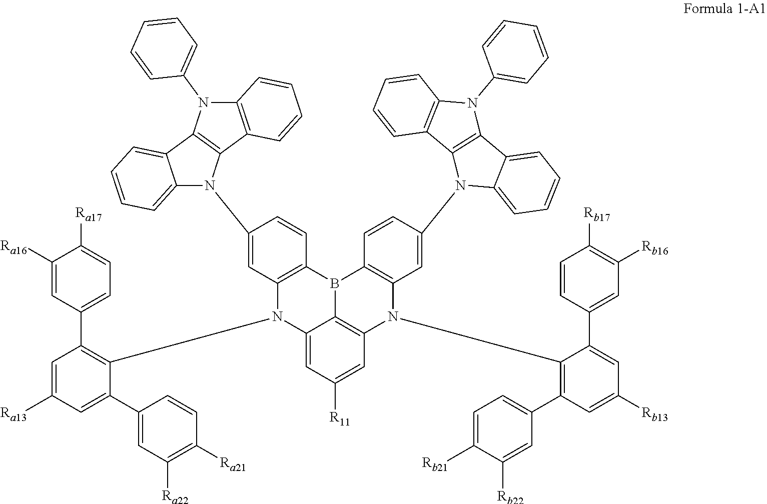

In Formula 1-A1, Rₐ₂₁, Rₐ₂₂, R_{b21}, and R_{b22} may each independently be hydrogen, deuterium, a substituted or unsubstituted alkyl group having 1 to 30 carbon atoms, or a substituted or unsubstituted aryl group having 6 to 30 ring-forming carbon atoms, and R₁₁, Rₐ₁₃, Rₐ₁₆, Rₐ₁₇, R_{b13}, R_{b16}, and R_{b17} may each be the same as defined in Formula 1-A.

In one or more embodiments, in Formula 1-A1, Rₐ₂₁, Rₐ₂₂, R_{b21}, and R_{b22} may each independently be hydrogen, a substituted or unsubstituted t-butyl group, or a substituted or unsubstituted phenyl group.

In one or more embodiments, the first compound represented by Formula 1-B may be represented by Formula 1-B1 or Formula 1-B2.

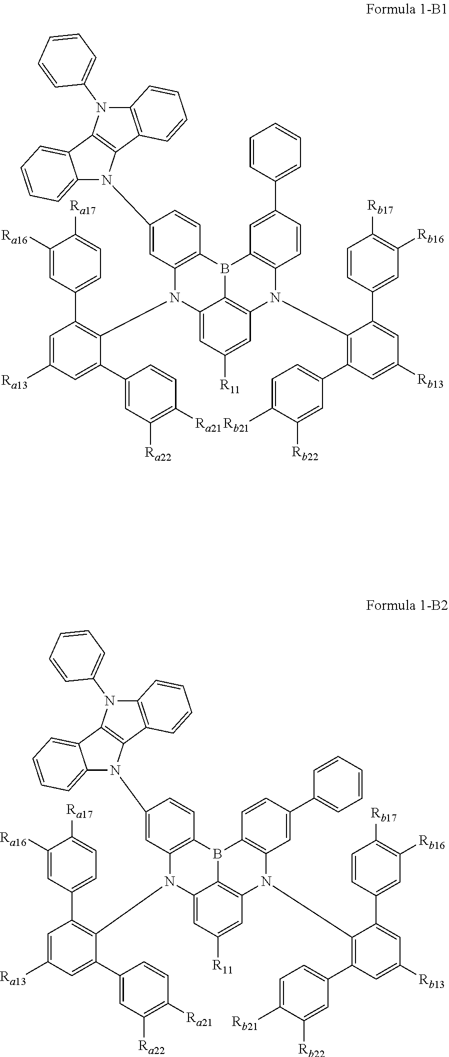

In Formula 1-B1 and Formula 1-B2, Rₐ₂₁, Rₐ₂₂, R_{b21}, and R_{b22} may each independently be hydrogen, deuterium, a substituted or unsubstituted alkyl group having 1 to 30 carbon atoms, or a substituted or unsubstituted aryl group having 6 to 30 ring-forming carbon atoms, and R₁₁, Rₐ₁₃, Rₐ₁₆, Rₐ₁₇, R_{b13}, R_{b16}, and R_{b17} may each be the same as defined in Formula 1-B.

In one or more embodiments, in Formula 1, a first biphenyl group including Rₐ₁ to Rₐ₉ and a second biphenyl group including R_{b1} to R_{b9} may each independently be represented by any one selected from among AB-1 to AB-12.

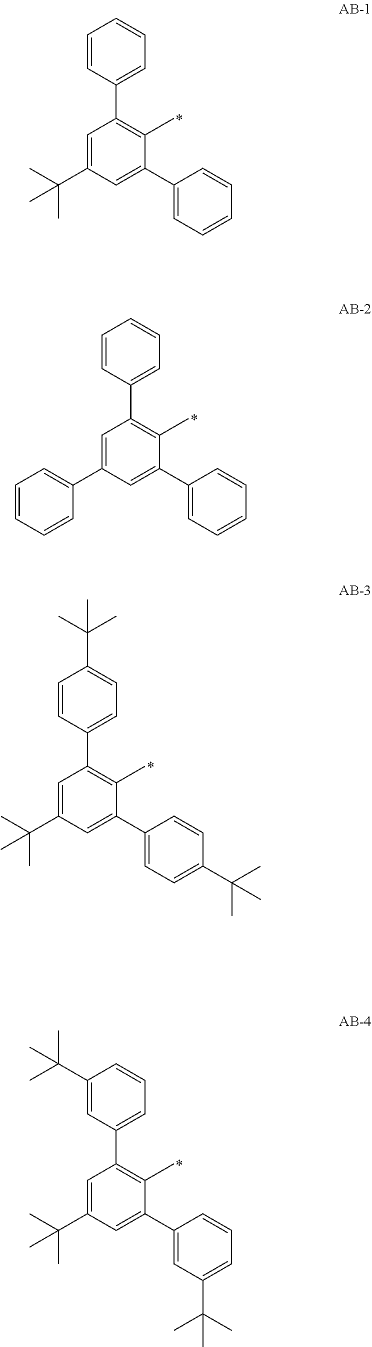

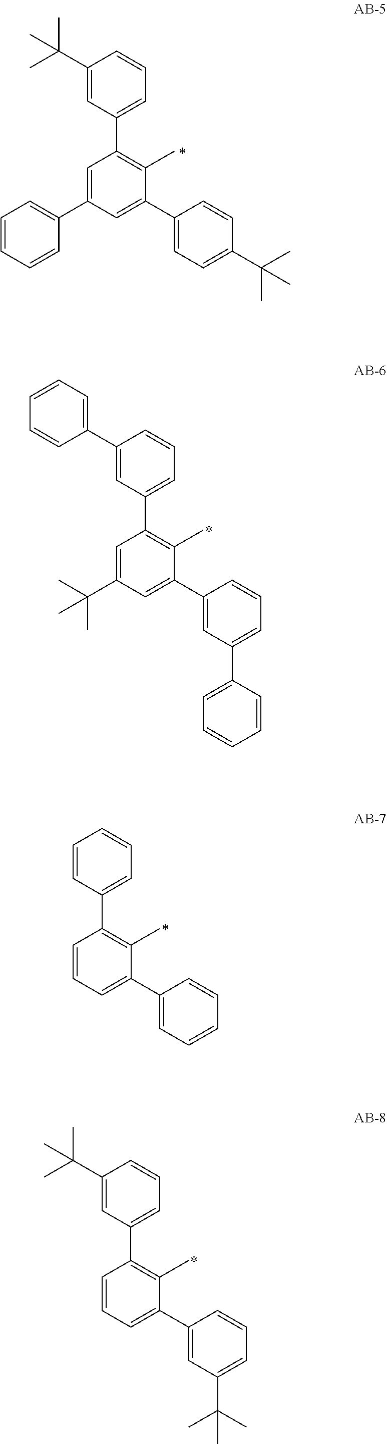

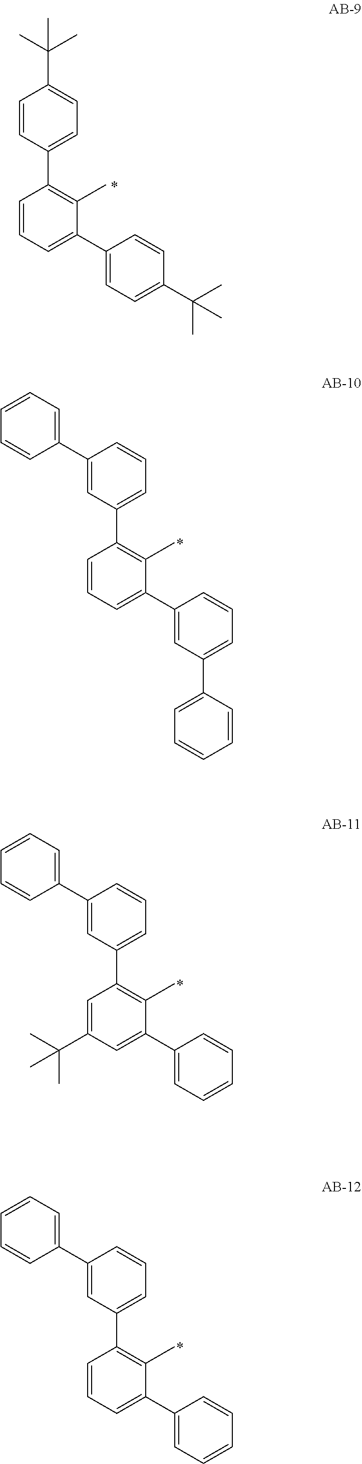

In one or more embodiments, in Formula 1, R₁ may be a substituted or unsubstituted t-butyl group or a substituted or unsubstituted phenyl group.

According to one or more embodiments of the disclosure, there is provided a fused polycyclic compound represented by Formula 1.

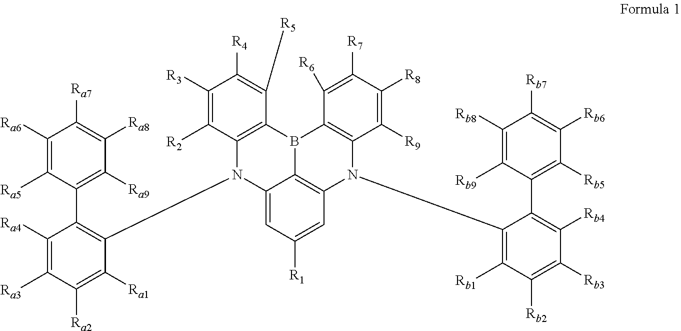

In Formula 1, at least one selected from among R₁ to R₉, Rₐ₁ to Rₐ₉, and R_{b1} to R_{b9} may be represented by Formula 2, and the rest thereof may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may form a ring by being bonded to an adjacent group.

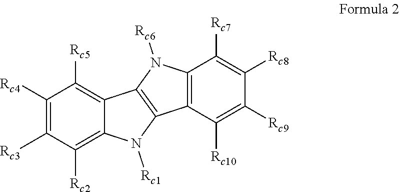

In Formula 2, any one selected from among R_{c1} to R_{c10} may be a position bonded to Formula 1, and the rest thereof may each independently be hydrogen, deuterium, or a substituted or unsubstituted aryl group having 6 to 30 ring-forming carbon atoms.

According to one or more embodiments of the present disclosure, an electronic device includes a base layer, a circuit layer on the base layer, a display element layer on the circuit layer and including a light emitting element, and a light control layer on the display element layer and including a quantum dot, wherein the light emitting element includes a first light emitting element configured to emit red light, a second light emitting element configured to emit green light, and a third light emitting element configured to emit blue light, wherein the third light emitting element includes a first electrode, a second electrode on the first electrode, and an emission layer between the first electrode and the second electrode and including a fused polycyclic compound represented by Formula 1.

### BRIEF DESCRIPTION OF DRAWINGS

The accompanying drawings are included to provide a further understanding of the present disclosure, and are incorporated in and constitute a part of this disclosure. The drawings illustrate example embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a plan view showing a display device according to one or more embodiments of the present disclosure;

FIG. 2 is a cross-sectional view showing a portion corresponding to the line I-I′ of the display device of FIG. 1;

FIG. 3 is a cross-sectional view schematically showing a light emitting element of one or more embodiments of the present disclosure;

FIG. 4 is a cross-sectional view schematically showing a light emitting element of one or more embodiments of the present disclosure;

FIG. 5 is a cross-sectional view schematically showing a light emitting element of one or more embodiments of the present disclosure;

FIG. 6 is a cross-sectional view schematically showing a light emitting element of one or more embodiments of the present disclosure;

FIG. 7 is a cross-sectional view schematically showing a light emitting element of one or more embodiments of the present disclosure;

FIG. 8 is a cross-sectional view showing a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure;

FIG. 11 is a cross-sectional view showing a display device according to one or more embodiments of the present disclosure; and

FIG. 12 is a view showing an interior of a vehicle in which display devices of one or more embodiments of the disclosure are arranged.

### DETAILED DESCRIPTION

The accompanying drawings are included to provide a further understanding of the present disclosure, and are incorporated in and constitute a part of this disclosure. The present disclosure may, however, be embodied and practiced in different forms and should not be construed as limited to example embodiments set forth herein. Rather, these example embodiments are provided so that this disclosure will be thorough and complete, and will fully convey the scope of the disclosure to those skilled in the art.

In this disclosure, it will be understood that if (e.g., when) an element (or a region, a layer, a portion, and/or the like) is referred to as being “on”, “connected to” or “coupled to” another element, it may be directly arranged on, connected or coupled to the other element, or one or more intervening elements may be arranged therebetween. In contrast, “directly on” may refer to that there are no additional layers, films, regions, plates, and/or like, between a layer, a film, a region, a plate, etc. and the other part. For example, “directly on” may refer to two layers or two members are arranged without utilizing an additional member such as an adhesive member therebetween.

Like reference numerals or symbols refer to like elements throughout the disclosure, and duplicative descriptions thereof may not be provided for conciseness. In the drawings, the thickness, the dimension ratio, and the size of the element may be exaggerated for effective description of the technical contents. As used herein, the term “and/or” or “or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

It will be understood that, although the terms “first,” “second,” and/or the like. may be used herein to describe one or more suitable elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed could be termed a second element, component, region, layer, or section without departing from the scope of the disclosure. Similarly, a second element, component, region, layer, or section may be termed a first element, component, region, layer, or section. As used herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

Also, terms of “below”, “on lower side”, “above”, “on upper side”, and/or the like may be used to describe the relationships of the elements illustrated in the drawings. These terms have relative concepts and are described on the basis of the directions indicated in the drawings.

It will be further understood that the terms “comprise(s)/comprising,” “include(s)/including,” and/or “have(has)/having”, when used in this disclosure, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the present disclosure, the term “substituted or unsubstituted” may refer to substituted or unsubstituted with at least one substituent selected from the group consisting of deuterium, a halogen, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” or “form a ring by being bonded to an adjacent group” may refer to that a group is bonded to an adjacent group to form a substituted or unsubstituted hydrocarbon ring or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic or polycyclic. In addition, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an adamantyl group, a 1-adamantyl group, a 2-adamantyl group, an isobornyl group, a bicycloheptyl group, and/or the like, but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, the hydrocarbon ring group refers to any functional group or substituent derived from an aliphatic hydrocarbon ring. The hydrocarbon ring group may be a saturated hydrocarbon ring group having 5 to 30 or 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

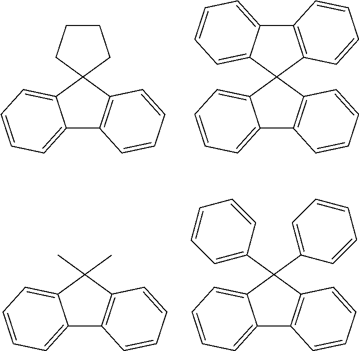

A heterocyclic group as used herein refers to any functional group or substituent derived from a ring containing at least one of B, O, N, P, Si, or S as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the present disclosure, a heteroaryl group may contain at least one of B, O, N, P, Si, or S as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the disclosure, the number of carbon atoms in a carbonyl group is not specifically limited, but may be 1 to 40, 1 to 30, or 1 to 20. For example, the carbonyl group may have the following structures, but embodiments of the present disclosure are not limited thereto.

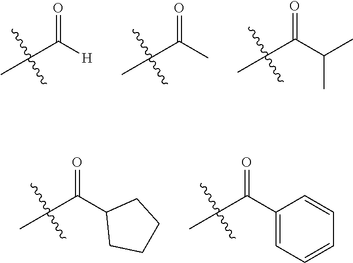

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

A boron group as used herein may refer to that a boron atom is bonded to the alkyl group or the aryl group defined above. The boron group includes an alkyl boron group and/or an aryl boron group. Examples of the boron group may include a dimethylboron group, a diethylboron group, a t-butylmethylboron group, a diphenylboron group, a phenylboron group, and/or the like, but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, and an arylamine group may be the same as the examples of the aryl group described above.

In the present disclosure, a direct linkage may refer to a single bond. In the disclosure,

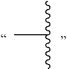

and “-*” each refer to a position to be connected.

Hereinafter, example embodiments of the present disclosure will be described in more detail with reference to the accompanying drawings.

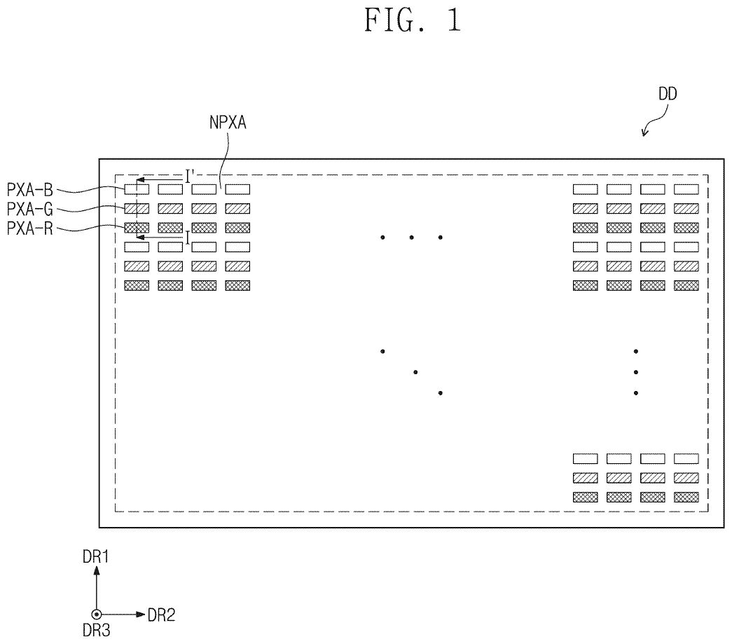

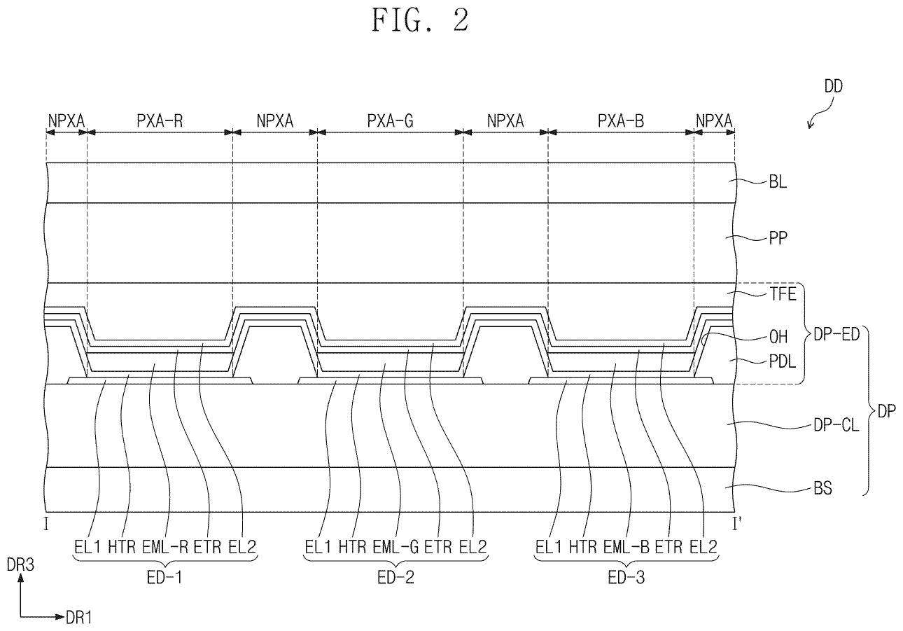

FIG. 1 is a plan view illustrating a display device DD according to one or more embodiments of the present disclosure. FIG. 2 is a cross-sectional view of the display device DD according to one or more embodiments. FIG. 2 is a cross-sectional view illustrating a part taken along the line I-I′ of the display device DD of FIG. 1. In this disclosure, an electronic device may be the display device DD or may include the display device DD.

The display device DD may include a display panel DP and an optical layer PP arranged on the display panel DP. The display panel DP may include light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display element layer DP-ED. The display element layer DP-ED may include a pixel defining film PDL, the light emitting elements ED-1, ED-2, and ED-3 arranged between respective portions of the pixel defining film PDL, and an encapsulation layer TFE arranged on the light emitting elements ED-1, ED-2, and ED-3.

The base layer BS may be a member which provides a base surface on which the display element layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. Each of the transistors may include a control electrode, an input electrode, and an output electrode. For example, in one or more embodiments, the circuit layer DP-CL may include switching transistor(s) and driving transistor(s) for driving the light emitting elements ED-1, ED-2, and ED-3 of the display element layer DP-ED.

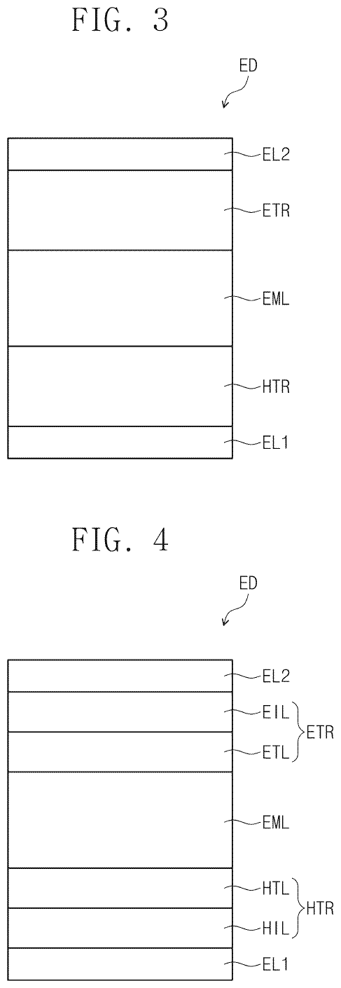

Each of the light emitting elements ED-1, ED-2, and ED-3 may have a structure of one of light emitting elements ED of embodiments according to FIGS. 3 to 7, which will be described in more detail later. Each of the light emitting elements ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates one or more embodiments in which the respective emission layers EML-R, EML-G, and EML-B of the light emitting elements ED-1, ED-2, and ED-3 are arranged in openings OH defined in the pixel defining film PDL, and the hole transport region HTR, the electron transport region ETR, and the second electrode EL2 are each provided as a common layer in the entire light emitting elements ED-1, ED-2, and ED-3. However, embodiments of the present disclosure are not limited thereto, for example, in one or more embodiments, the hole transport region HTR and the electron transport region ETR may each be provided by being patterned inside the openings OH defined in the pixel defining film PDL. For example, the hole transport region HTR, the respective emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers.

The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. In one or more embodiments, the encapsulation-organic film may include an acrylic-based compound, an epoxy-based compound, and/or the like. In one or more embodiments, the encapsulation-organic film may include a photopolymerizable organic material, but embodiments of the present disclosure are not particularly limited thereto.

The encapsulation layer TFE may be arranged on the second electrode EL2 and may be arranged filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from each other on a plane (e.g., in a plan view).

Each of the light emitting regions PXA-R, PXA-G, and PXA-B may be a region divided by the pixel defining film PDL. The non-light emitting areas NPXA may be areas between adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The respective emission layers EML-R, EML-G, and EML-B of the light emitting elements ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIG. 1 and FIG. 2, three light emitting regions PXA-R, PXA-G, and PXA-B, which emit red light, green light, and blue light, respectively, are exemplarily illustrated. For example, the display device DD of one or more embodiments may include a red light emitting region PXA-R, a green light emitting region PXA-G, and a blue light emitting region PXA-B that are separated from each other.

In the display device DD according to one or more embodiments, the plurality of light emitting elements ED-1, ED-2, and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range, or at least one light emitting element may be to emit a light beam in a wavelength range different from the others. For example, in one or more embodiments, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In addition, the red light emitting region PXA-R, the green light emitting region PXA-G, and the blue light emitting region PXA-B may be alternately arranged in this order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. The areas of the light emitting regions PXA-R, PXA-G, and PXA-B may refer to areas if (e.g., when) viewed on a plane defined by the first direction axis DR1 and the second direction axis DR2 (e.g., the areas in a plan view of the light emitting regions PXA-R, PXA-G, and PXA-B).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, in one or more embodiments, the arrangement form of the light emitting regions PXA-R, PXA-G, and PXA-B may be a pentile (PENTILE©) arrangement form (for example, an RGBG matrix, an RGBG structure, or an RGBG matrix structure) or a diamond (Diamond Pixel™) arrangement form (e.g., a display (e.g., an OLED display) containing red, blue, and green (RGB) light-emitting regions arranged in the shape of diamonds). PENTILE© is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but embodiments of the present disclosure are not limited thereto.

Hereinafter, FIG. 3 to FIG. 7 are each a cross-sectional view schematically showing a light emitting element according to one or more embodiments of the present disclosure. The light emitting element ED according to one or more embodiments may include a first electrode EL1, a hole transport region HTR, an emission layer EML, an electron transport region ETR, and a second electrode EL2, which are sequentially stacked in the stated order.

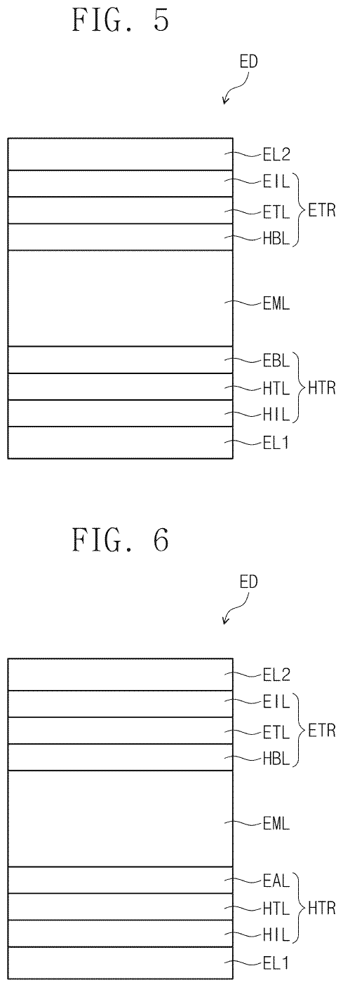

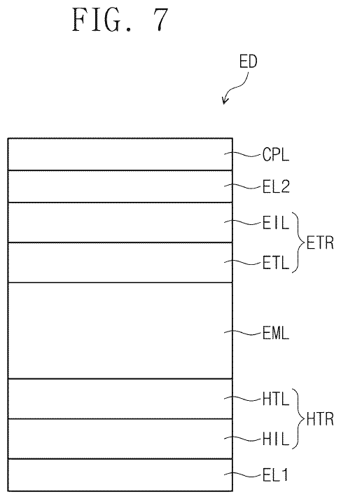

Compared to FIG. 3, FIG. 4 shows a cross-sectional view of a light emitting element ED of one or more embodiments in which the hole transport region HTR includes a hole injection layer HIL and a hole transport layer HTL, and the electron transport region ETR includes an electron injection layer EIL and an electron transport layer ETL. In addition, compared to FIG. 3, FIG. 5 shows a cross-sectional view of a light emitting element ED of one or more embodiments in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. Compared to FIG. 3, FIG. 6 shows a cross-sectional view of a light emitting element ED of one or more embodiments in which the hole transport region HTR includes a hole injection layer HIL, a hole transport layer HTL, and an emission-auxiliary layer EAL, and the electron transport region ETR includes an electron injection layer EIL, an electron transport layer ETL, and a hole blocking layer HBL. Compared to FIG. 4, FIG. 7 shows a cross-sectional view of a light emitting element ED of one or more embodiments including a capping layer CPL arranged on the second electrode EL2.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, in one or more embodiments, the first electrode EL1 may have a three-layer structure of ITO/Ag/ITO, but embodiments of the present disclosure are not limited thereto. In one or more embodiments, the first electrode EL1 may include one of the above-described metal materials, one or more combinations of at least two metal materials of the above-described metal materials, any oxide of the above-described metal materials, and/or the like. A thickness of the first electrode EL1 may be from about 700 ångström (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, or an emission-auxiliary layer EAL or an electron blocking layer EBL. A thickness of the hole transport region HTR may be, for example, from about 50 Å to about 15,000 Å. The emission-auxiliary layer EAL may also be referred to as a buffer layer.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and/or a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/emission-auxiliary layer EAL, a hole injection layer HIL/emission-auxiliary layer EAL, a hole transport layer HTL/emission-auxiliary layer EAL, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

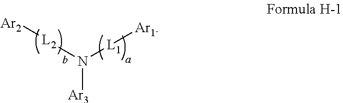

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a and/or b are each an integer of 2 or greater, a plurality of L₁'s and/or a plurality of L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

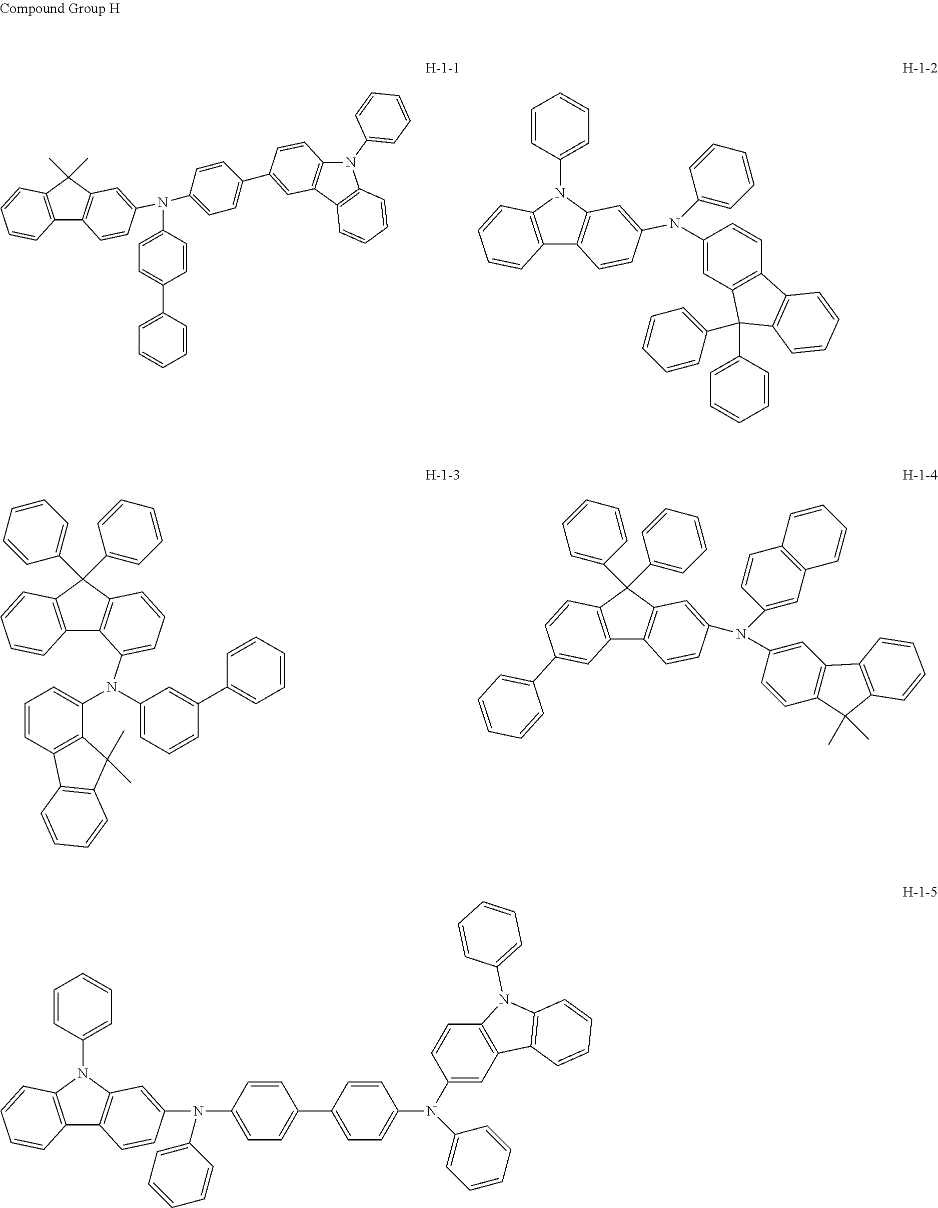 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

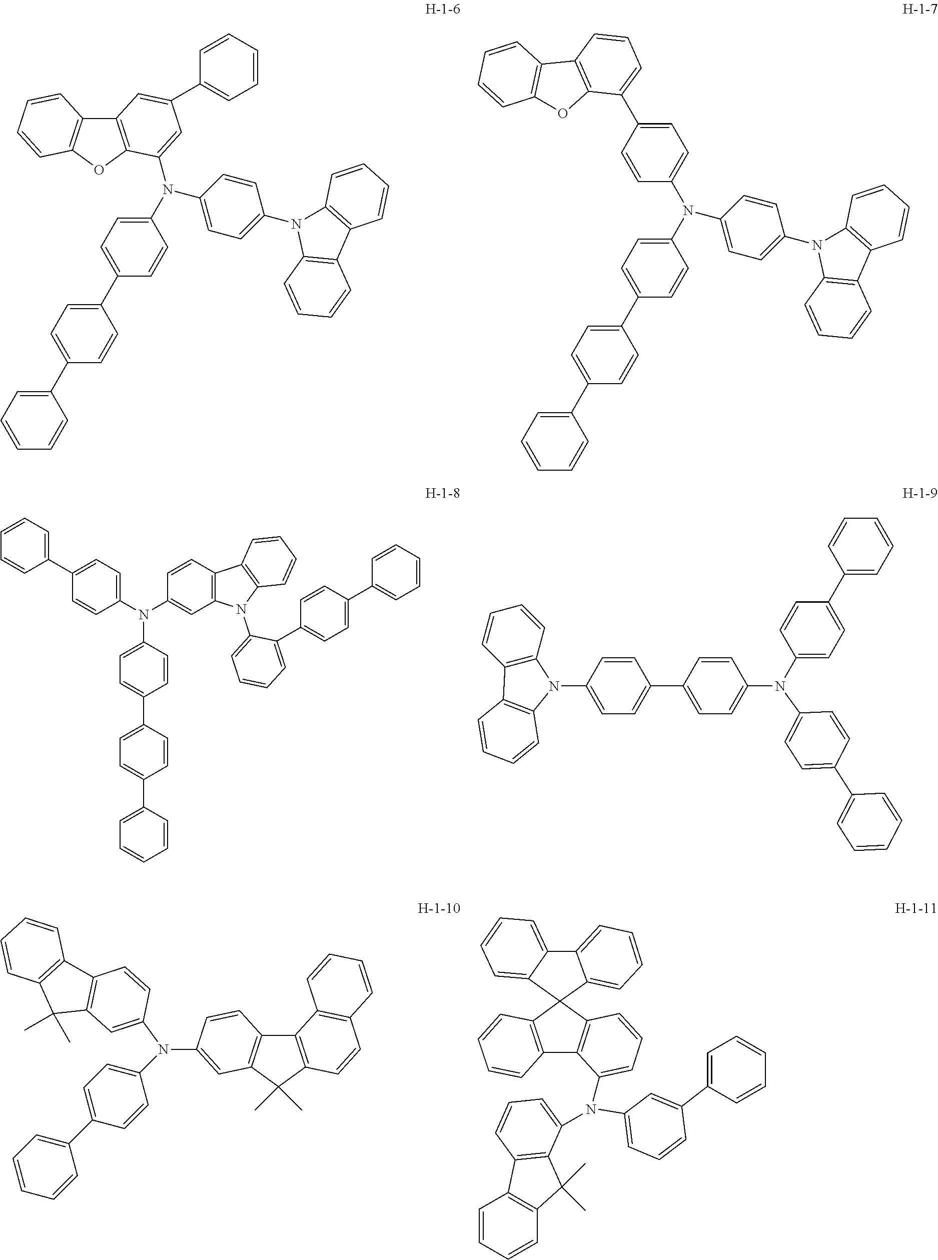

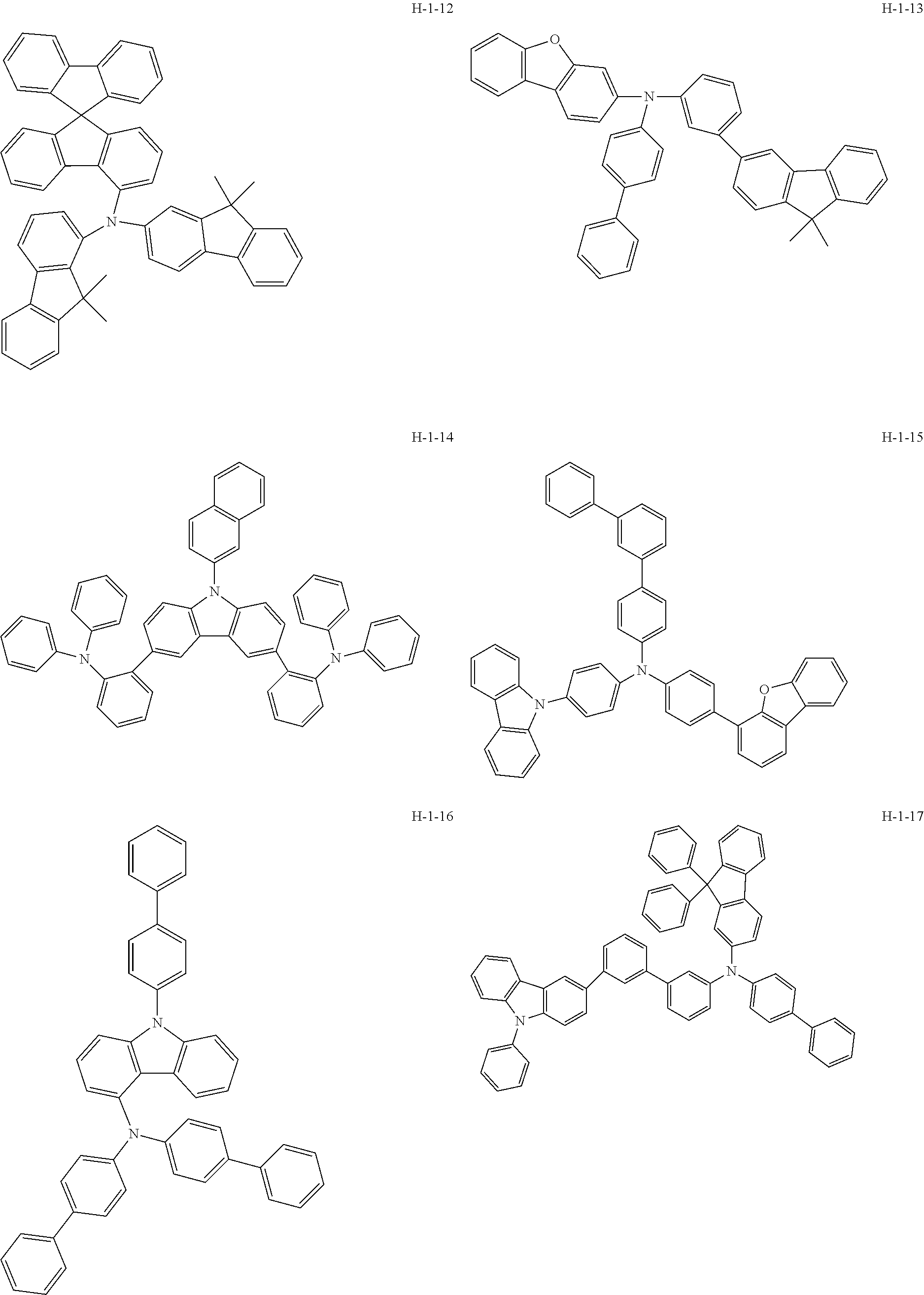

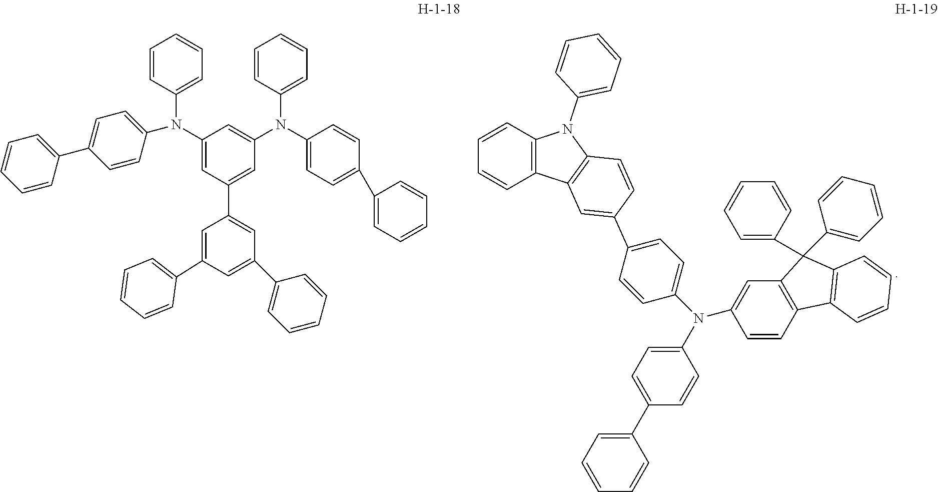 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include one or more selected from among a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In one or more embodiments, the hole transport region HTR may include one or more selected from among a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the above-described compounds of the hole transport region in at least one of a hole injection layer HIL, a hole transport layer HTL, an emission-auxiliary layer EAL, or an electron blocking layer EBL.

A thickness of the hole transport region HTR may be from about 100 Å to about 10,000 Å, for example, from about 100 Å to about 5,000 Å. If (e.g., when) the hole transport region HTR includes a hole injection layer HIL, the hole injection layer HIL may have, for example, a thickness of about 30 Å to about 1,000 Å. If (e.g., when) the hole transport region HTR includes a hole transport layer HTL, the hole transport layer HTL may have a thickness of about 30 Å to about 1,000 Å. For example, if (e.g., when) the hole transport region HTR includes an electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

In one or more embodiments, the hole transport region HTR may further include a charge generating material to increase conductivity (e.g., electric conductivity) in addition to the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in one or more embodiments, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F₄-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one of the emission-auxiliary layer EAL or the electron blocking layer EBL, in addition to the hole injection layer HIL and the hole transport layer HTL. The emission-auxiliary layer EAL may increase luminous efficiency by compensating for a resonance distance according to the wavelength of light emitted from the emission layer EML, and controlling hole charge balance. In addition, the emission-auxiliary layer EAL may also serve to prevent or reduce electron injection into the hole transport region HTR. As for materials included in the emission-auxiliary layer EAL, materials which may be included in the hole transport region HTR may be used. The electron blocking layer EBL is a layer serving to prevent or reduce electron injection from the electron transport region ETR to the hole transport region HTR.

In one or more embodiments, the emission layer EML may include a first compound of one or more embodiments. The emission layer EML according to one or more embodiments may further include at least one selected from among second to fourth compounds. The second compound may include a 3-ring fused ring containing a nitrogen atom as a ring-forming atom. The third compound may include a hexagonal ring group (e.g., six-membered ring group) containing at least one nitrogen atom as a ring-forming atom. The fourth compound may include an organometallic complex. The second to fourth compounds will be discussed in more detail later.

In the present disclosure, the first compound may be referred to as a fused polycyclic compound of one or more embodiments. The fused polycyclic compound of one or more embodiments may include, as a central structure, a 5-ring fused ring including two nitrogen atoms and one boron atom as ring-forming atoms. In addition, the fused polycyclic compound of one or more embodiments may include an indoloindole moiety and a biphenyl moiety bonded directly or indirectly to the central structure. Consequently, the fused polycyclic compound of one or more embodiments may have enhanced multiple resonance properties, and may prevent or reduce intermolecular interactions, thereby reducing (or preventing) Dexter energy transfer. In one or more embodiments, the light emitting element ED including a fused polycyclic compound of one or more embodiments may exhibit excellent or suitable luminous efficiency. In addition, the light emitting element ED including the fused polycyclic compound of one or more embodiments may exhibit properties of a low driving voltage and a long lifespan.

The light emitting element ED of one or more embodiments may include the fused polycyclic compound of one or more embodiments, for example, as the first compound. The fused polycyclic compound of one or more embodiments may be represented by Formula 1.

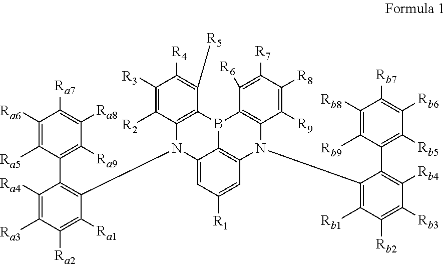

In Formula 1, at least one selected from among R₁ to R₉, Rₐ₁ to Rₐ₉, and R_{b1} to R_{b9} may be represented by Formula 2. Formula 2 may represent an indoloindole moiety. For example, in one or more embodiments, at least one selected from among R₃, R₄, R₇, and R₈ may be represented by Formula 2. In one or more embodiments, one group or two groups selected from among R₃, R₄, R₇, and R₈ may be represented by Formula 2.

In Formula 1, the rest of R₁ to R₉, Rₐ₁ to Rₐ₉, and R_{b1} to R_{b9}, which are not represented by Formula 2, may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may form a ring by being bonded to an adjacent group. For example, in one or more embodiments, the rest of R₁ to R₉, Rₐ₁ to Rₐ₉, and R_{b1} to R_{b9}, which are not represented by Formula 2, may each independently be hydrogen, a substituted or unsubstituted t-butyl group, or a substituted or unsubstituted phenyl group. In one or more embodiments, R₁ may be a substituted or unsubstituted t-butyl group or a substituted or unsubstituted phenyl group.

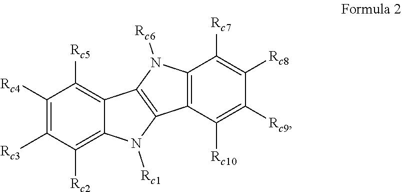

In Formula 2, any one selected from among R₁₁ to R_{c10} is a position bonded to Formula 1, e.g., bonded to a portion of Formula 1 that is not represented by Formula 2, and the rest thereof may each independently be hydrogen, deuterium, or a substituted or unsubstituted aryl group having 6 to 30 ring-forming carbon atoms. For example, in one or more embodiments, among R_{c1} to R_{c10}, one selected from among R_{c1} to R_{c6} may be a position bonded to Formula 1, and the rest thereof may each independently be hydrogen or a substituted or unsubstituted phenyl group. In one or more embodiments, among R_{c1} to R_{c10}, R_{c1} or R_{c6} may be a position bonded to Formula 1, and the rest thereof may each independently be hydrogen or a substituted or unsubstituted phenyl group.

In one or more embodiments, Formula 2 may be represented by Formula 2-A. Formula 2-A may represent embodiments in which R_{c1} in Formula 2 is a position bonded to Formula 1, and R_{c6} is an unsubstituted phenyl group.

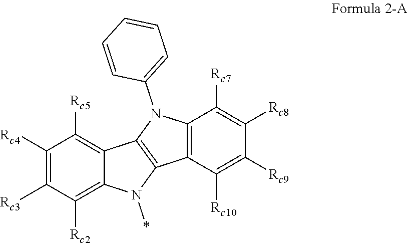

In Formula 2-A, “-*” is a position bonded to Formula 1. In Formula 2-A, the same contents as those described with reference to Formula 2 may be applied to R_{c2} to R_{c5} and R_{c7} to R_{c10}. In other words, R_{c2} to R_{c5} and R_{c7} to R_{c10} in Formula 2-A may each independently be the same as defined in Formula 2.

In one or more embodiments, in Formula 1, a first biphenyl group including Rₐ₁ to Rₐ₉ and a second biphenyl group including R_{b1} to R_{b9} may each independently be represented by any one selected from among AB-1 to AB-12. For example, in one or more embodiments, the first biphenyl group and the second biphenyl group may be the same. In one or more embodiments, the first biphenyl group and the second biphenyl group may be different from each other. In AB-1 to AB-12, “-*” is a position bonded to a nitrogen atom of Formula 1.

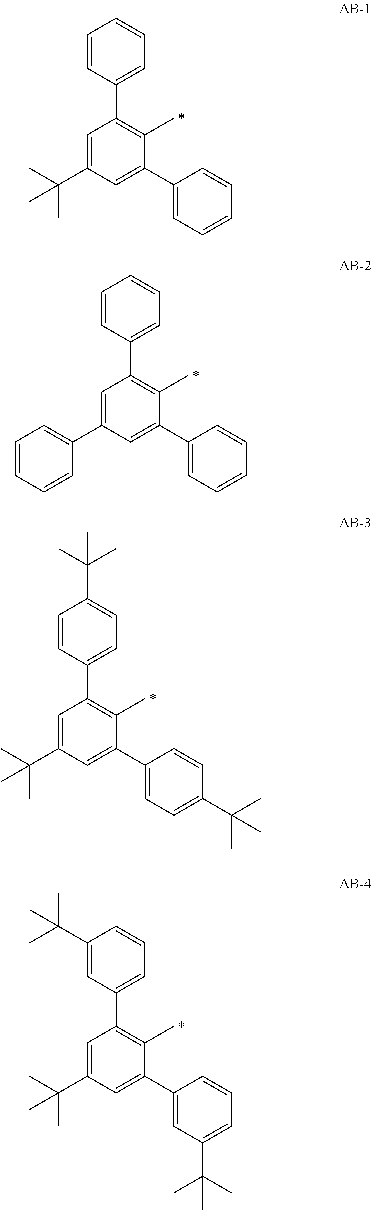

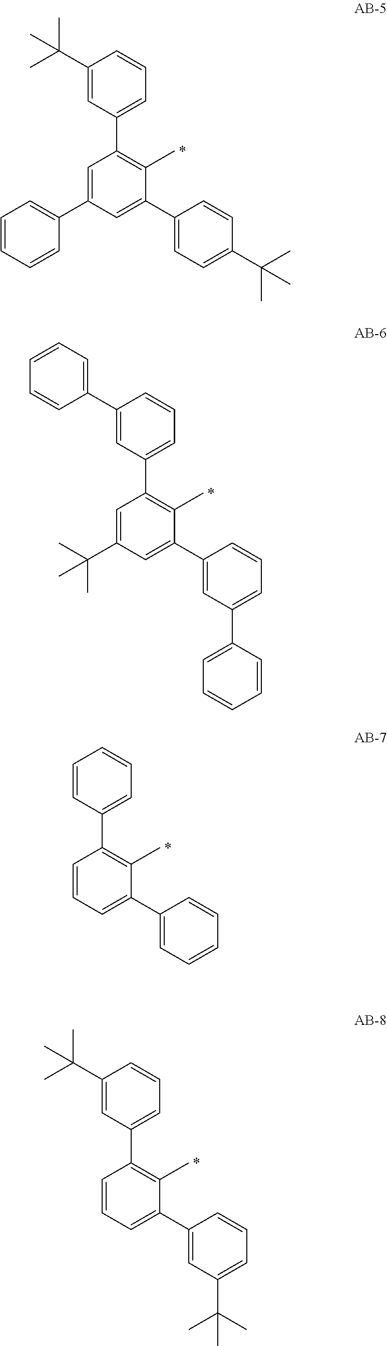

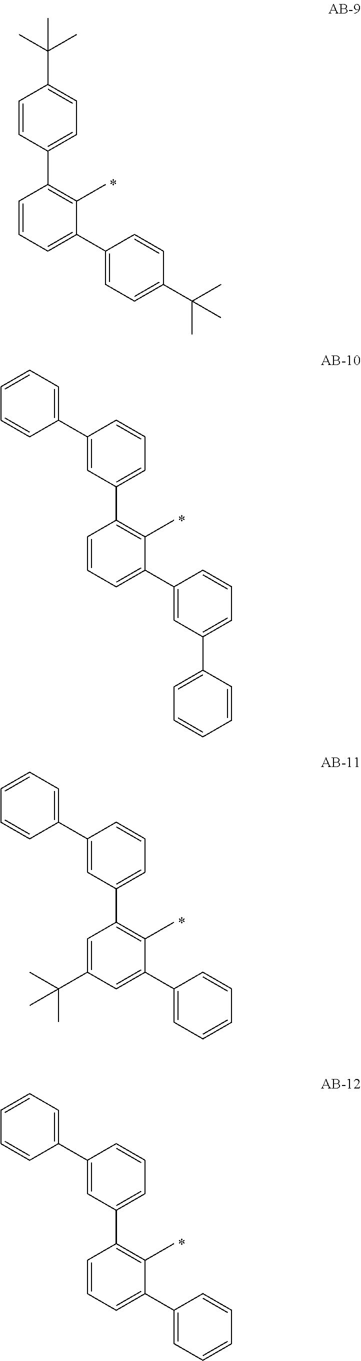

In one or more embodiments, the fused polycyclic compound represented by Formula 1 may be represented by Formula 1-A or Formula 1-B. Formula 1-A may represent embodiments in which R₃ and R₈ in Formula 1 are each represented by Formula 2, and R_{c1} in Formula 2 is a position bonded to Formula 1. Formula 1-B may represent embodiments in which R₃ in Formula 1 is represented by Formula 2, and R_{c1} in Formula 2 is a position bonded to Formula 1.

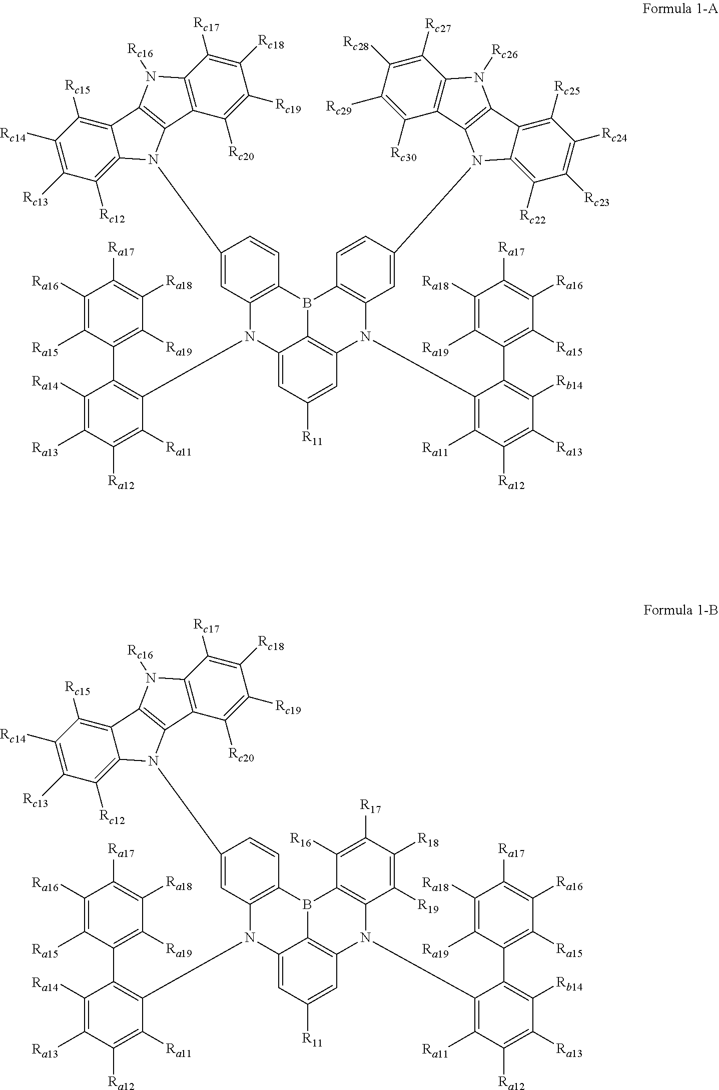

In Formula 1-A, R_{c22} to R_{c30} may each independently be hydrogen, deuterium, or a substituted or unsubstituted aryl group having 6 to 30 ring-forming atoms. For example, in one or more embodiments, R_{c22} to R_{c30} may each independently be hydrogen or a substituted or unsubstituted phenyl group.

In Formula 1-B, R₁₆ to R₁₉ may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may form a ring by being bonded to an adjacent group. For example, in one or more embodiments, R₁₆ to R₁₉ may each independently be a hydrogen atom or a substituted or unsubstituted phenyl group.

In Formula 1-A and Formula 1-B, R₁₁, Rₐ₁₁ to Rₐ₁₉, and R_{b11} to R_{b19} may each independently be hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may form a ring by being bonded to an adjacent group. R_{c12} to R_{c20} may each independently be hydrogen, deuterium, or a substituted or unsubstituted aryl group having 6 to 30 ring-forming carbon atoms.

For example, in one or more embodiments, Rₐ₁₁ to Rₐ₁₉ and R_{b11} to R_{b19} may each independently be a hydrogen atom, a substituted or unsubstituted t-butyl group, or a substituted or unsubstituted phenyl group. R_{c12} to R_{c20} may each independently be hydrogen or a substituted or unsubstituted phenyl group. R₁₁ may be an unsubstituted t-butyl group or an unsubstituted phenyl group. For example, in one or more embodiments, a biphenyl group including Rₐ₁₁ to Rₐ₁₉ corresponds to the first biphenyl group described above, and may be represented by any one selected from among AB-1 to AB-12 described above. A biphenyl group including R_{b11} to R_{b19} corresponds to the second biphenyl group described above, and may be represented by any one selected from among AB-1 to AB-12 described above.

In one or more embodiments, the fused polycyclic compound represented by Formula 1-A may be represented by Formula 1-A1. Formula 1-A1 may represent embodiments in which Rₐ₁₁, R_{b11}, R_{c16}, and R_{c26} in Formula 1-A may each independently be a substituted or unsubstituted phenyl group.

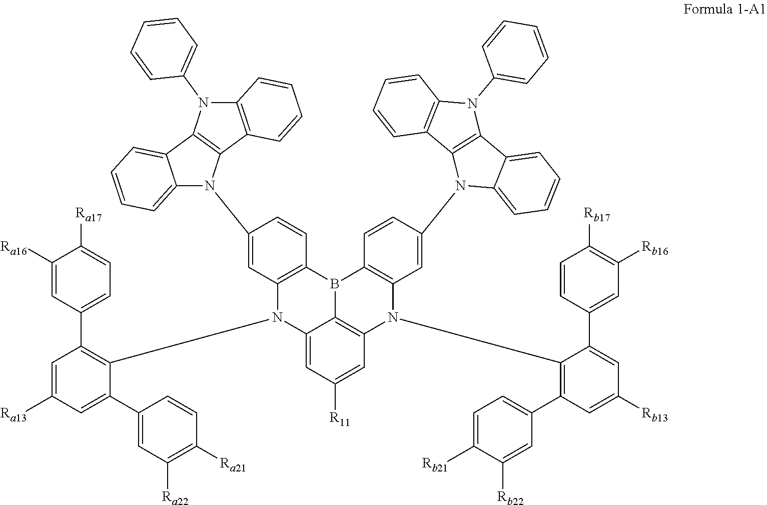

In Formula 1-A1, the same contents as those described with reference to Formula 1-A may be applied to R₁₁, Rₐ₁₃, Rₐ₁₆, Rₐ₁₇, R_{b13}, R_{b16}, and R_{b17}, in other words, R₁₁, Rₐ₁₃, Rₐ₁₆, Rₐ₁₇, R_{b13}, R_{b16}, and R_{b17} in Formula 1-A1 may each independently be the same as defined in Formula 1-A. In Formula 1-A1, Rₐ₂₁, Rₐ₂₂, R_{b21}, and R_{b22} may each independently be hydrogen, deuterium, a substituted or unsubstituted alkyl group having 1 to 30 carbon atoms, or a substituted or unsubstituted aryl group having 6 to 30 ring-forming carbon atoms. For example, in one or more embodiments, Rₐ₂₁, Rₐ₂₂, R_{b21}, and R_{b22} may each independently be hydrogen, a substituted or unsubstituted t-butyl group, or a substituted or unsubstituted phenyl group. A terphenyl group including Rₐ₁₃, Rₐ₁₆, Rₐ₁₇, Rₐ₂₁, and Rₐ₂₂ may be represented by any one selected from among AB-1 to AB-12 described above. A terphenyl group including R_{b13}, R_{b16}, R_{b17}, R_{b21}, and R_{b22} may be represented by any one selected from among AB-1 to AB-12 described above.

In one or more embodiments, the fused polycyclic compound represented by Formula 1-B may be represented by Formula 1-B1 or Formula 1-B2. Formula 1-B1 may represent embodiments in which Rₐ₁₁, R_{b11}, R_{c16}, and R₁₇ in Formula 1-B may each independently be a substituted or unsubstituted phenyl group. Formula 1-B2 may represent embodiments in which Rₐ₁₁, R_{b11}, R_{c16}, and R₁₈ in Formula 1-B may each independently be a substituted or unsubstituted phenyl group.

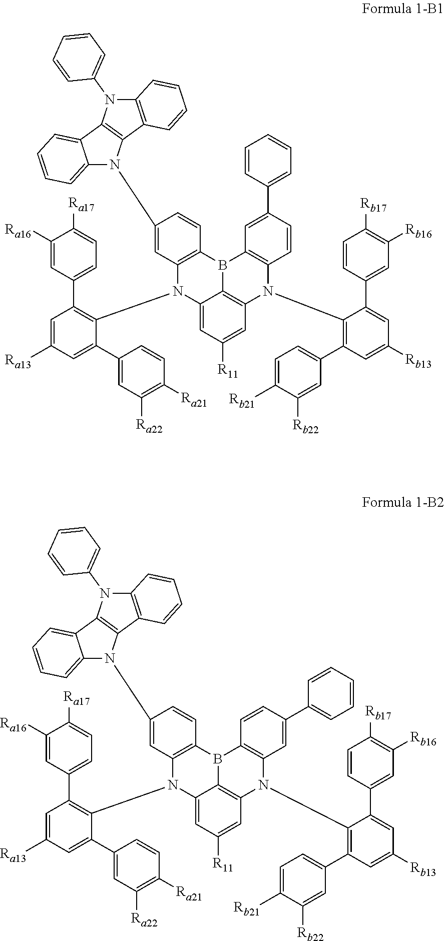

In Formula 1-B1 and Formula 1-B2, the same contents as those described with reference to Formula 1-B may be applied to R₁₁, Rₐ₁₃, Rₐ₁₆, Rₐ₁₇, R_{b13}, R_{b16}, and R_{b17}, in other words, R₁₁, Rₐ₁₃, Rₐ₁₆, Rₐ₁₇, R_{b13}, R_{b16}, and R_{b17} in Formula 1-B1 and Formula 1-B2 may each independently be the same as defined in Formula 1-B. In Formulas 1-B1 and Formula 1-B2, Rₐ₂₁, Rₐ₂₂, R_{b21}, and R_{b22} may each independently be hydrogen, deuterium, a substituted or unsubstituted alkyl group having 1 to 30 carbon atoms, or a substituted or unsubstituted aryl group having 6 to 30 ring-forming carbon atoms. For example, in one or more embodiments, Rₐ₂₁, Rₐ₂₂, R_{b21}, and R_{b22} may each independently be hydrogen, a substituted or unsubstituted t-butyl group, or a substituted or unsubstituted phenyl group. A terphenyl group including Rₐ₁₃, Rₐ₁₆, Rₐ₁₇, Rₐ₂₁, and Rₐ₂₂ may be represented by any one selected from among AB-1 to AB-12 described above. A terphenyl group including R_{b13}, R_{b16}, R_{b17}, R_{b21}, and R_{b22} may be represented by any one selected from among AB-1 to AB-12 described above.

The fused polycyclic compound represented by Formula 1 may be any one selected from among compounds of Compound Group 1. The fused polycyclic compound of one or more embodiments may be any one selected from among the compounds of Compound Group 1. The light emitting element ED of one or more embodiments may include at least one selected from among the compounds of Compound Group 1.

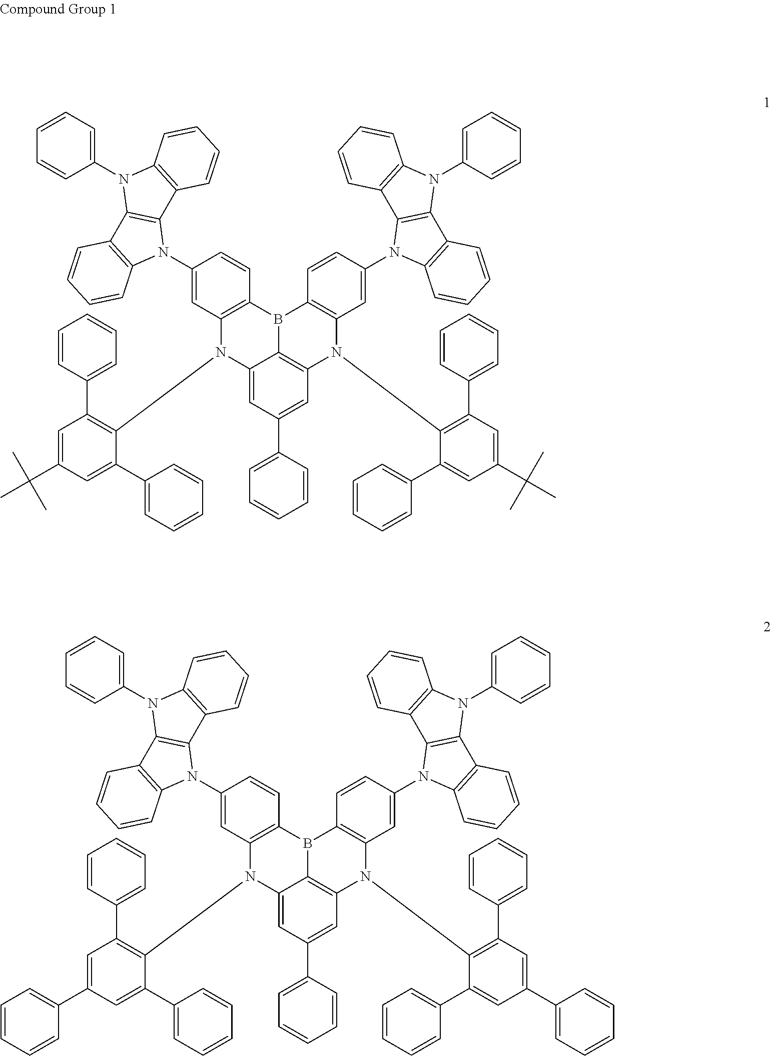 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(-c5ccccc5)cc2c43)c(-c2ccccc2)c1 ; c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cc(-c6ccccc6)cc5-c5ccccc5)c5cc(-c6ccccc6)cc3c54)c(-c3ccccc3)c2)cc1]

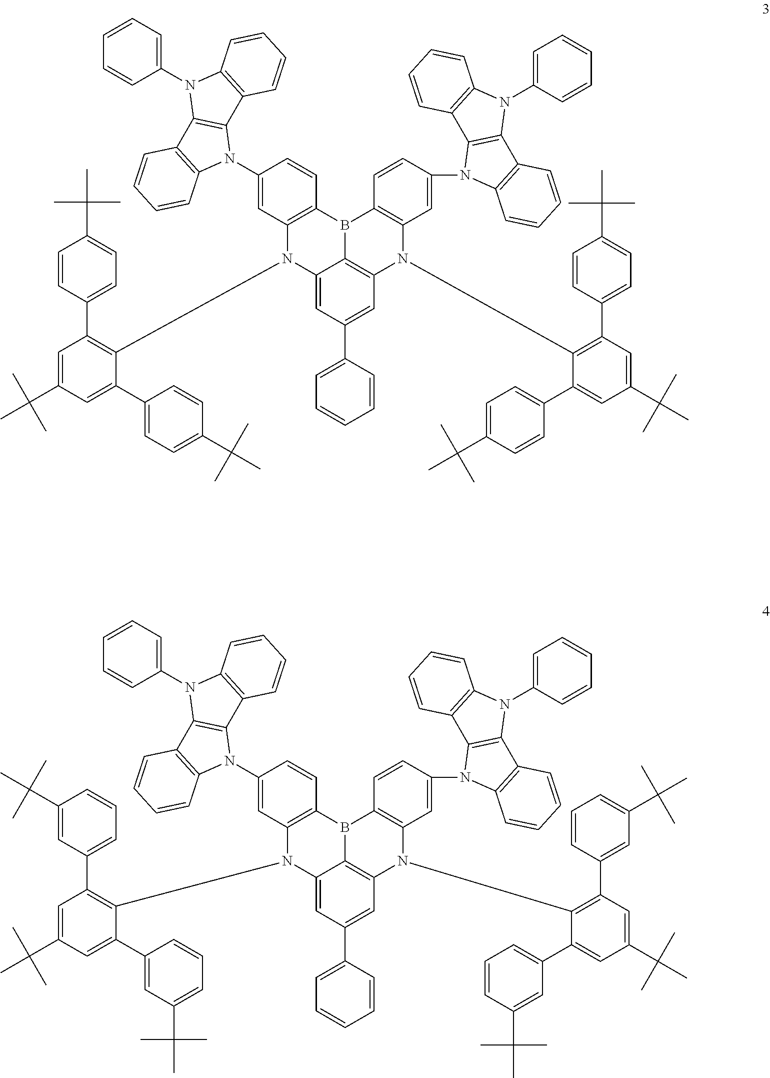

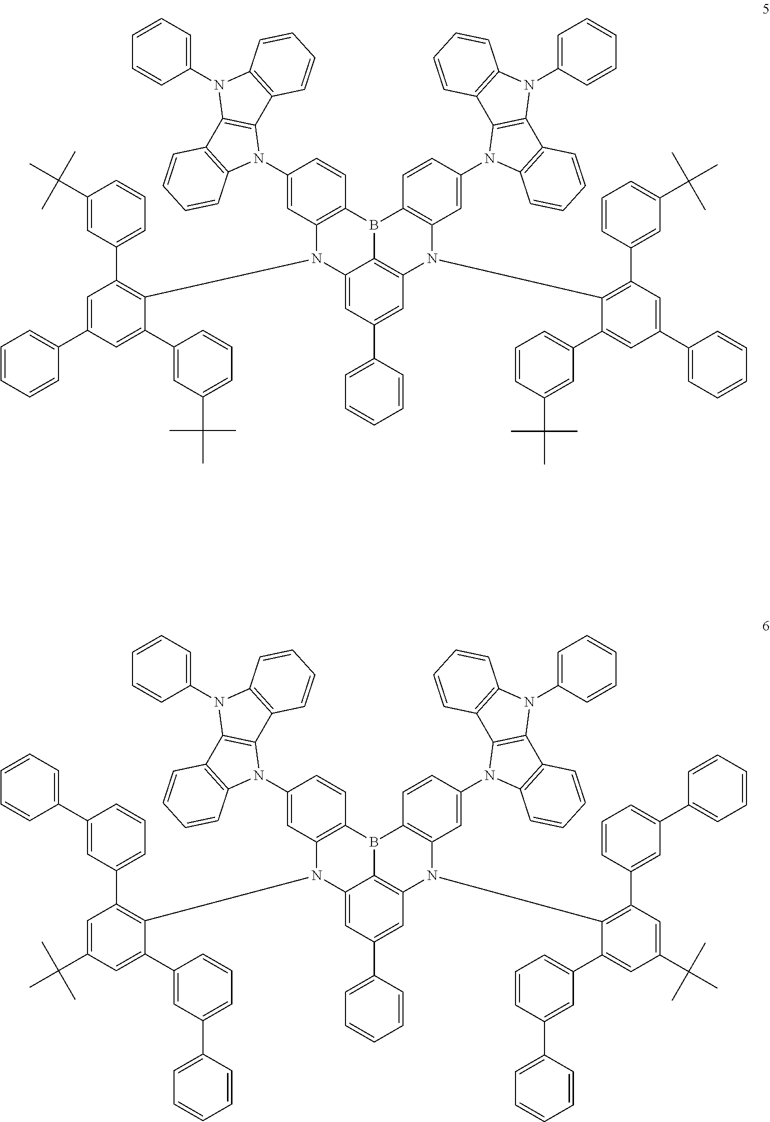 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(-c5ccccc5)cc2c43)c1 ; CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1]

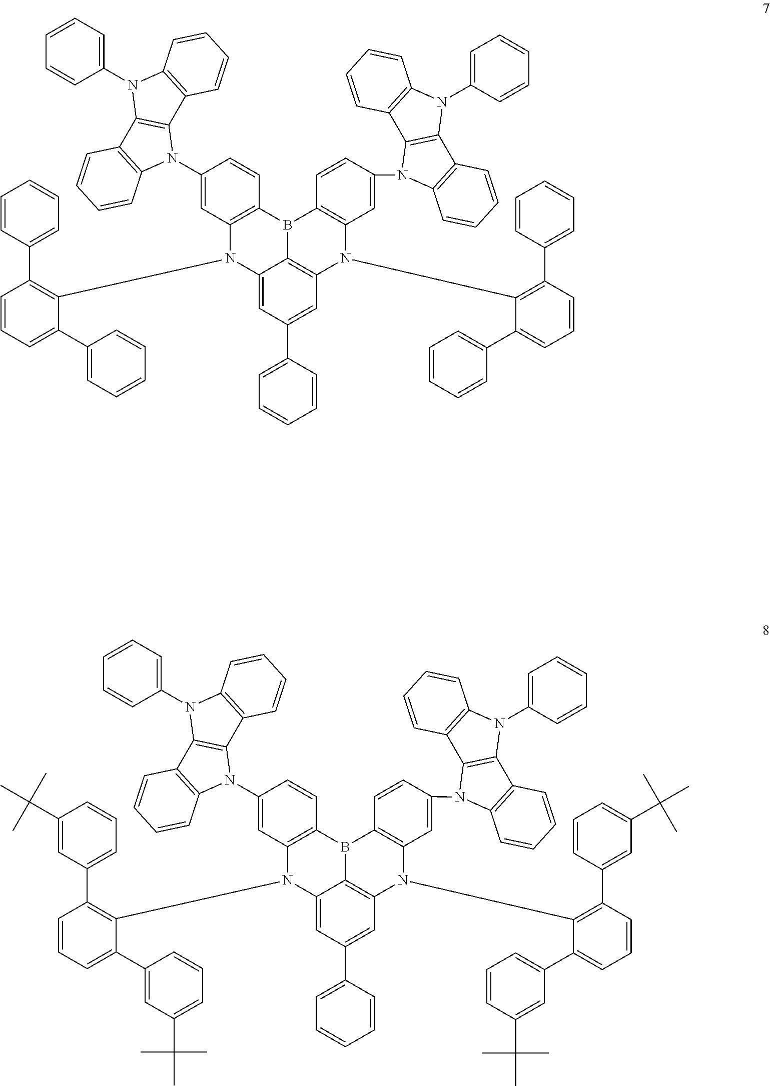 [SMILES: c1ccc(-c2cc3c4c(c2)N(c2c(-c5ccccc5)cccc2-c2ccccc2)c2cc(-n5c6ccccc6c6c5c5ccccc5n6-c5ccccc5)ccc2B4c2ccc(-n4c5ccccc5c5c4c4ccccc4n5-c4ccccc4)cc2N3c2c(-c3ccccc3)cccc2-c2ccccc2)cc1 ; CC(C)(C)c1cccc(-c2cccc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cccc4-c4cccc(C(C)(C)C)c4)c4cc(-c5ccccc5)cc2c43)c1]

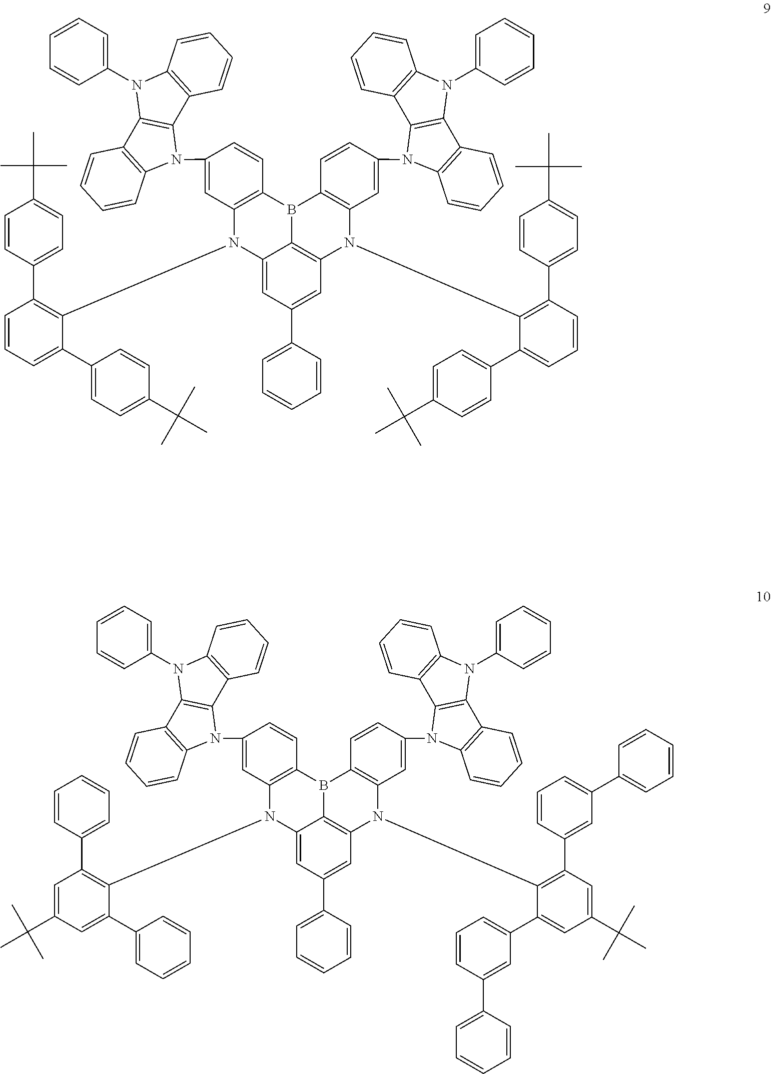

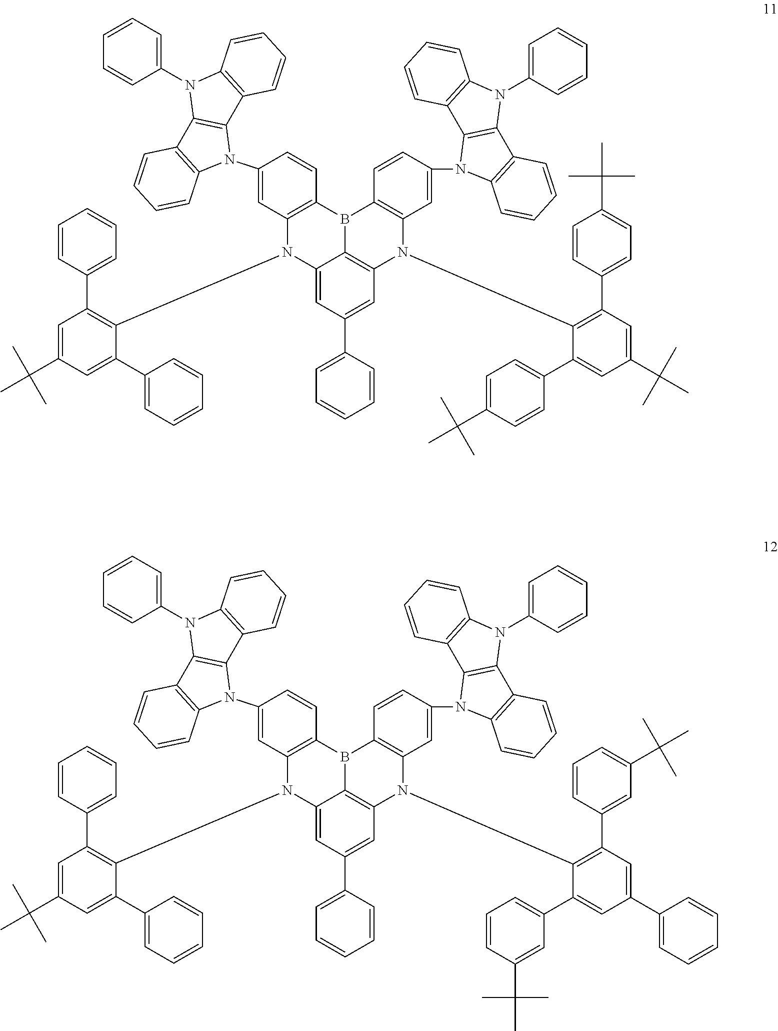

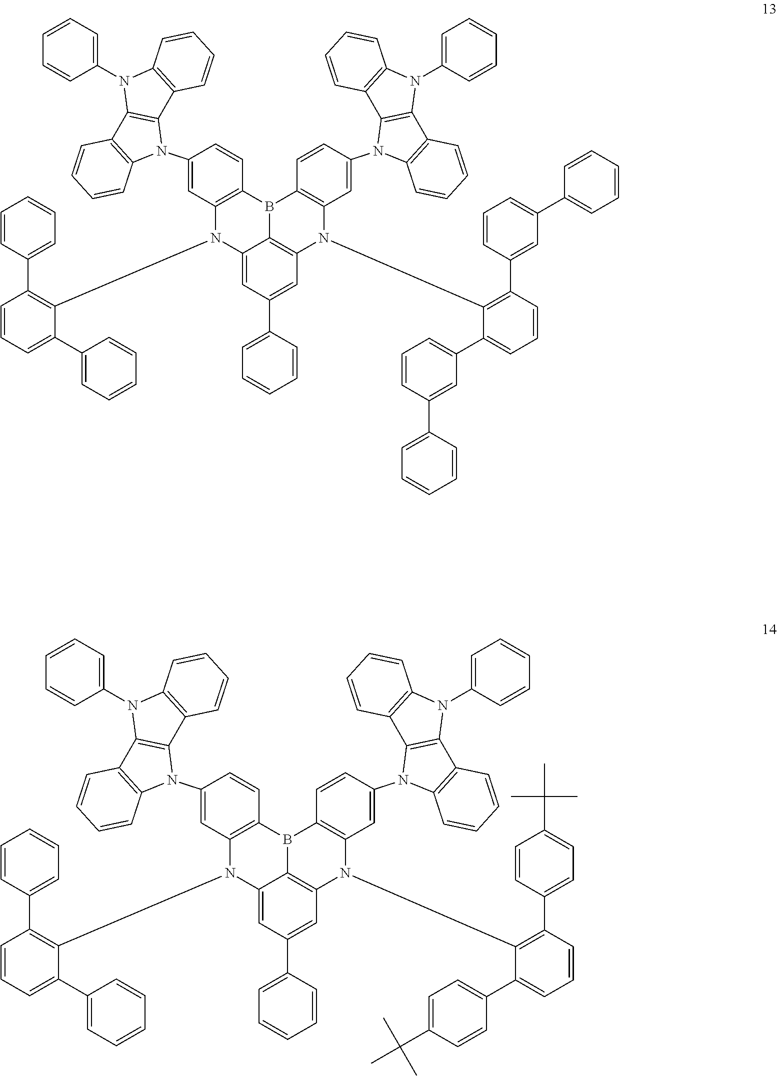 [SMILES: c1ccc(-c2cccc(-c3cccc(-c4cccc(-c5ccccc5)c4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c2)cc1 ; CC(C)(C)c1ccc(-c2cccc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cccc4-c4ccccc4)c4cc(-c5ccccc5)cc2c43)cc1]

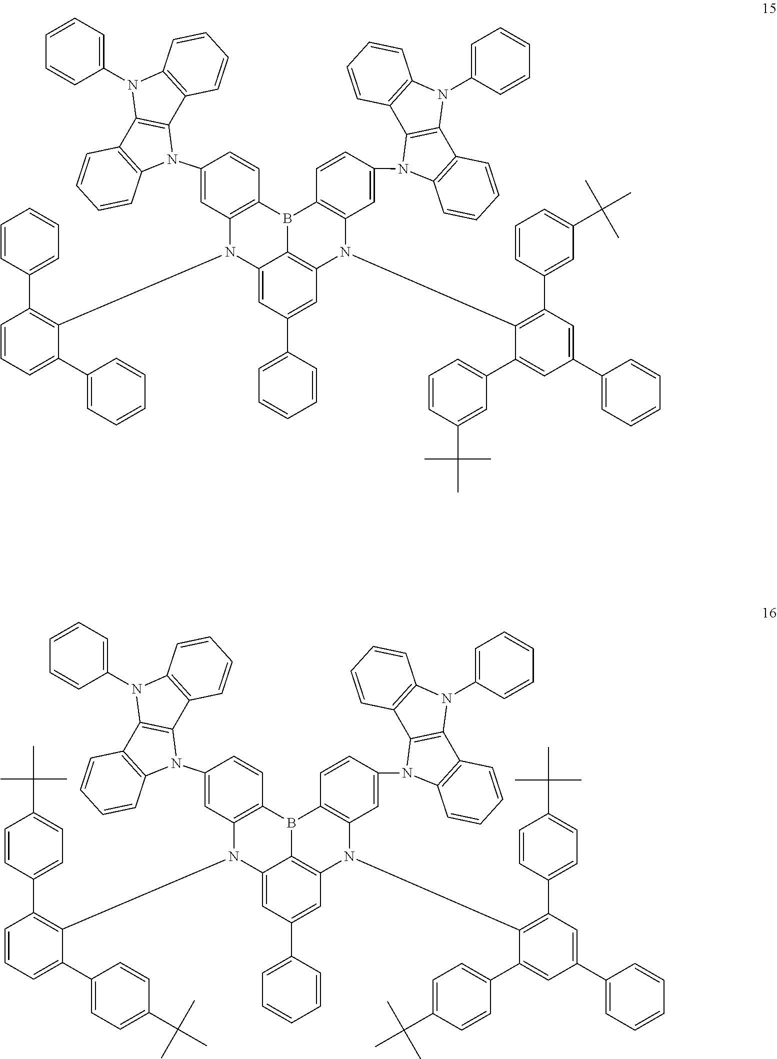 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cccc4-c4ccccc4)c4cc(-c5ccccc5)cc2c43)c1 ; CC(C)(C)c1ccc(-c2cccc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccc(C(C)(C)C)cc5)cc(-c5ccccc5)cc4-c4ccc(C(C)(C)C)cc4)c4cc(-c5ccccc5)cc2c43)cc1]

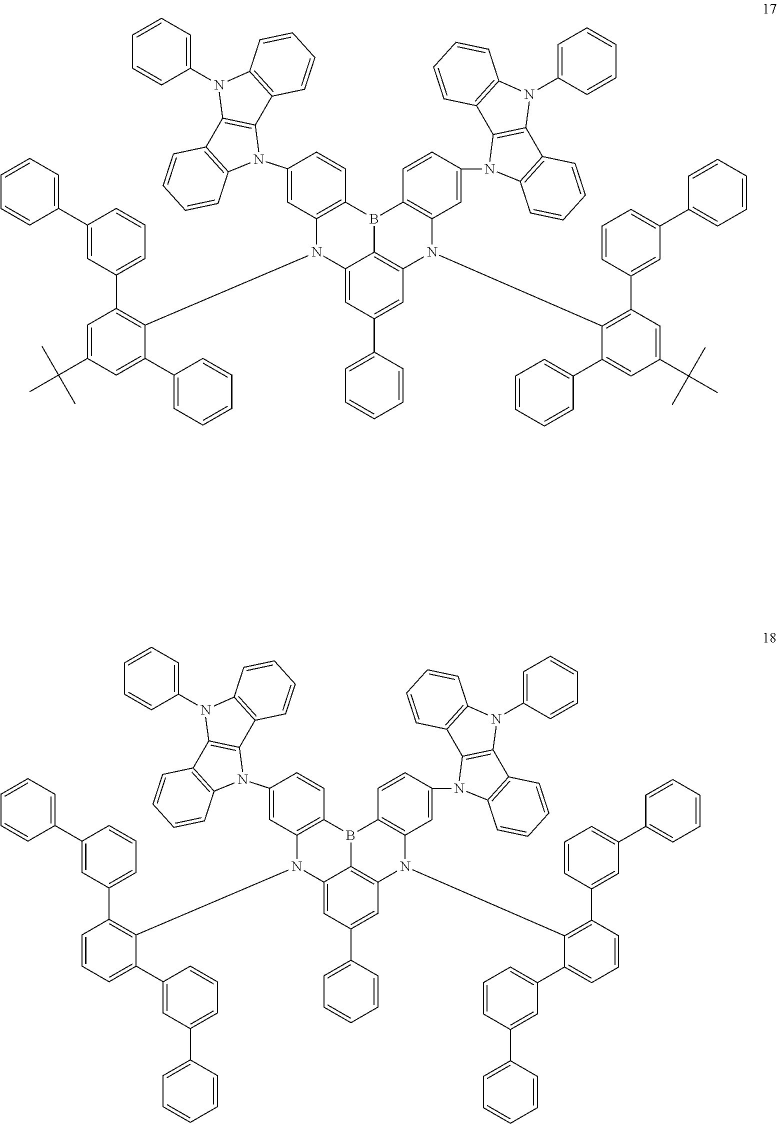 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(-c5ccccc5)cc2c43)c(-c2cccc(-c3ccccc3)c2)c1 ; c1ccc(-c2cccc(-c3cccc(-c4cccc(-c5ccccc5)c4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6cccc(-c7ccccc7)c6)cccc5-c5cccc(-c6ccccc6)c5)c5cc(-c6ccccc6)cc3c54)c2)cc1]

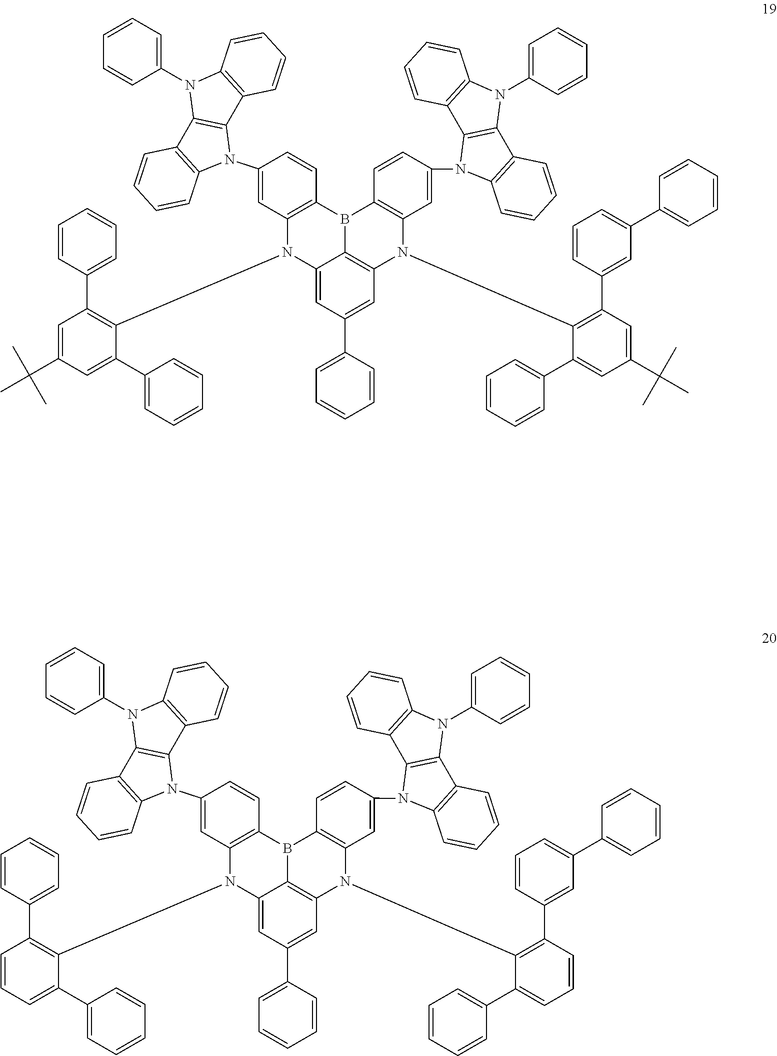 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(-c5ccccc5)cc2c43)c(-c2ccccc2)c1 ; c1ccc(-c2cccc(-c3cccc(-c4ccccc4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c2)cc1]

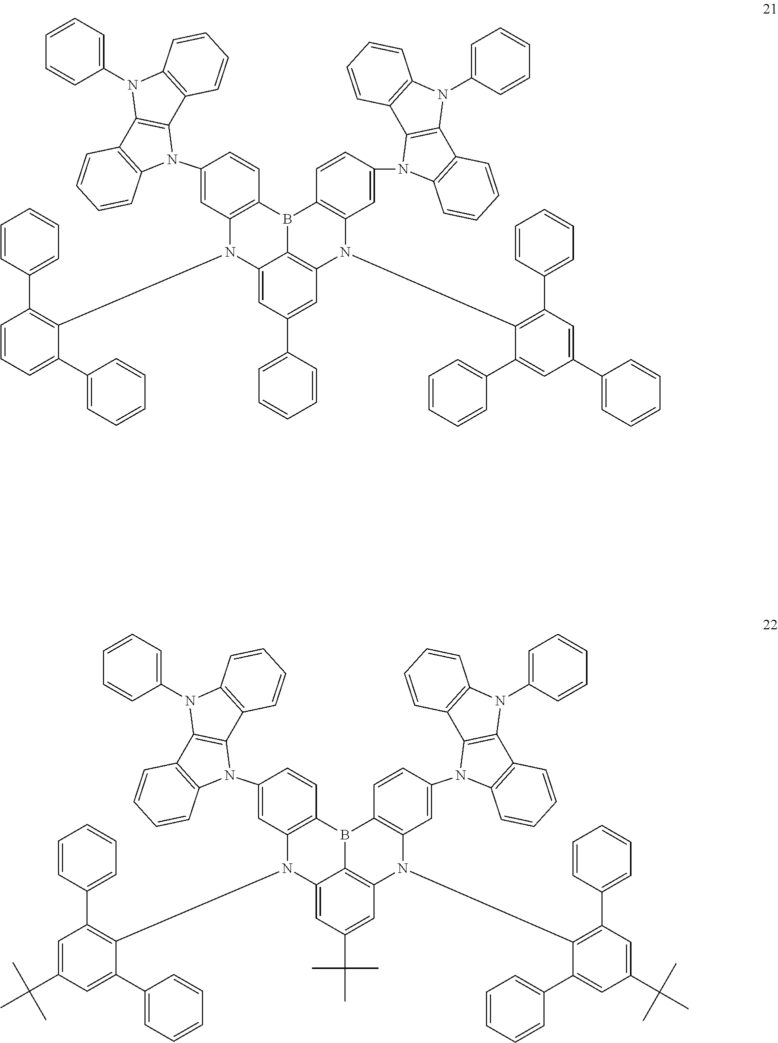 [SMILES: c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c(-c3ccccc3)c2)cc1 ; CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2ccccc2)c1]

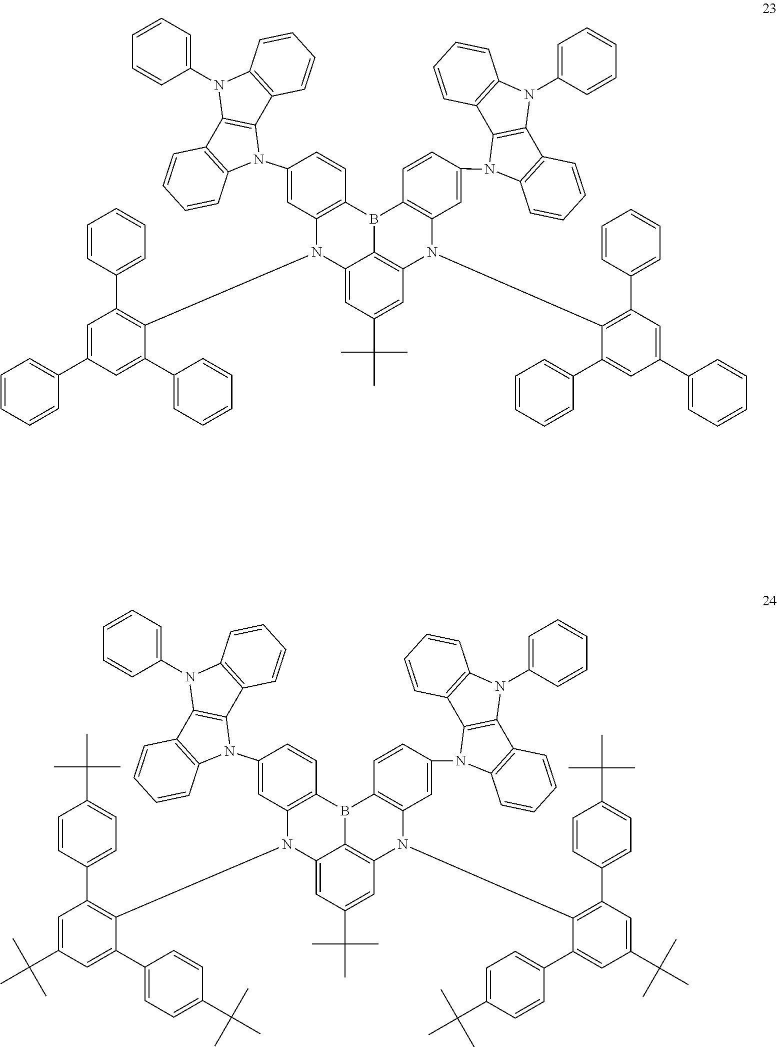 [SMILES: CC(C)(C)c1cc2c3c(c1)N(c1c(-c4ccccc4)cc(-c4ccccc4)cc1-c1ccccc1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

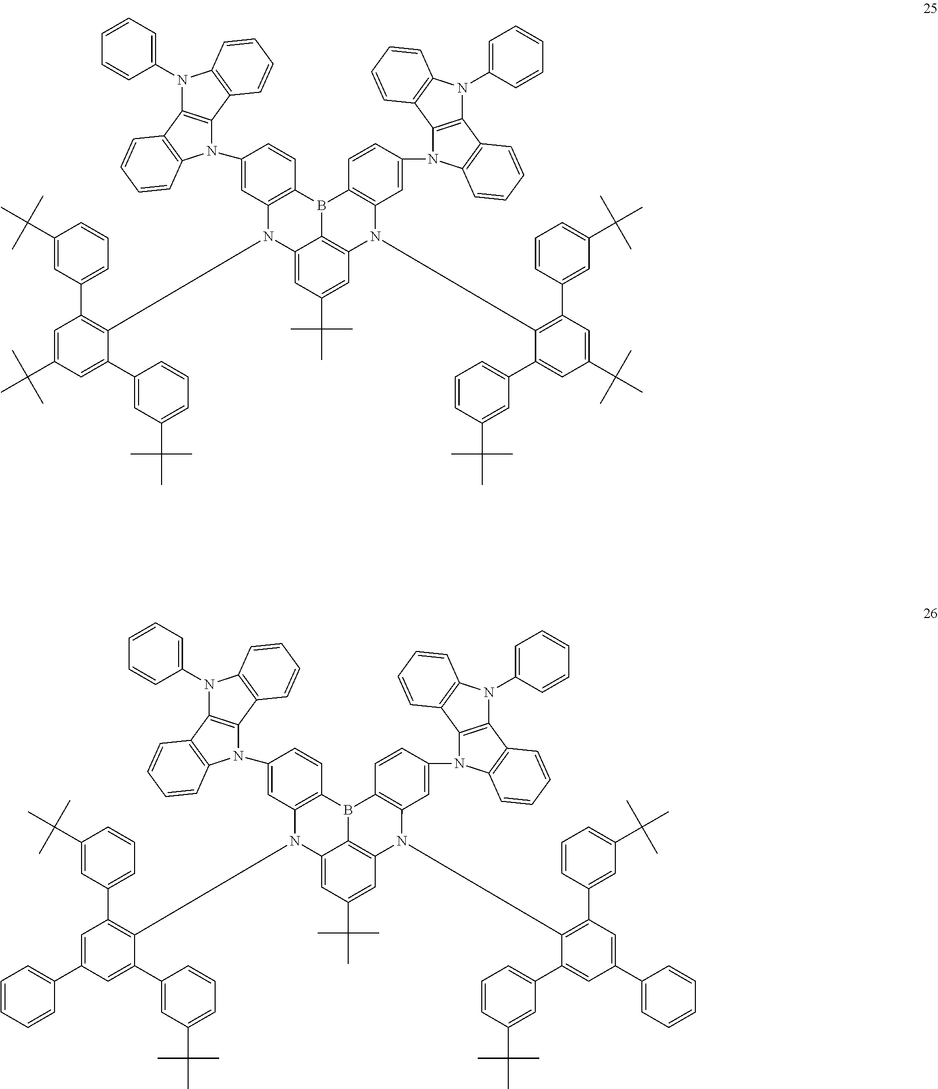 [SMILES: CC(C)(C)c1cccc(-c2cc(C(C)(C)C)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1]

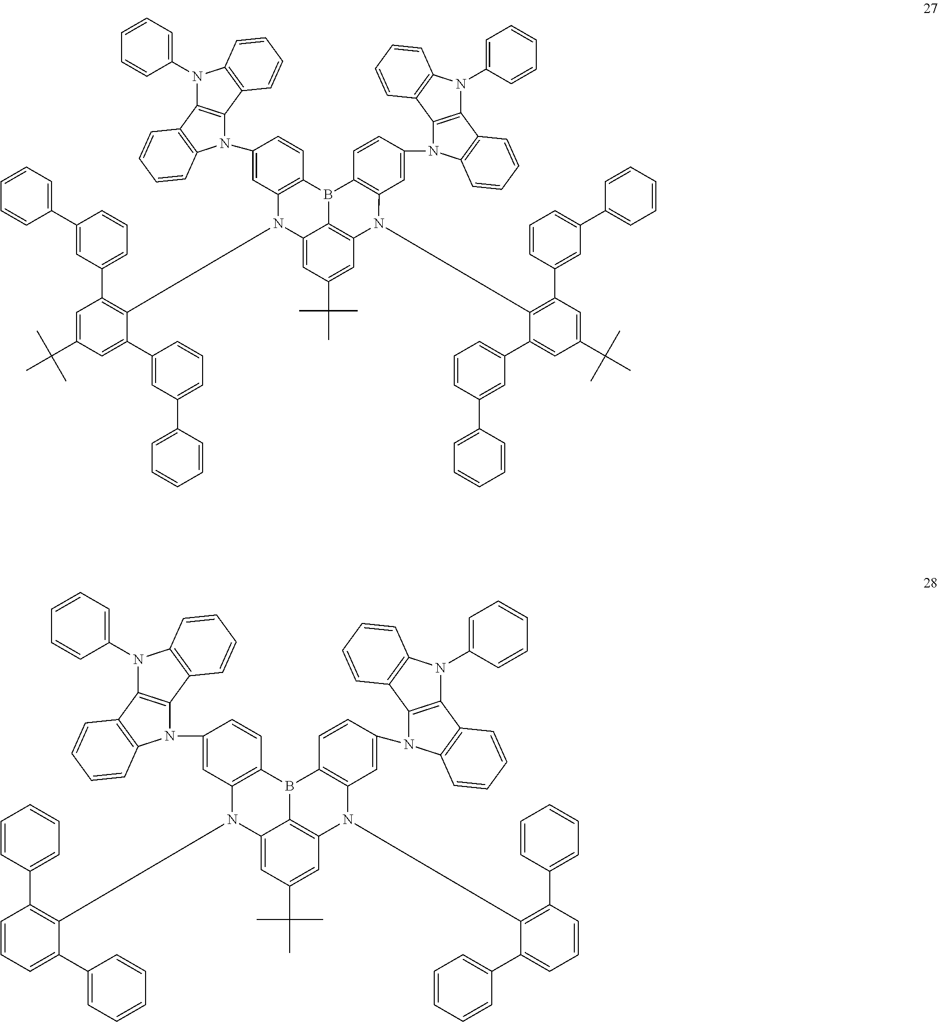 [SMILES: CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cccc1-c1ccccc1]

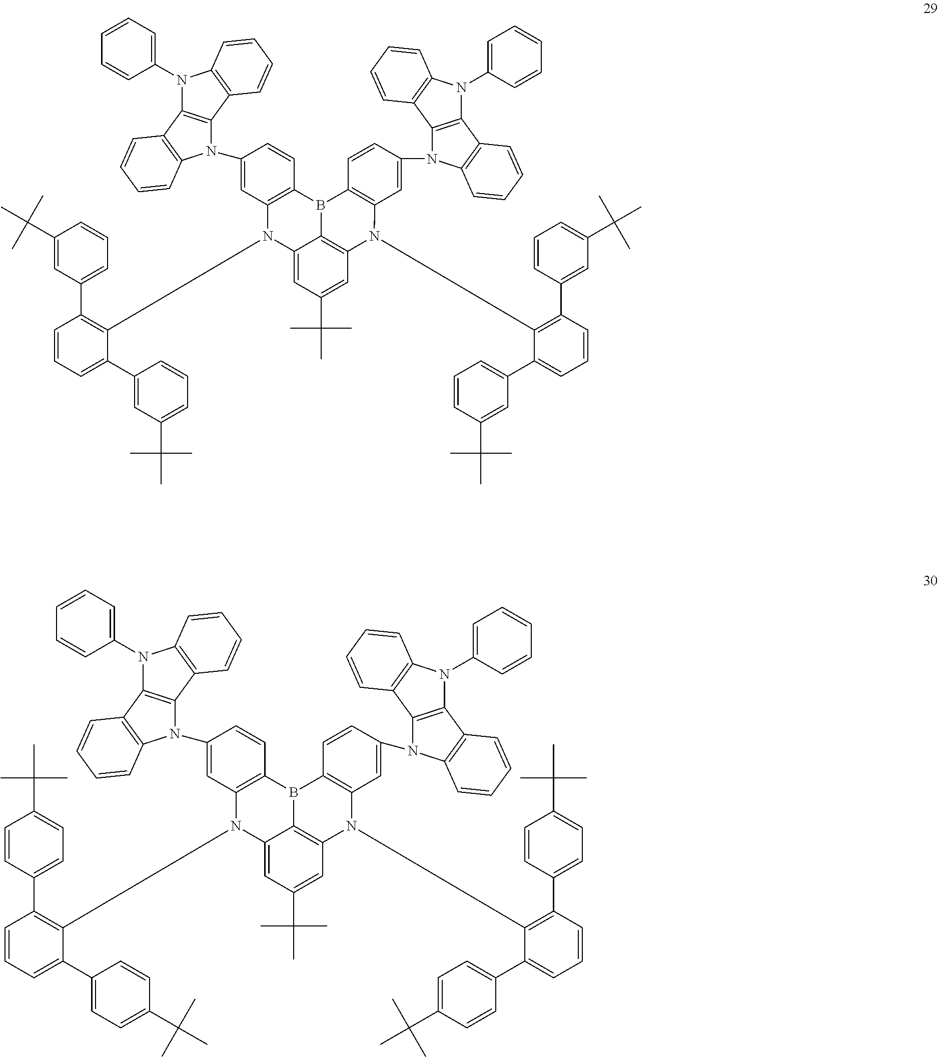

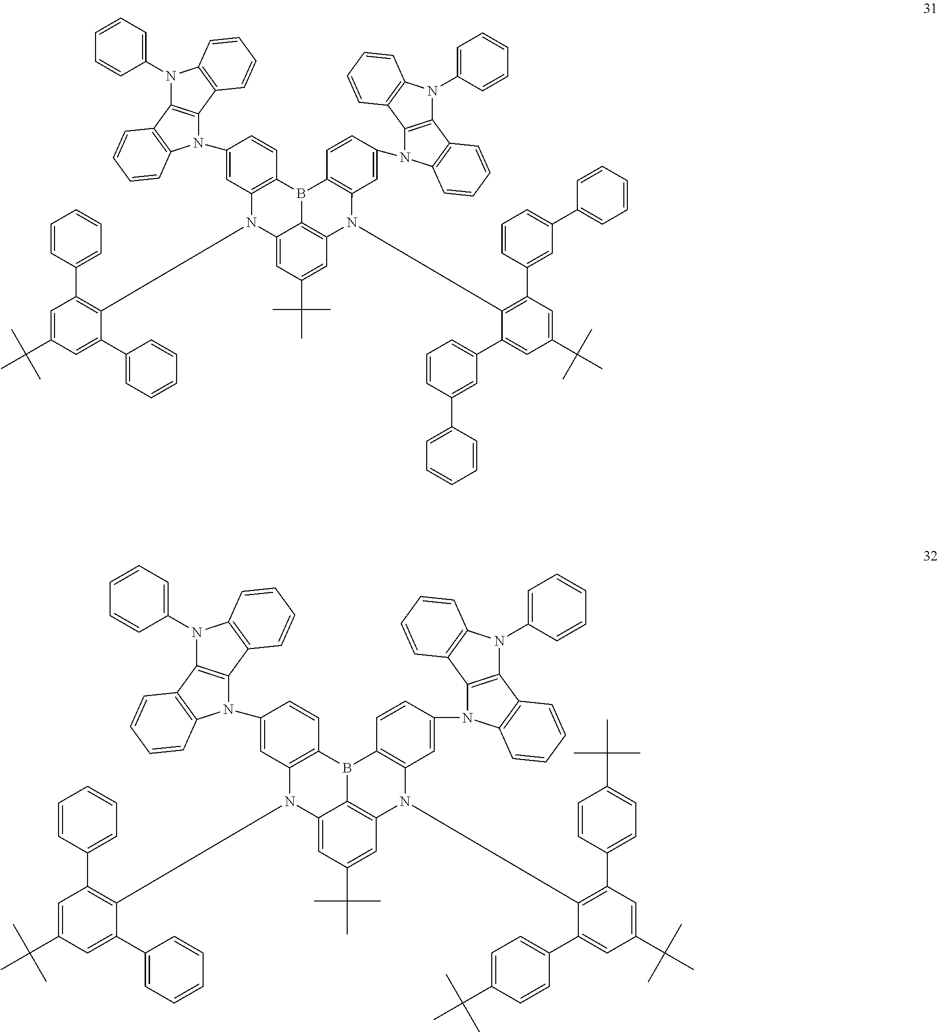 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2ccccc2)c1 ; CC(C)(C)c1ccc(-c2cc(C(C)(C)C)cc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)cc1]

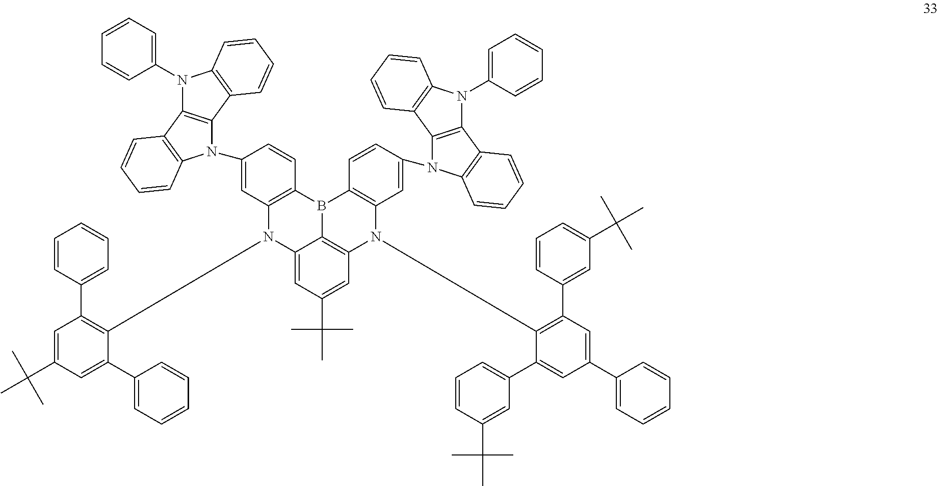 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c1]

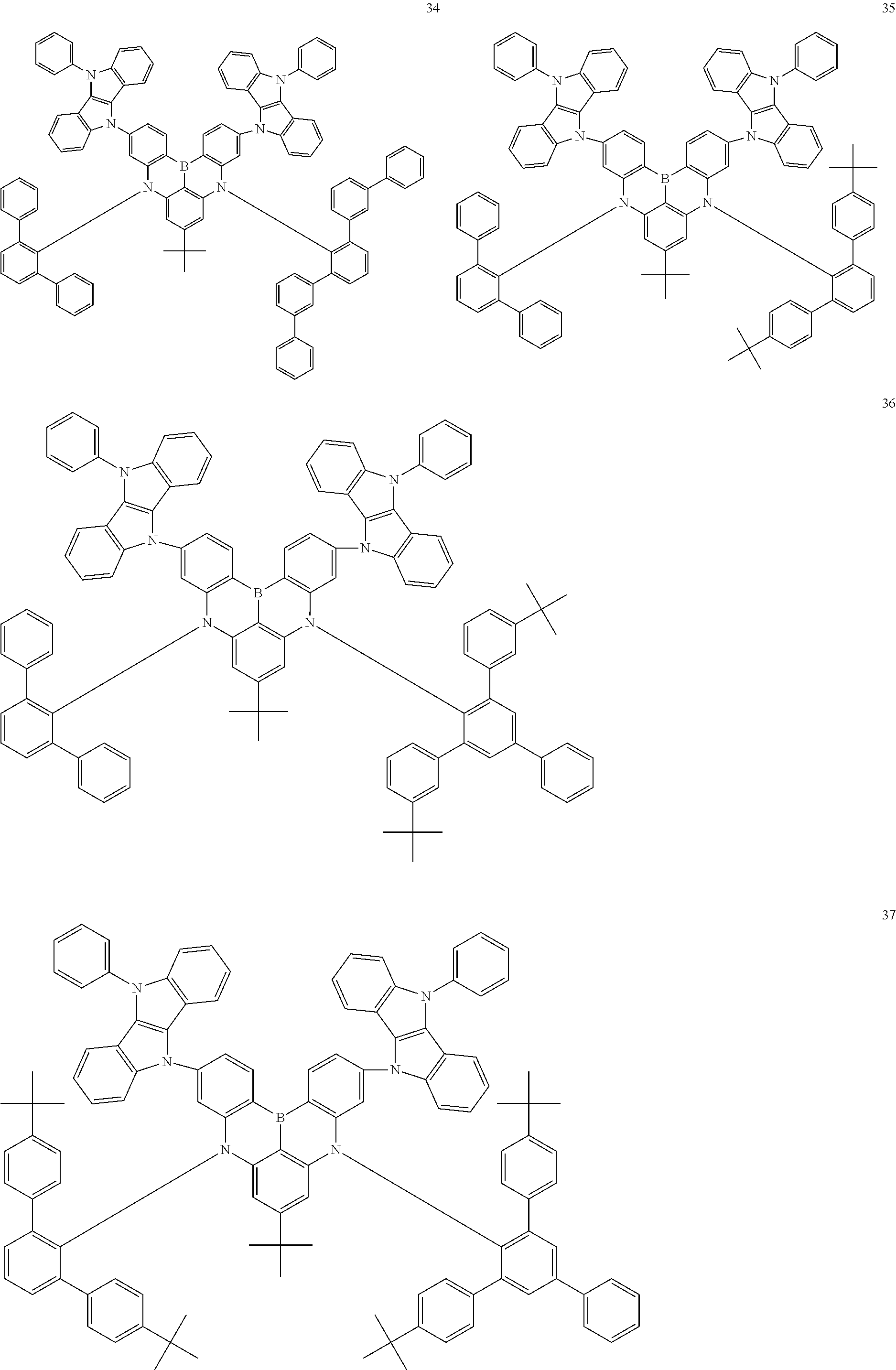

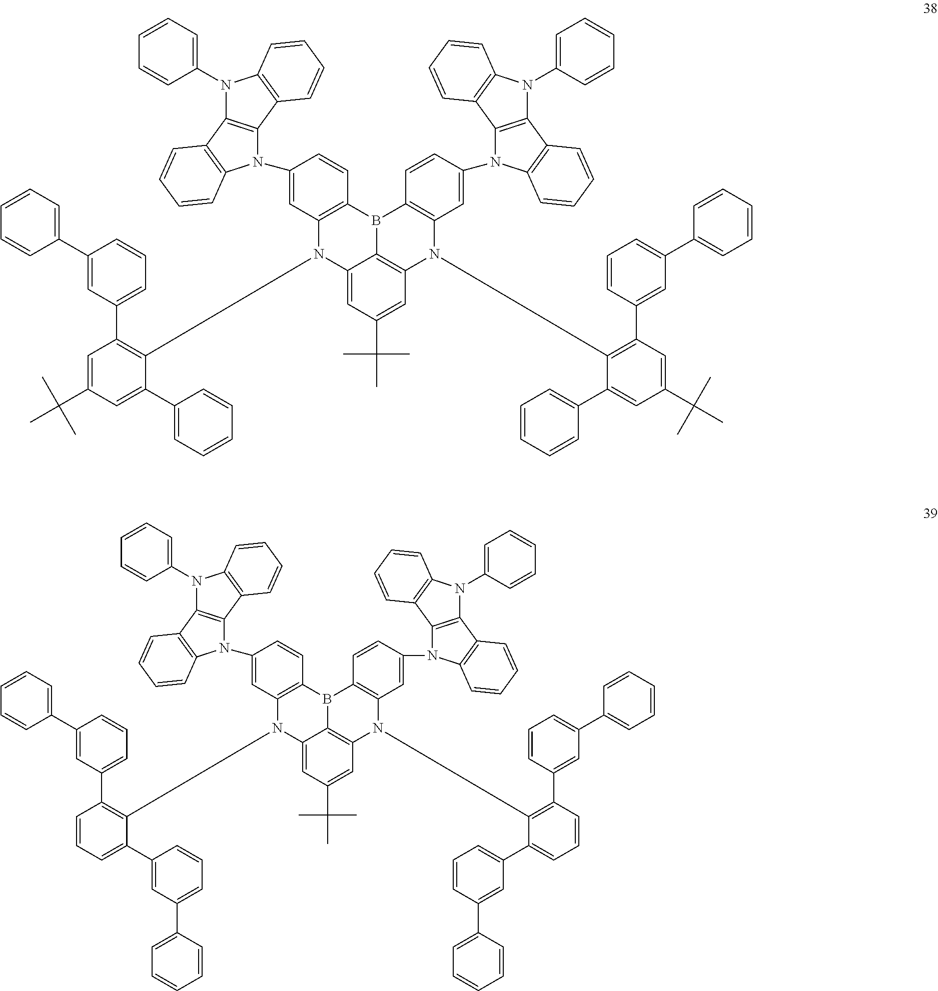 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2cccc(-c3ccccc3)c2)cccc1-c1cccc(-c2ccccc2)c1]

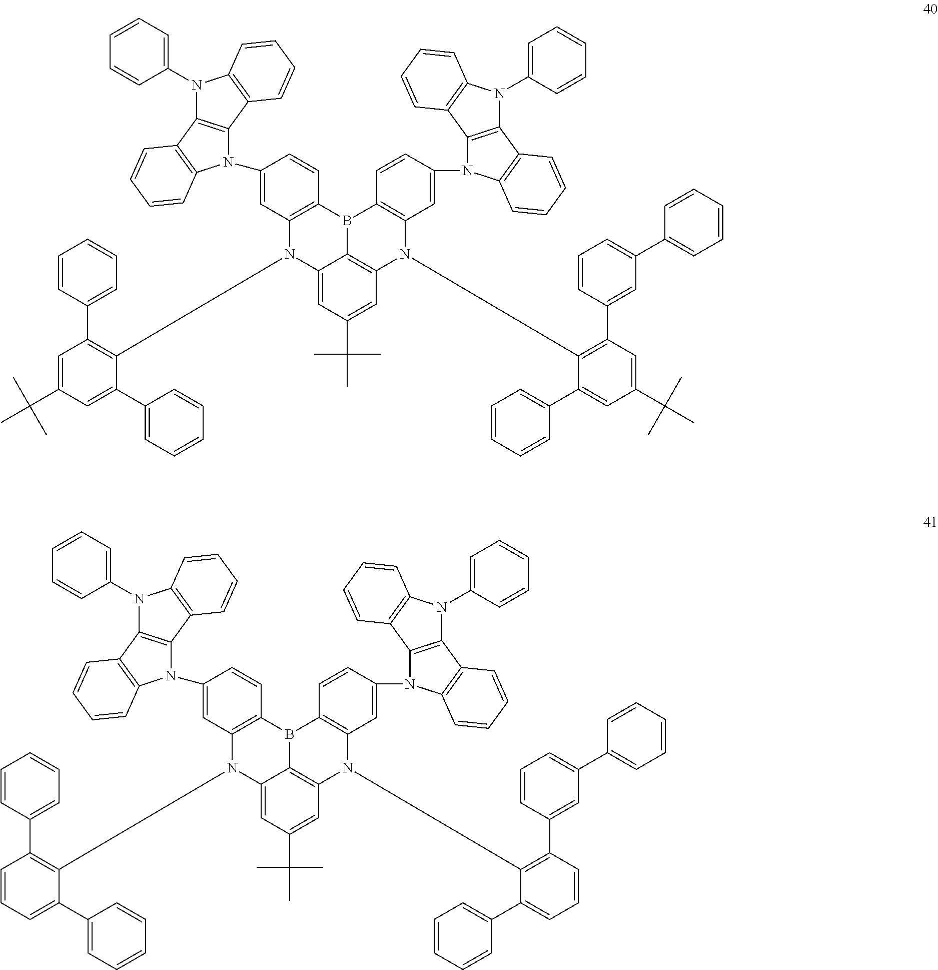 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2ccccc2)c1 ; CC(C)(C)c1cc2c3c(c1)N(c1c(-c4ccccc4)cccc1-c1cccc(-c4ccccc4)c1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cccc1-c1ccccc1]

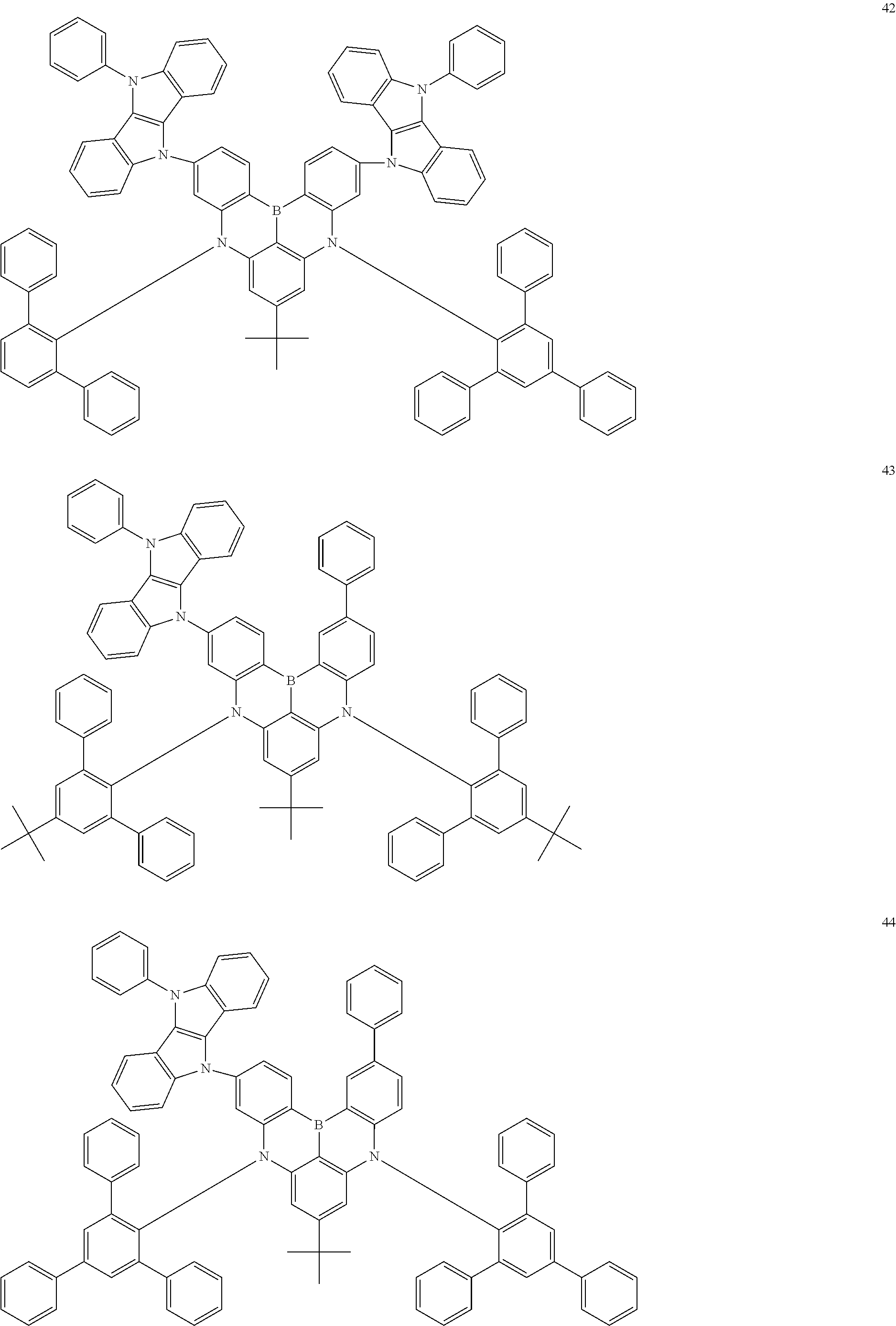

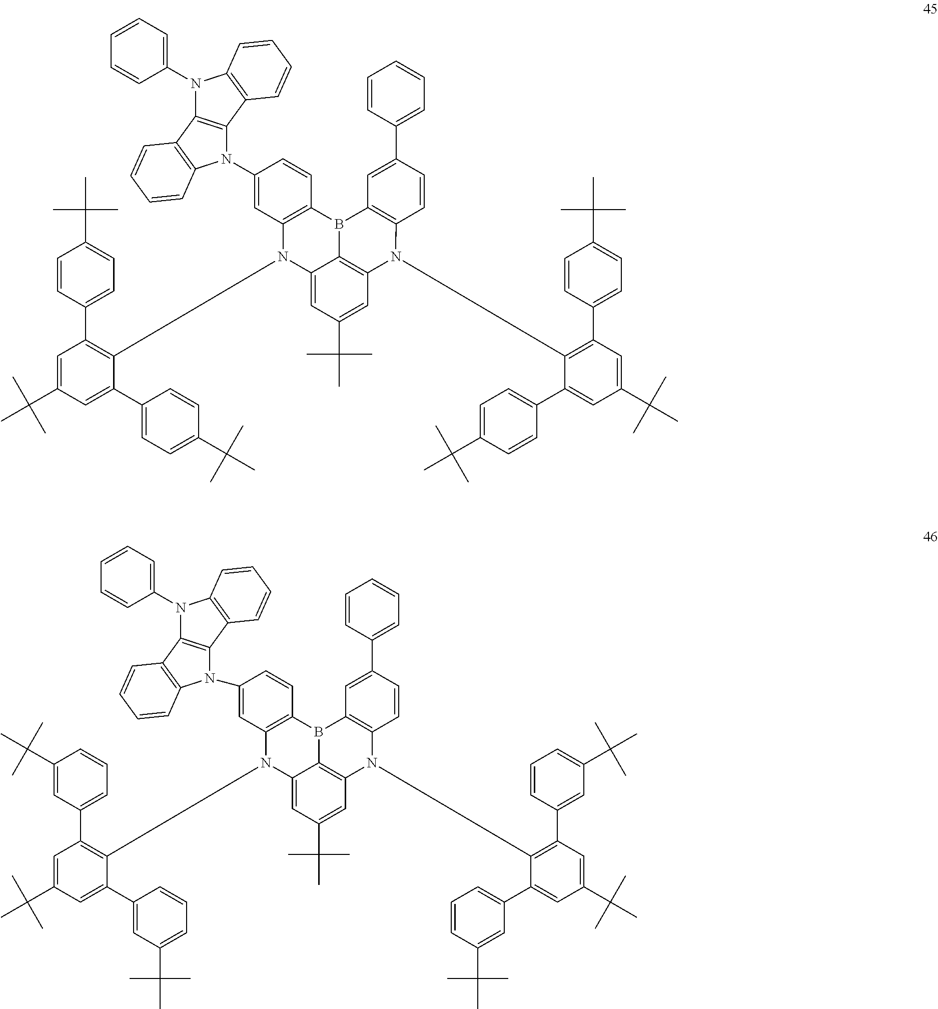

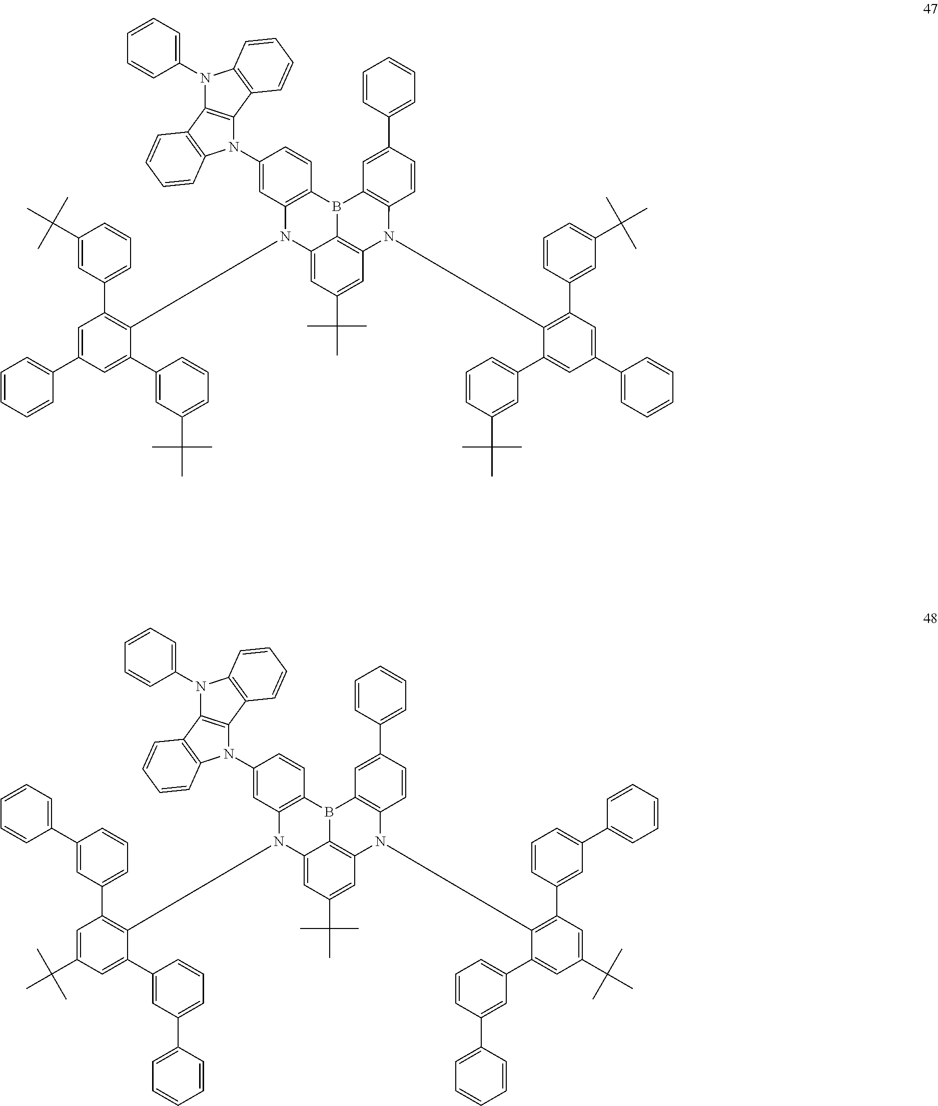 [SMILES: CC(C)(C)c1cccc(-c2cc(-c3ccccc3)cc(-c3cccc(C(C)(C)C)c3)c2N2c3ccc(-c4ccccc4)cc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3ccc(-c4ccccc4)cc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

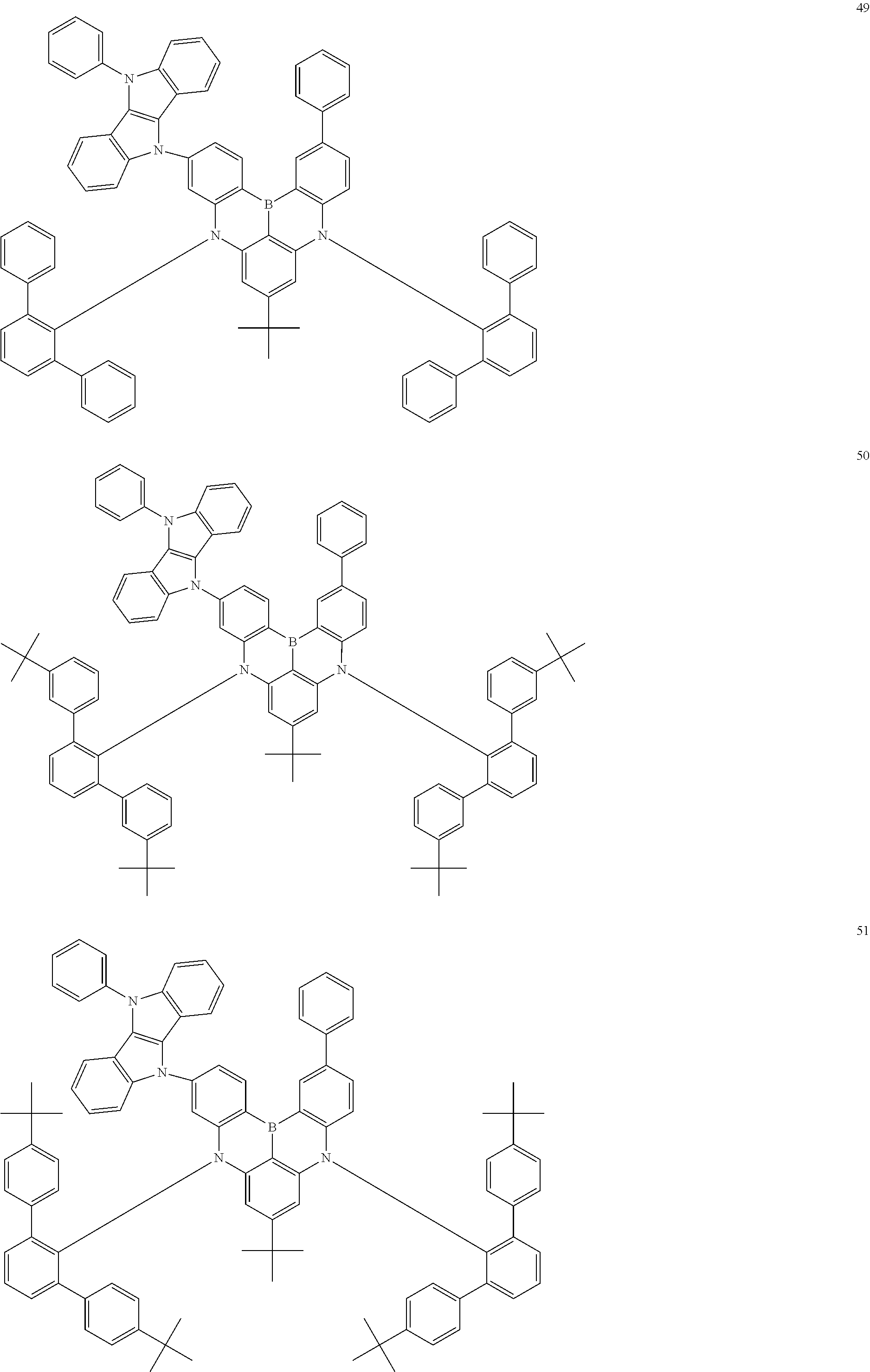

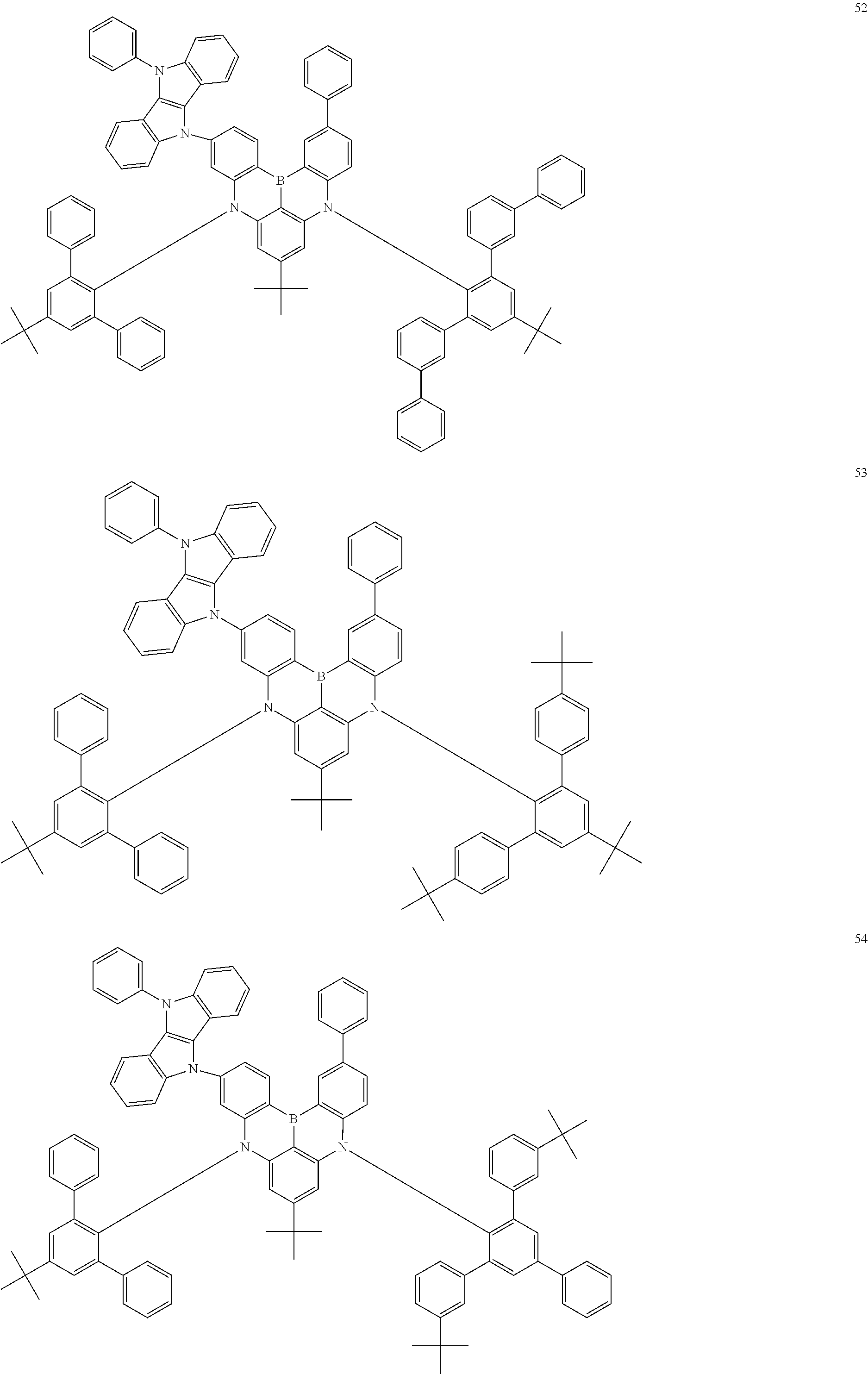

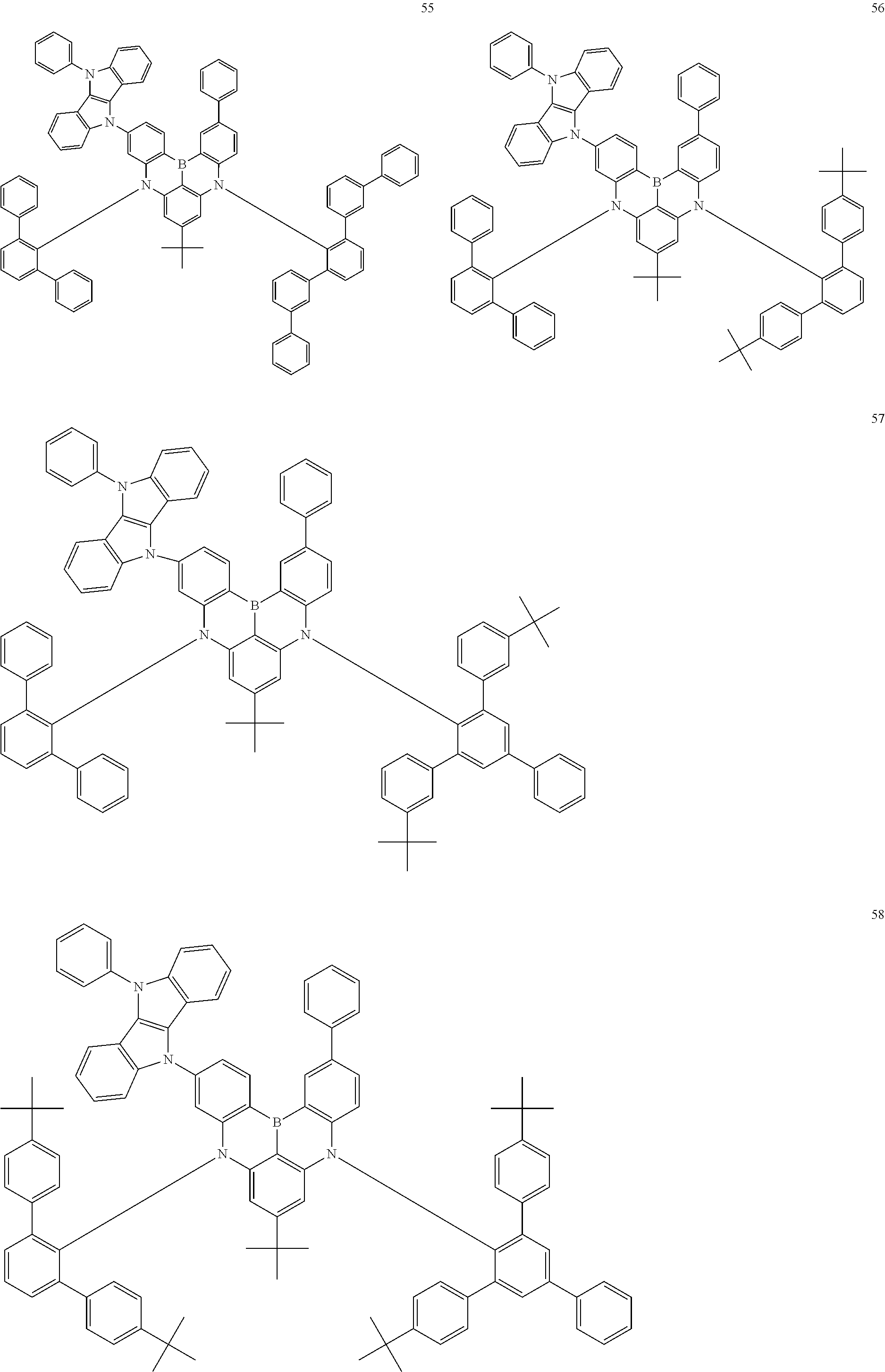

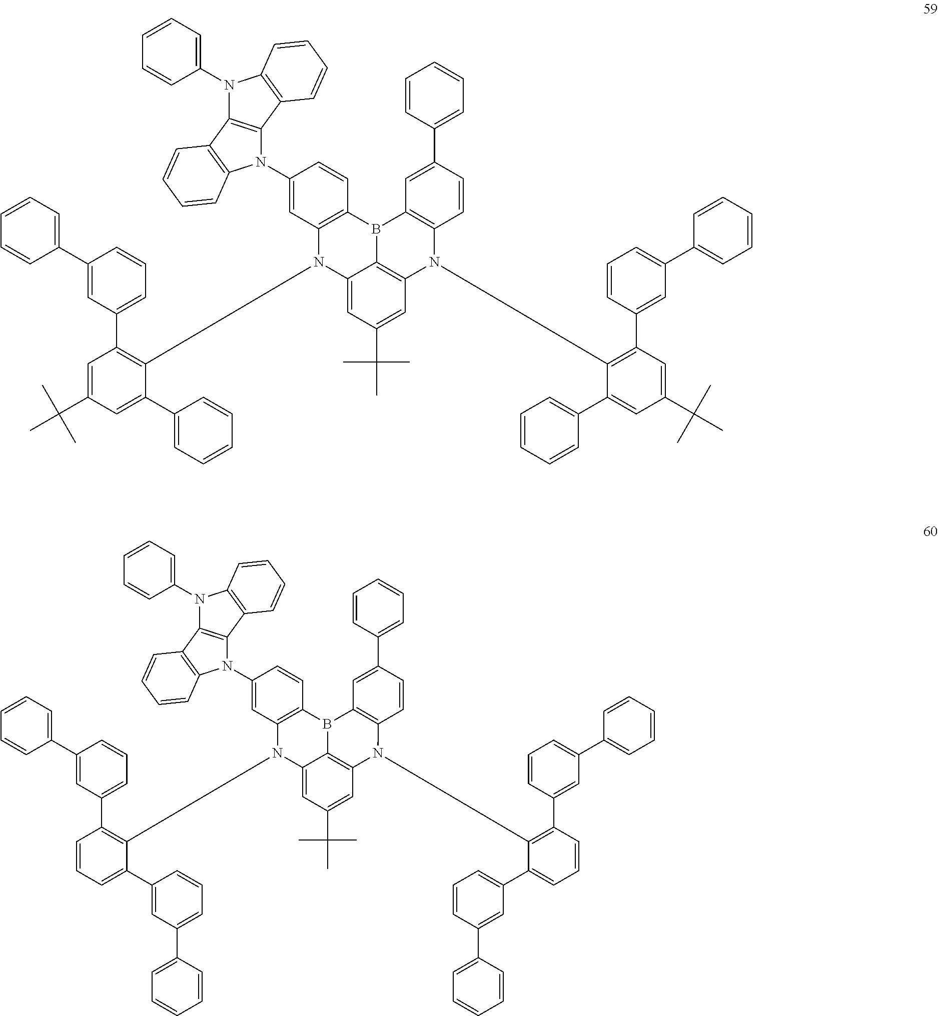 [SMILES: CC(C)(C)c1cc(-c2ccccc2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1cc(-c3ccccc3)ccc1N2c1c(-c2cccc(-c3ccccc3)c2)cccc1-c1cccc(-c2ccccc2)c1]

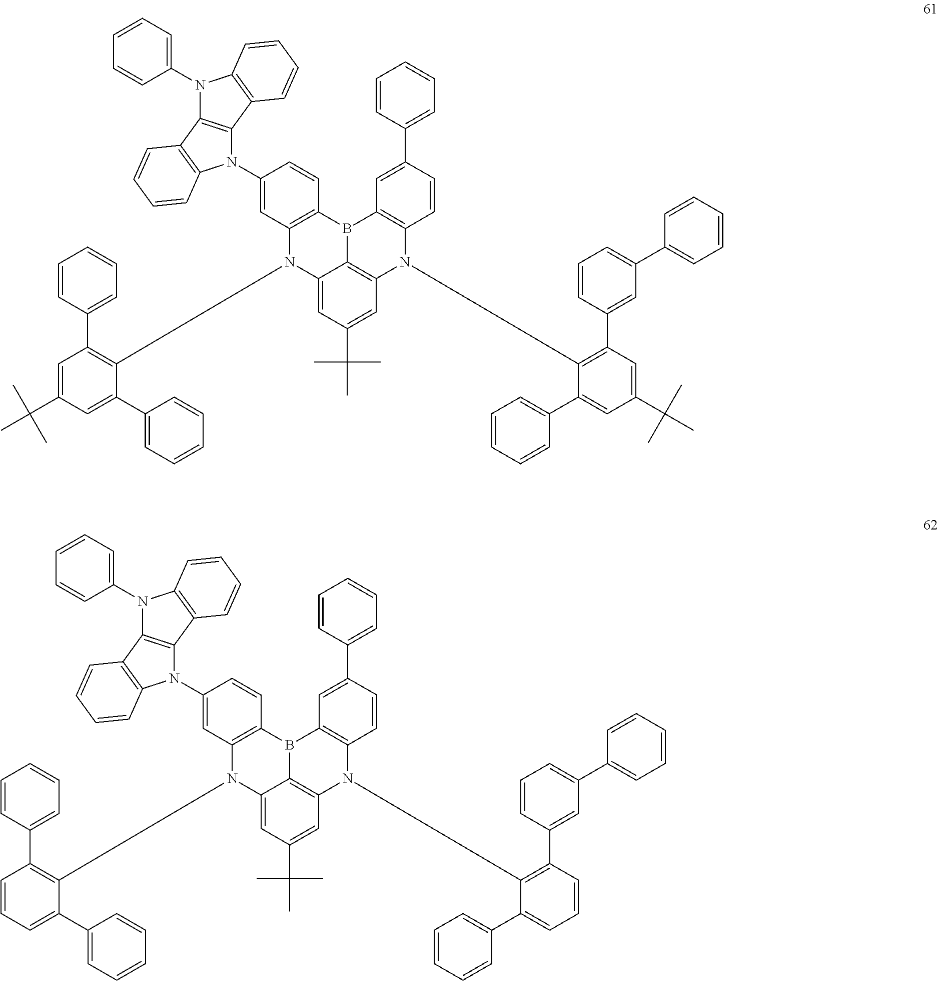 [SMILES: CC(C)(C)c1cc(-c2ccccc2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1cc(-c3ccccc3)ccc1N2c1c(-c2ccccc2)cccc1-c1cccc(-c2ccccc2)c1]

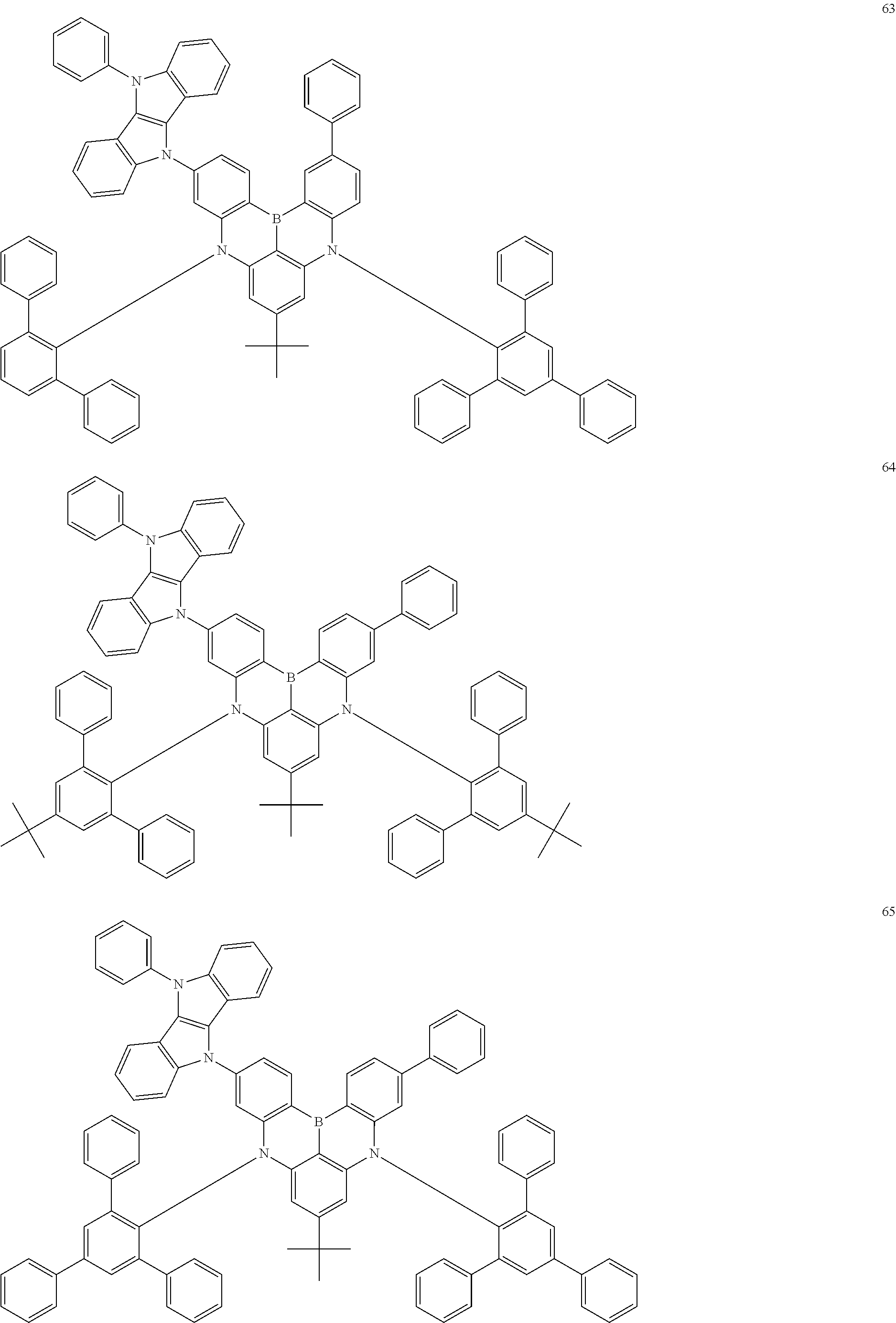

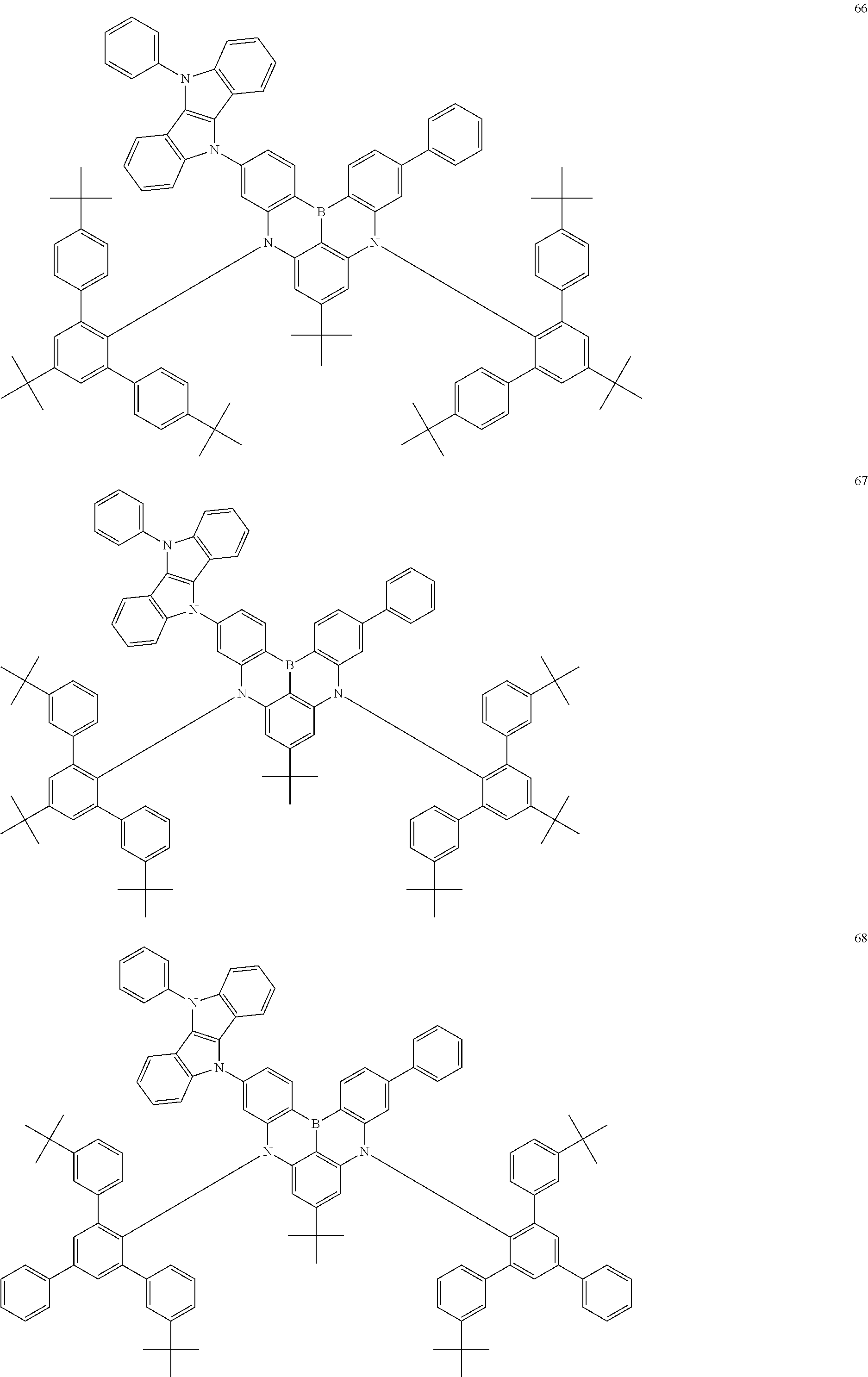

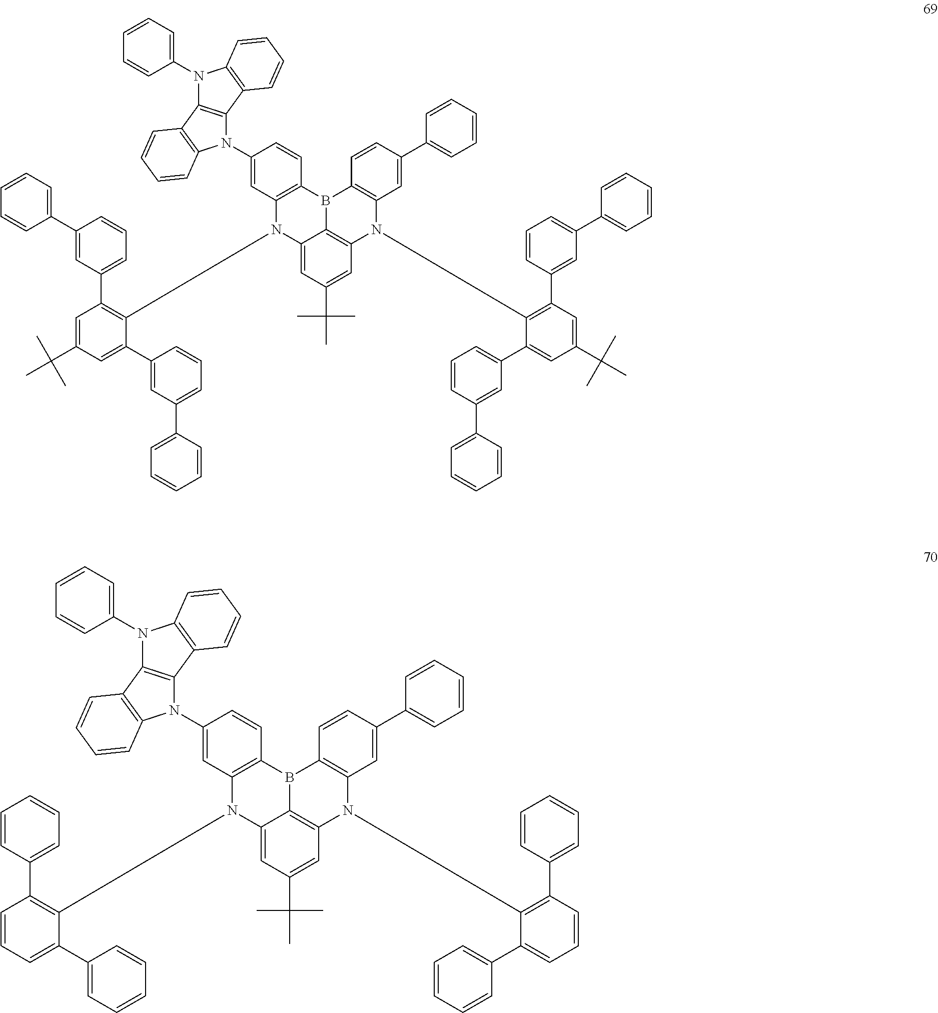 [SMILES: CC(C)(C)c1cc(-c2cccc(-c3ccccc3)c2)c(N2c3cc(-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-c3ccccc3)cc1N2c1c(-c2ccccc2)cccc1-c1ccccc1]

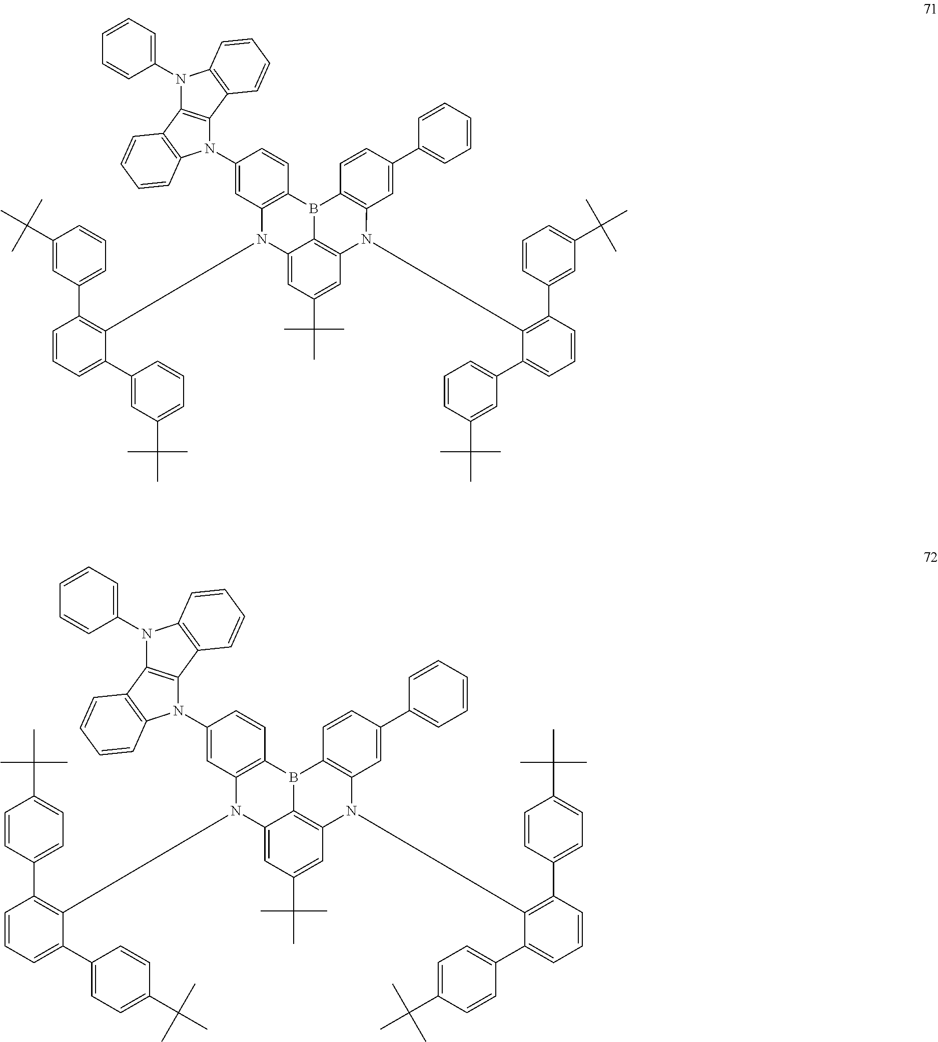

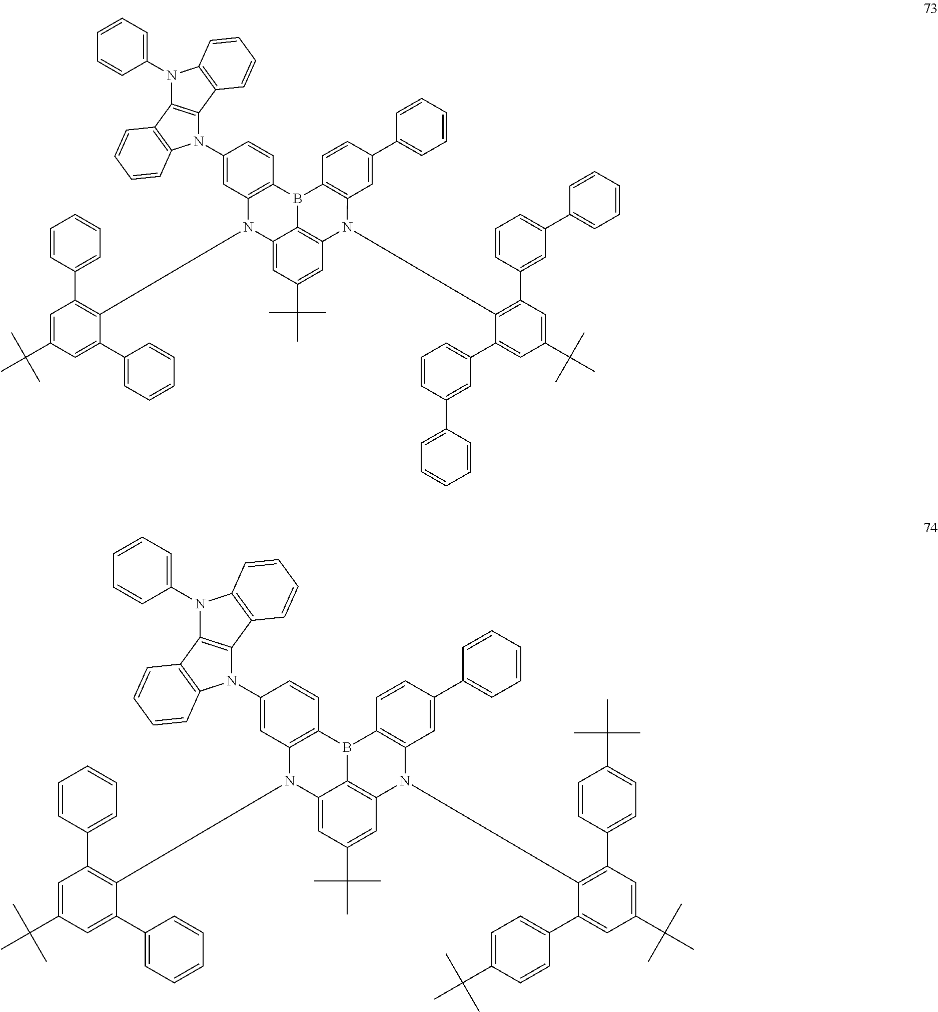 [SMILES: CC(C)(C)c1cc(-c2cccc(-c3ccccc3)c2)c(N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1ccc(-c2cc(C(C)(C)C)cc(-c3ccc(C(C)(C)C)cc3)c2N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)cc1]

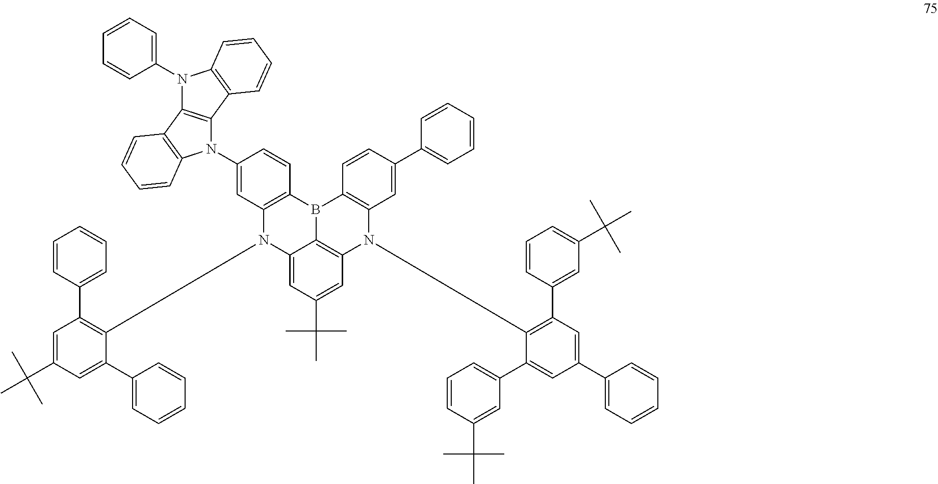 [SMILES: CC(C)(C)c1cccc(-c2cc(-c3ccccc3)cc(-c3cccc(C(C)(C)C)c3)c2N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c1]

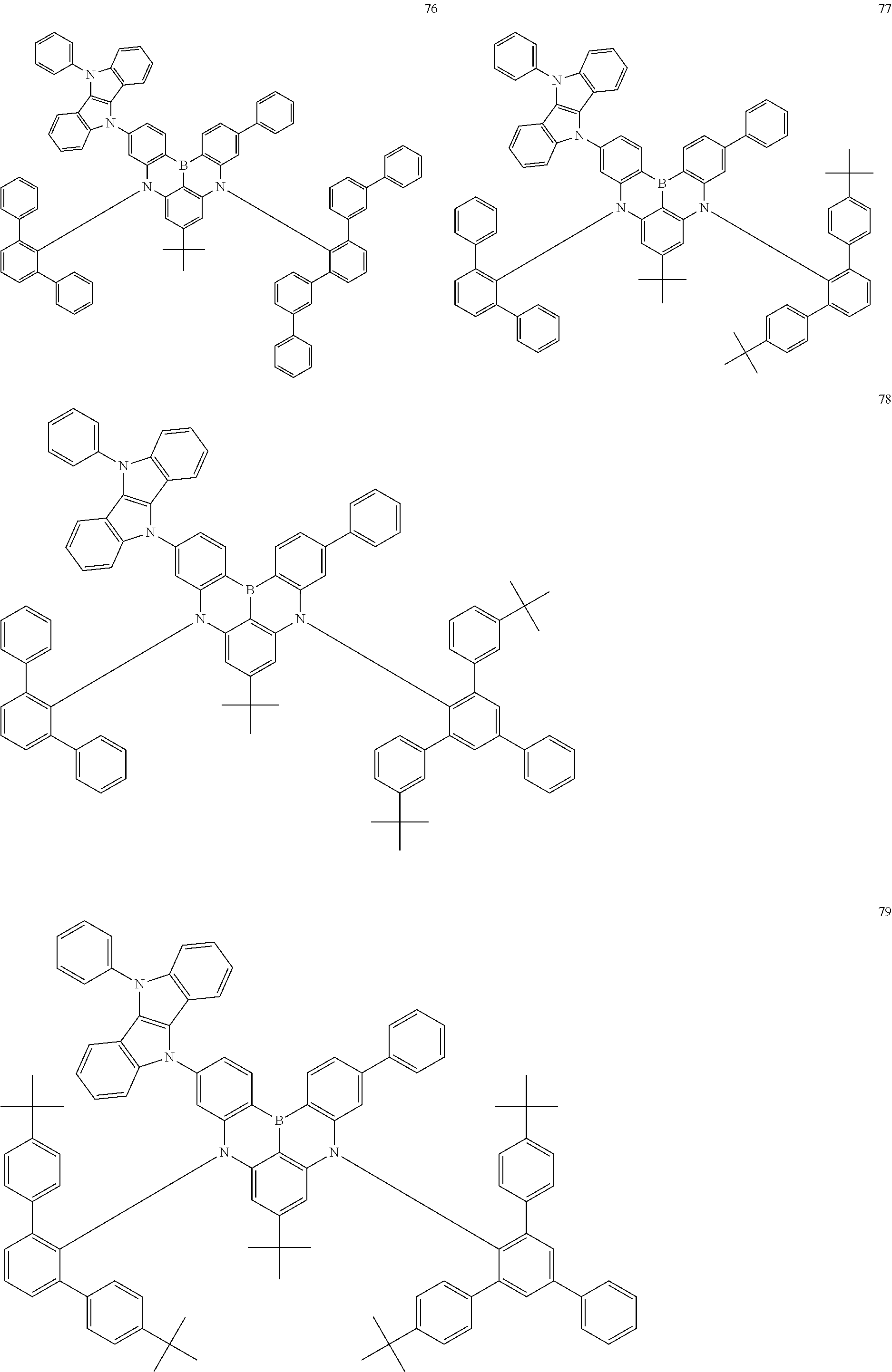

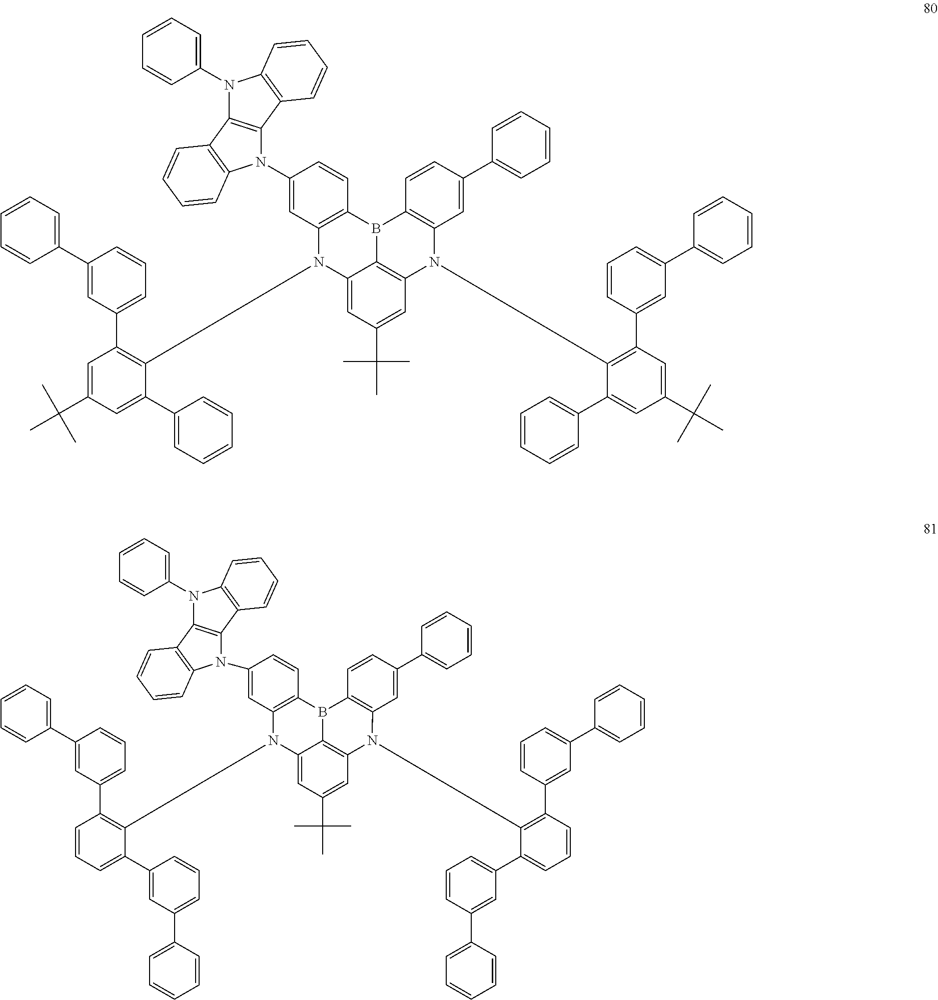 [SMILES: CC(C)(C)c1cc(-c2ccccc2)c(N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1ccc(-c3ccccc3)cc1N2c1c(-c2cccc(-c3ccccc3)c2)cccc1-c1cccc(-c2ccccc2)c1]

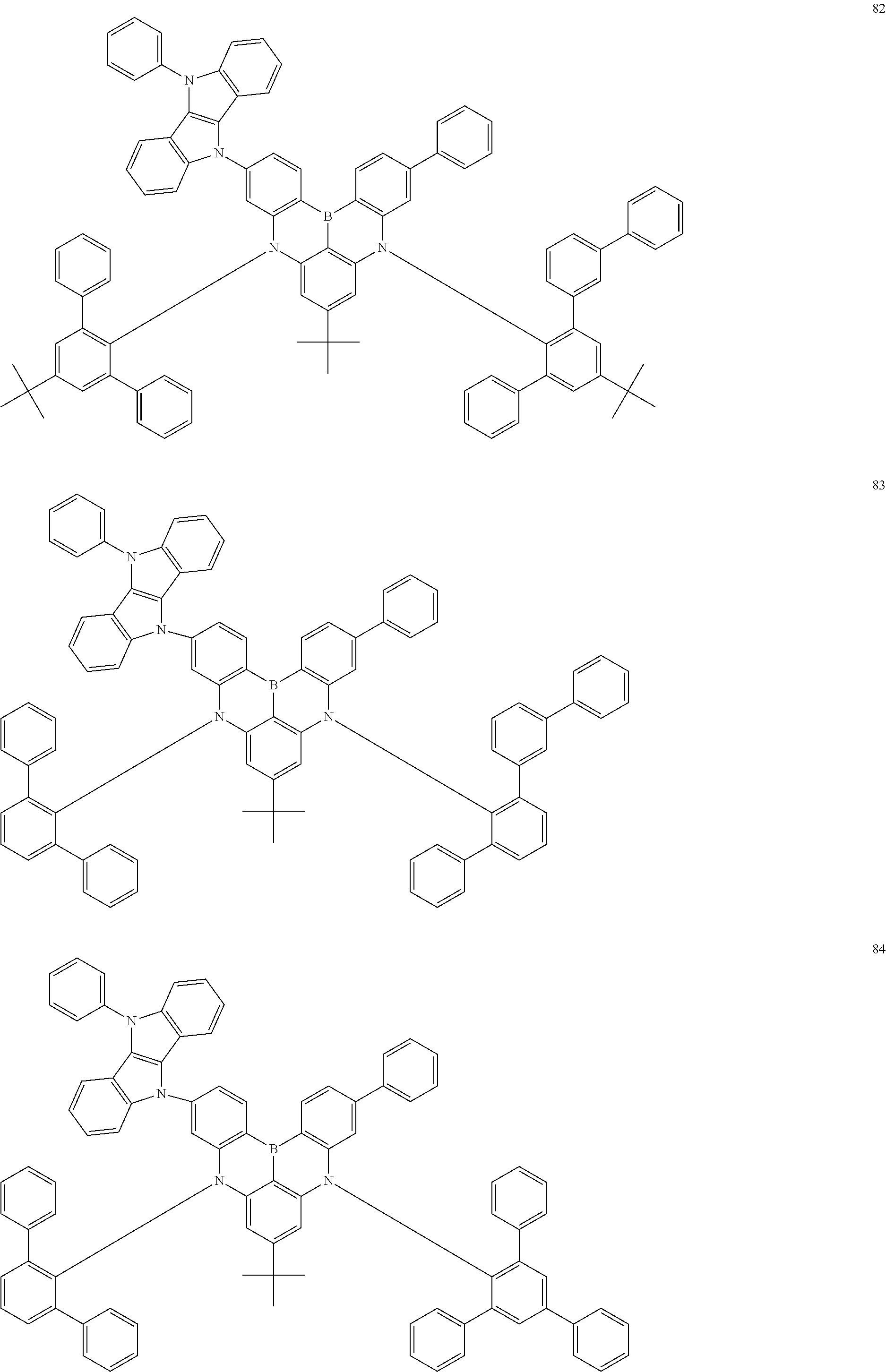 [SMILES: CC(C)(C)c1cc(-c2ccccc2)c(N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-c3ccccc3)cc1N2c1c(-c2ccccc2)cccc1-c1cccc(-c2ccccc2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-c3ccccc3)cc1N2c1c(-c2ccccc2)cc(-c2ccccc2)cc1-c1ccccc1]

The light emitting element ED including the fused polycyclic compound of one or more embodiments may be to emit blue light. The third light emitting element ED-3 (see FIG. 2) which is to emit blue light may include the fused polycyclic compound of one or more embodiments.

The emission layer EML may include the fused polycyclic compound of one or more embodiments as a dopant. The fused polycyclic compound of one or more embodiments may be a delayed fluorescence material. The fused polycyclic compound of one or more embodiments may be a thermally activated delayed fluorescence (TADF) material. The fused polycyclic compound of one or more embodiments may be to emit light by converting a triplet exciton into a singlet exciton by a reverse inter system crossing (RISC) mechanism.

The fused polycyclic compound of one or more embodiments may be a multiple resonance (MR) type (kind) dopant. The emission layer EML including the fused polycyclic compound, which is the multiple resonance (MR) type (kind) dopant, may be to emit light with a narrow full width at half maximum (FWHM). Accordingly, the light emitting element ED including the fused polycyclic compound of one or more embodiments may be to emit light with improved color purity.

The fused polycyclic compound of one or more embodiments includes, as a central structure, a 5-ring fused ring including two nitrogen atoms and one boron atom as ring-forming atoms, and an indoloindole moiety and a biphenyl moiety may be each bonded to the central structure. The biphenyl moiety may be bonded to the nitrogen atom, which is a ring-forming atom of the central structure. The indoloindole moiety is represented by Formula 2, and may be bonded to a carbon atom among the ring-forming atoms of the central structure.

The boron atom, which is a ring-forming atom, includes an empty p orbital, and a compound including the boron atom exhibits electron deficiency properties due to the empty p orbital of the boron atom, and is easily bonded to a nucleophile or attacked by a nucleophile, and/or the like. As such, a ring group including the boron atom in the compound is transformed into a regular tetrahedral structure, and consequently a light emitting element including such a compound is deteriorated. In addition, a typical compound which includes a boron atom and is used as a light emitting material has a plate-like (e.g., planar) structure, and the typical compound having a plate-like structure facilitates intermolecular interactions. Intermolecular interactions, such as intermolecular aggregation, intermolecular excimer formation, and intermolecular exciplex formation, cause degradation in the efficiency and lifespan of a light emitting element including such compounds.

The fused polycyclic compound of one or more embodiments includes an indoloindole moiety, and the indoloindole moiety corresponds to a bulky substituent. The indoloindole moiety may increase the distance between molecules, thereby preventing or reducing (or minimizing) intermolecular interactions and Dexter energy transfer. As the Dexter energy transfer is prevented or reduced, the concentration of a triplet exciton T1 may be reduced, and the light emitting element ED including the fused polycyclic compound of one or more embodiments may exhibit properties of a long lifespan.

Because the indoloindole moiety prevents the intermolecular aggregation, the purification of compound may be facilitated during the synthesis of the fused polycyclic compound, the stability related to thermal decomposition in sublimation and purification steps during the synthesis may be increased, and the color purity during luminescence may be improved. In addition, the indoloindole moiety has stronger electron donating properties than a carbazole groups, and the fused polycyclic compound of one or more embodiments including the indoloindole moiety may have enhanced multiple resonance properties. Therefore, the light emitting element ED including the fused polycyclic compound of one or more embodiments may exhibit excellent or suitable luminous efficiency.

In one or more embodiments, the emission layer EML includes the fused polycyclic compound of one or more embodiments, and may further include at least one selected from among the second to fourth compounds. In one or more embodiments, the emission layer EML may include the second compound represented by Formula HT-1. For example, the second compound may be used as a hole transporting host material of the emission layer EML.

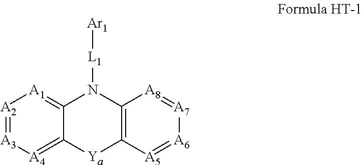

In Formula HT-1, A₁ to A₈ may each independently be N or CR₅₁. For example, in one or more embodiments, all of A₁ to A₈ may be CR₅₁. In one or more embodiments, any one selected from among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that two six-membered rings (e.g., two benzene rings) linked to the nitrogen atom in Formula HT-1 are linked via a direct linkage,

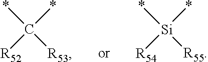

In Formula HT-1, if (e.g., when) Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, in one or more embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₅₁ to R₅₅ may be each independently bonded to an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds represented by Compound Group 2. The emission layer EML may include at least one selected from among the compounds represented by Compound Group 2 as a hole transporting host material.

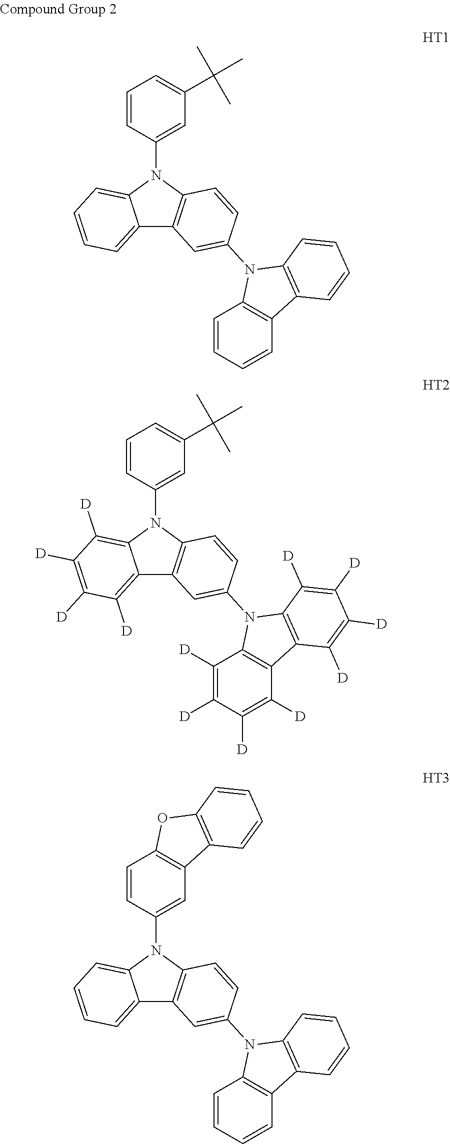

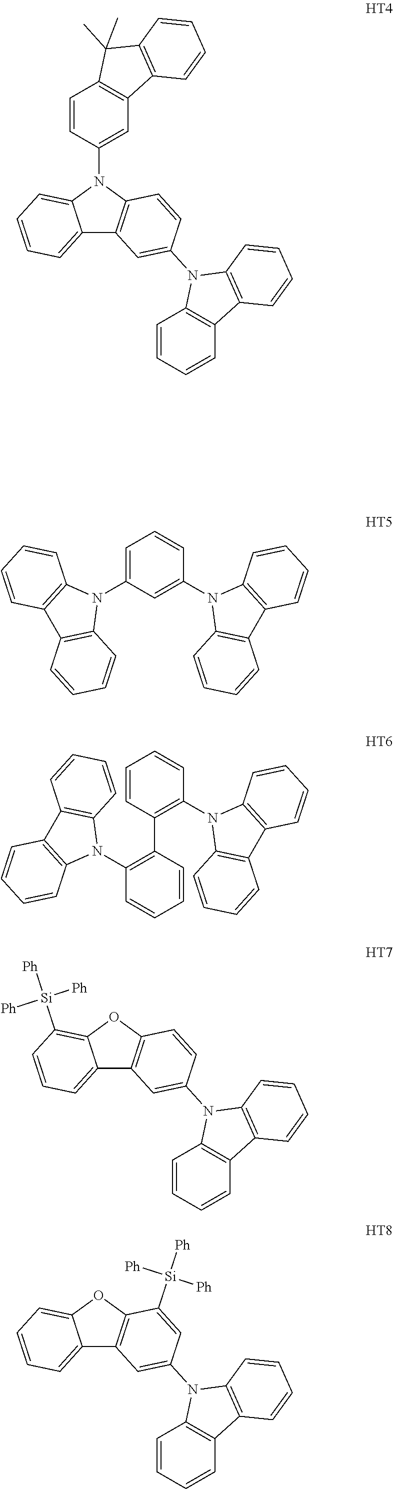

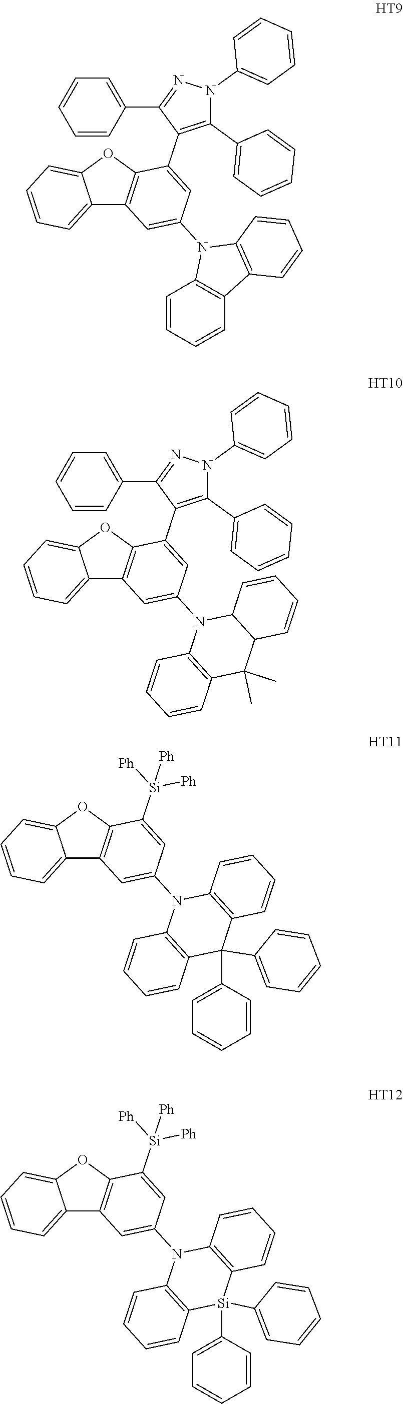

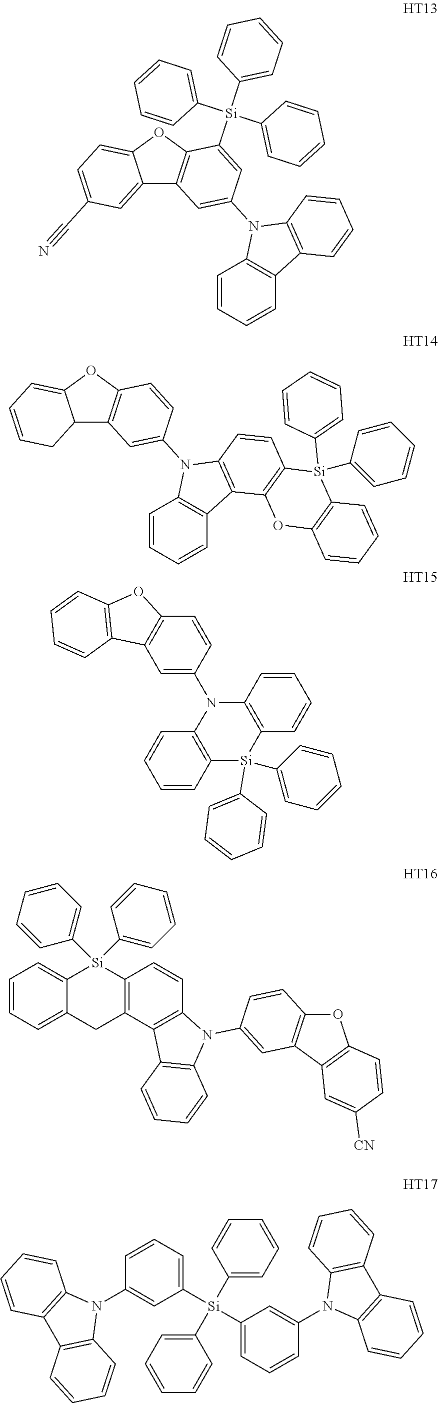

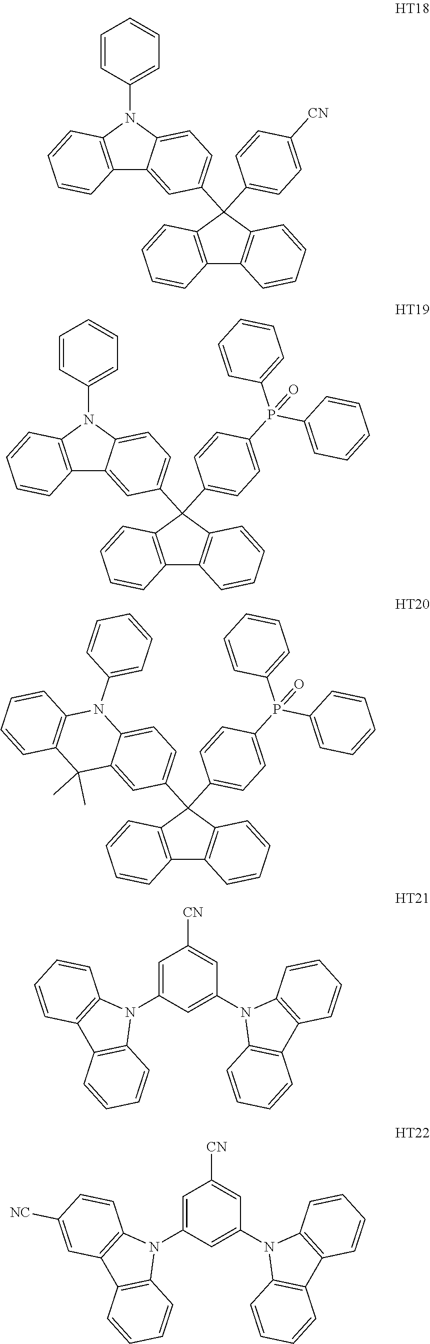

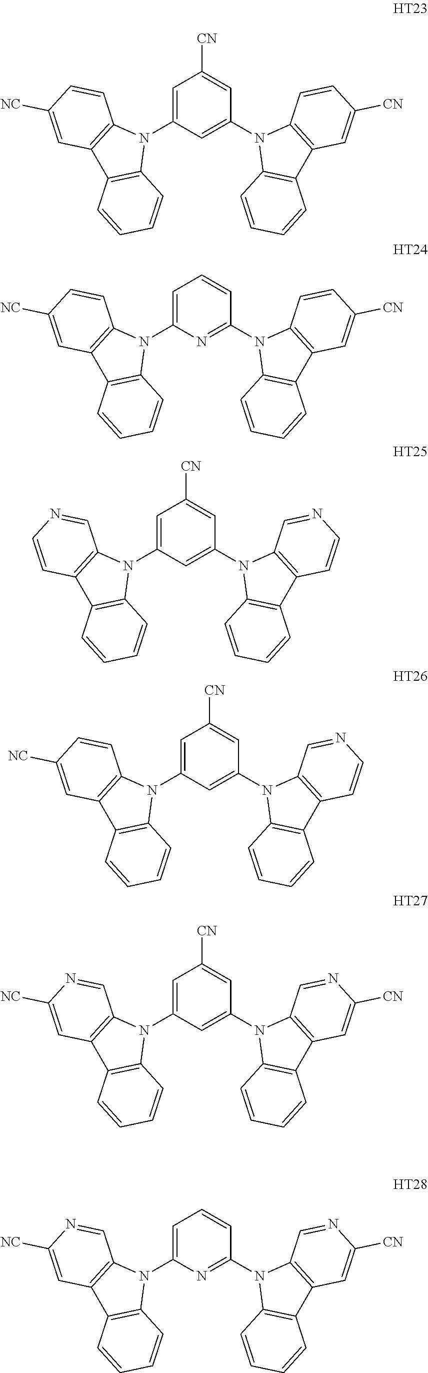

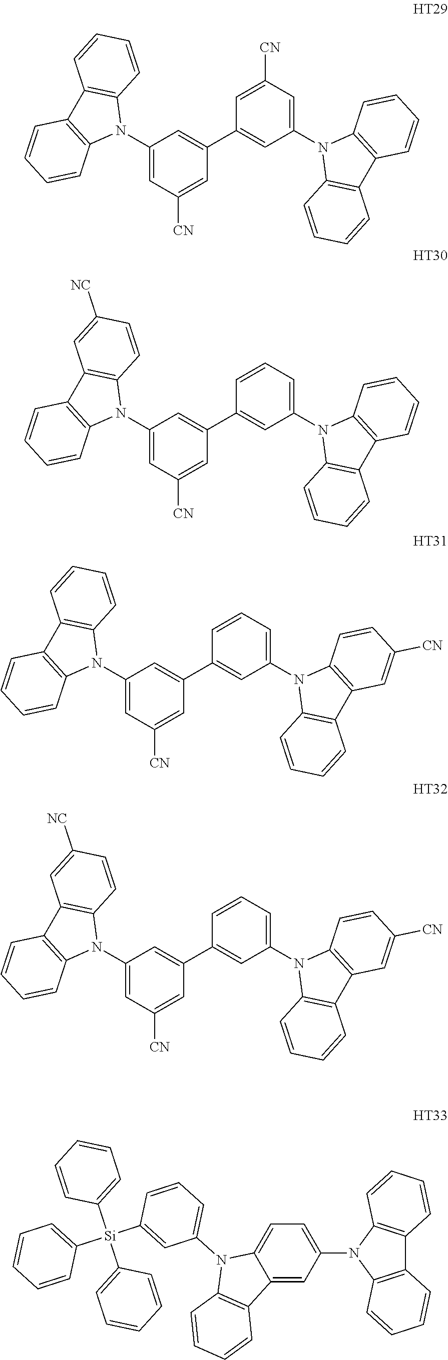 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

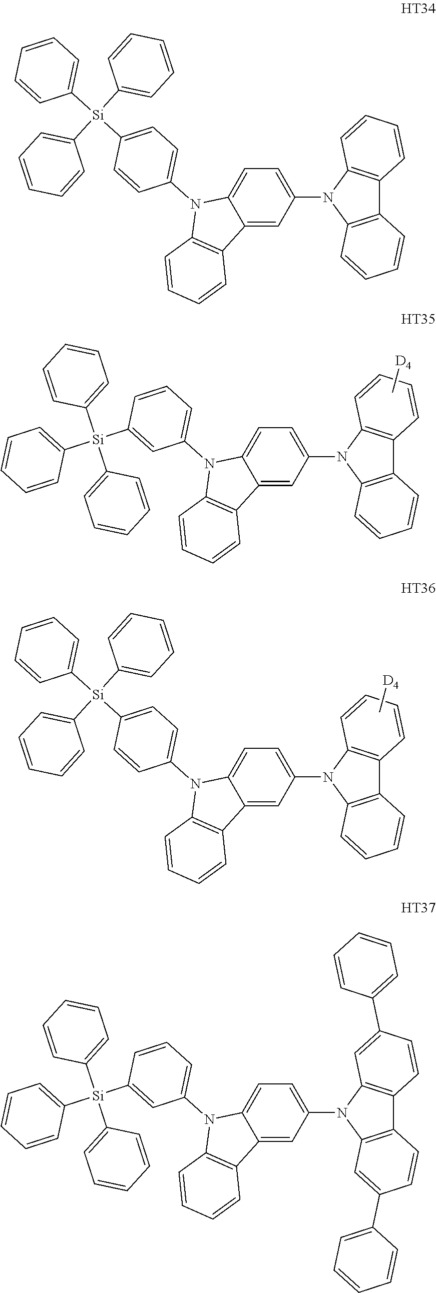

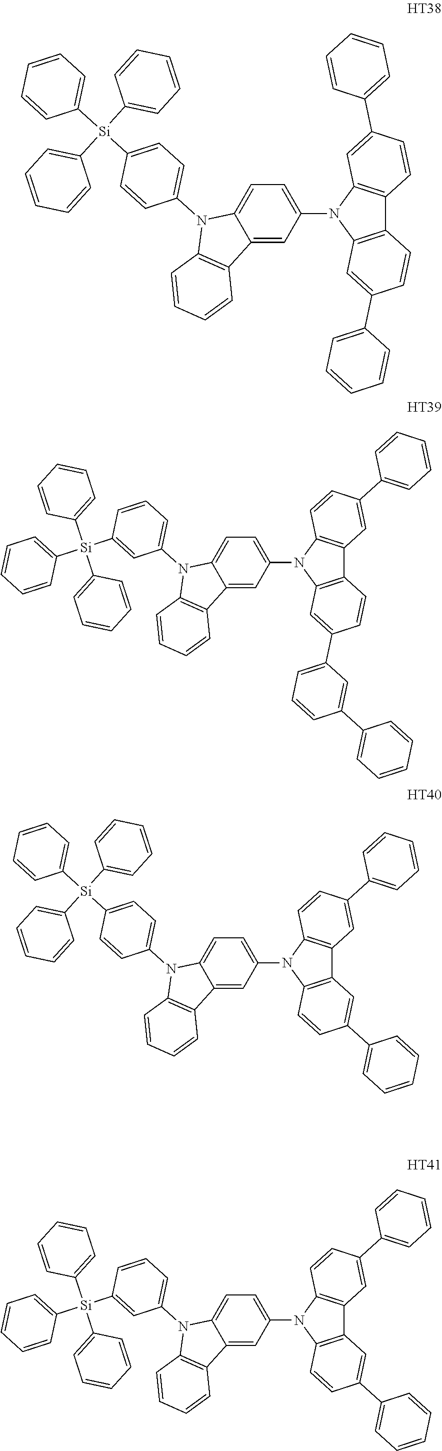 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2cccc(-c3ccc4c5cc(-c6ccccc6)ccc5n(-c5ccc6c(c5)c5ccccc5n6-c5cccc([Si](c6ccccc6)(c6ccccc6)c6ccccc6)c5)c4c3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

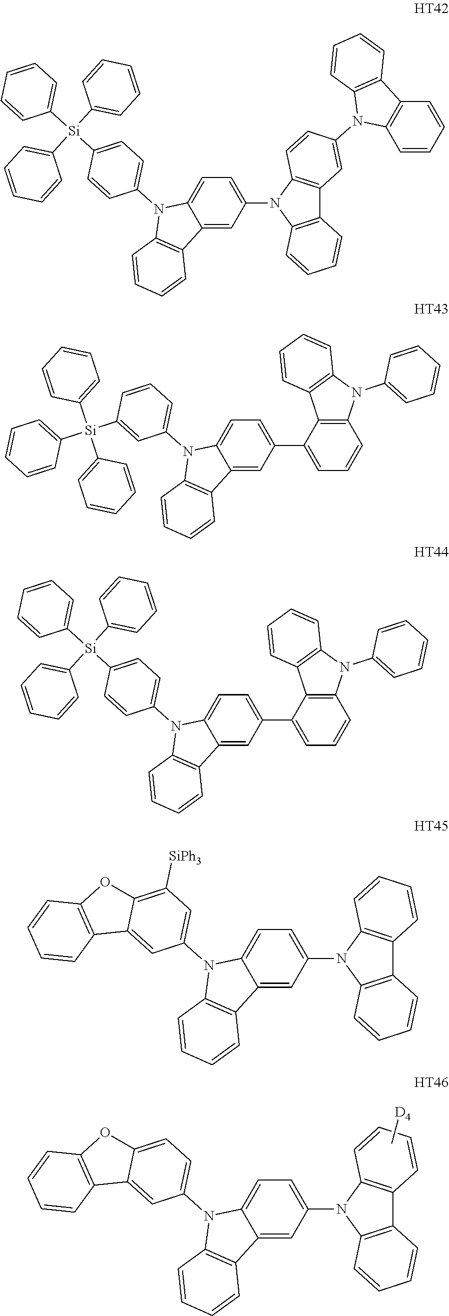

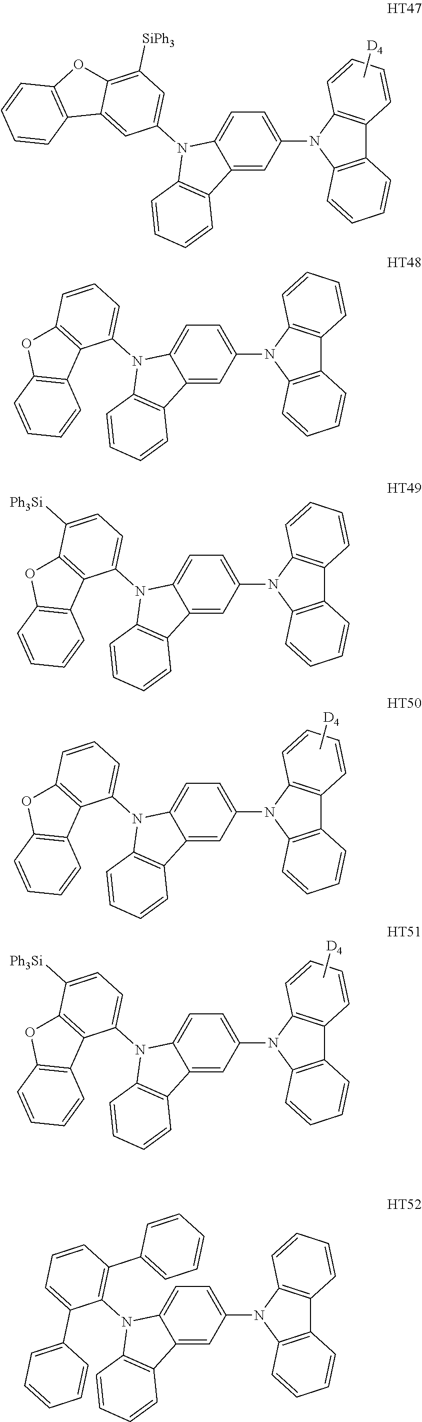

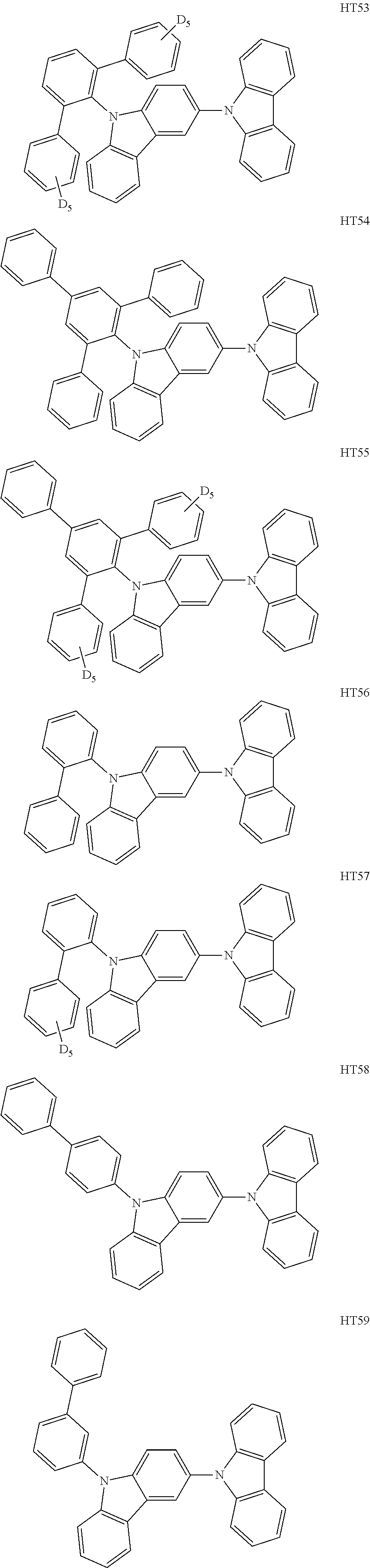

In embodiment compounds presented in Compound Group 2, “D” may refer to deuterium, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transporting host material for the emission layer EML.

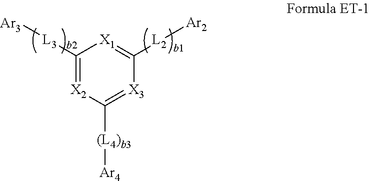

In Formula ET-1, at least one selected from among X₁ to X₃ is N, and the rest are CR₅₆. For example, in one or more embodiments, any one selected from among X₁ to X₃ may be N, and the rest may each independently be CR₅₆. In these embodiments, the third compound represented by Formula ET-1 may include a pyridine moiety. In one or more embodiments, two selected from among X₁ to X₃ may be N, and the rest may be CR₅₆. In these case, the third compound represented by Formula ET-1 may include a pyrimidine moiety. In one or more embodiments, X₁ to X₃ may all be N. In these embodiments, the third compound represented by Formula ET-1 may include a triazine moiety.

In Formula ET-1, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are integers of 2 or greater, L₂'s to L₄'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light emitting element ED of one or more embodiments may include any one selected from among the compounds in Compound Group 3.

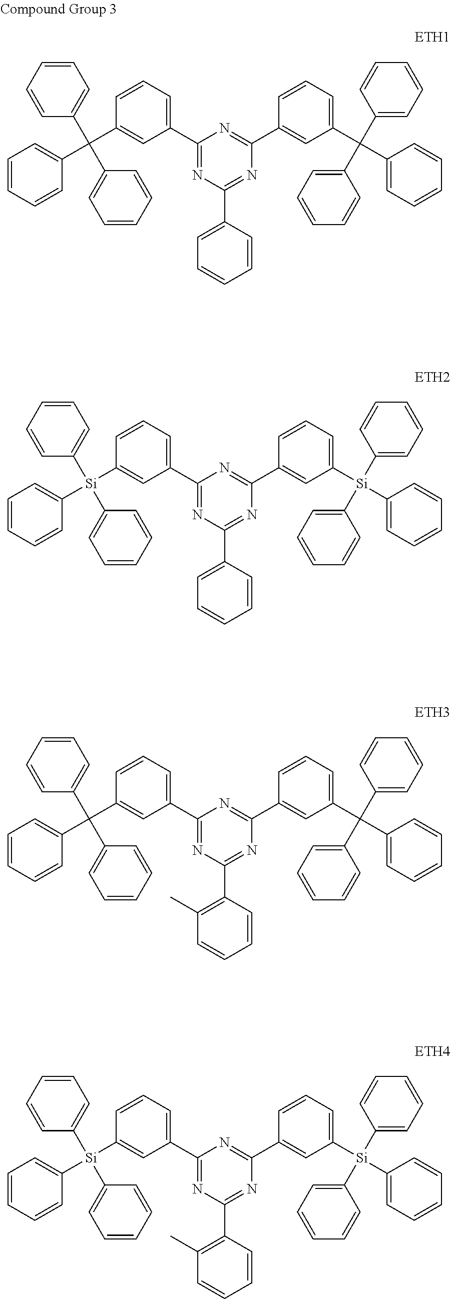 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

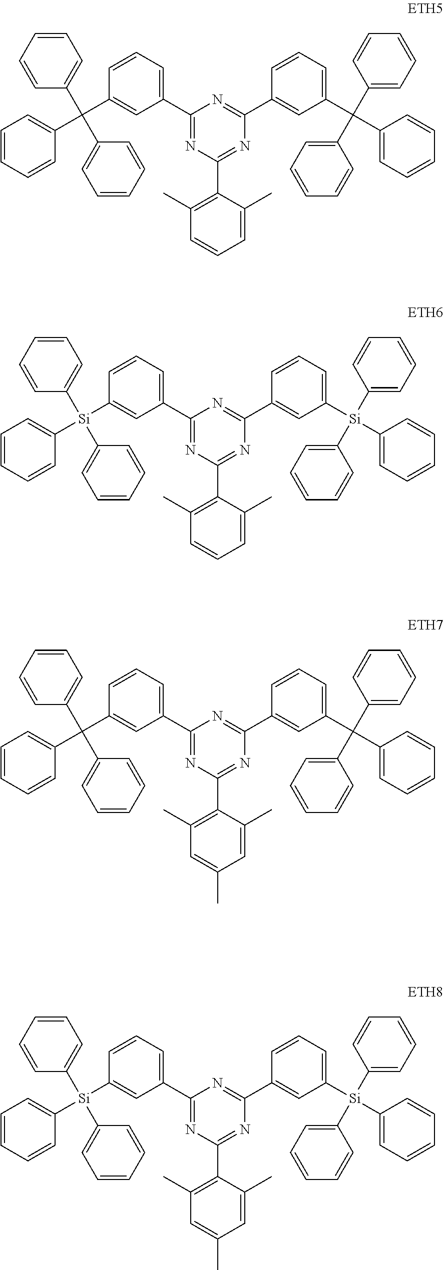 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

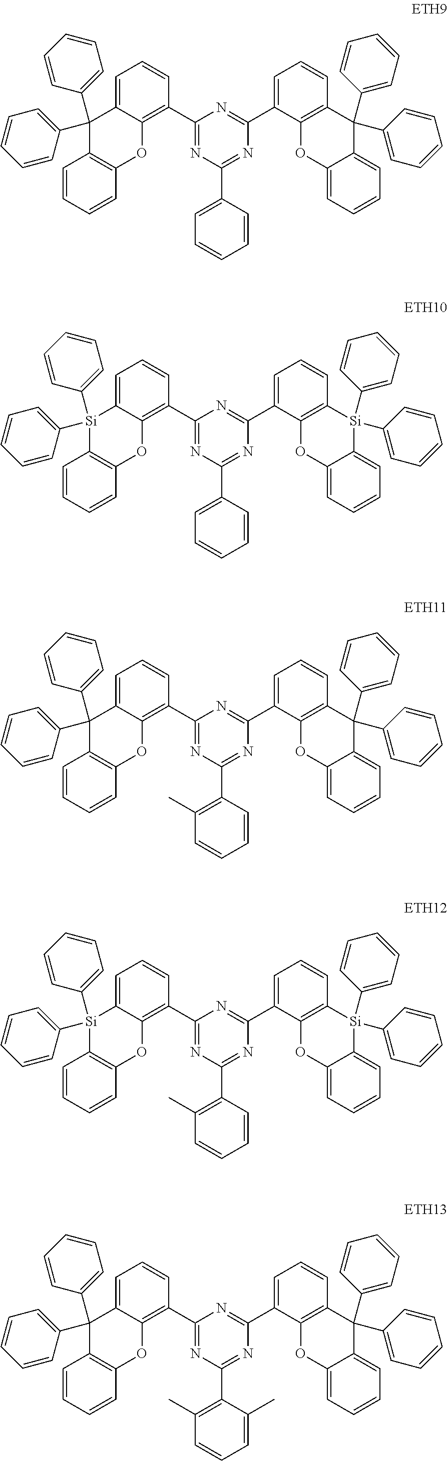

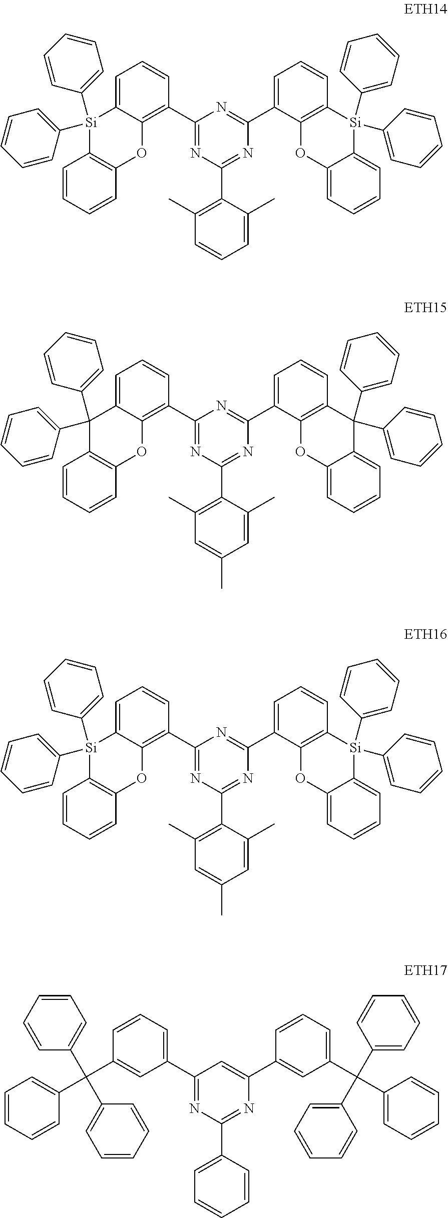 [SMILES: Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1]

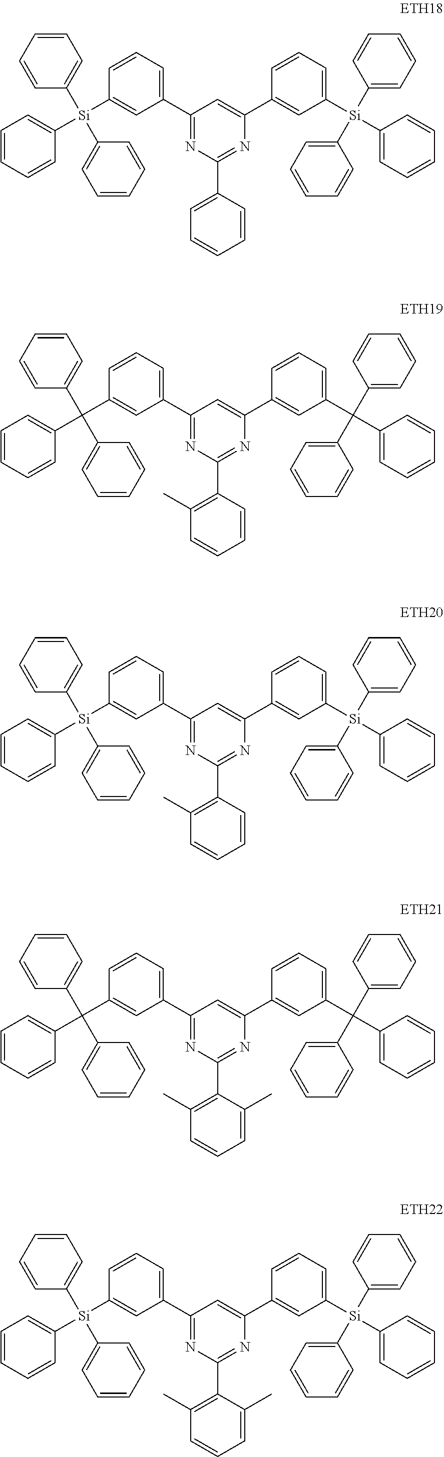

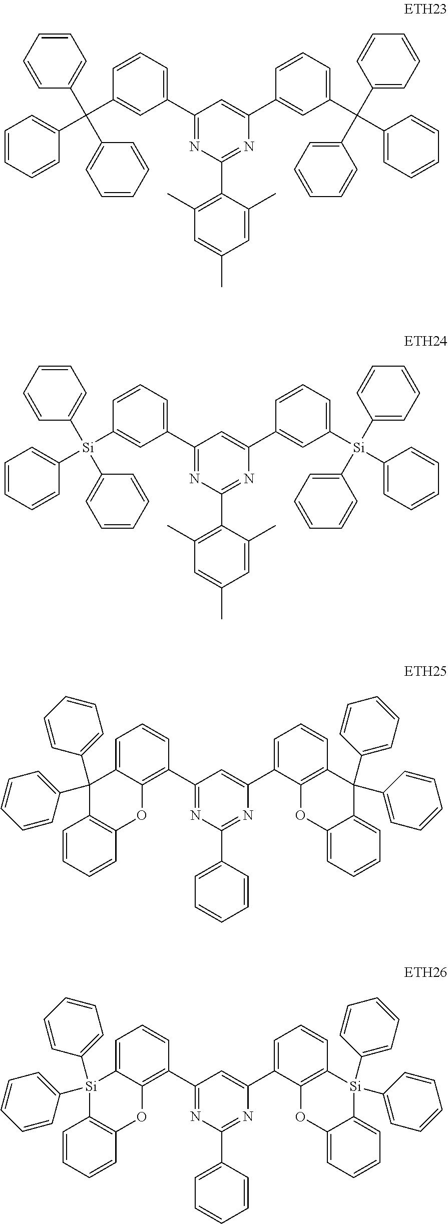 [SMILES: Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1]

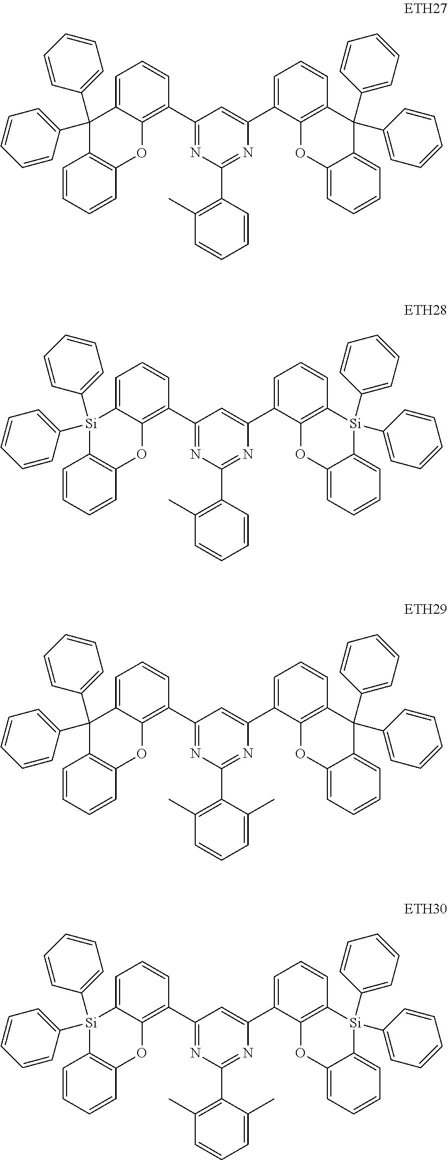 [SMILES: Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

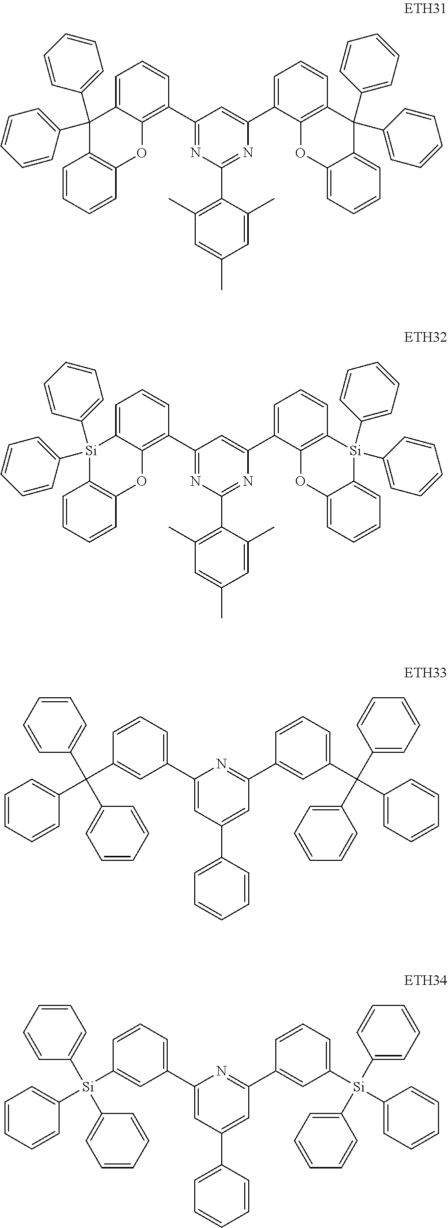 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1]

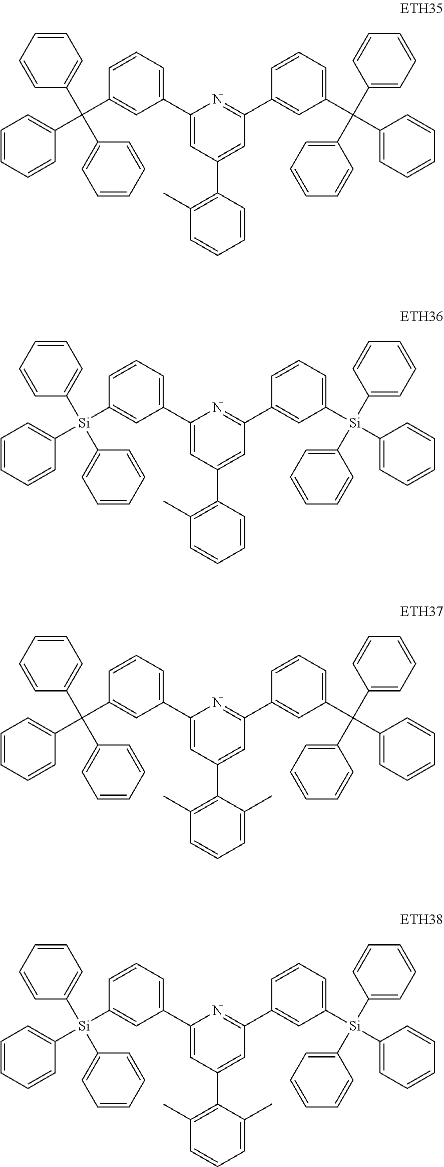 [SMILES: Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

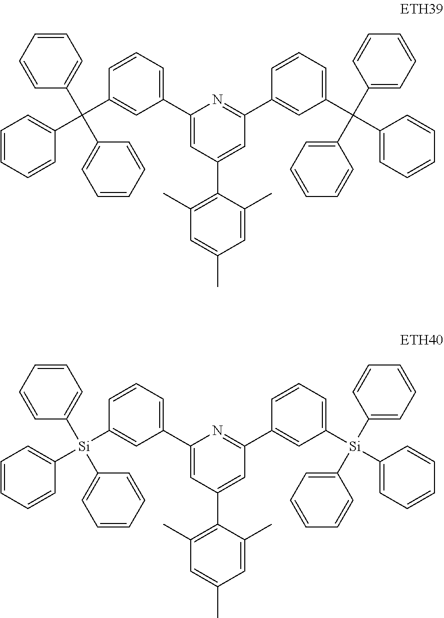 [SMILES: Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

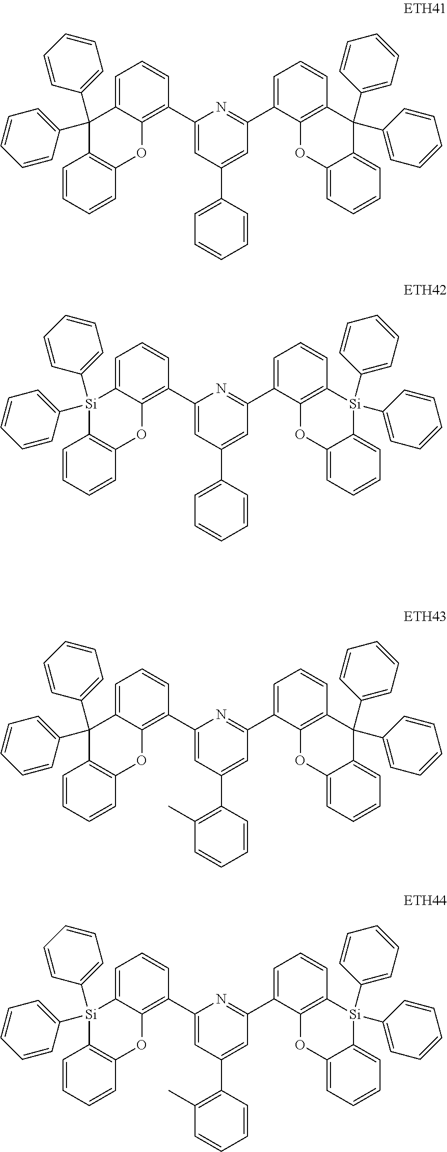 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

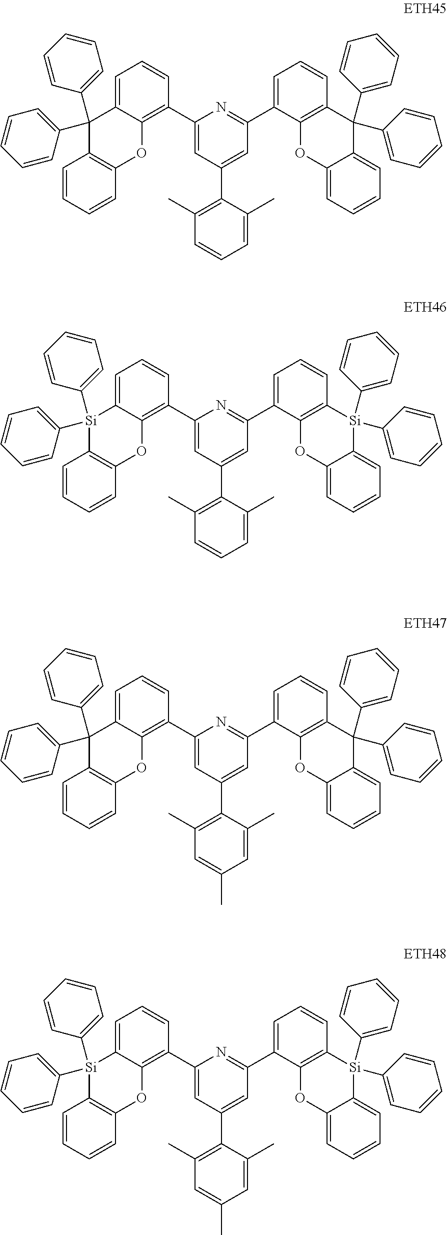 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

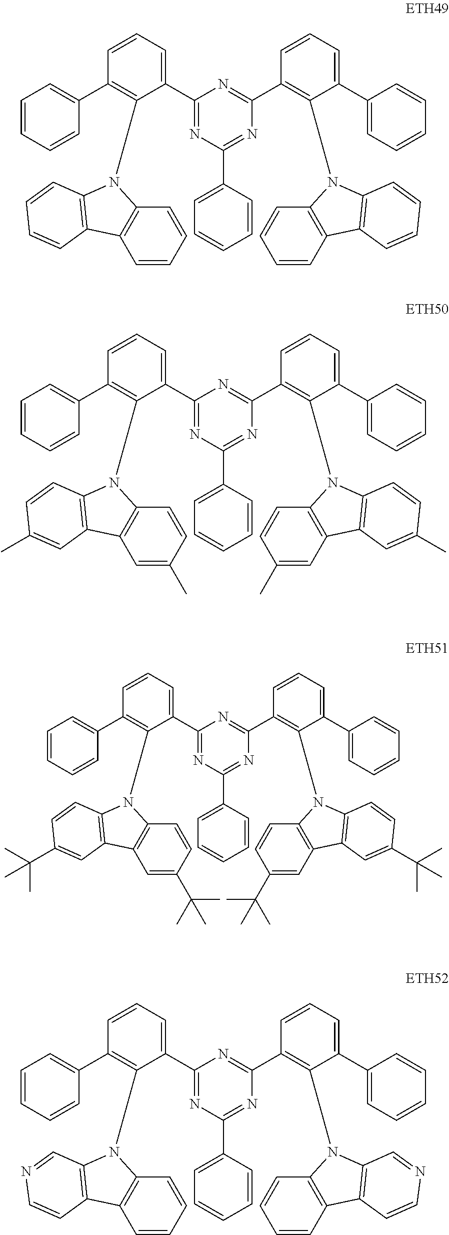

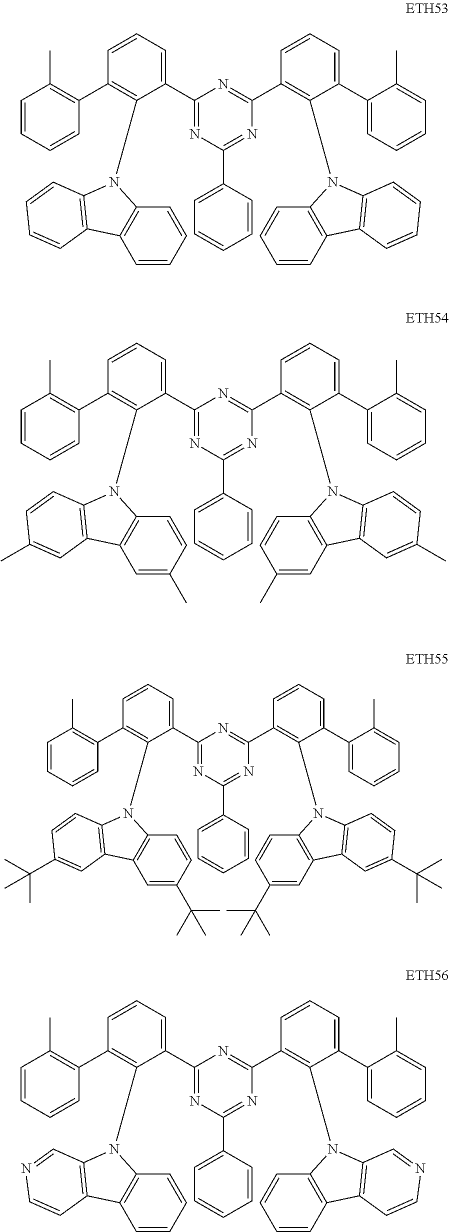

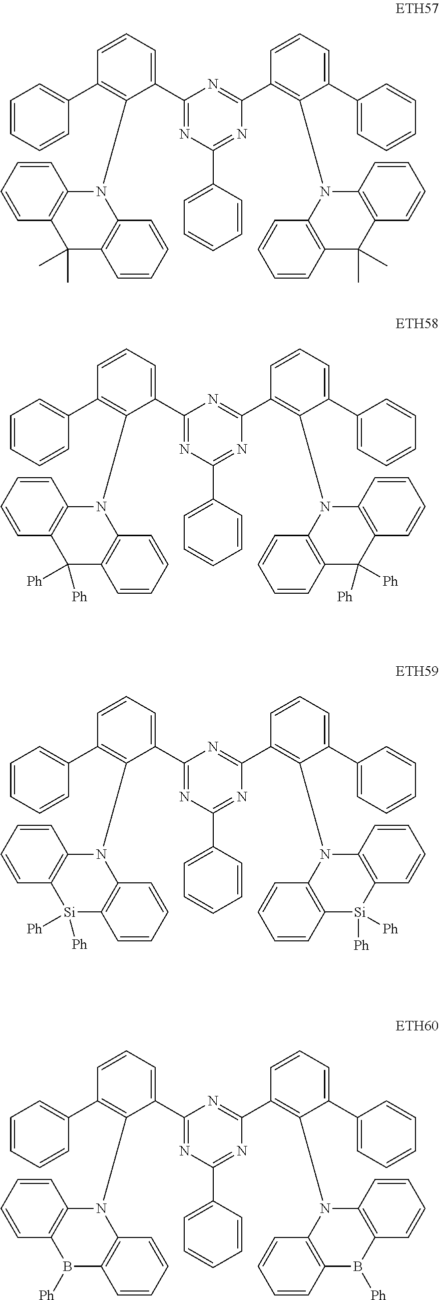

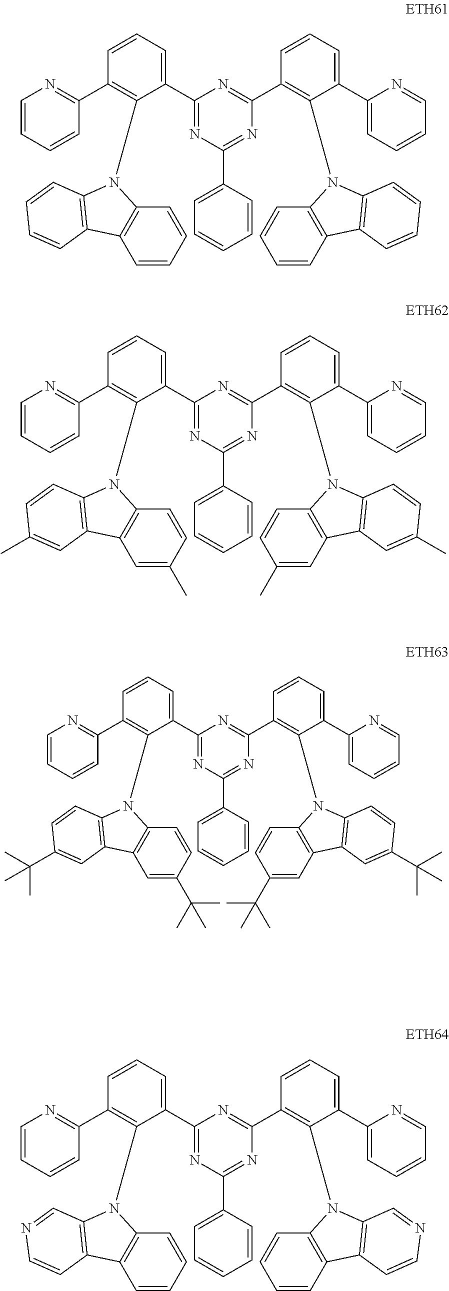

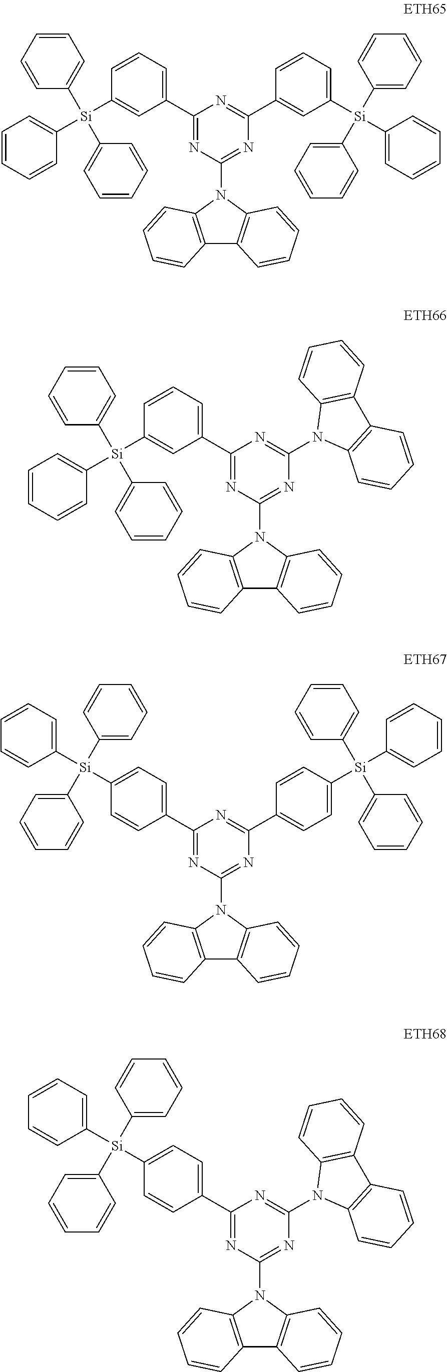 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

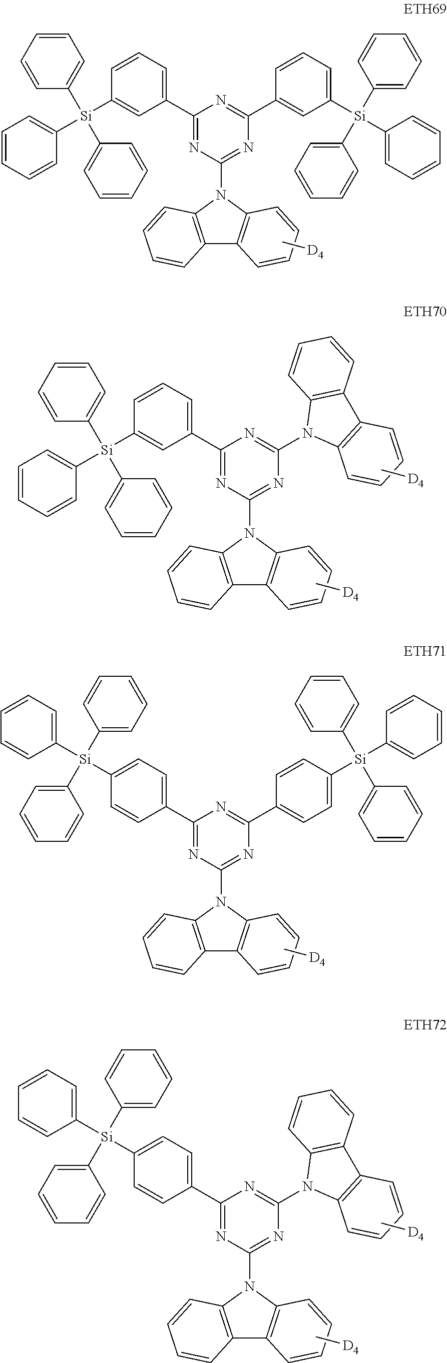

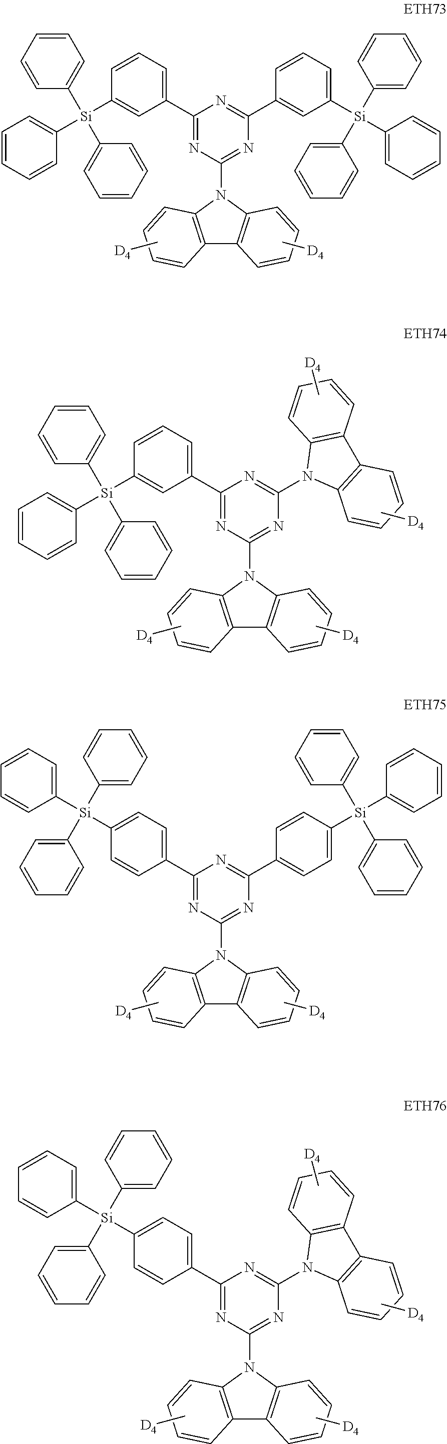

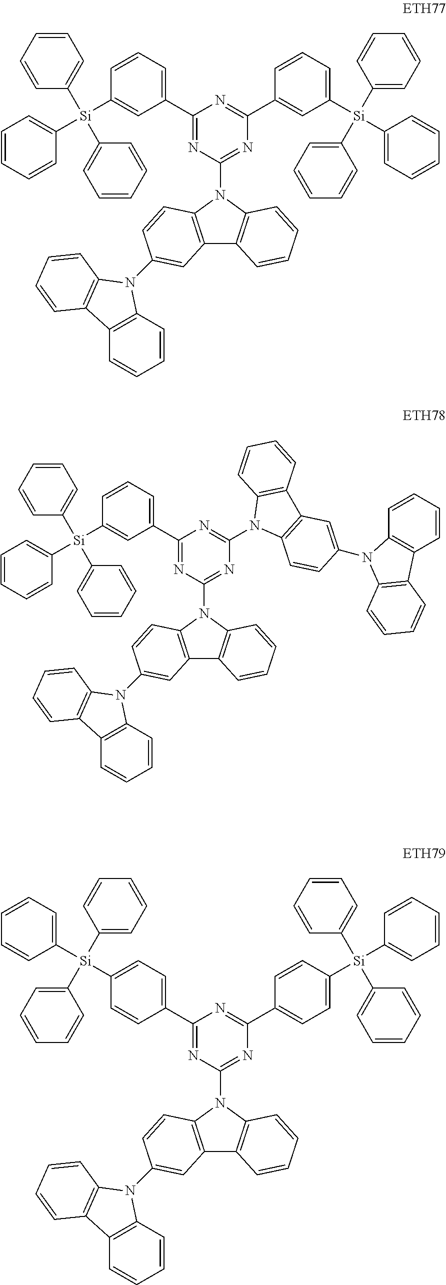 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

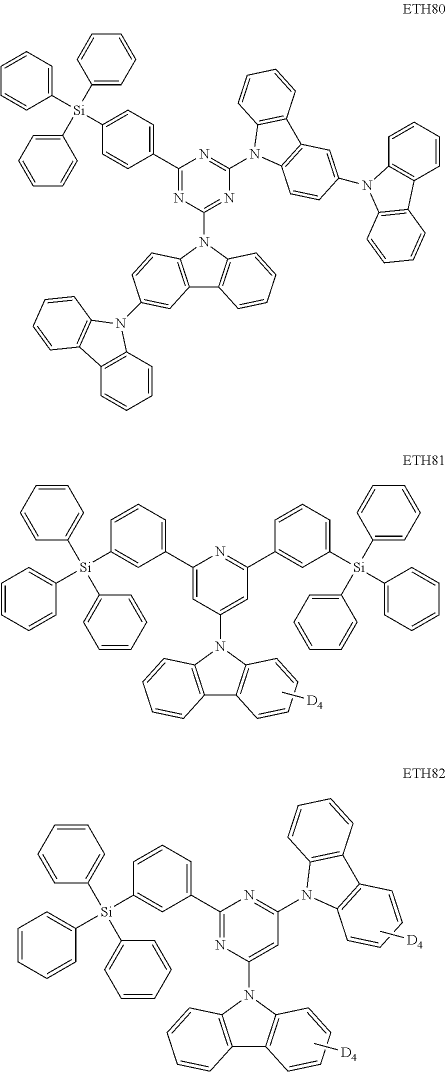

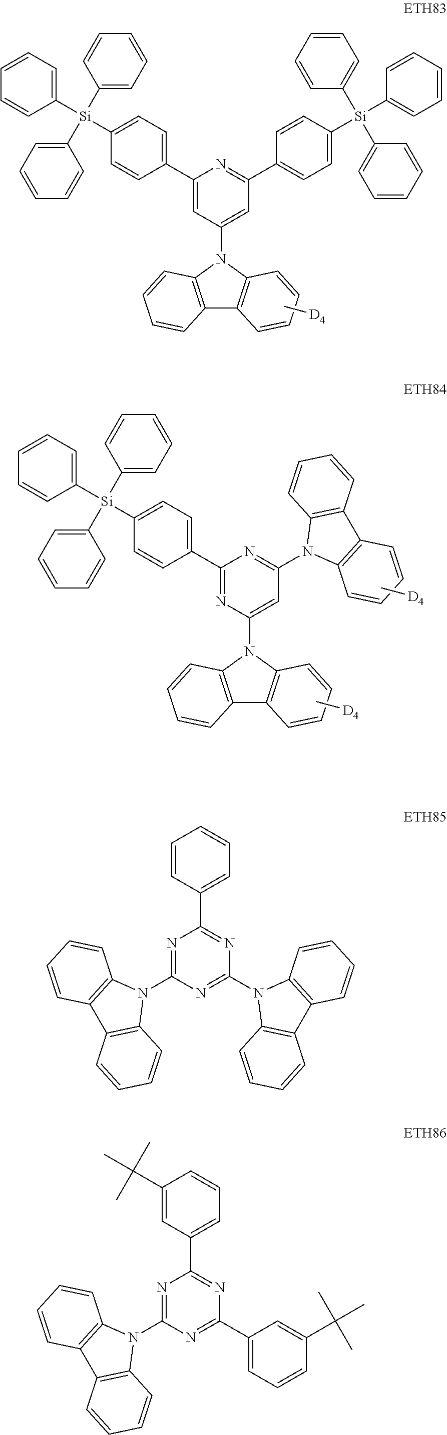

In the embodiment compounds presented in Compound Group 3, “D” refers to deuterium, and “Ph” refers to an unsubstituted phenyl group.

In one or more embodiments, the emission layer EML may include the second compound and the third compound, and the second compound and the third compound may form an exciplex. In the emission layer EML, an exciplex may be formed by the hole transporting host and the electron transporting host. In these embodiments, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, in one or more embodiments, an absolute value of the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described above. The fourth compound may be used as a phosphorescent sensitizer of the emission layer EML. The energy may be transferred from the fourth compound to the first compound, thereby emitting light.

For example, in one or more embodiments, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

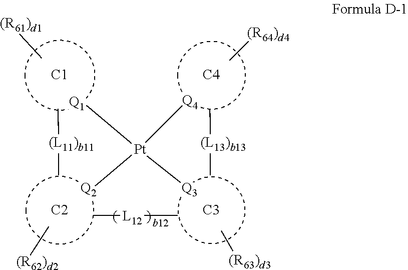

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage, *—O—*, *—S—*,

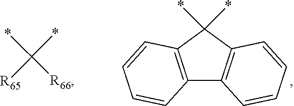

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃ refers to a part linked to C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₆₁ to R₆₆ may independently be bonded to an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with each of R₆₁ to R₆₄. The embodiment in which each of d1 to d4 is 4 and R₆₁'s to R₆₄' are each hydrogen may be the same as the embodiment in which each of d1 to d4 is 0. When each of d1 to d4 is an integer of 2 or greater, a plurality of R₆₁'s to R₆₄'s may each be the same, or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

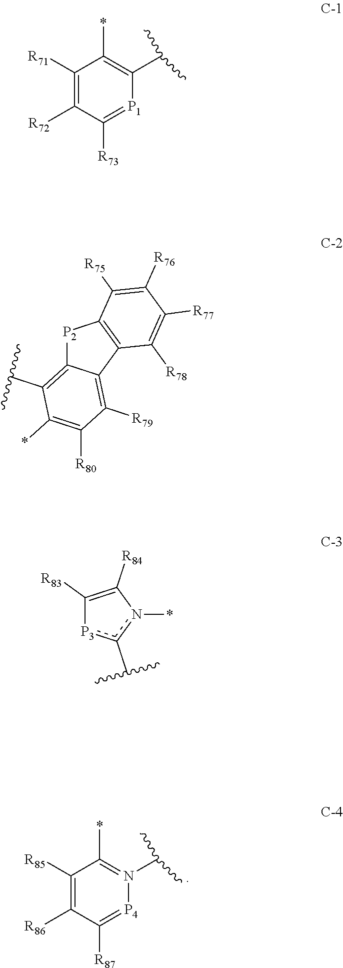

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In addition, in C-1 to C-4

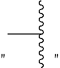

corresponds to a part linked to Pt that is a central metal atom, and “-*” corresponds to a part linked to a neighboring cyclic group (C1 to C4) or an adjacent linker (L₁₁ to L₁₃).

The emission layer EML of one or more embodiments may include the first compound, which is a fused polycyclic compound represented by Formula 1, and at least one selected from among the second to fourth compounds. For example, in one or more embodiments, the emission layer EML may include the first compound, the second compound, and the third compound. In the emission layer EML, the second compound and the third compound may form an exciplex, and the energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, in one or more embodiments, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In addition, if (e.g., when) the energy delivery to the first compound is increased, an exciton formed in the emission layer EML is not accumulated inside the emission layer EML but emits light rapidly, and thus deterioration of the element may be reduced. Therefore, the service life of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be any one (e.g., one) selected from among compounds represented in Compound Group 4. The emission layer EML may include at least one among the compounds represented in Compound Group 4 as a sensitizer material.

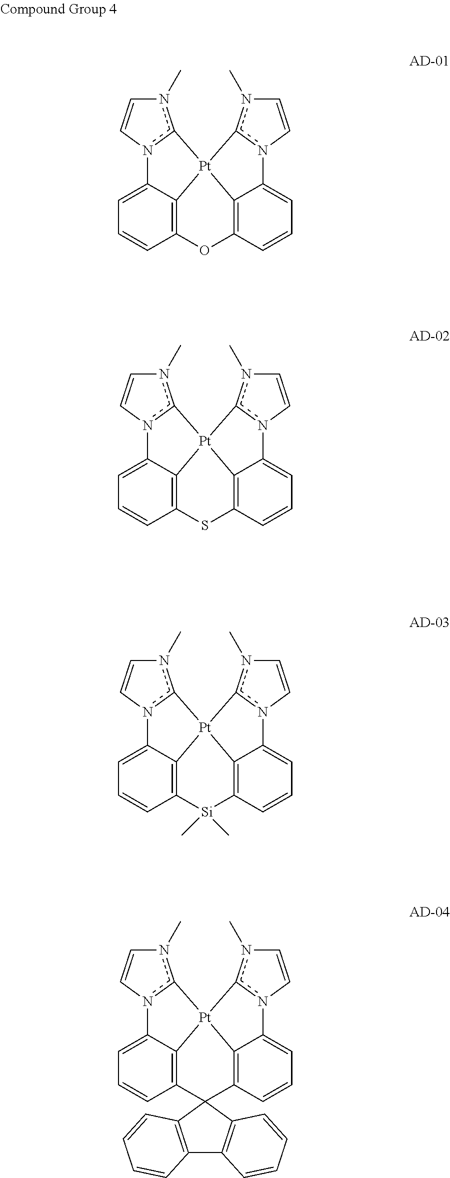

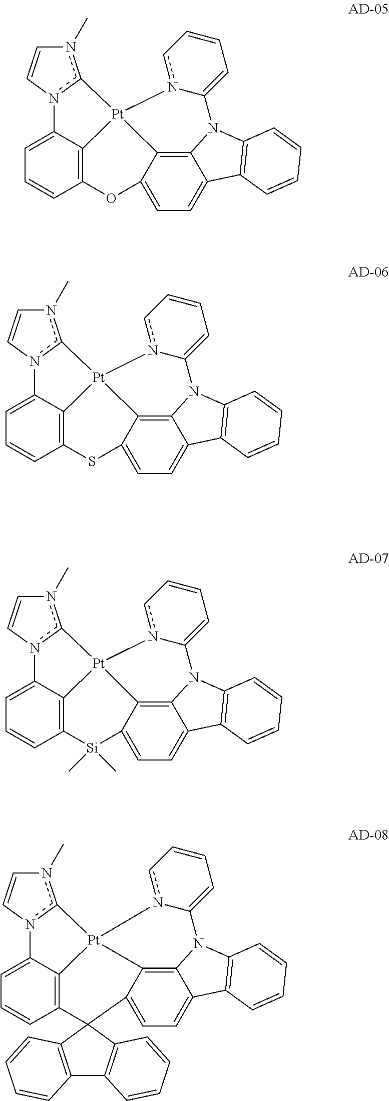

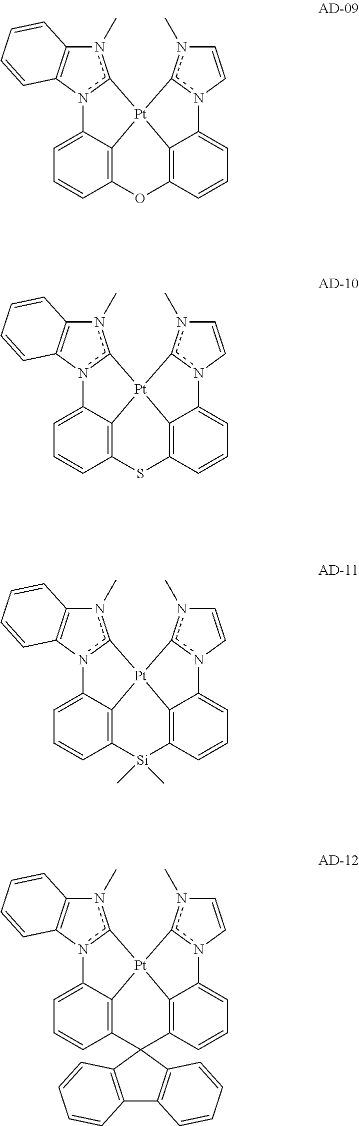

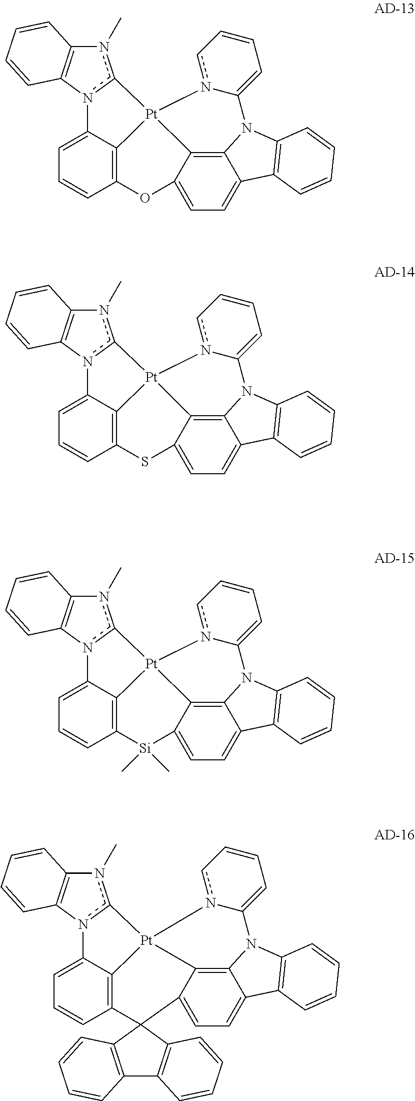

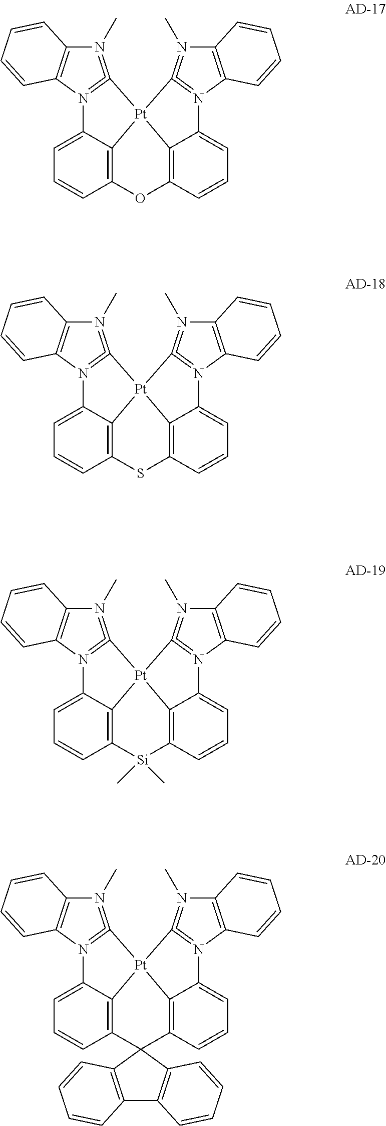

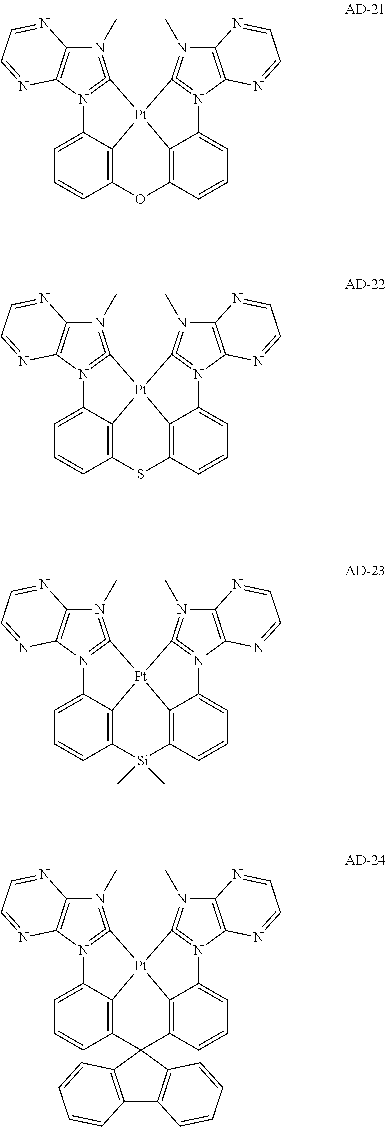

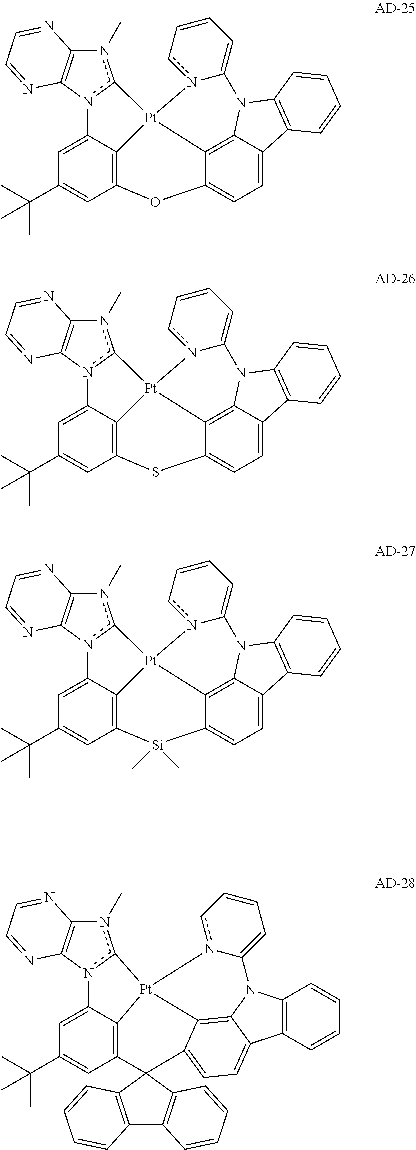

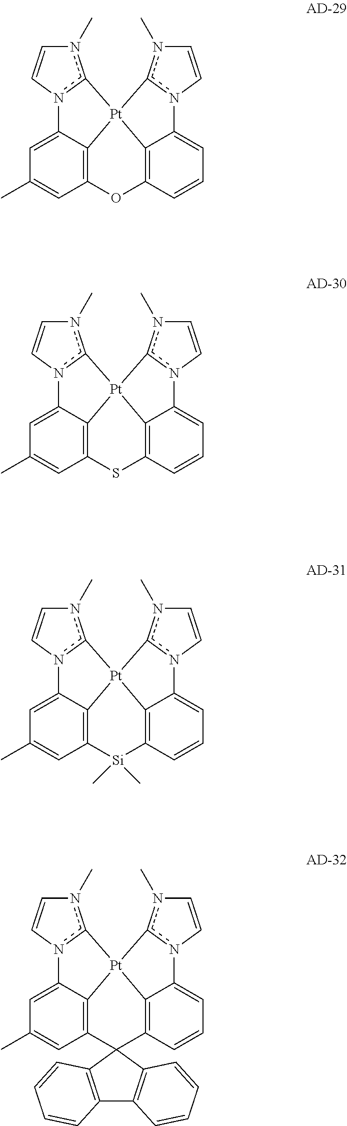

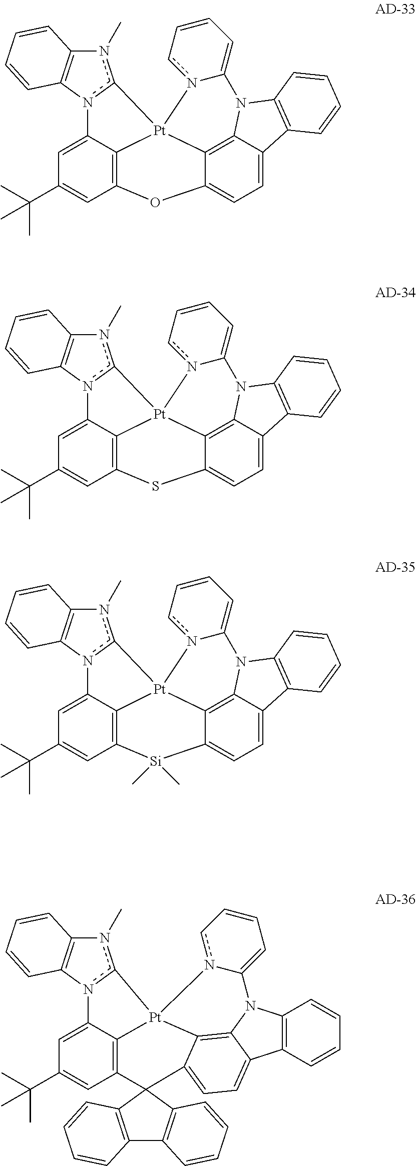

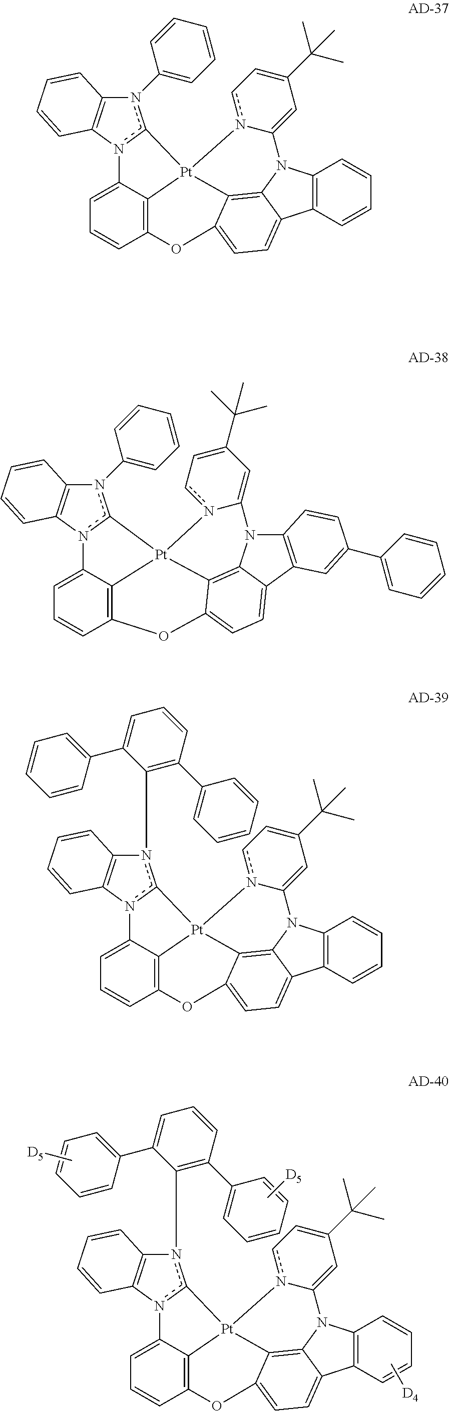

In the embodiment compounds presented in Compound Group 4, “D” refers to deuterium.

When the emission layer EML in the light emitting element ED of one or more embodiments includes all of the first compound, the second compound, and the third compound, with respect to a total weight of the first compound, the second compound, and the third compound, the content (e.g., amount) of the first compound may be about 0.1 wt % to about 5 wt %. However, embodiments of the present disclosure are not limited thereto. When the content (e.g., amount) of the first compound satisfy the above-described proportion, the energy transfer from the second compound and the third compound to the first compound may increase, and thus the luminous efficiency and element service life may increase.

The contents (e.g., amounts) of the second compound and the third compound in the emission layer EML may be the rest excluding the weight of the first compound. For example, the contents of the second compound and the third compound in the emission layer EML may be about 65 wt % to about 99 wt % with respect to the total weight of the first compound, the second compound, and the third compound.

In the total weight of the second compound and the third compound, a weight ratio of the second compound to the third compound may be about 3:7 to about 7:3.

When the contents (e.g., amounts) of the second compound and the third compound satisfy the above-described ratio, a charge balance characteristic in the emission layer EML are improved, and thus the luminous efficiency and element service life may increase. When the contents (e.g., amounts) of the second compound and the third compound deviate from the above-described ratio range, a charge balance in the emission layer EML is broken, and thus the luminous efficiency may be reduced and the element may be easily deteriorated.

In one or more embodiments, when the emission layer EML includes the fourth compound, the content (e.g., amount) of the fourth compound in the emission layer EML may be about 10 wt % to about 30 wt % with respect to a total weight of the first compound, the second compound, the third compound, and the fourth compound. However, embodiments of the present disclosure are not limited thereto. When the content (e.g., amount) of the fourth compound satisfies the above-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life of the light emitting element may be achieved.

The emission layer EML may be provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED of one or more embodiments, the emission layer EML may include at least one of an anthracene derivative, a pyrene derivative, a fluoranthene derivative, a chrysene derivative, a dihydrobenzanthracene derivative, or a triphenylene derivative. For example, in one or more embodiments, the emission layer EML may include the anthracene derivative and/or the pyrene derivative.

In each light emitting element ED of embodiments illustrated in FIGS. 3 to 7, the emission layer EML may further include a suitable host and/or dopant besides the above-described host and dopant, and for example, in one or more embodiments, the emission layer EML may include a compound represented by Formula E-1. The compound represented by Formula E-1 may be used as a fluorescent host material.

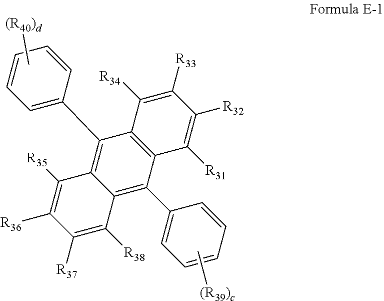

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among R₃₁ to R₄₀ may be each independently bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among Compound E1 to Compound E19:

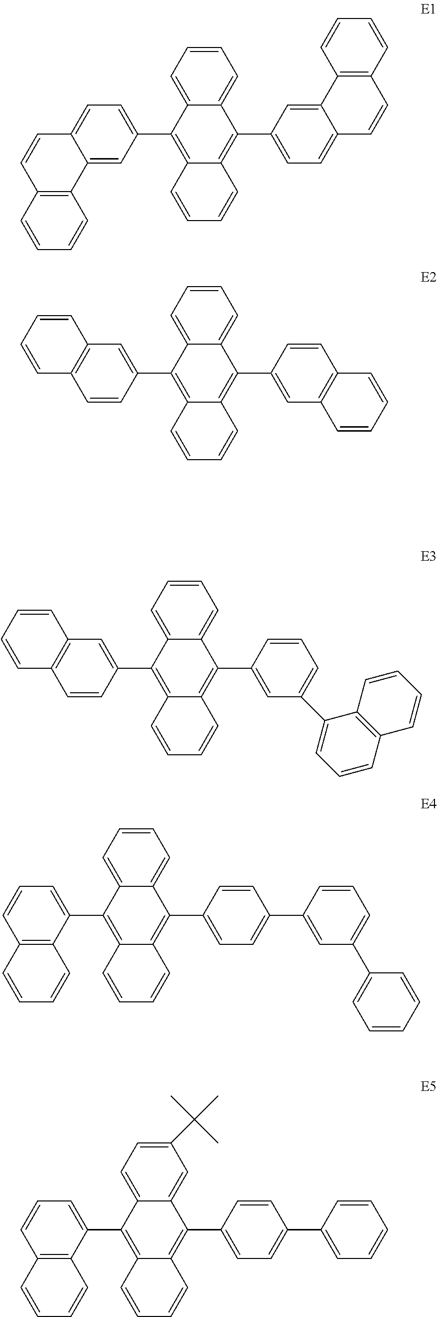

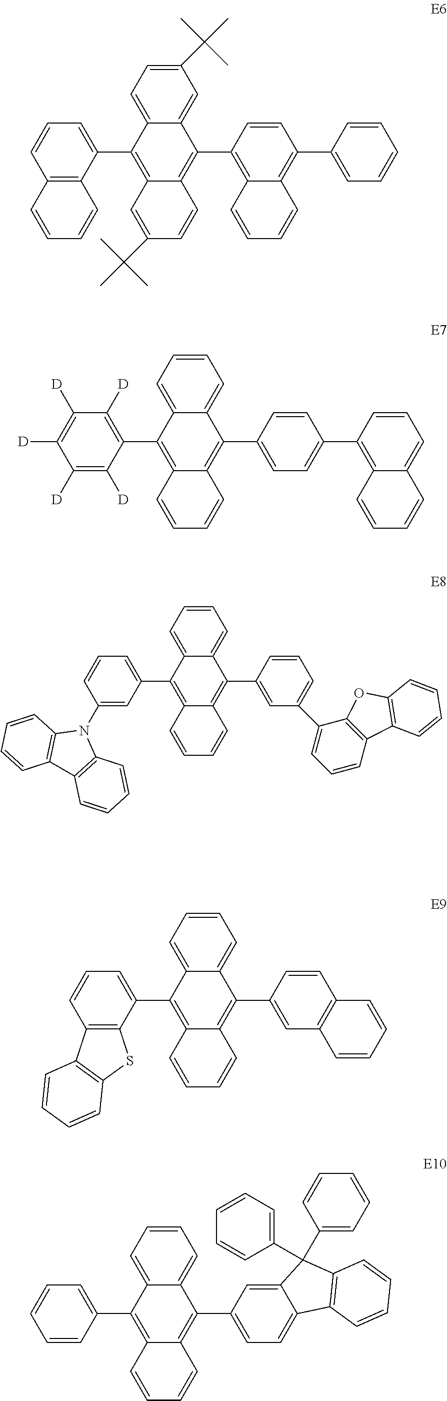

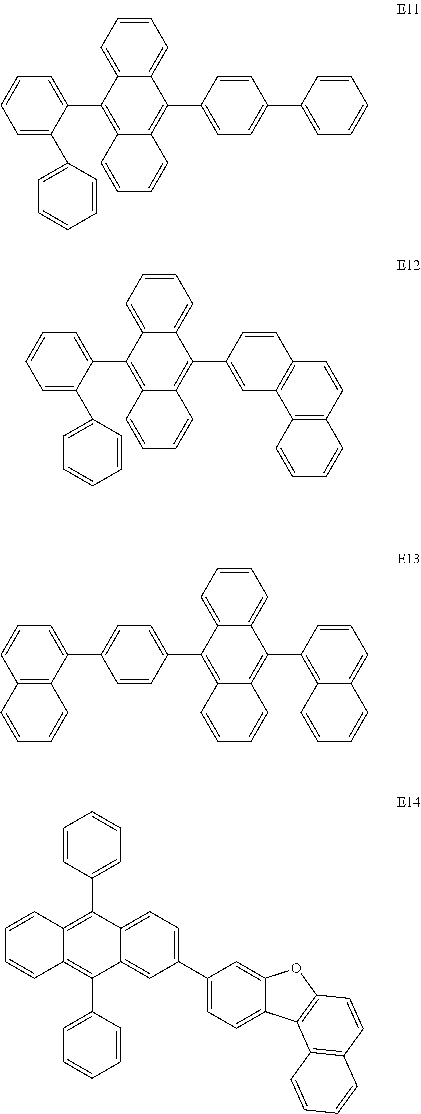

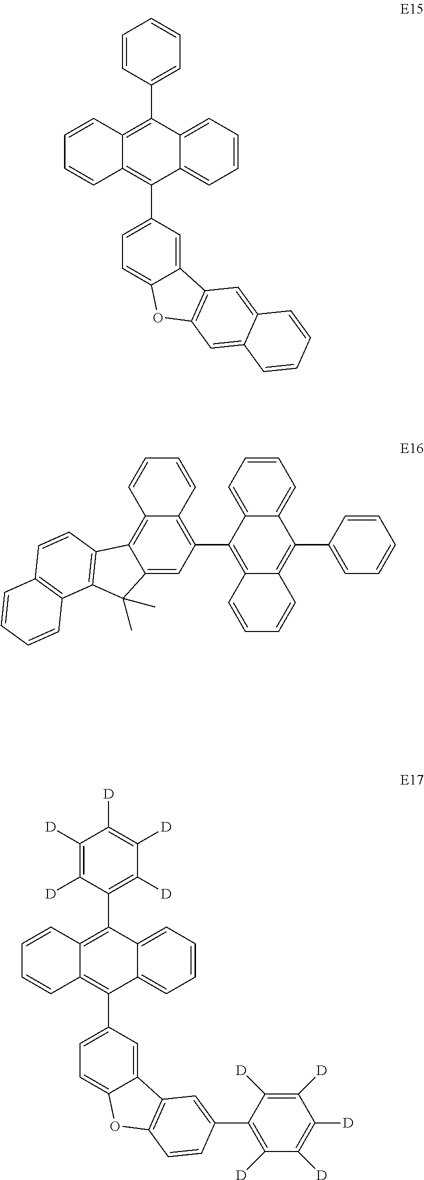

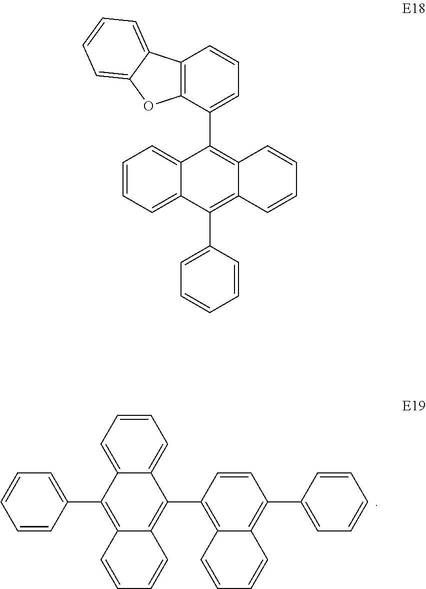

In one or more embodiments, the emission layer EML may include a compound represented by Formula E-2a or Formula E-2b. The compound represented by Formula E-2a or Formula E-2b may be used as a phosphorescent host material.

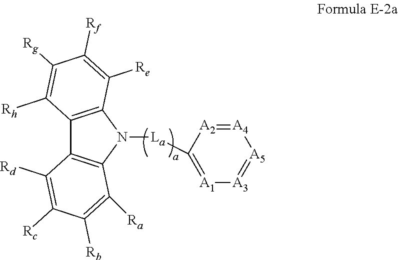

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of Lₐ's may each independently be a substituted or unsubstituted arylene group having 6 to 30 ring-forming carbon atoms or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

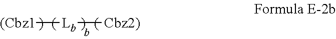

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, b may be an integer of 0 to 10, and if (e.g., when) b is an integer of 2 or greater, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are mere examples, and the compound represented by Formula E-2a or Formula E-2b is not limited to those represented in Compound Group E-2.

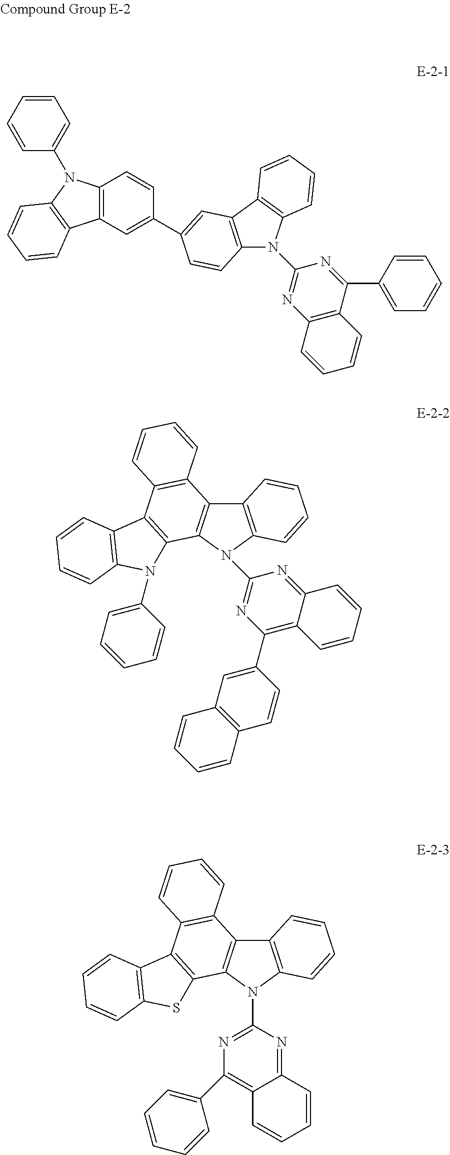 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

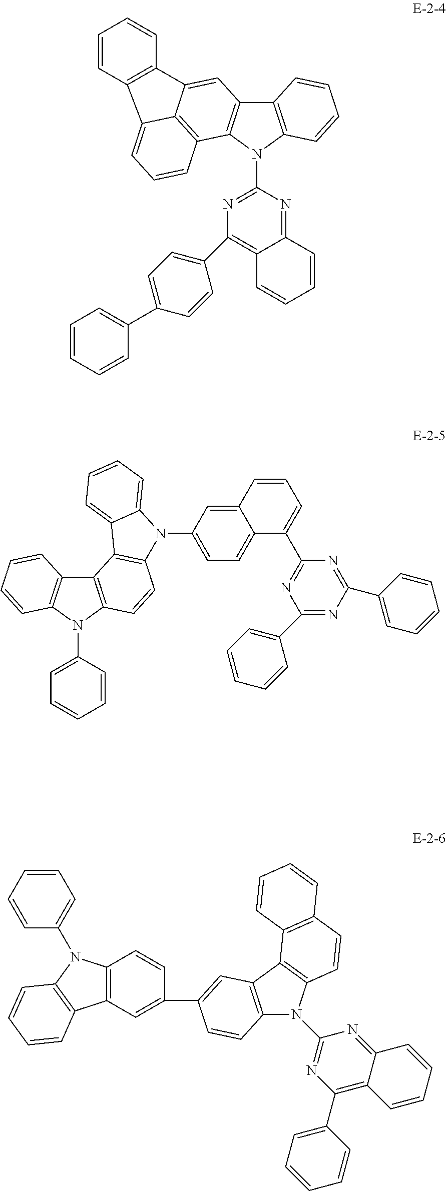 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

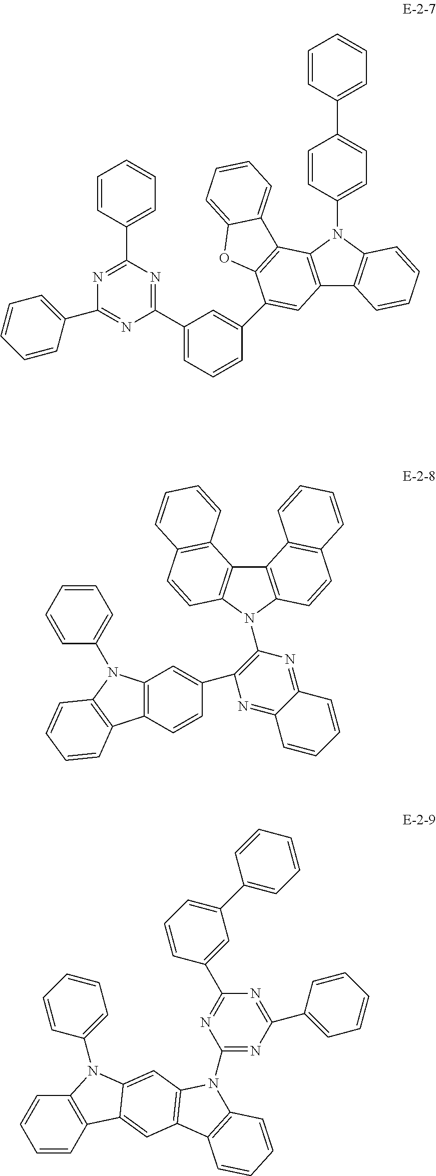 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

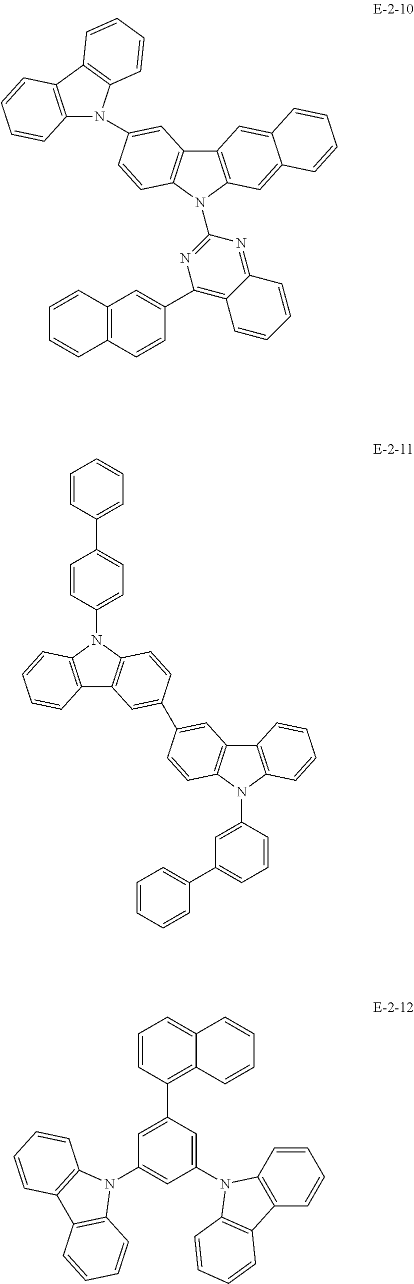 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

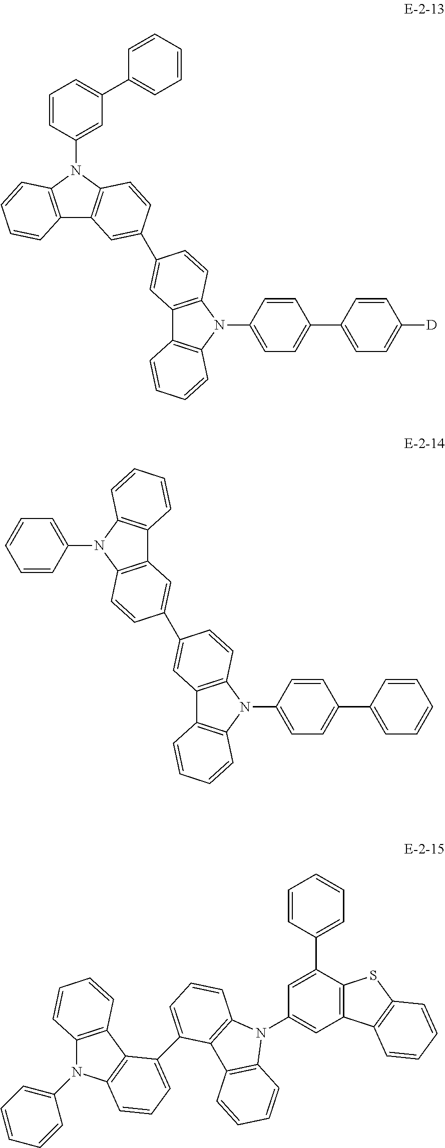 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

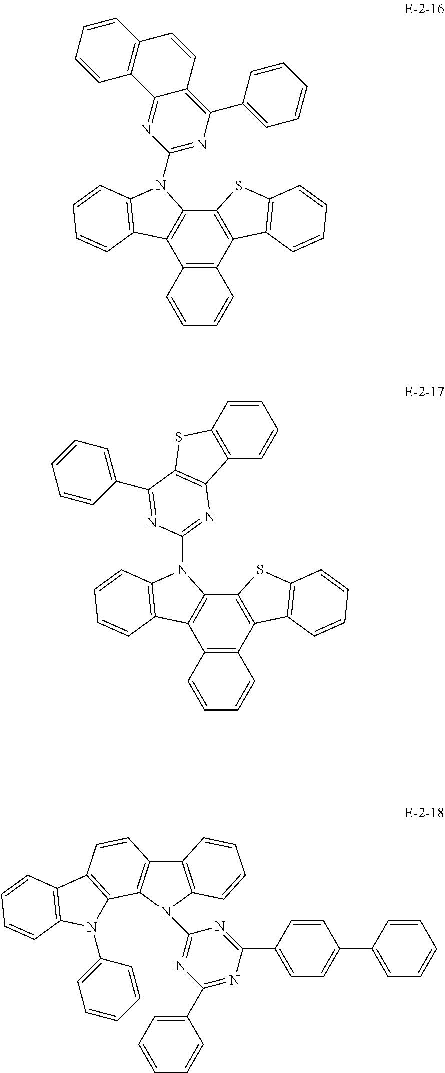 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

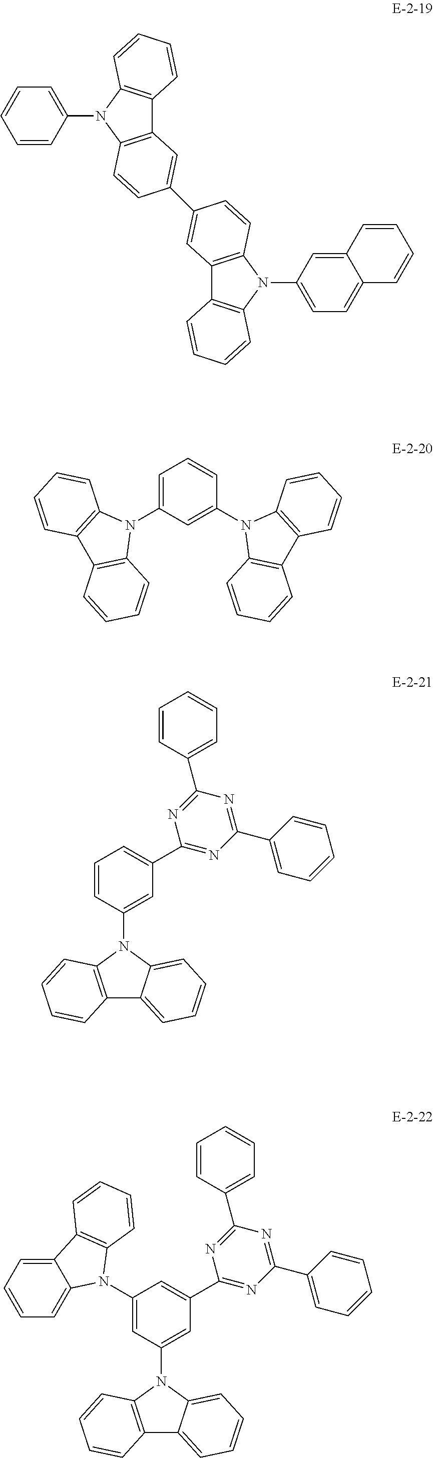 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

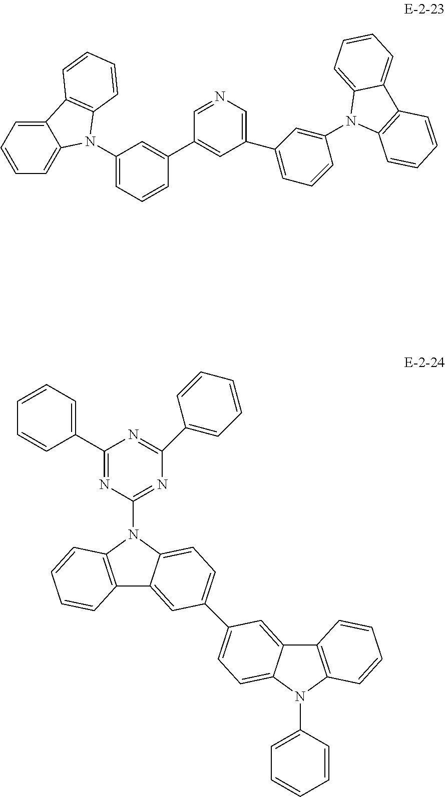 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto, for example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like, may be used as a host material.

In one or more embodiments, the emission layer EML may include a compound represented by Formula M-a. The compound represented by Formula M-a may be used as a phosphorescent dopant material.

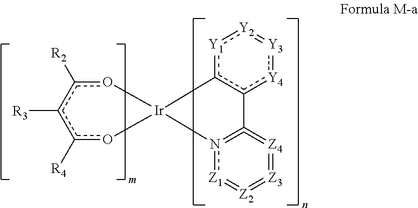

In Formula M-a, Y₁ to Y₄ and Z₁ to Z₄ may each independently be CR₁ or N, R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25:

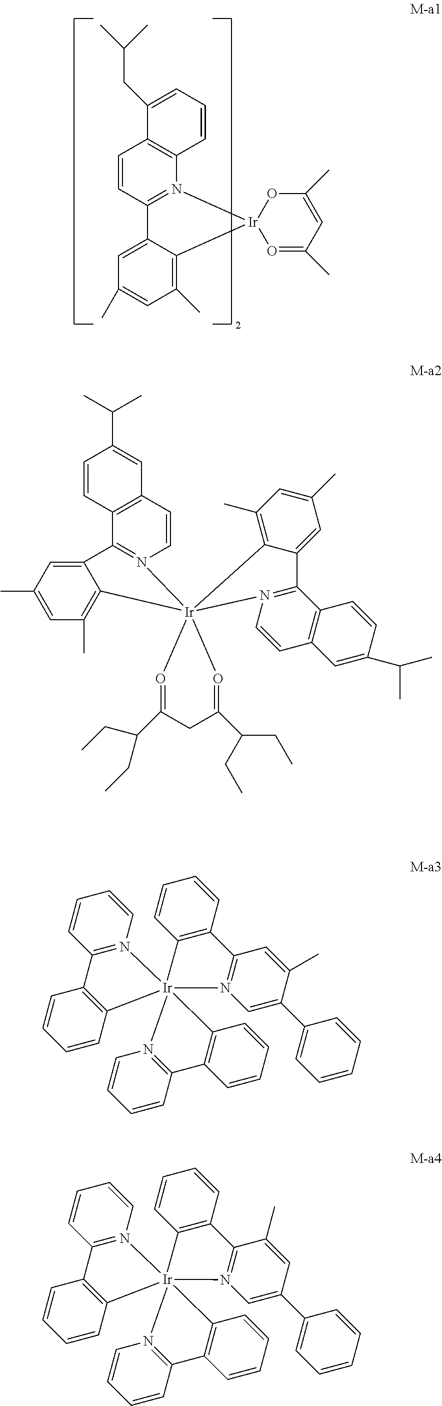

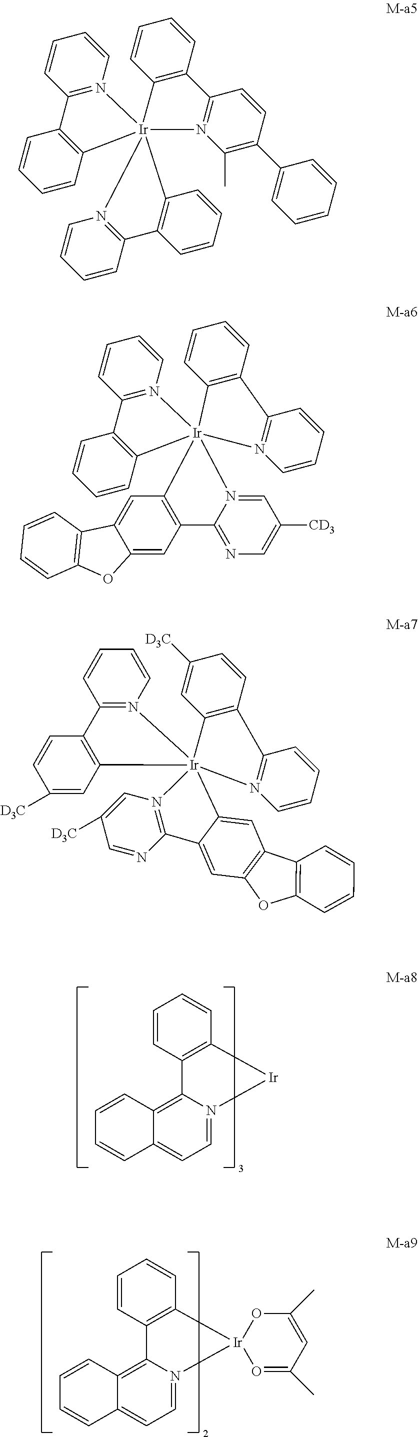

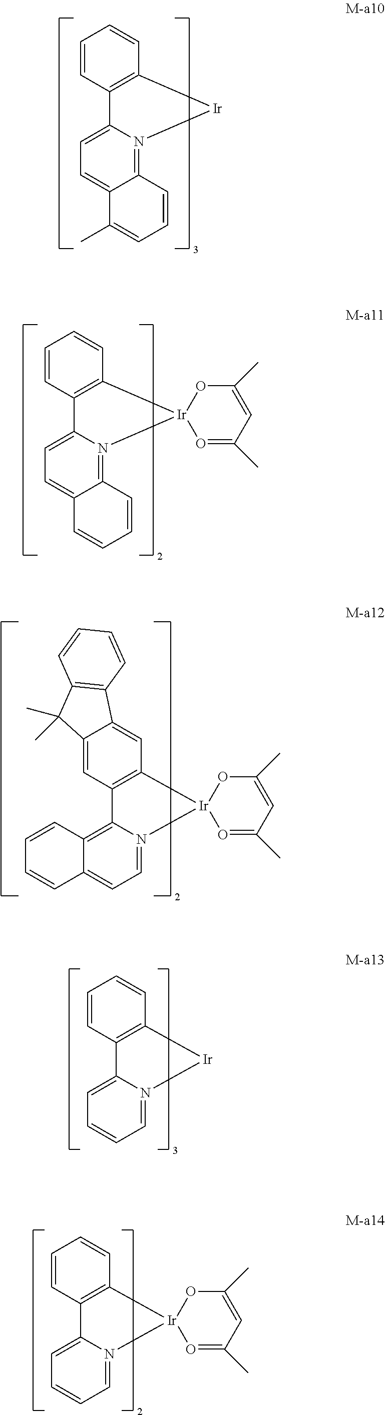

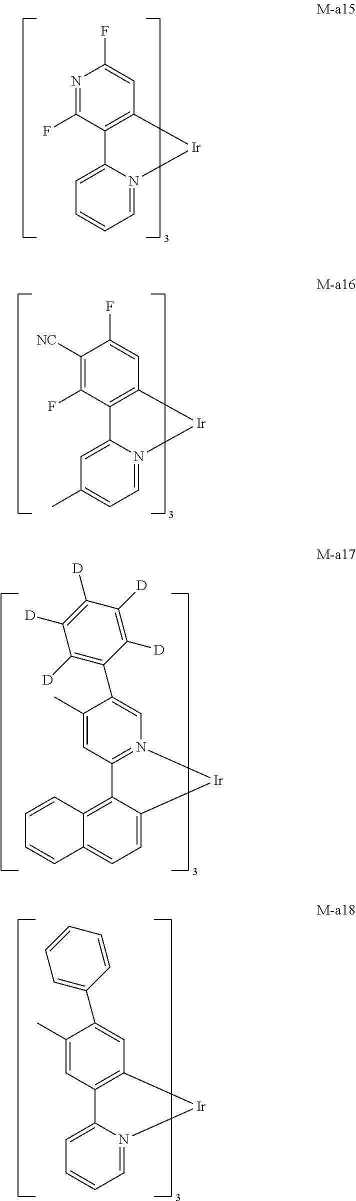

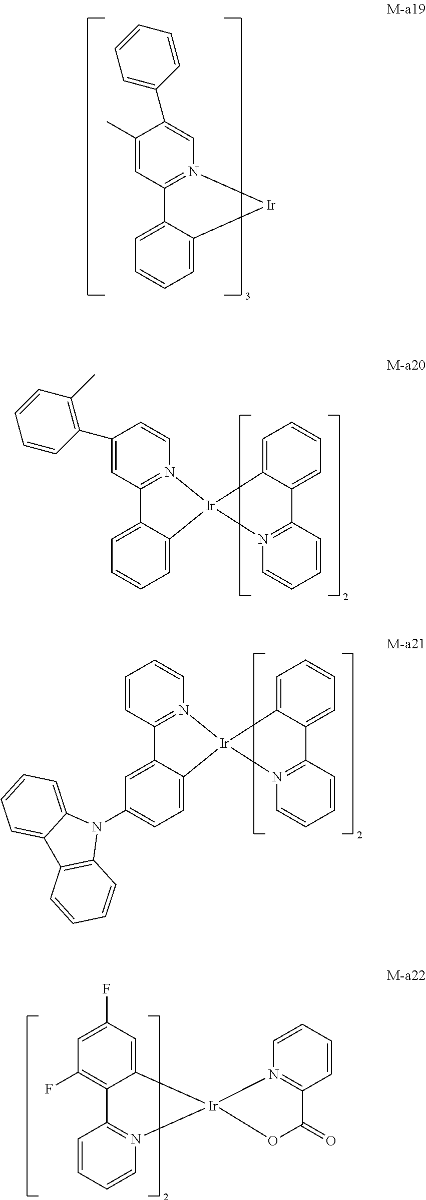

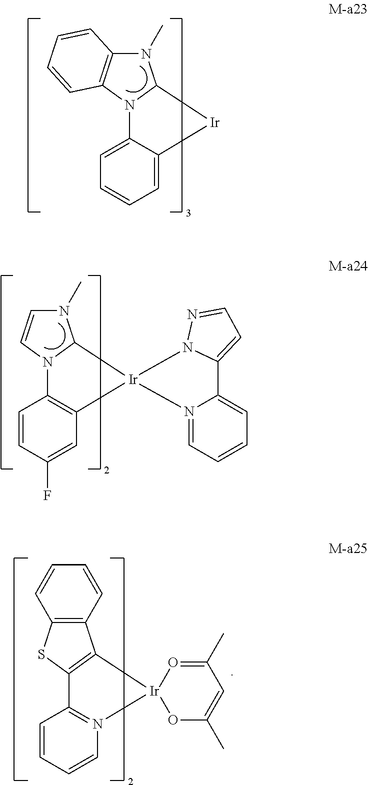

In one or more embodiments, the emission layer EML may include a compound represented by any one selected from among Formula F-a to Formula F-c. The compound represented by Formula F-a to Formula F-c may be used as a fluorescence dopant material.

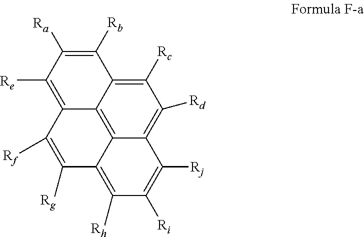

In Formula F-a, two selected from among Rₐ to Rⱼ may each independently be substituted with *—NAr₁Ar₂. The others, which are not substituted with *—NAr₁Ar₂, among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, at least one of Ar₁ or Ar₂ may be a heteroaryl group containing O or S as a ring-forming atom.

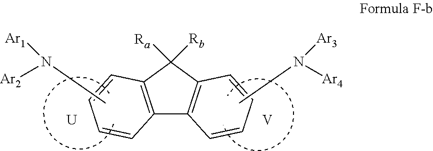

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a part of a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

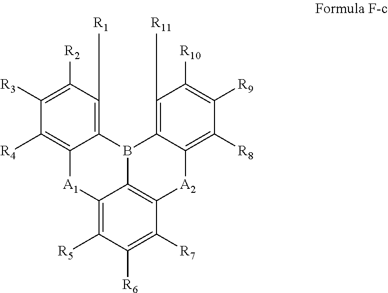

In Formula F-c, A₁ and A₂ may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, in Formula F-c, A₁ and A₂ may each independently be bonded to substituents of an adjacent ring to form a fused ring. For example, if (e.g., when) A₁ and A₂ may each independently be NRₘ, in one or more embodiments, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, one or more selected from among styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and/or the like.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N, C2′)picolinate) (Flrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments of the present disclosure are not limited thereto.

In one or more embodiments, the emission layer EML may include a quantum dot material. In one or more embodiments, the quantum dot material may have a core/shell structure. A core of a quantum dot may be selected from among a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, and/or a (e.g., any suitable) combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a (e.g., any suitable) mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a (e.g., any suitable) mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a (e.g., any suitable) mixture thereof.

In one or more embodiments, the Group II-VI compound may further include a Group I metal and/or a Group IV element. The Group I-II-VI compound may be selected from among CuSnS and CuZnS, and the Group II-IV-VI compound may be selected from among ZnSnS and/or the like. The Group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂, and a (e.g., any suitable) mixture thereof.

The Group II-IV-V compound may be selected from ternary compounds selected from the group consisting of ZnSnP, ZnSnP₂, ZnSnAs₂, ZnGeP₂, ZnGeAs₂, CdSnP₂, CdGeP₂, and a (e.g., any suitable) mixture thereof.

The Group III-VI compound may include a binary compound such as GaS, Ga₂S₃, GaSe, Ga₂Se₃, GaTe, InTe, InS, InSe, In₂S₃, In₂Se₃, and/or the like, a ternary compound such as InGaS₃, InGaSe₃, and/or the like, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a (e.g., any suitable) mixture thereof, and/or a quaternary compound such as AgInGaS₂, CuInGaS₂, and/or the like.

The Group III-V compound may be selected from the group consisting of a binary compound selected from the group consisting of GaN, GaP, GaAs, GaSb, AlN, AlP, AlAs, AlSb, InN, InP, InAs, InSb, and a (e.g., any suitable) mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a (e.g., any suitable) mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a (e.g., any suitable) mixture thereof. In one or more embodiments, the Group III-V compound may further include a Group II metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and a (e.g., any suitable) mixture thereof, a ternary compound selected from the group consisting of SnSeS, SnSeTe, SnSTe, PbSeS, PbSeTe, PbSTe, SnPbS, SnPbSe, SnPbTe, and a (e.g., any suitable) mixture thereof, and a quaternary compound selected from the group consisting of SnPbSSe, SnPbSeTe, SnPbSTe, and a (e.g., any suitable) mixture thereof. The Group IV element may be selected from the group consisting of Si, Ge, and a (e.g., any suitable) mixture thereof. The Group IV compound may be a binary compound selected from the group consisting of SiC, SiGe, and a (e.g., any suitable) mixture thereof.

Each element included in a multi-element compound, such as the binary compound, the ternary compound, or the quaternary compound, may be present in a particle at a substantially uniform concentration or non-uniform concentration. For example, the above formula represents types (kinds) of elements included in a compound, and the ratio of elements in the compound may vary. For example, AgInGaS₂ may represent AgInₓGa₁₋ₓS₂ (wherein x is a real number of 0 and 1).

In one or more embodiments, the quantum dot may have a single structure in which the concentration of each element included in the corresponding quantum dot is substantially uniform or a dual structure of a core-shell. For example, a material included in the core and a material included in the shell may be different from each other.

A shell of the quantum dot may serve as a protective layer for preventing or reducing the chemical deformation of the core to maintain semiconductor properties, and/or a charging layer to impart electrophoresis properties to the quantum dot. The shell may be a single layer or multiple layers. The interface between the core and the shell may have a concentration gradient in which the concentration of an element present in the shell becomes lower toward the center.

In one or more embodiments, a quantum dot may have the aforementioned core-shell structure including a core having nano-crystals and a shell around (e.g., surrounding) the core. An example of the shell of the quantum dot may be a metal or non-metal oxide, a semiconductor compound, or a (e.g., any suitable) combination thereof.

For example, the metal or non-metal oxide for the shell may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like, or a ternary compound such as MgAl₂O₄, CoFe₂O₄, NiFe₂O₄, CoMn₂O₄, and/or the like, but embodiments of the present disclosure are not limited thereto.

In addition, the semiconductor compound suitable as a shell may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like as an example, but embodiments of the present disclosure are not limited thereto.

Each element included in a multi-element compound such as the binary compound or the ternary compound may be present in a particle at a substantially uniform concentration or non-uniform concentration. For example, the above formula represents types (kinds) of elements included in a compound, but the ratio of elements in the compound may vary.

The quantum dot may have a full width of half maximum (FWHM) of a light emission spectrum of about 45 nm or less, about 40 nm or less, or about 30 nm or less, and color purity or color reproducibility of the quantum dot may be improved in the above range. In addition, light emitted through such a quantum dot is emitted in all directions, so that a wide viewing angle may be improved.

In addition, although the form of the quantum dot is not particularly limited as long as it is a form generally used in the art, a quantum dot in the form of spherical nanoparticles, pyramidal nanoparticles, multi-arm nanoparticles, cubic nanoparticles, nanotubes, nanowires, nanofibers, nanoplate particles, and/or the like may be used.

Because an energy band gap of the quantum dot may be adjusted by adjusting the size of the quantum dot or adjusting an element ratio in a quantum dot compound, it may obtain light of one or more suitable wavelength bands from a quantum-dot emission layer. Therefore, a light emitting element which emits light of one or more suitable wavelengths may be implemented by using a quantum dot as described above (e.g., using quantum dots of different sizes from each other or having different element ratios in a quantum dot compound). For example, the adjustment of the size of the quantum dot and/or the element ratio in the quantum dot compound may enable the quantum dots to emit red, green, and/or blue light. In one or more embodiments, the quantum dots may be configured to emit white light by combining light of one or more suitable colors.

In each of the light emitting elements ED of embodiments illustrated in FIGS. 3 to 7, the electron transport region ETR may be provided on the emission layer EML. The electron transport region ETR may include at least one of a hole blocking layer HBL, an electron transport layer ETL, or an electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of an electron injection layer EIL or an electron transport layer ETL, or may have a single layer structure formed of an electron injection material and/or an electron transport material. In one or more embodiments, the electron transport region ETR may have a single layer structure formed of a plurality of different materials, or may have a structure in which an electron transport layer ETL/electron injection layer EIL or a hole blocking layer HBL/electron transport layer ETL/electron injection layer EIL are stacked in order (e.g., in the stated order) from the emission layer EML, but embodiments of the present disclosure are not limited thereto. The electron transport region ETR may have a thickness, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2:

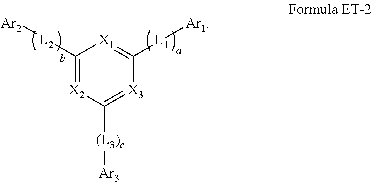

In Formula ET-2, at least one selected from among X₁ to X₃ may be N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c are each independently an integer of 2 or greater, L₁'s to L₃'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), and/or a (e.g., any suitable) mixture thereof.

In one or more embodiments, the electron transport region ETR may include at least one selected from among Compound ET1 to Compound ET36:

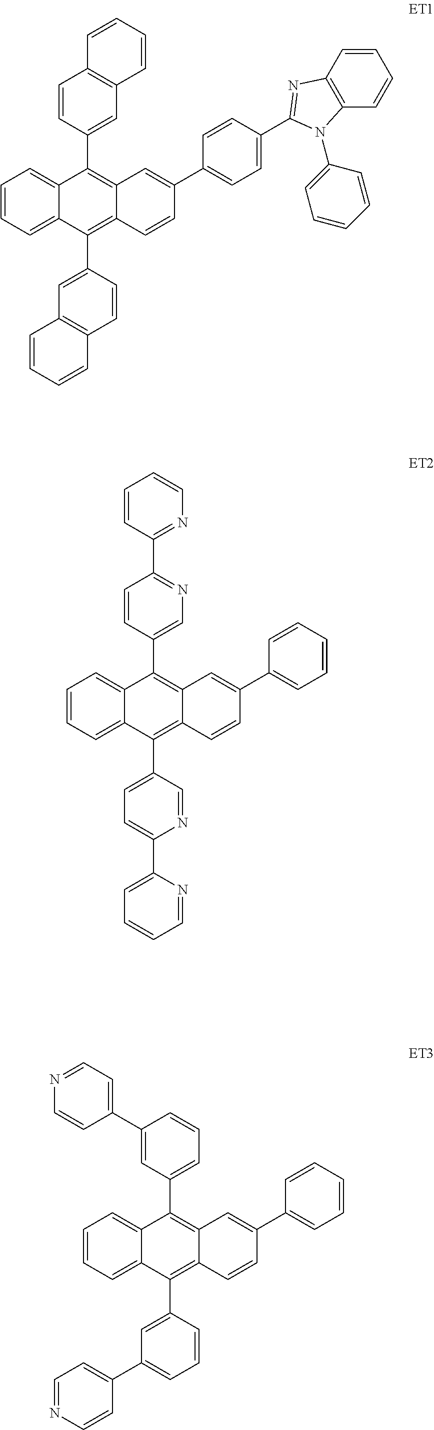 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

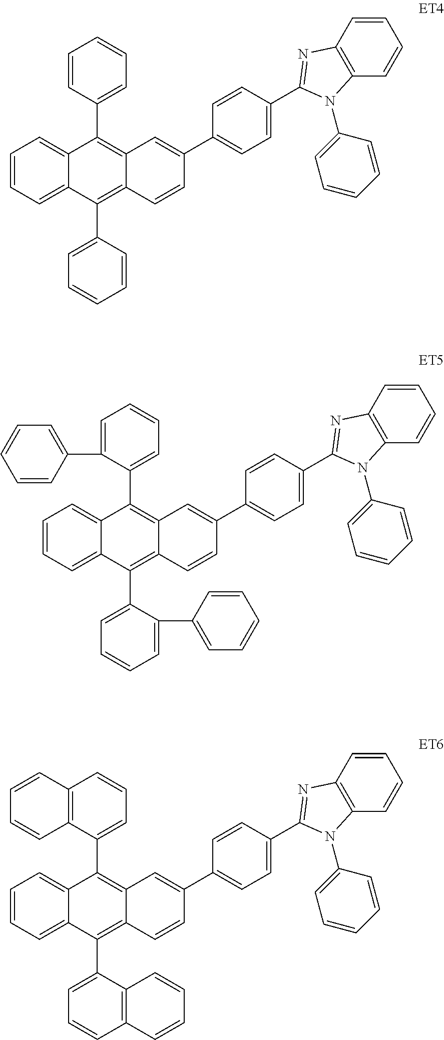 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

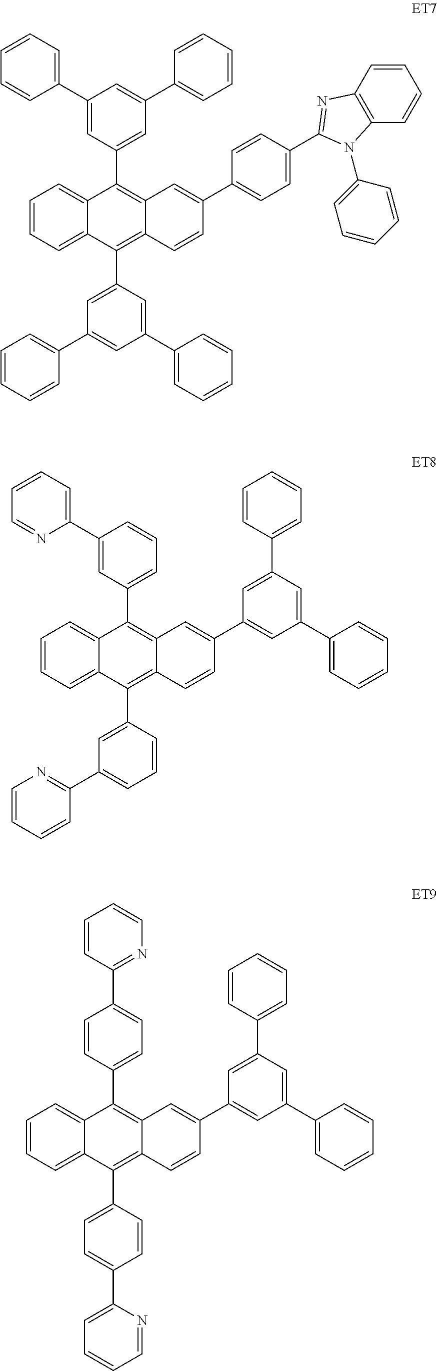 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

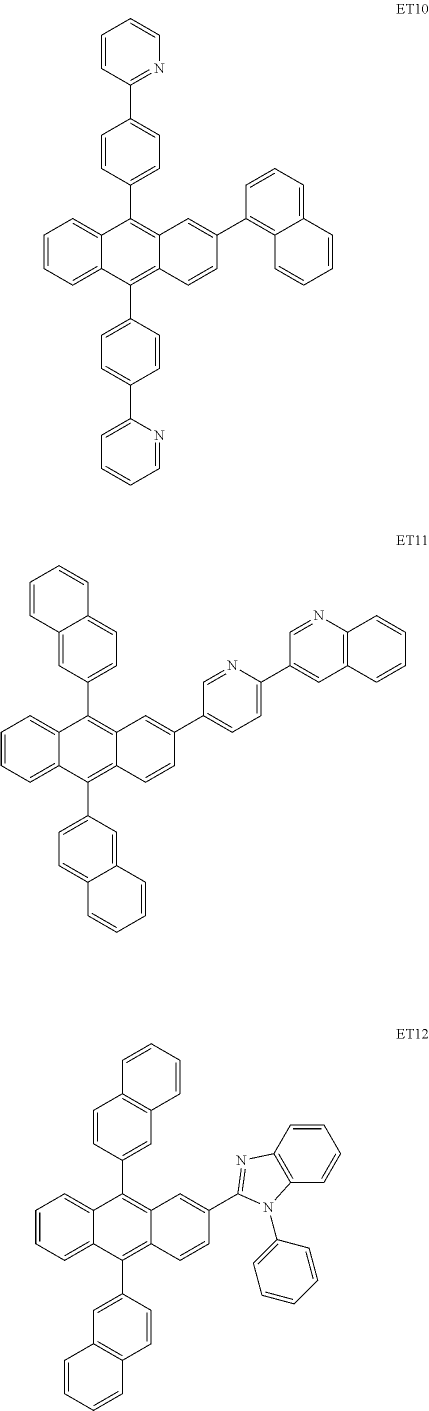 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

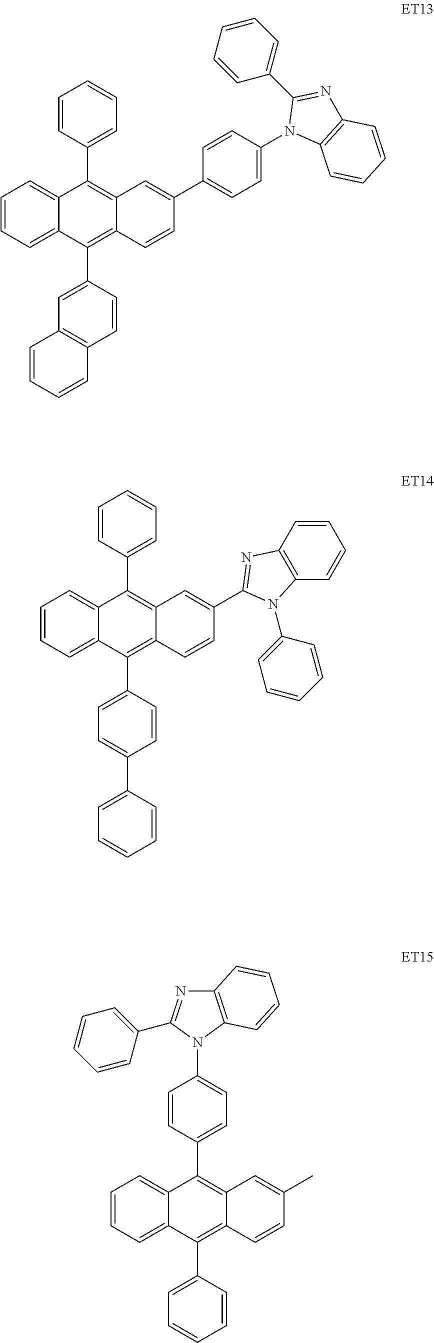 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

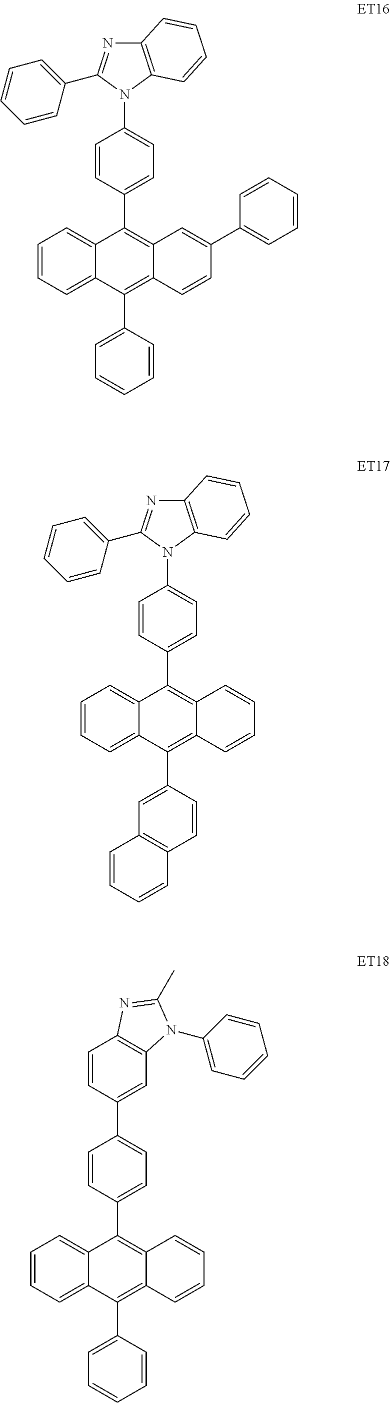 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

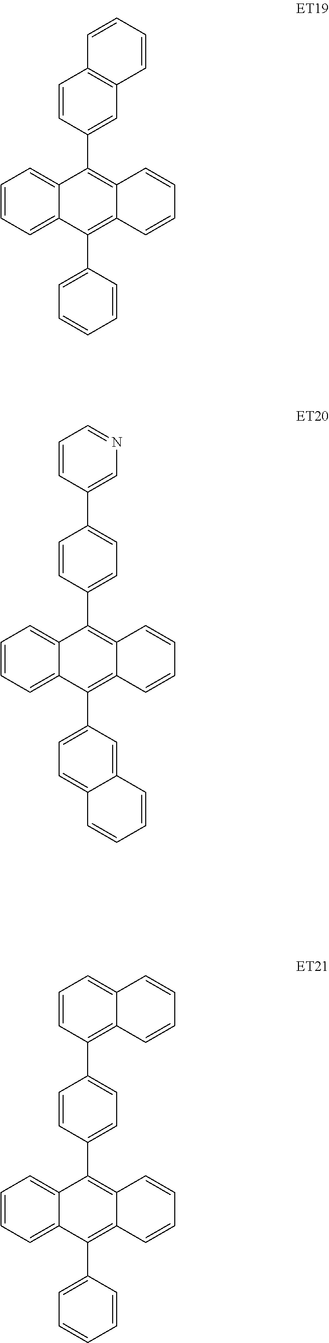

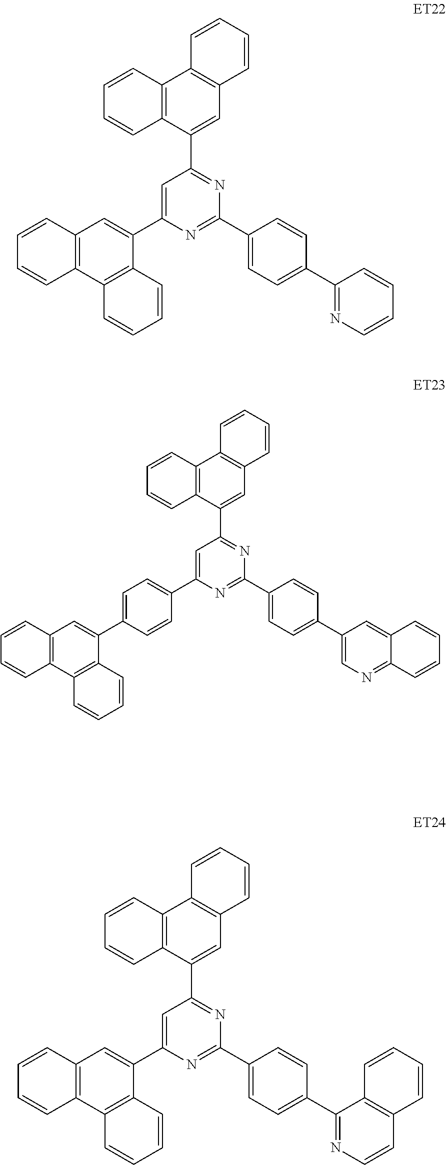 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

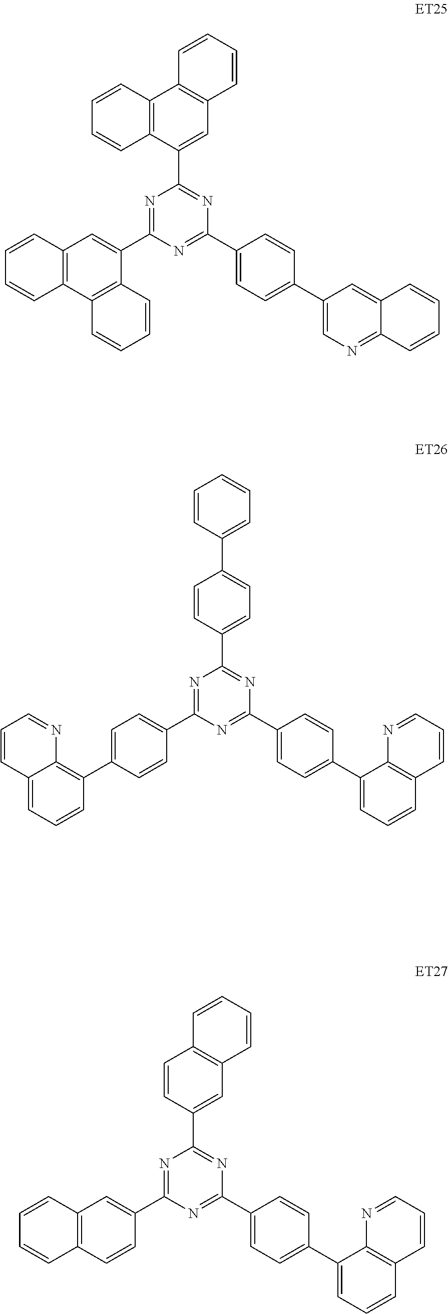 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

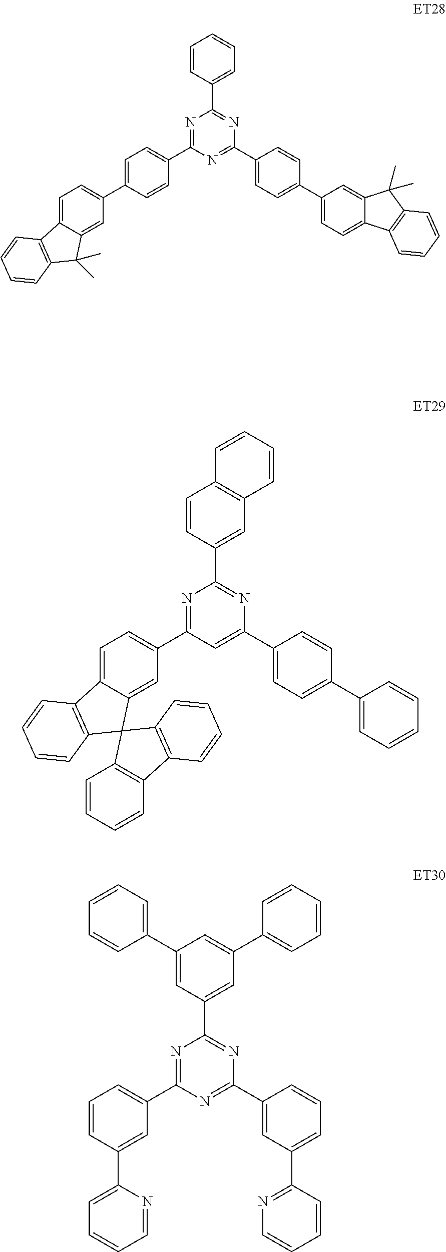 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

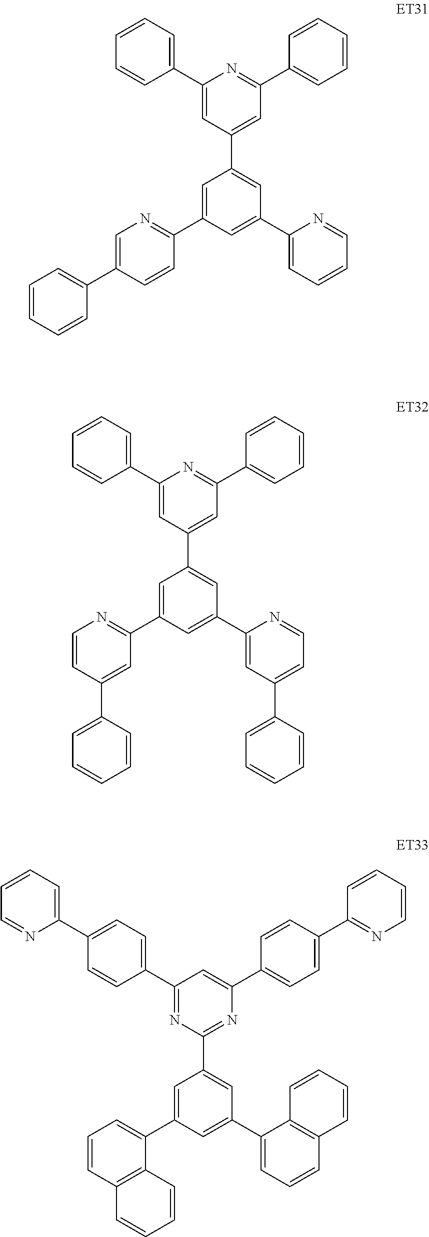 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

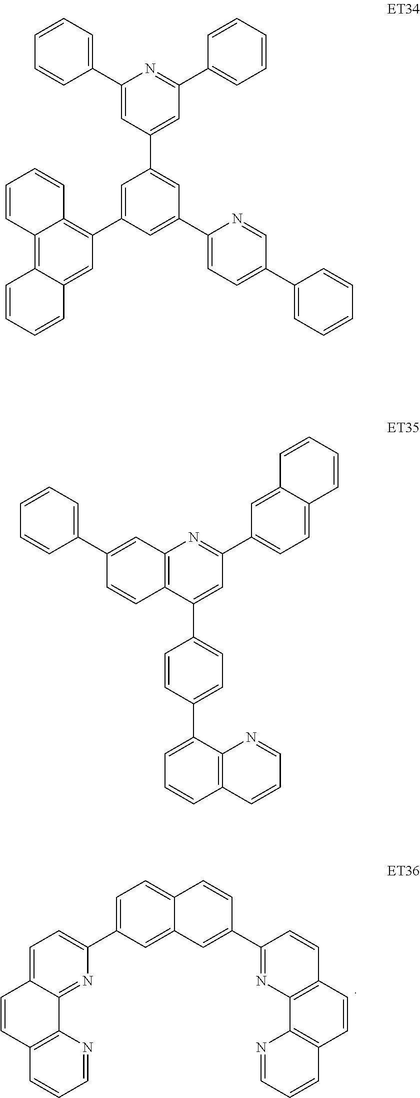 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCl, RbI, CuI, and/or KI, a lanthanide metal such as Yb, or a co-deposited material of the metal halide and the lanthanide metal. For example, in one or more embodiments, the electron transport region ETR may include KI:Yb, RbI:Yb, LiF:Yb, and/or the like, as a co-deposited material. In one or more embodiments, the electron transport region ETR may be formed using a metal oxide such as Li₂O and/or BaO, or 8-hydroxyl-lithium quinolate (Liq), and/or the like, but embodiments of the present disclosure are not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, one or more of a metal acetate, a metal benzoate, a metal acetoacetate, a metal acetylacetonate, or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the above-described materials, but embodiments of the present disclosure are not limited thereto.

The electron transport region ETR may include one or more of the above-described compounds of the electron transport region in at least one of an electron injection layer EIL, an electron transport layer ETL, or a hole blocking layer HBL.

If (e.g., when) the electron transport region ETR includes an electron transport layer ETL, the electron transport layer ETL may have a thickness of about 100 Å to about 1,000 Å, for example, about 150 Å to about 500 Å. If (e.g., when) the thickness of the electron transport layer ETL satisfies the aforementioned range, satisfactory electron transport characteristics may be obtained without a substantial increase in driving voltage. If (e.g., when) the electron transport region ETR includes an electron injection layer EIL, the electron injection layer EIL may have a thickness of about 1 Å to about 100 Å, for example, about 3 Å to about 90 Å. If (e.g., when) the thickness of the electron injection layer EIL satisfies the above-described range, satisfactory electron injection characteristics may be obtained without a substantial increase in driving voltage.

The second electrode EL2 may be provided on the electron transport region ETR. In one or more embodiments, the second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

If (e.g., when) the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In one or more embodiments, the second electrode EL2 may have a multilayer structure including a reflective film or a transflective film formed of one or more of the above-described materials, and a transparent conductive film formed of ITO, IZO, ZnO, ITZO, and/or the like. For example, in one or more embodiments, the second electrode EL2 may include one of the above-described metal materials, a (e.g., any suitable) combination of at least two metal materials of the above-described metal materials, an oxide of the above-described metal materials, and/or the like.

In one or more embodiments, the second electrode EL2 may be connected with an auxiliary electrode. If (e.g., when) the second electrode EL2 is connected with the auxiliary electrode, the resistance of the second electrode EL2 may be decreased.

In one or more embodiments, a capping layer CPL may further be arranged on the second electrode EL2 of the light emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ, SiO_{y}, and/or the like.

In one or more embodiments, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, embodiments of the present disclosure are not limited thereto, for example, in one or more embodiments, the capping layer CPL may include at least one selected from among Compounds P1 to P5:

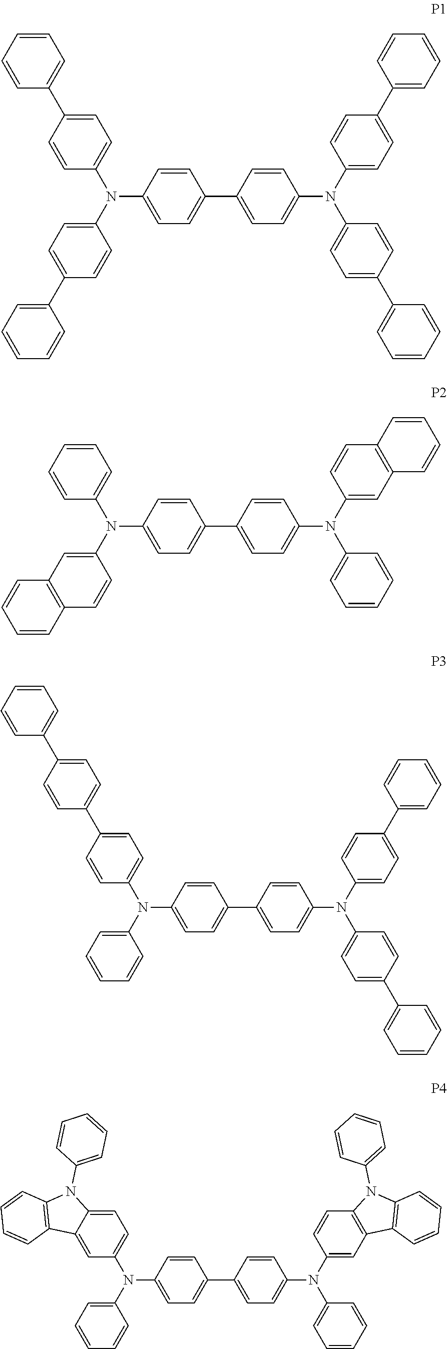 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

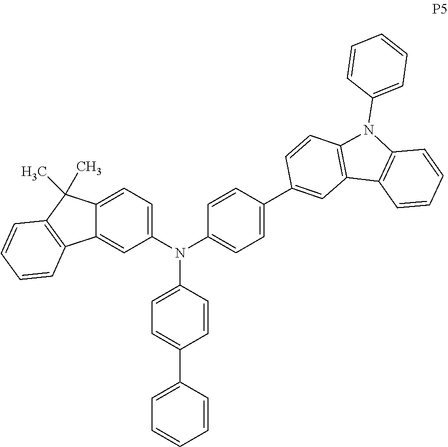 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, in one or more embodiments, the refractive index of the capping layer CPL may be about 1.6 or more with respect to light in a wavelength range of about 550 nm to about 660 nm.

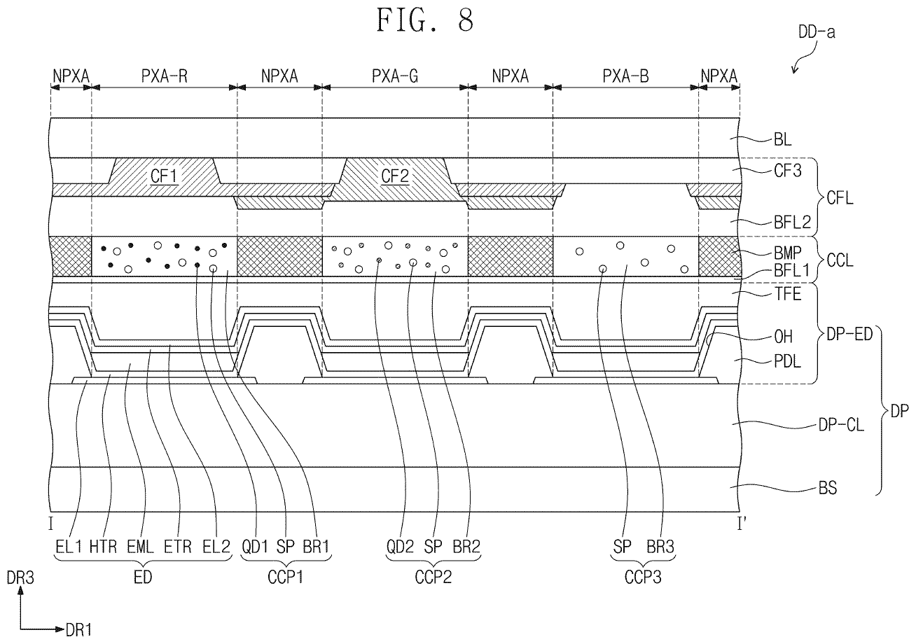

Each of FIGS. 8 to 11 is a cross-sectional view of a display device according to one or more embodiments. Hereinafter, in describing the display devices of embodiments with reference to FIGS. 8 to 11, the duplicated features which have been described in FIGS. 1 to 7 are not described again for conciseness, but only their differences will be mainly described.

Referring to FIG. 8, the display device DD-a according to one or more embodiments may include a display panel DP including a display element layer DP-ED, a light control layer CCL arranged on the display panel DP, and a color filter layer CFL. In one or more embodiments illustrated in FIG. 8, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The structure of any one of the light emitting elements ED illustrated in FIGS. 3 to 7 may be equally applied to the structure of the light emitting element ED illustrated in FIG. 8. The light emitting element ED of one or more embodiments illustrated in FIG. 8 may include the fused polycyclic compound of one or more embodiments. The light emitting element ED including the fused polycyclic compound of one or more embodiments may exhibit high luminous efficiency and long lifespan.

Referring to FIG. 8, the emission layer EML may be arranged in an opening OH defined in a pixel defining film PDL. For example, the emission layer EML which is divided by the pixel defining film PDL and provided corresponding to each of light emitting regions PXA-R, PXA-G, and PXA-B may be to emit light in substantially the same wavelength range. In the display device DD-a of one or more embodiments, the emission layer EML may be to emit blue light. In one or more embodiments, the emission layer EML may be provided as a common layer across the entire light emitting regions PXA-R, PXA-G, and PXA-B.

The light control layer CCL may include a light conversion body. The light conversion body may be a quantum dot, a phosphor, and/or the like. The light conversion body may be to emit provided light by converting the wavelength thereof. For example, the light control layer CCL may a layer containing a quantum dot or a layer containing a phosphor.

The light control layer CCL may include a plurality of light control parts CCP1, CCP2, and CCP3. The light control parts CCP1, CCP2, and CCP3 may be spaced and/or apart (e.g., spaced apart or separated) from one another.

Referring to FIG. 8, divided patterns BMP may be arranged between the light control parts CCP1, CCP2, and CCP3 which are spaced and/or apart (e.g., spaced apart or separated) from one another, but embodiments of the present disclosure are not limited thereto. FIG. 8 illustrates that the divided patterns BMP do not overlap the light control parts CCP1, CCP2, and CCP3, but, in one or more embodiments, at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, in one or more embodiments, the first quantum dot QD1 may be a red quantum dot to emit red light, and the second quantum dot QD2 may be a green quantum dot to emit green light. The same as described above on quantum dots may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. In one or more embodiments, the scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed accordingly. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed accordingly, and may each be formed of one or more suitable resin compositions, which may be generally referred to as a binder. For example, the base resins BR1, BR2, and BR3 may each independently be an acrylic-based resin, a urethane-based resin, a silicone-based resin, an epoxy-based resin, and/or the like. The base resins BR1, BR2, and BR3 may each be transparent resins. In one or more embodiments, the first base resin BR1, the second base resin BR2, and the third base resin BR3 may be the same as or different from one another.

In one or more embodiments, the light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2, and CCP3 from being exposed to moisture/oxygen. In one or more embodiments, the barrier layer BFL1 may cover the light control parts CCP1, CCP2, and CCP3. In one or more embodiments, a barrier layer BFL2 may be provided between the light control parts CCP1, CCP2, and CCP3 and the color filter layer CFL.

The barrier layers BFL1 and BFL2 may each include at least one inorganic layer. For example, in one or more embodiments, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may each independently further include an organic film. The barrier layers BFL1 and BFL2 may each be formed of a single layer or a plurality of layers.

In the display device DD-a of one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, in one or more embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. The first filter CF1 may include a red pigment and/or a red dye, the second filter CF2 may include a green pigment and/or a green dye, and the third filter CF3 may include a blue pigment and/or a blue dye.

In one or more embodiments, the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in one or more embodiments, the first filter CF1 and the second filter CF2 may each be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment and/or a black dye. The light shielding part may prevent or reduce light leakage, and may separate boundaries between adjacent filters CF1, CF2, and CF3. In one or more embodiments, the light shielding part may be formed of a blue filter.

The first to third filters CF1, CF2, and CF3 may be arranged corresponding to the red light emitting region PXA-R, the green light emitting region PXA-G, and the blue light emitting region PXA-B, respectively.

In one or more embodiments, a base substrate BL may be arranged on the color filter layer CFL. The base substrate BL may be a member which provides a base surface on which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

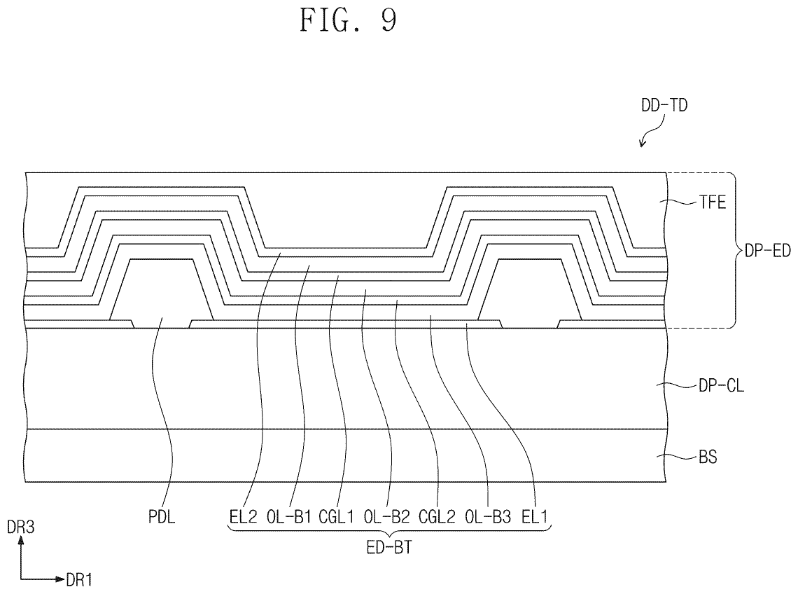

FIG. 9 is a cross-sectional view illustrating a portion of a display device according to one or more embodiments. In a display device DD-TD of one or more embodiments, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in a thickness direction between the first electrode EL1 and the second electrode EL2. The light emitting structures OL-B1, OL-B2, and OL-B3 each may include an emission layer EML (FIG. 8) and a hole transport region HTR and an electron transport region ETR arranged with the emission layer EML (FIG. 8) located therebetween. For example, the light emitting element ED-BT included in the display device DD-TD of one or more embodiments may be a light emitting element having a tandem structure and including a plurality of emission layers.

At least one selected from among the light emitting structures OL-B1, OL-B2, and OL-B3 may include the fused polycyclic compound of one or more embodiments. The light emitting element ED-BT including the fused polycyclic compound of one or more embodiments may exhibit high luminous efficiency and long lifespan.

In one or more embodiments illustrated in FIG. 9, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from one another. For example, in one or more embodiments, the light emitting element ED-BT including the plurality of light emitting structures OL-B1, OL-B2, and OL-B3 which emit light beams having wavelength ranges different from one another may be to emit white light (e.g., combined white light).

Charge generation layers CGL1 and CGL2 may be respectively arranged between two of the neighboring light emitting structures OL-B1, OL-B2, and OL-B3. The charge generation layers CGL1 and CGL2 may each independently include a p-type (kind) charge (e.g., P-charge) generation layer and/or an n-type (kind) charge (e.g., N-charge) generation layer.

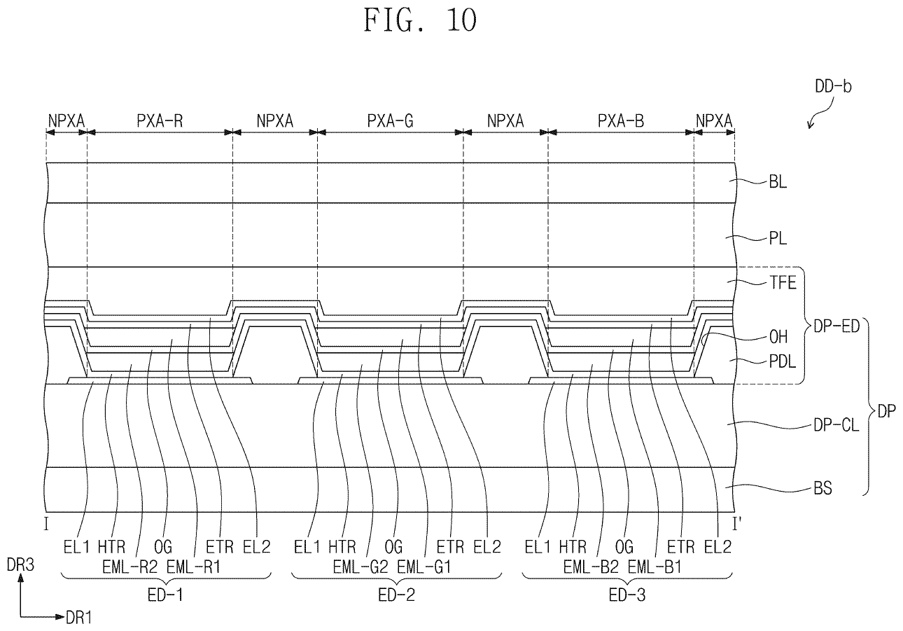

Referring to FIG. 10, a display device DD-b according to one or more embodiments may include light emitting elements ED-1, ED-2, and ED-3 in each of which two emission layers are stacked. Compared with the display device DD illustrated in FIG. 2, the display device DD-b illustrated in FIG. 10 has a difference in that the first to third light emitting elements ED-1, ED-2, and ED-3 each include two emission layers stacked in a thickness direction. In each of the first to third light emitting elements ED-1, ED-2, and ED-3, the two emission layers may be to emit light in substantially the same wavelength region.

At least one selected from among the light emitting elements ED-1, ED-2, and ED-3 may include the fused polycyclic compound of one or more embodiments. The light emitting elements (at least one selected from among the light emitting elements ED-1, ED-2, and ED-3) including the fused polycyclic compound of one or more embodiments may exhibit high luminous efficiency and long life span.

In one or more embodiments, the first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be separately arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In one or more embodiments, the emission auxiliary part OG may include an electron transport region, a charge generation layer, and a hole transport region that are sequentially stacked (e.g., in the stated order). The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be arranged between the emission auxiliary part OG and the electron transport region ETR. The second red emission layer EML-R2, the second green emission layer EML-G2, and the second blue emission layer EML-B2 may each be arranged between the hole transport region HTR and the emission auxiliary part OG.

For example, in one or more embodiments, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2 that are sequentially stacked (e.g., in the stated order). The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2 that are sequentially stacked (e.g., in the stated order). The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2 that are sequentially stacked (e.g., in the stated order).

In one or more embodiments, an optical auxiliary layer PL may be arranged on the display element layer DP-ED. The optical auxiliary layer PL may include a polarizing layer. The optical auxiliary layer PL may be arranged on the display panel DP and control reflected light in the display panel DP due to external light. In some embodiments, the optical auxiliary layer PL may not be provided in the display device.

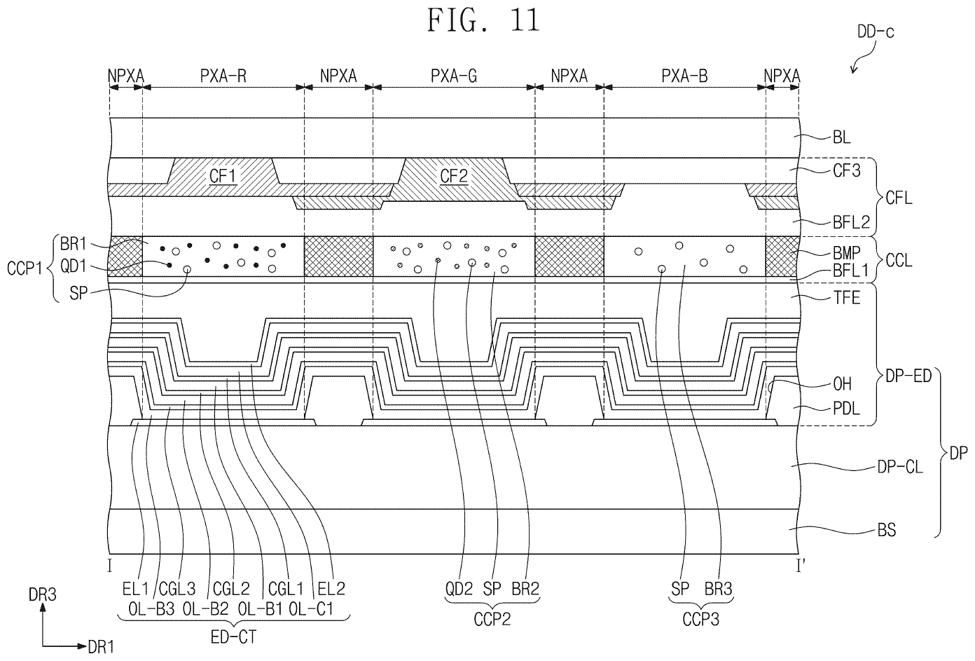

Unlike FIG. 9 and FIG. 10, FIG. 11 illustrates that a display device DD-c includes four light emitting structures OL-B1, OL-B2, OL-B3, and OL-C1. A light emitting element ED-CT may include a first electrode EL1 and a second electrode EL2, which face each other, and first to fourth light emitting structures OL-B1, OL-B2, OL-B3, and OL-C1 that are stacked in a thickness direction between the first electrode EL1 and the second electrode EL2. At least one selected from among the four light emitting structures OL-B1, OL-B2, OL-B3, and OL-C1 may include the fused polycyclic compound of one or more embodiments. The light emitting element ED-CT including the fused polycyclic compound of one or more embodiments may exhibit high luminous efficiency and long lifespan.

Charge generation layers CGL1, CGL2, and CGL3 may each be separately arranged between the first to fourth light emitting structures OL-B1, OL-B2, OL-B3, and OL-C1, accordingly. In one or more embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light beams in different wavelength regions.

The charge generation layers CGL1, CGL2, and CGL3 arranged between adjacent light emitting structures OL-B1, OL-B2, OL-B3, and OL-C1 may each independently include a p-type (kind) charge (e.g., P-charge) generation layer and/or an n-type (kind) charge (e.g., N-charge) generation layer.

In one or more embodiments, an electronic apparatus may include a display device including a plurality of light emitting elements, and a control part which controls the display device. The electronic apparatus of one or more embodiments may be an apparatus that is activated according to an electrical signal. The electronic apparatus may include display devices of one or more embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

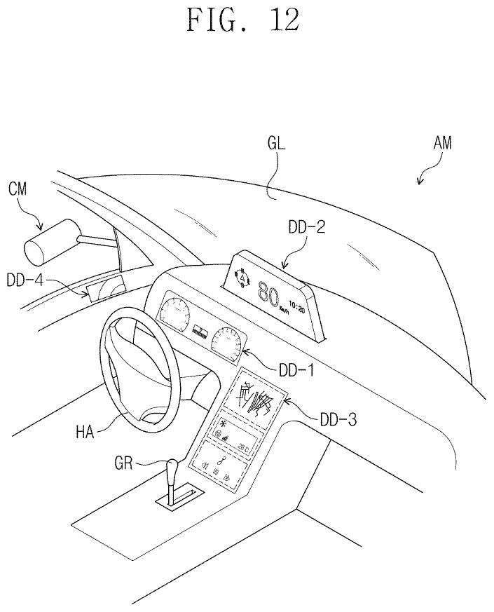

FIG. 12 is a view illustrating a vehicle AM in which first to fourth display devices DD-1, DD-2, DD-3, and DD-4 are arranged. At least one selected from among the first to fourth display devices DD-1, DD-2, DD-3, and DD-4 may include the same configuration as one of the display devices DD, DD-TD, DD-a, DD-b, and DD-c described with reference to FIGS. 1, and 2, and 8 to 11.

FIG. 12 illustrates a vehicle AM, but this is a mere example, and the first to fourth display devices DD-1, DD-2, DD-3, and DD-4 may be arranged in other transportation apparatuses such as bicycles, motorcycles, trains, ships, and/or airplanes. In one or more embodiments, at least one selected from among the first to fourth display devices DD-1, DD-2, DD-3, and DD-4 including the same configuration as one of the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. These are merely provided as example embodiments, and thus the display device may be employed in other electronic apparatuses unless departing from the disclosure.

In one or more embodiments, at least one selected from among the first to fourth display devices DD-1, DD-2, DD-3, and DD-4 may include the light emitting element ED described with reference to FIGS. 3 to 7. At least one selected from among the first to fourth display devices DD-1, DD-2, DD-3, and DD-4 may include the fused polycyclic compound of one or more embodiments. The display device (one or more of the first to fourth display devices DD-1, DD-2, DD-3, and DD-4) including the fused polycyclic compound of one or more embodiments may exhibit excellent or suitable display quality.

Referring to FIG. 12, the vehicle AM may include a steering wheel HA and a gear GR for driving the vehicle AM. In addition, the vehicle AM may include a front window GL arranged so as to face a driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. The first scale and the second scale may be each indicated as a digital image.

The second display device DD-2 may be arranged in a second region opposite to (e.g., facing) a driver seat and overlapping the front window GL. The driver seat may be a seat in which the steering wheel HA faces. For example, the second display device DD-2 may be a head up display (HUD) which displays second information of the vehicle AM. The second display device DD-2 may be optically transparent. The second information may include digital numbers which indicate a driving speed, and may further include information such as the current time. In one or more embodiments, the second information of the second display device DD-2 may be projected to the front window GL to be displayed.

The third display device DD-3 may be arranged in a third region adjacent to the gear GR. For example, the third display device DD-3 may be arranged between the driver seat and a passenger seat and may be a center information display (CID) for the vehicle for displaying third information. The passenger seat may be a seat spaced and/or apart (e.g., spaced apart or separated) from the driver seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR, and may be arranged in a fourth region adjacent to a side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may each include different information. However, embodiments of the present disclosure are not limited thereto, and a part of the first to fourth information may include the same information as one another.

Hereinafter, referring to Examples and Comparative Examples, a fused polycyclic compound according to one or more embodiments of the present disclosure and a light emitting element of one or more embodiments will be described in more detail. In addition, Examples shown herein are for explaining purposes only to facilitate the understanding of the disclosure, and thus, the scope of the disclosure is not limited thereto.

### EXAMPLES

### 1. Synthesis of Fused Polycyclic Compound of Embodiment

A method for synthesizing a fused polycyclic compound according to the present embodiment will be described in more detail with reference to a method for synthesizing Fused Polycyclic Compounds 8, 22, 82, 2, 6, and 52. In addition, the method for synthesizing a fused polycyclic compound to be described is only an example, and the method for synthesizing a fused polycyclic compound according to one or more embodiments of the disclosure is not limited to the following examples.

### (1) Synthesis of Fused Polycyclic Compound 8

Fused Polycyclic Compound 8 according to one or more embodiments may be synthesized with reference to, for example, steps (e.g., acts or tasks) of Reaction Formula 1.

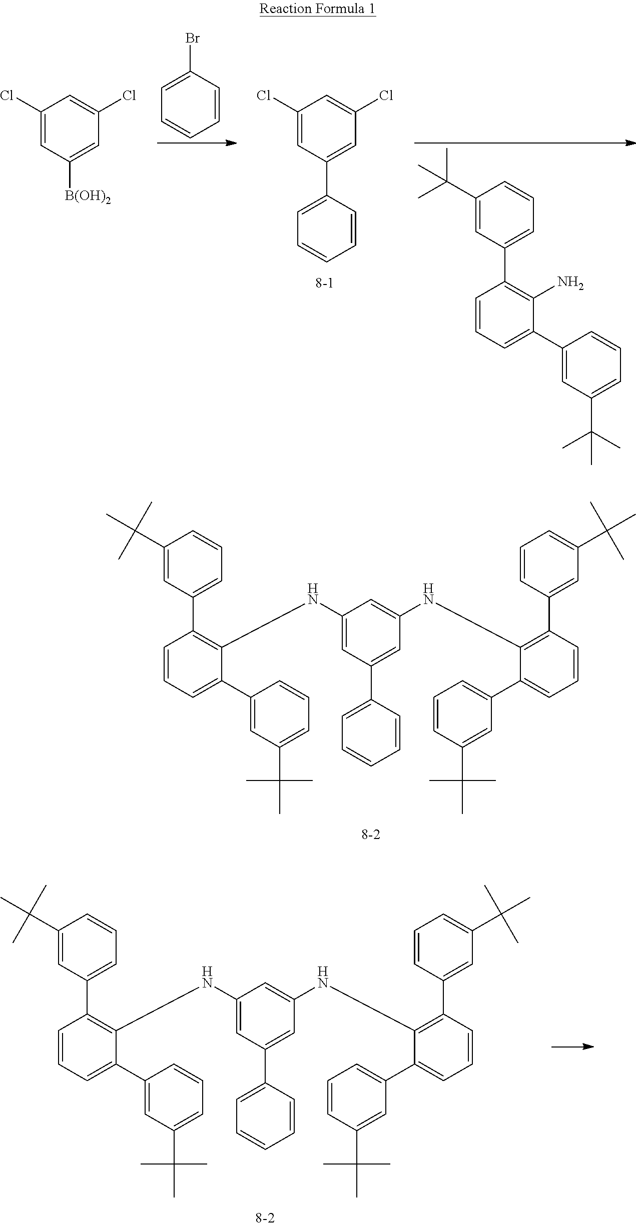

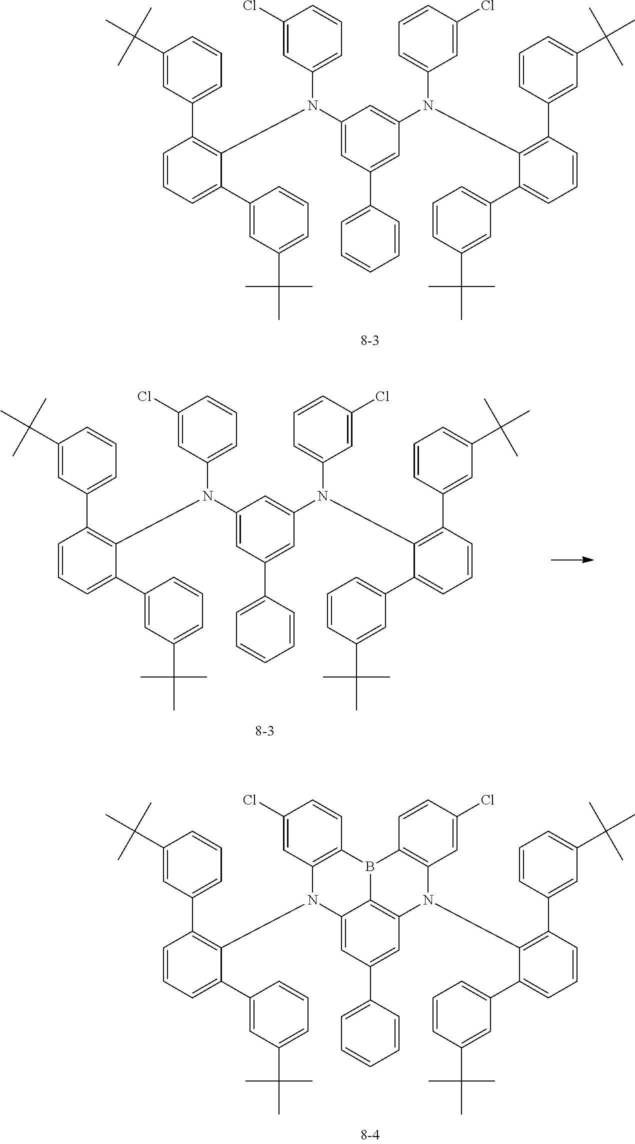

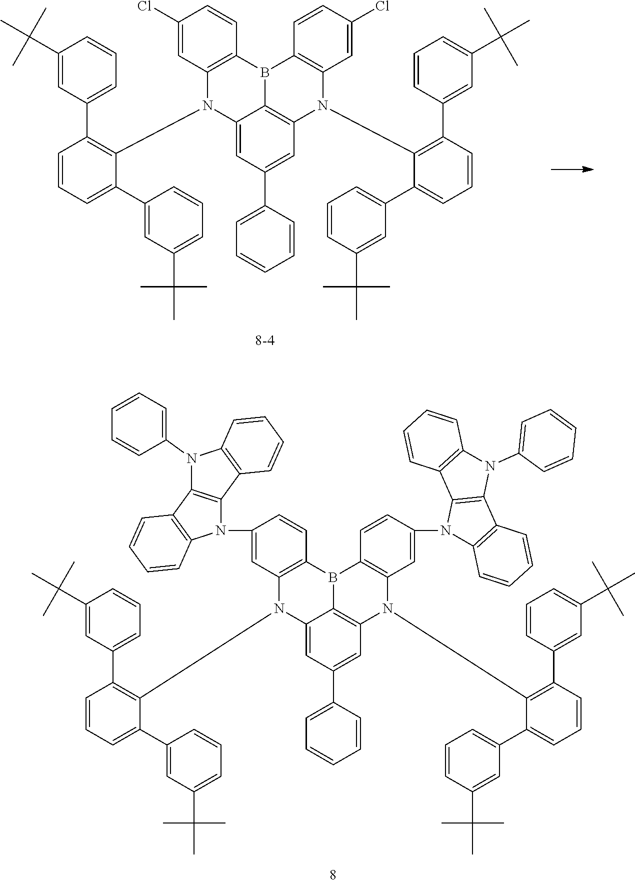

### Synthesis of Intermediate Compound 8-1

(3,5-dichlorophenyl)boronic acid (1.2 eq), bromobenzene (1 eq), tris(dibenzylideneacetone)dipalladium(0) (Pd₂(dba)₃) (0.05 eq), Pd(PPh₃)₄ (0.05 eq), and potassium carbonate (1.5 eq) were added, and dissolved in toluene/H₂O, which is a solvent, and then the reaction solution was stirred at 100° C. for 12 hours. After the solution was cooled, water (1 L) and ethyl acetate (300 mL) were added thereto to extract and collect an organic layer, and then the organic layer was dried with anhydrous magnesium sulfate MgSO₄ and then filtered. The filtered solution was depressurized to remove a solvent, and the obtained product was purified and separated by column chromatography using silica gel and by using CH₂Cl₂ and hexane as development solvents to obtain Intermediate Compound 8-1. (Yield: 88%)

### Synthesis of Intermediate Compound 8-2

Under a nitrogen atmosphere, Intermediate Compound 8-1 (1 eq), 3,3″-di-tert-butyl-[1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 8-2. (Yield: 82%)

### Synthesis of Intermediate Compound 8-3

Under a nitrogen atmosphere, Intermediate Compound 8-2 (1 eq), 3-iodochlorobenzene (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 8-3. (Yield: 63%)

### Synthesis of Intermediate Compound 8-4

Under a nitrogen atmosphere, Intermediate Compound 8-3 (1 eq) was dissolved in o-dichlorobenzene, and then cooled by using water-ice, followed by slowly adding BBr₃ (5 eq) dropwise thereto, and then the reaction solution was stirred at 180° C. for 24 hours. After the solution was cooled, the reaction was terminated by adding triethylamine (5 eq) thereto, and an organic layer was extracted and collected with water/CH₂Cl₂, dried with anhydrous MgSO₄, and then filtered. The filtered solution was depressurized to remove a solvent, and the obtained product was purified and separated by column chromatography using silica gel to obtain Intermediate Compound 8-4. (Yield: 46%)

### Synthesis of Compound 8

Under a nitrogen atmosphere, Intermediate Compound 8-4 (1 eq), 5-phenyl-5,10-dihydroindolo[3,2-b]indole (2.4 eq), Pd₂(dba)₃ (0.05 eq), tris-tert-butyl phosphine (0.1 eq), and sodium tert-butoxide (3 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Compound 8. (Yield: 60%)

In other words, the synthesis of the fused polycyclic compound 8 involves a series of steps with various intermediate compounds. Initially, Intermediate Compound 8-1 is produced by reacting (3,5-dichlorophenyl)boronic acid with bromobenzene in the presence of palladium catalysts and potassium carbonate in a toluene/water solvent mixture. This reaction is stirred at 100° C. for 12 hours, followed by extraction and purification to yield Intermediate Compound 8-1. Subsequent steps involve further reactions under a nitrogen atmosphere with different reagents and conditions, including the use of o-xylene as a solvent and various palladium catalysts. Each intermediate compound is purified through column chromatography, leading to the final product, Compound 8, with varying yields at each stage. The final step involves reacting Intermediate Compound 8-4 with 5-phenyl-5,10-dihydroindolo[3,2-b]indole, resulting in Compound 8 with a yield of 60%.

The fused polycyclic compound features a central structure with a 5-ring fused ring containing two nitrogen atoms and one boron atom. It also includes an indoloindole moiety and a biphenyl moiety bonded to the central structure. This design helps prevent or reduce intermolecular interactions and Dexter energy transfer, thereby improving the luminous efficiency of the light-emitting element.

### (2) Synthesis of Fused Polycyclic Compound 22

Fused Polycyclic Compound 22 according to one or more embodiments may be synthesized with reference to, for example, steps of Reaction Formula 2.

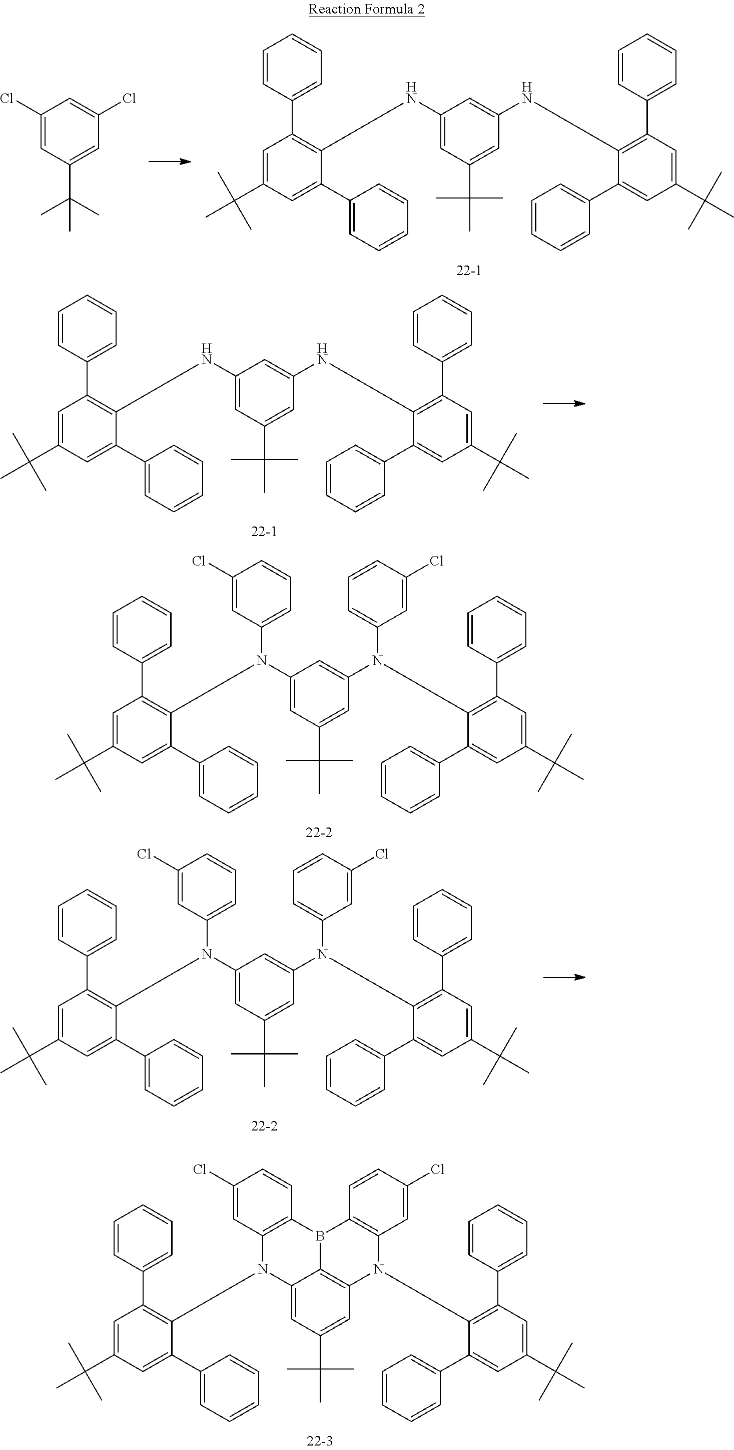

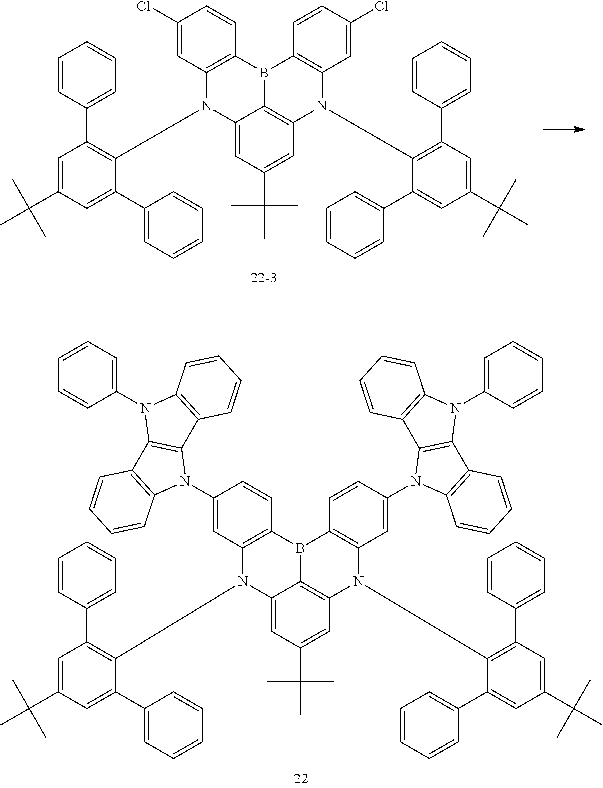

### Synthesis of Intermediate Compound 22-1

Under a nitrogen atmosphere, 1-(tert-butyl)-3,5-dichlorobenzene (1 eq), 5′-(tert-butyl)-[1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 22-1. (Yield: 78%)

### Synthesis of Intermediate Compound 22-2

Under a nitrogen atmosphere, Intermediate Compound 22-1 (1 eq), 3-iodochlorobenzene (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 22-2. (Yield: 66%)

### Synthesis of Intermediate Compound 22-3

Under a nitrogen atmosphere, Intermediate Compound 22-2 (1 eq) was dissolved in o-dichlorobenzene, and then cooled by using water-ice, followed by slowly adding BBr₃ (5 eq) dropwise thereto, and then the reaction solution was stirred at 180° C. for 24 hours. After the solution was cooled, the reaction was terminated by adding triethylamine (5 eq) thereto, and an organic layer was extracted and collected with water/CH₂Cl₂, dried with anhydrous MgSO₄, and then filtered. The filtered solution was depressurized to remove a solvent, and the obtained product was purified and separated by column chromatography using silica gel to obtain Intermediate Compound 22-3. (Yield: 39%)

### Synthesis of Compound 22

Under a nitrogen atmosphere, Intermediate Compound 22-3 (1 eq), 5-phenyl-5,10-dihydroindolo[3,2-b]indole (2.4 eq), Pd₂(dba)₃ (0.05 eq), tris-tert-butyl phosphine (0.1 eq), and sodium tert-butoxide (3 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Compound 22. (Yield: 82%)

### (3) Synthesis of Fused Polycyclic Compound 82

Fused Polycyclic Compound 82 according to one or more embodiments may be synthesized with reference to, for example, steps of Reaction Formula 3.

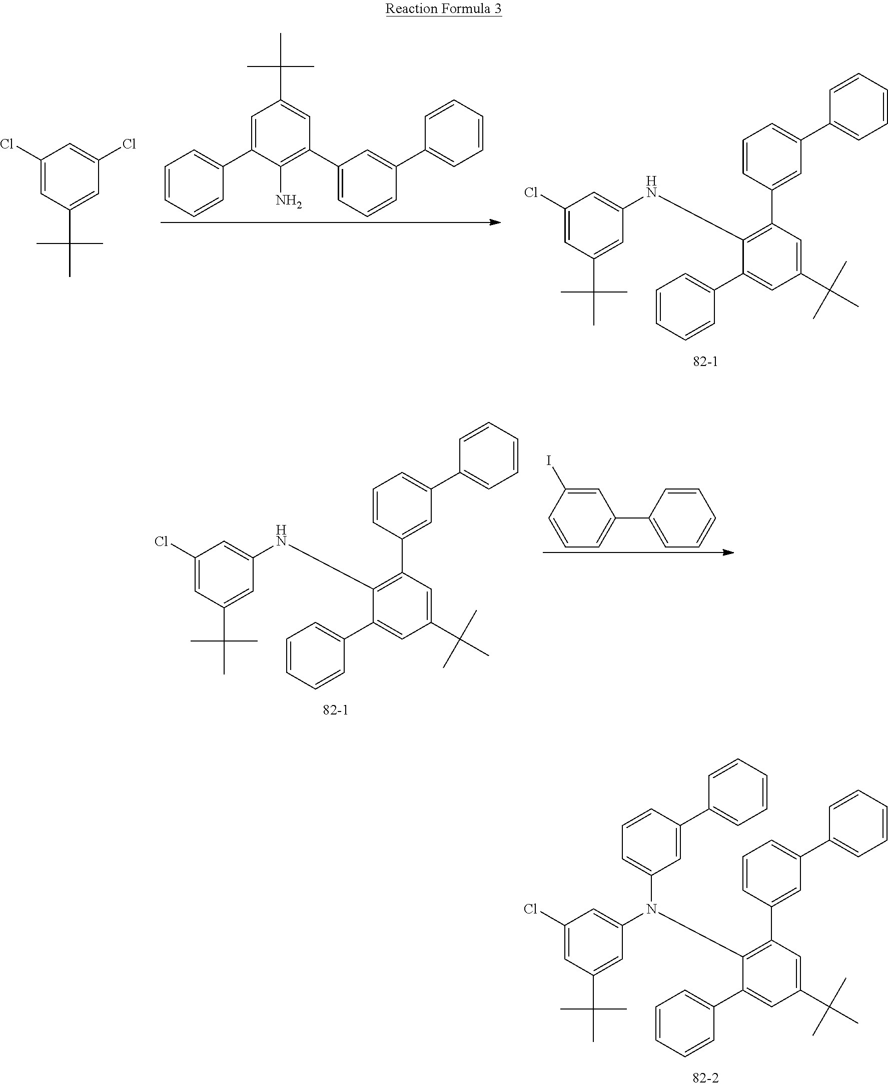

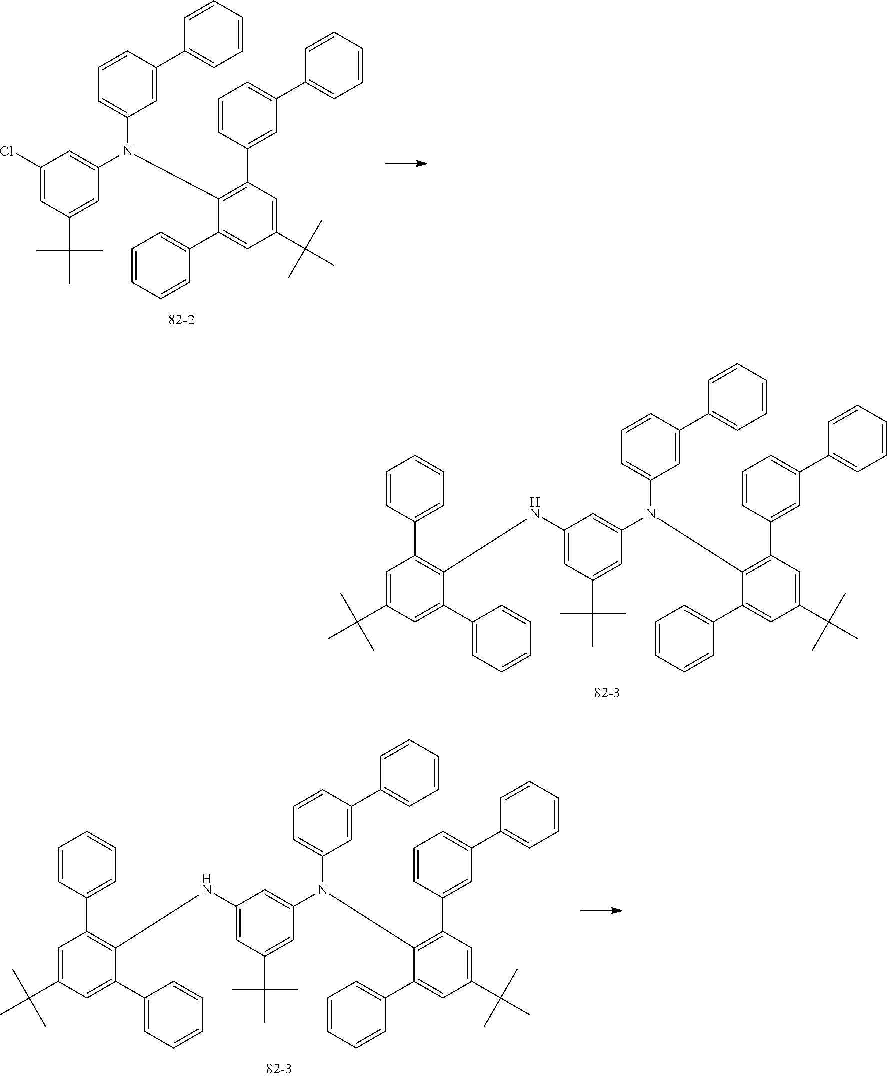 [SMILES: CC(C)(C)c1cc(Cl)cc(N(c2cccc(-c3ccccc3)c2)c2c(-c3ccccc3)cc(C(C)(C)C)cc2-c2cccc(-c3ccccc3)c2)c1 ; CC(C)(C)c1cc(Nc2c(-c3ccccc3)cc(C(C)(C)C)cc2-c2ccccc2)cc(N(c2cccc(-c3ccccc3)c2)c2c(-c3ccccc3)cc(C(C)(C)C)cc2-c2cccc(-c3ccccc3)c2)c1 ; CC(C)(C)c1cc(Nc2c(-c3ccccc3)cc(C(C)(C)C)cc2-c2ccccc2)cc(N(c2cccc(-c3ccccc3)c2)c2c(-c3ccccc3)cc(C(C)(C)C)cc2-c2cccc(-c3ccccc3)c2)c1]

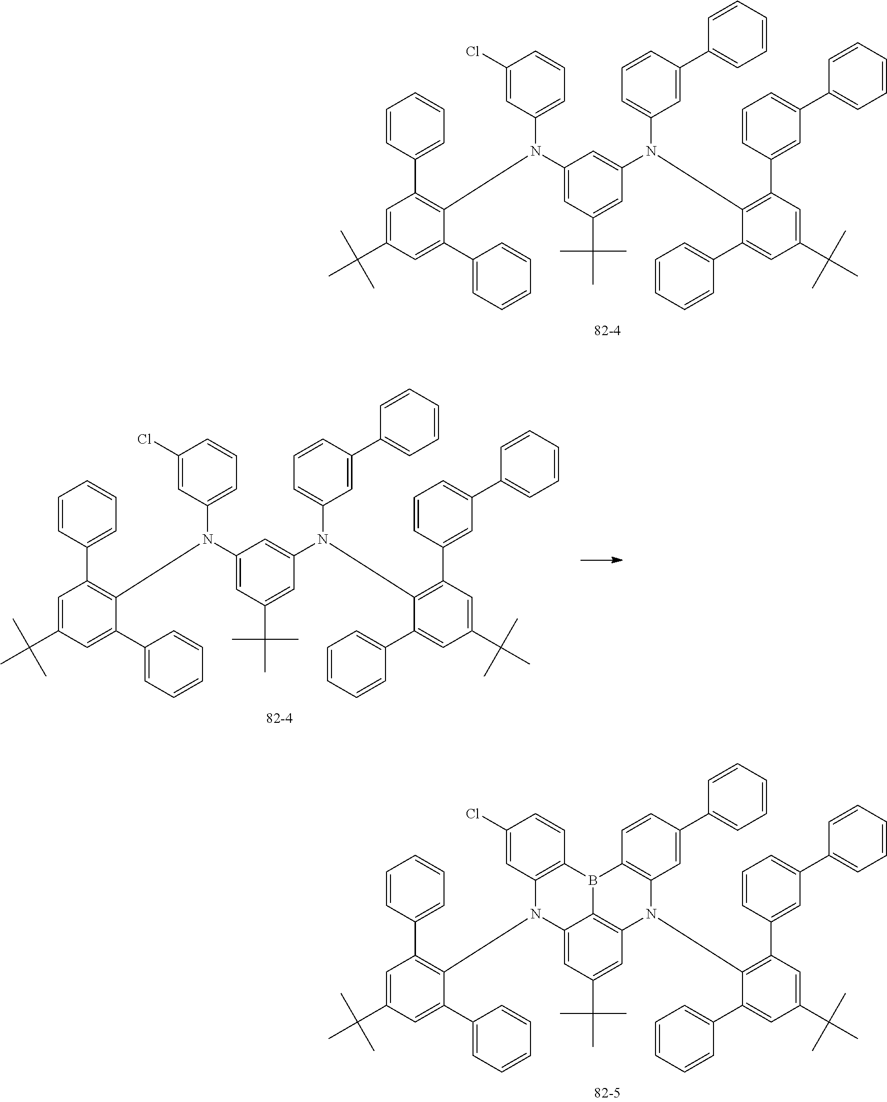 [SMILES: CC(C)(C)c1cc(N(c2cccc(Cl)c2)c2c(-c3ccccc3)cc(C(C)(C)C)cc2-c2ccccc2)cc(N(c2cccc(-c3ccccc3)c2)c2c(-c3ccccc3)cc(C(C)(C)C)cc2-c2cccc(-c3ccccc3)c2)c1 ; CC(C)(C)c1cc(N(c2cccc(Cl)c2)c2c(-c3ccccc3)cc(C(C)(C)C)cc2-c2ccccc2)cc(N(c2cccc(-c3ccccc3)c2)c2c(-c3ccccc3)cc(C(C)(C)C)cc2-c2cccc(-c3ccccc3)c2)c1 ; CC(C)(C)c1cc(-c2ccccc2)c(N2c3cc(Cl)ccc3B3c4ccc(-c5ccccc5)cc4N(c4c(-c5ccccc5)cc(C(C)(C)C)cc4-c4cccc(-c5ccccc5)c4)c4cc(C(C)(C)C)cc2c43)c(-c2ccccc2)c1]

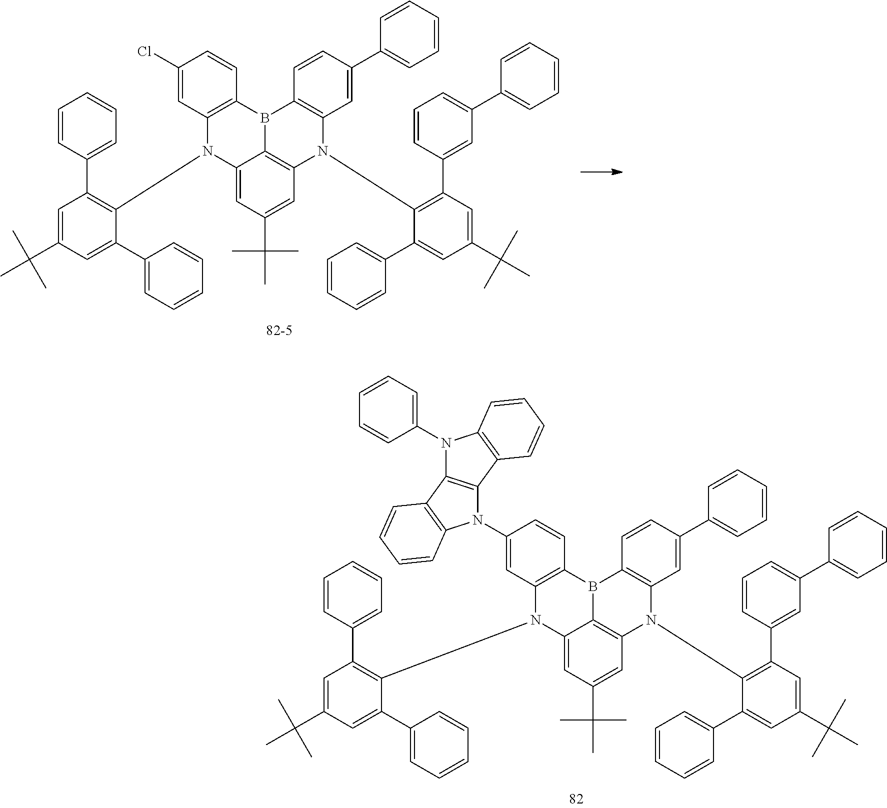 [SMILES: CC(C)(C)c1cc(-c2ccccc2)c(N2c3cc(Cl)ccc3B3c4ccc(-c5ccccc5)cc4N(c4c(-c5ccccc5)cc(C(C)(C)C)cc4-c4cccc(-c5ccccc5)c4)c4cc(C(C)(C)C)cc2c43)c(-c2ccccc2)c1 ; CC(C)(C)c1cc(-c2ccccc2)c(N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1]

### Synthesis of Intermediate Compound 82-1

Under a nitrogen atmosphere, 1-(tert-butyl)-3,5-dichlorobenzene (1 eq), 5′-(tert-butyl)-[1,1′:3′,1″:3″,1′″-quaterphenyl]-2′-amine (1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 82-1. (Yield: 63%)

### Synthesis of Intermediate Compound 82-2

Under a nitrogen atmosphere, Intermediate Compound 82-1 (1 eq), 3-iodo-1,1′-biphenyl (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 82-2. (Yield: 60%)

### Synthesis of Intermediate Compound 82-3

Under a nitrogen atmosphere, Intermediate Compound 82-2 (1 eq), 5′-(tert-butyl)-[1,1′:3′,1″-terphenyl](1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 82-3. (Yield: 61%)

### Synthesis of Intermediate Compound 82-4

Under a nitrogen atmosphere, Intermediate Compound 82-3 (1 eq), 3-iodochlorobenzene (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 82-4. (Yield: 60%)

### Synthesis of Intermediate Compound 82-5

Under a nitrogen atmosphere, Intermediate Compound 82-4 (1 eq) was dissolved in o-dichlorobenzene, and then cooled by using water-ice, followed by slowly adding BBr₃ (5 eq) dropwise thereto, and then the reaction solution was stirred at 180° C. for 24 hours. After the solution was cooled, the reaction was terminated by adding triethylamine (5 eq) thereto, and an organic layer was extracted and collected with water/CH₂Cl₂, dried with anhydrous MgSO₄, and then filtered. The filtered solution was depressurized to remove a solvent, and the obtained product was purified and separated by column chromatography using silica gel to obtain Intermediate Compound 82-5. (Yield: 35%)

### Synthesis of Compound 82

Under a nitrogen atmosphere, Intermediate Compound 82-5 (1 eq), 5-phenyl-5,10-dihydroindolo[3,2-b]indole (2.4 eq), Pd₂(dba)₃ (0.1 eq), tris-tert-butyl phosphine (0.2 eq), and sodium tert-butoxide (3 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Compound 82. (Yield: 43%)

### (4) Synthesis of Fused Polycyclic Compound 2

Fused Polycyclic Compound 2 according to one or more embodiments may be synthesized with reference to, for example, steps of Reaction Formula 4.

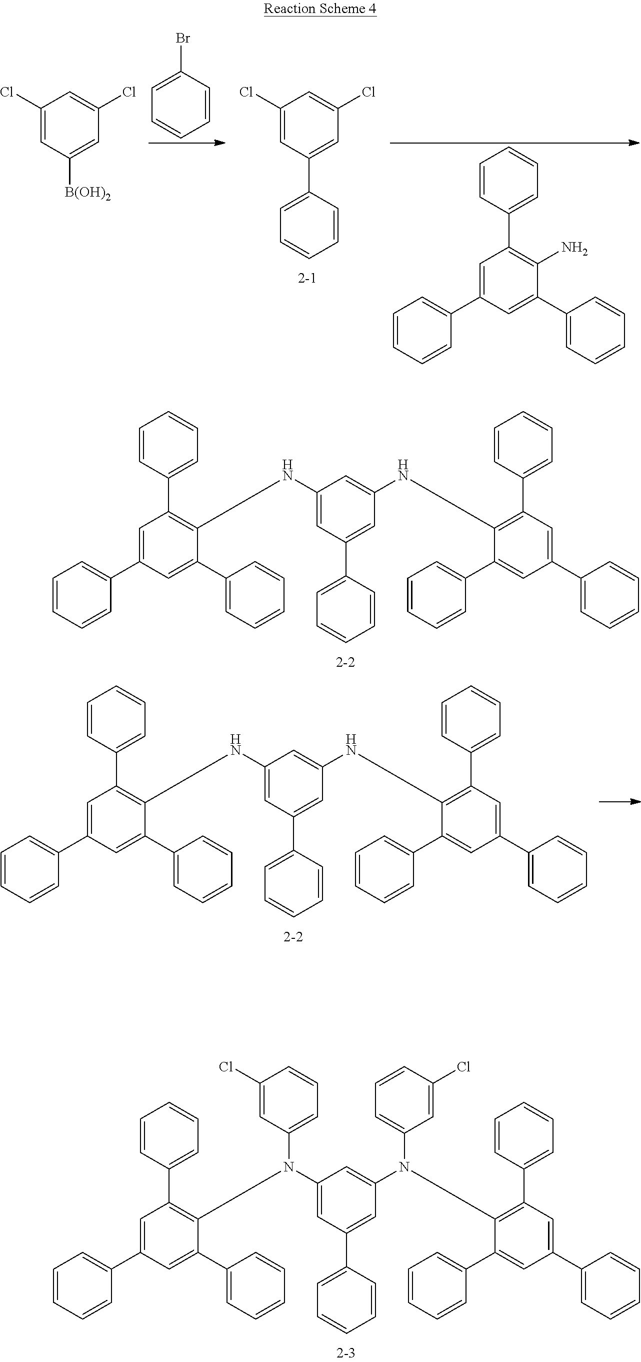

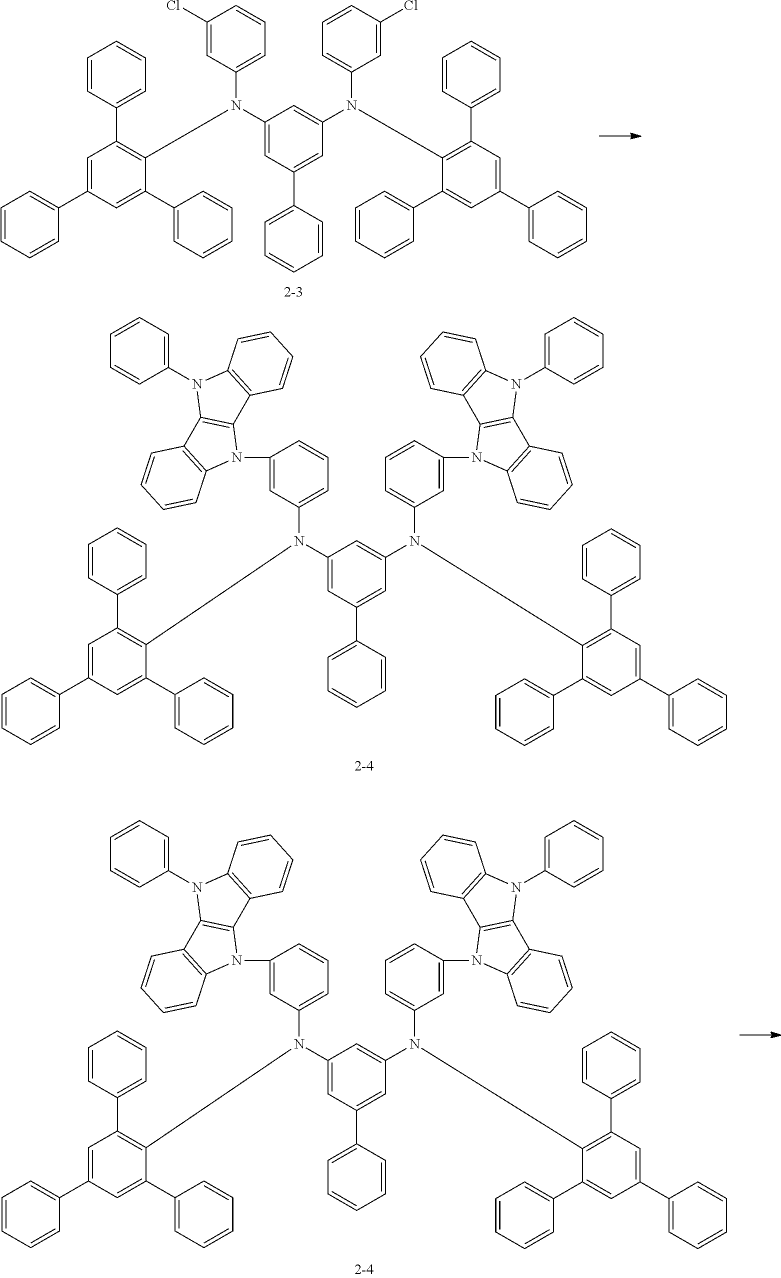

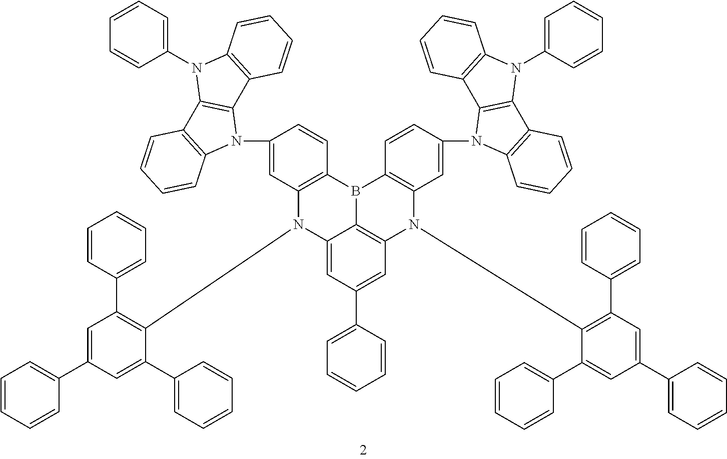 [SMILES: c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cc(-c6ccccc6)cc5-c5ccccc5)c5cc(-c6ccccc6)cc3c54)c(-c3ccccc3)c2)cc1]

### Synthesis of Intermediate Compound 2-1

(3,5-dichlorophenyl)boronic acid (1.2 eq), bromobenzene (1 eq), tris(dibenzylideneacetone)dipalladium(0) (0.05 eq), Pd(PPh₃)₄ (0.05 eq), and potassium carbonate (1.5 eq) were added, and dissolved in toluene/H₂O, which is a solvent, and then the reaction solution was stirred at 100° C. for 12 hours. After the solution was cooled, water (1 L) and ethyl acetate (300 mL) were added thereto to extract and collect an organic layer, and then the organic layer was dried with anhydrous MgSO₄ and then filtered. The filtered solution was depressurized to remove a solvent, and the obtained product was purified and separated by column chromatography using silica gel and by using CH₂Cl₂ and hexane as development solvents to obtain Intermediate Compound 2-1. (Yield: 88%)

### Synthesis of Intermediate Compound 2-2

Under a nitrogen atmosphere, Intermediate Compound 2-1 (1 eq), 5′-phenyl-[1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 2-2. (Yield: 79%)

### Synthesis of Intermediate Compound 2-3

Under a nitrogen atmosphere, Intermediate Compound 2-2 (1 eq), 3-iodochlorobenzene (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 2-3. (Yield: 65%)

### Synthesis of Intermediate Compound 2-4

Under a nitrogen atmosphere, Intermediate Compound 2-3 (1 eq), 5-phenyl-5,10-dihydroindolo[3,2-b]indole (2.4 eq), Pd₂(dba)₃ (0.05 eq), tris-tert-butyl phosphine (0.1 eq), and sodium tert-butoxide (3 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 2-4. (Yield: 41%)

### Synthesis of Compound 2

Under a nitrogen atmosphere, Intermediate Compound 2-4 (1 eq) was dissolved in o-dichlorobenzene, and then cooled by using water-ice, followed by slowly adding BBr₃ (5 equiv.) dropwise thereto, and then the reaction solution was stirred at 180° C. for 24 hours. After the solution was cooled, the reaction was terminated by adding triethylamine (5 equiv.) thereto, and an organic layer was extracted and collected with water/CH₂Cl₂, dried with anhydrous MgSO₄, and then filtered. The filtered solution was depressurized to remove a solvent, and the obtained product was purified and separated by column chromatography using silica gel to obtain Compound 2. (Yield: 63%)

### (5) Synthesis of Fused Polycyclic Compound 6

Fused Polycyclic Compound 6 according to one or more embodiments may be synthesized with reference to, for example, steps of Reaction Formula 5.

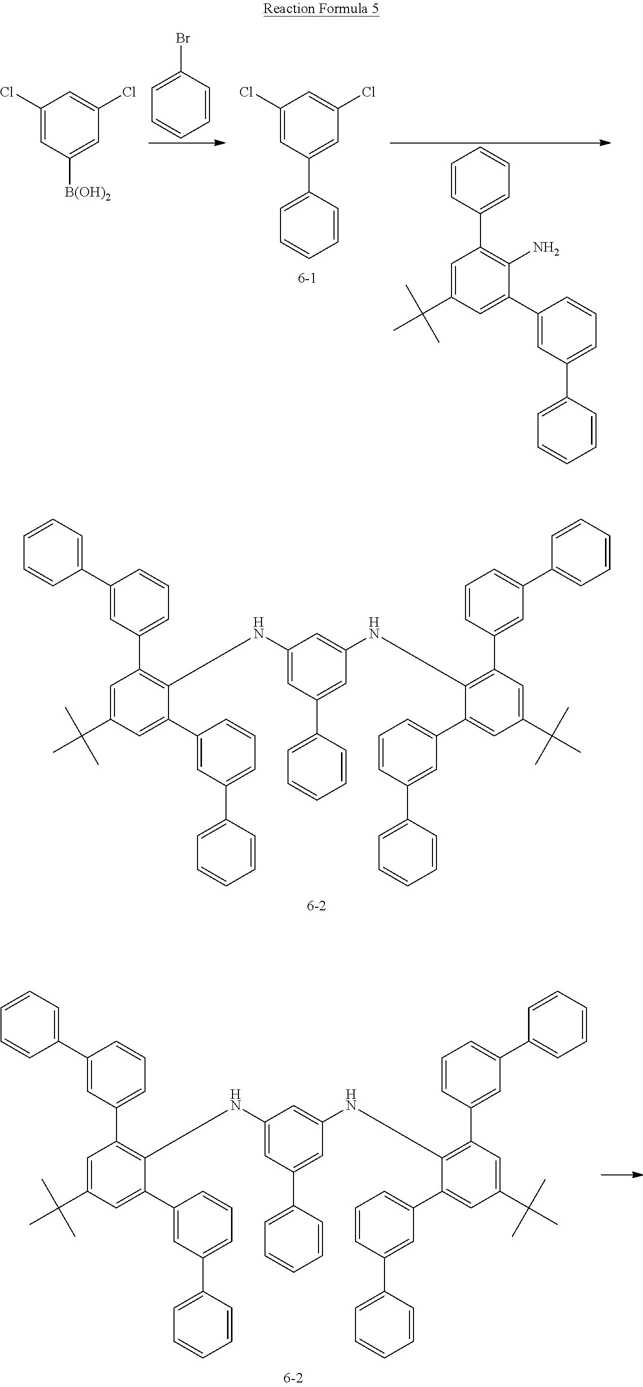

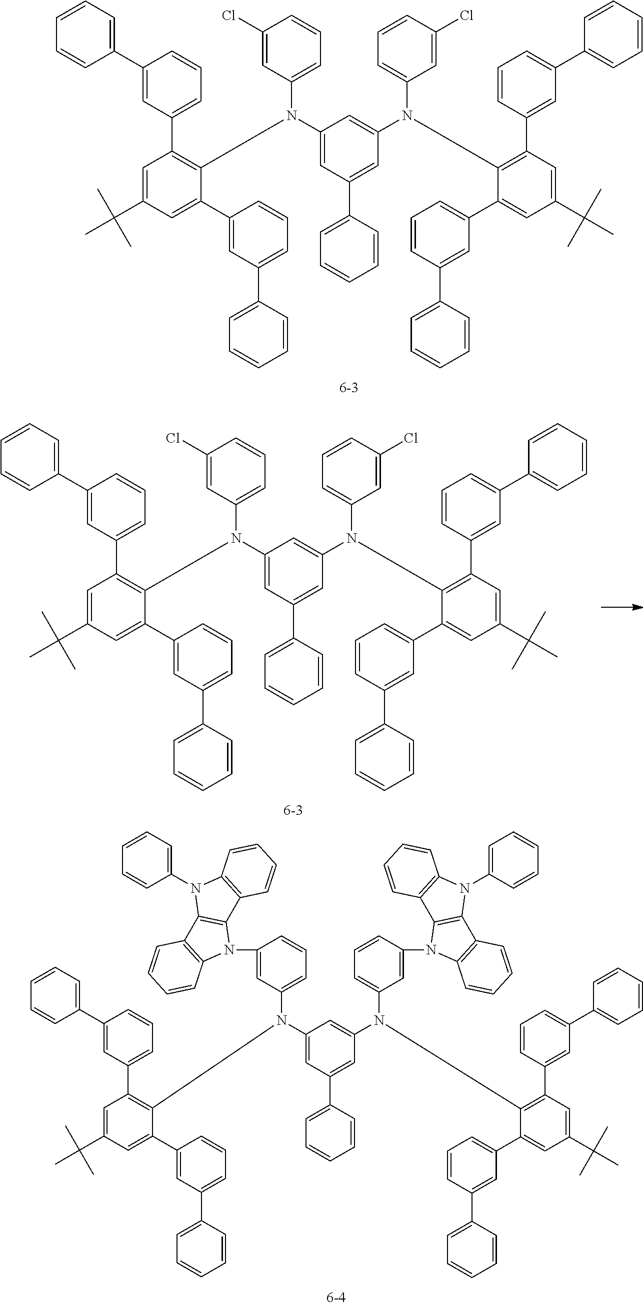

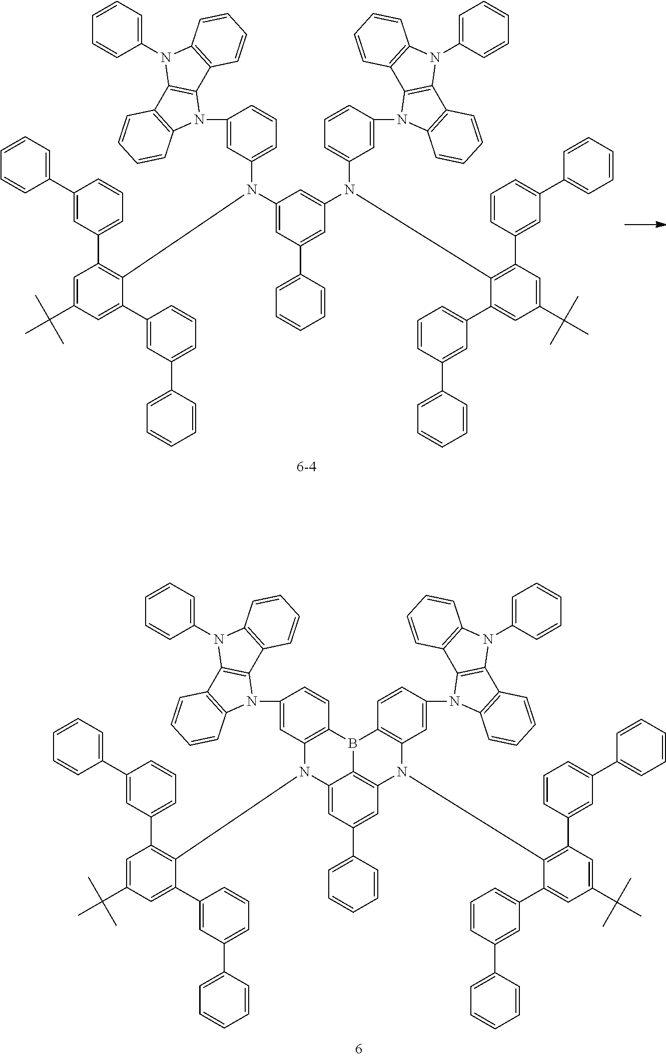 [SMILES: CC(C)(C)c1cc(-c2cccc(-c3ccccc3)c2)c(N(c2cc(-c3ccccc3)cc(N(c3cccc(-n4c5ccccc5c5c4c4ccccc4n5-c4ccccc4)c3)c3c(-c4cccc(-c5ccccc5)c4)cc(C(C)(C)C)cc3-c3cccc(-c4ccccc4)c3)c2)c2cccc(-n3c4ccccc4c4c3c3ccccc3n4-c3ccccc3)c2)c(-c2cccc(-c3ccccc3)c2)c1 ; CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1]

### Synthesis of Intermediate Compound 6-1

(3,5-dichlorophenyl)boronic acid (1.2 eq), bromobenzene (1 eq), tris(dibenzylideneacetone)dipalladium(0) (0.05 eq), Pd(PPh₃)₄ (0.05 eq), and potassium carbonate (1.5 eq) were added, and dissolved in toluene/H₂O, which is a solvent, and then the reaction solution was stirred at 100° C. for 12 hours. After the solution was cooled, water (1 L) and ethyl acetate (300 mL) were added thereto to extract and collect an organic layer, and then the organic layer was dried with anhydrous MgSO₄ and then filtered. The filtered solution was depressurized to remove a solvent, and the obtained product was purified and separated by column chromatography using silica gel and by using CH₂Cl₂ and hexane as development solvents to obtain Intermediate Compound 6-1. (Yield: 88%)

### Synthesis of Intermediate Compound 6-2

Under a nitrogen atmosphere, Intermediate Compound 6-1 (1 eq), 5″-(tert-butyl)-[1,1′:3′,1″:3″,1′″:3′″,1″″-quinquephenyl]-2″-amine (2.1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 6-2. (Yield: 74%)

### Synthesis of Intermediate Compound 6-3

Under a nitrogen atmosphere, Intermediate Compound 6-2 (1 eq), 3-iodochlorobenzene (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 6-3. (Yield: 66%)

### Synthesis of Intermediate Compound 6-4

Under a nitrogen atmosphere, Intermediate Compound 6-3 (1 eq), 5-phenyl-5,10-dihydroindolo[3,2-b]indole (2.4 eq), Pd₂(dba)₃ (0.05 eq), tris-tert-butyl phosphine (0.1 eq), and sodium tert-butoxide (3 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 6-4. (Yield: 41%)

### Synthesis of Compound 6

Under a nitrogen atmosphere, Intermediate Compound 6-4 (1 eq) was dissolved in o-dichlorobenzene, and then cooled by using water-ice, followed by slowly adding BBr₃ (5 equiv.) dropwise thereto, and then the reaction solution was stirred at 180° C. for 24 hours. After the solution was cooled, the reaction was terminated by adding triethylamine (5 equiv.) thereto, and an organic layer was extracted and collected with water/CH₂Cl₂, dried with anhydrous MgSO₄, and then filtered. The filtered solution was depressurized to remove a solvent, and the obtained product was purified and separated by column chromatography using silica gel to obtain Compound 6. (Yield: 63%)

### (6) Synthesis of Fused Polycyclic Compound 52

Fused Polycyclic Compound 52 according to one or more embodiments may be synthesized with reference to, for example, steps of Reaction Formula 6.

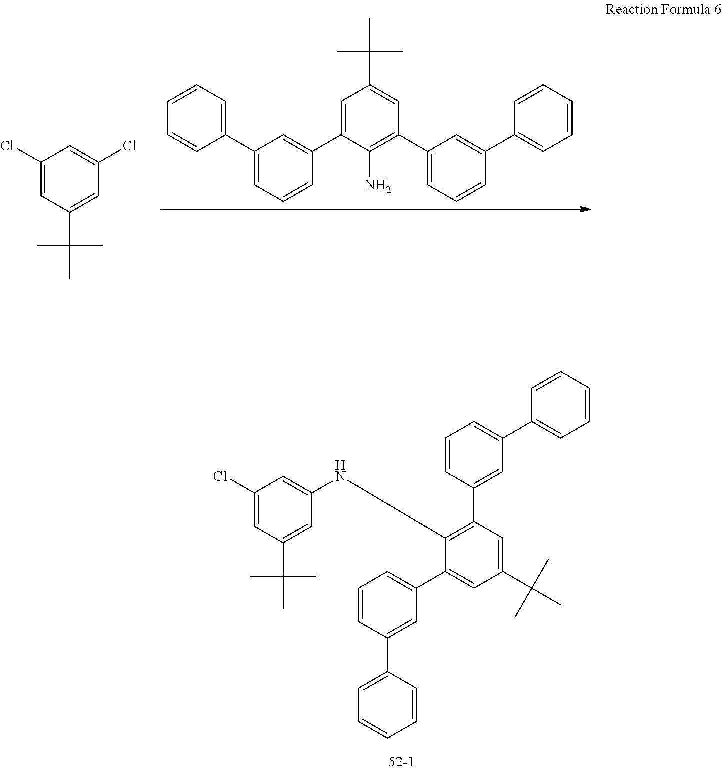

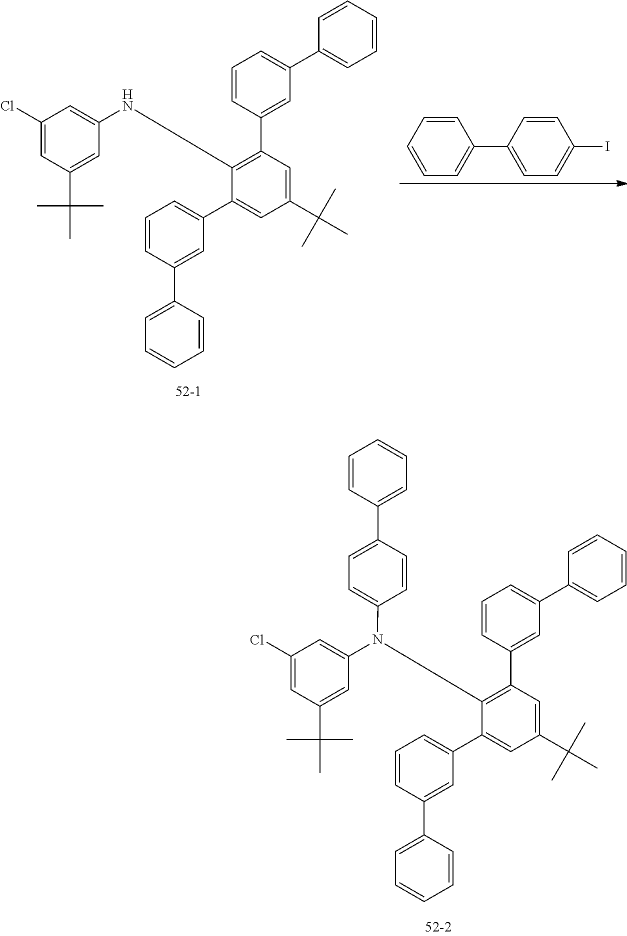 [SMILES: CC(C)(C)c1cc(Cl)cc(Nc2c(-c3cccc(-c4ccccc4)c3)cc(C(C)(C)C)cc2-c2cccc(-c3ccccc3)c2)c1 ; Ic1ccc(-c2ccccc2)cc1 ; CC(C)(C)c1cc(Cl)cc(N(c2ccc(-c3ccccc3)cc2)c2c(-c3cccc(-c4ccccc4)c3)cc(C(C)(C)C)cc2-c2cccc(-c3ccccc3)c2)c1]

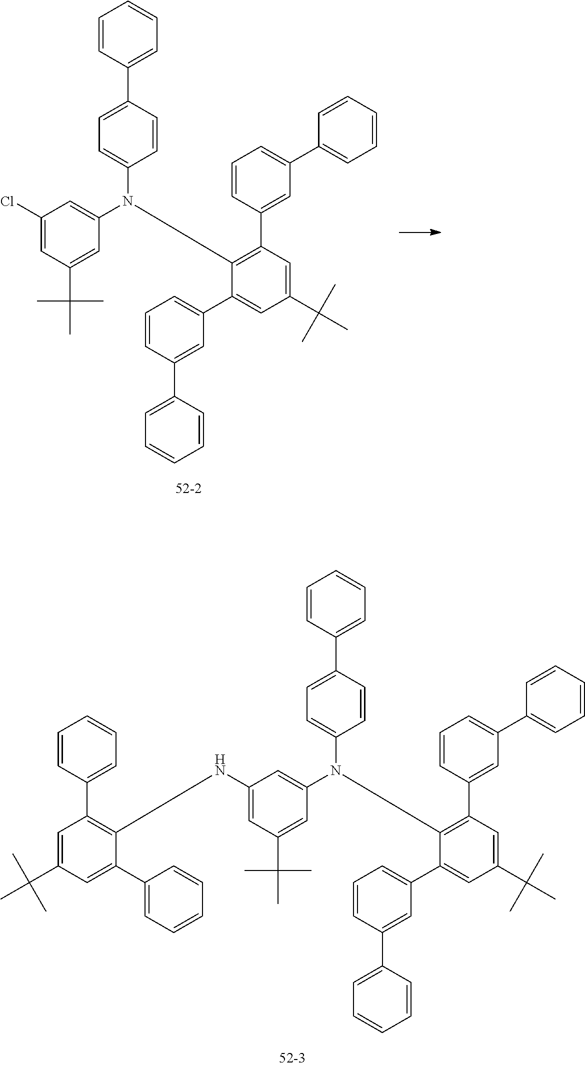 [SMILES: CC(C)(C)c1cc(Cl)cc(N(c2ccc(-c3ccccc3)cc2)c2c(-c3cccc(-c4ccccc4)c3)cc(C(C)(C)C)cc2-c2cccc(-c3ccccc3)c2)c1 ; CC(C)(C)c1cc(Nc2c(-c3ccccc3)cc(C(C)(C)C)cc2-c2ccccc2)cc(N(c2ccc(-c3ccccc3)cc2)c2c(-c3cccc(-c4ccccc4)c3)cc(C(C)(C)C)cc2-c2cccc(-c3ccccc3)c2)c1]

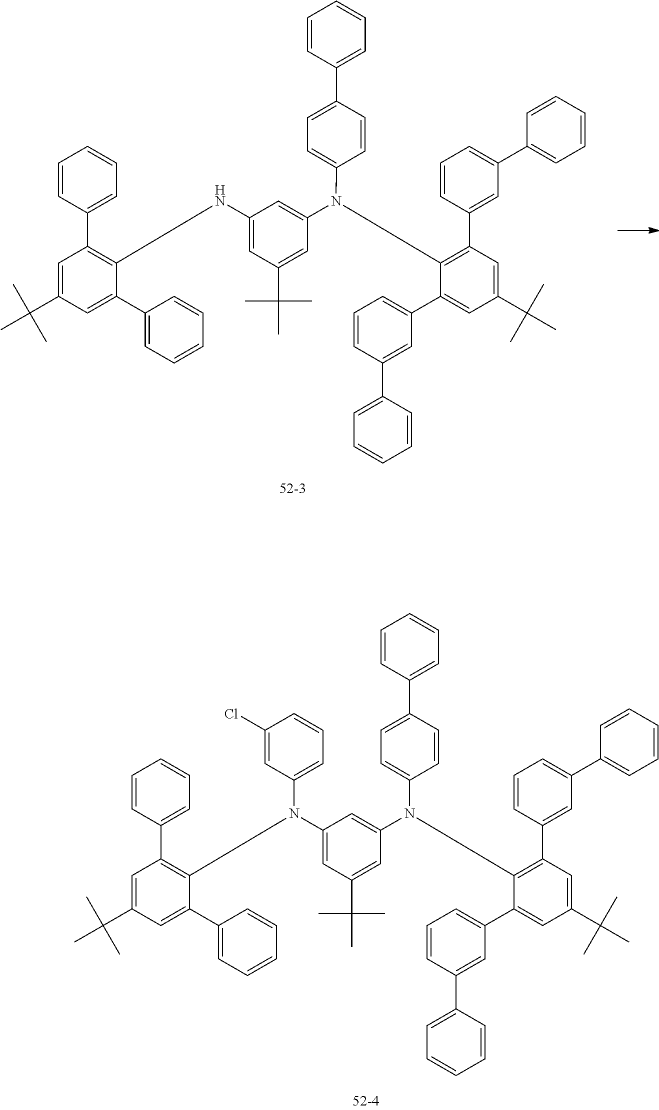 [SMILES: CC(C)(C)c1cc(Nc2c(-c3ccccc3)cc(C(C)(C)C)cc2-c2ccccc2)cc(N(c2ccc(-c3ccccc3)cc2)c2c(-c3cccc(-c4ccccc4)c3)cc(C(C)(C)C)cc2-c2cccc(-c3ccccc3)c2)c1 ; CC(C)(C)c1cc(N(c2ccc(-c3ccccc3)cc2)c2c(-c3cccc(-c4ccccc4)c3)cc(C(C)(C)C)cc2-c2cccc(-c3ccccc3)c2)cc(N(c2cccc(Cl)c2)c2c(-c3ccccc3)cc(C(C)(C)C)cc2-c2ccccc2)c1]

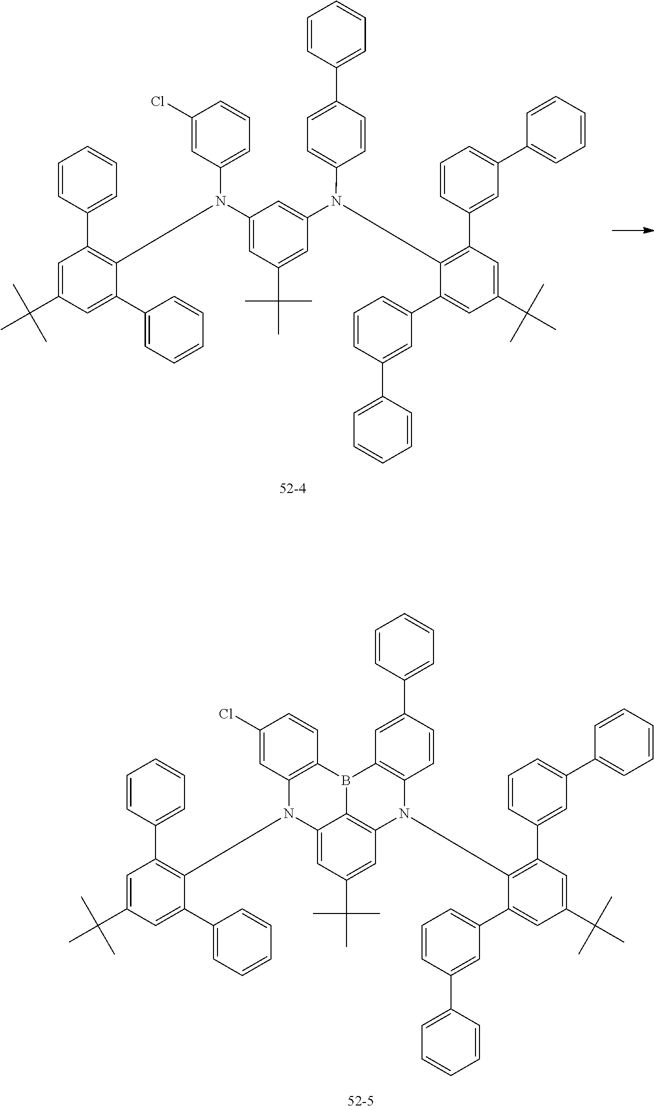 [SMILES: CC(C)(C)c1cc(N(c2ccc(-c3ccccc3)cc2)c2c(-c3cccc(-c4ccccc4)c3)cc(C(C)(C)C)cc2-c2cccc(-c3ccccc3)c2)cc(N(c2cccc(Cl)c2)c2c(-c3ccccc3)cc(C(C)(C)C)cc2-c2ccccc2)c1 ; CC(C)(C)c1cc(-c2cccc(-c3ccccc3)c2)c(N2c3ccc(-c4ccccc4)cc3B3c4ccc(Cl)cc4N(c4c(-c5ccccc5)cc(C(C)(C)C)cc4-c4ccccc4)c4cc(C(C)(C)C)cc2c43)c(-c2cccc(-c3ccccc3)c2)c1]

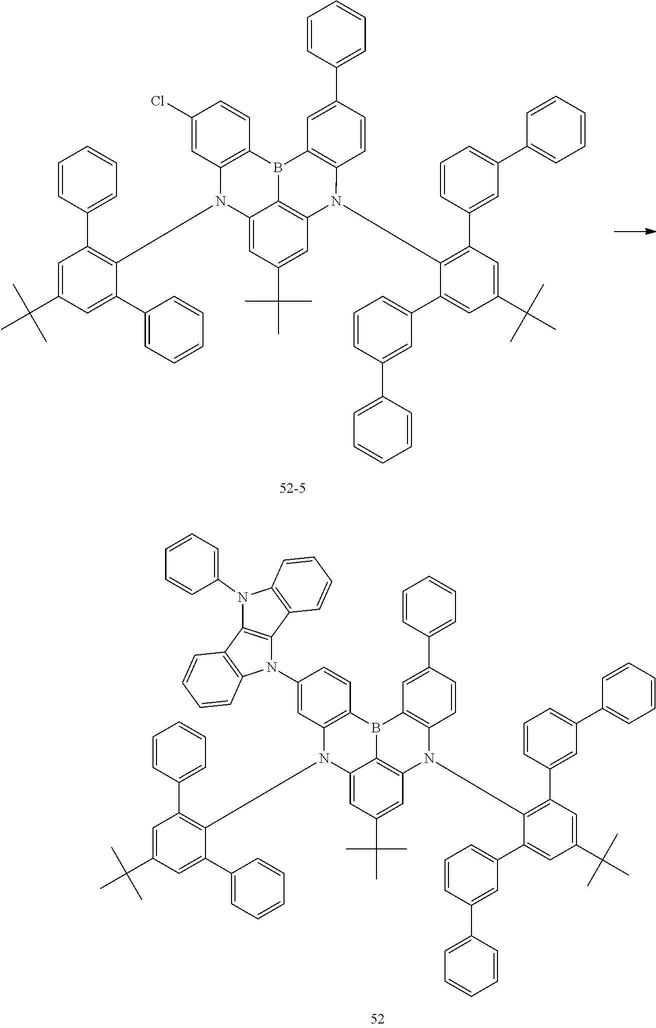 [SMILES: CC(C)(C)c1cc(-c2cccc(-c3ccccc3)c2)c(N2c3ccc(-c4ccccc4)cc3B3c4ccc(Cl)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc(-c2cccc(-c3ccccc3)c2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1]

### Synthesis of Intermediate Compound 52-1

Under a nitrogen atmosphere, 1-(tert-butyl)-3,5-dichlorobenzene (1 eq), 5″-(tert-butyl)-[1,1′:3′,1″:3″,1′″:3′″,1″″-quinquephenyl]-2″-amine (1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 52-1. (Yield: 62%)

### Synthesis of Intermediate Compound 52-2

Under a nitrogen atmosphere, Intermediate Compound 52-1 (1 eq), 4-iodo-1,1′-biphenyl (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 52-2. (Yield: 62%)

### Synthesis of Intermediate Compound 52-3

Under a nitrogen atmosphere, Intermediate Compound 52-2 (1 eq), 5′-(tert-butyl)-[1,1′:3′,1″-terphenyl]-2′-amine (1 eq), Pd₂(dba)₃ (0.05 eq), tris-tert-butyl phosphine (0.1 eq), and sodium tert-butoxide (1.5 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 52-3. (Yield: 62%)

### Synthesis of Intermediate Compound 52-4

Under a nitrogen atmosphere, Intermediate Compound 52-3 (1 eq), 3-iodochlorobenzene (10 eq), Pd₂(dba)₃ (0.5 eq), tris-tert-butyl phosphine (1 eq), and sodium tert-butoxide (4 eq) were added, and dissolved in o-xylene, and then the reaction solution was stirred at 160° C. for 3 days. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Intermediate Compound 52-4. (Yield: 61%)

### Synthesis of Intermediate Compound 52-5

Under a nitrogen atmosphere, Intermediate Compound 52-4 (1 eq) was dissolved in o-dichlorobenzene, and then cooled by using water-ice, followed by slowly adding BBr₃ (5 equiv.) dropwise thereto, and then the reaction solution was stirred at 180° C. for 24 hours. After the solution was cooled, the reaction was terminated by adding triethylamine (5 equiv.) thereto, and an organic layer was extracted and collected with water/CH₂Cl₂, dried with anhydrous MgSO₄, and then filtered. The filtered solution was depressurized to remove a solvent, and the obtained product was purified and separated by column chromatography using silica gel to obtain Intermediate Compound 52-5. (Yield: 34%)

### Synthesis of Compound 52

Under a nitrogen atmosphere, Intermediate Compound 52-5 (1 eq), 5-phenyl-5,10-dihydroindolo[3,2-b]indole (2.4 eq), Pd₂(dba)₃ (0.1 eq), tris-tert-butyl phosphine (0.2 eq), and sodium tert-butoxide (3 eq) were added, and dissolved in o-xylene, and then the reaction solution was stirred at 140° C. for 1 day. After the solution was cooled, water and ethyl acetate were added thereto to extract and collect an organic layer, and then the organic layer was dried with anhydrous MgSO₄ and then filtered. The filtered solution was depressurized to remove a solvent, and the obtained product was purified and separated by column chromatography using silica gel to obtain Compound 52. (Yield: 43%)

### 2. Manufacturing and Evaluation of Light Emitting Element

### (1) Manufacturing of Light Emitting Element

A light emitting element including the fused polycyclic compound of one or more embodiments or including a Comparative Example Compound in an emission layer was manufactured in the following manner. Compounds 8, 22, 82, 2, 6, and 52, which are each the fused polycyclic compound of one or more embodiments, were respectively used as a dopant material of an emission layer to manufacture light emitting elements of Examples 1-1 to 1-6 and Examples 2-1 to 2-6. Light emitting elements of Comparative Examples 1-1 and 2-1 were each manufactured by using Comparative Example Compound CX1 as a dopant material of an emission layer, and light emitting elements of Comparative Examples 1-2 and 2-2 were each manufactured by using Comparative Compound CX2 as a dopant material of an emission layer.

As a first electrode (anode), a glass substrate (a product of Corning Co.) having an ITO electrode of 15 Ω/cm² (1200 Å) was cut to a size of 50 mm×50 mm×0.7 mm, ultrasonically cleaned for 5 minutes each with isopropyl alcohol and pure water, and then irradiated with ultraviolet light for 30 minutes and exposed to ozone to be cleaned, and then mounted on a vacuum deposition apparatus.

On the first electrode, NPD was deposited to form a hole injection layer having a thickness of 300 Å, a hole transport layer material described in Table 1 and Table 2 was deposited on the hole injection layer to form a hole transport layer having a thickness of 200 Å. Thereafter, CzSi was deposited on the hole transport layer to form a light emitting auxiliary layer (i.e., emission-auxiliary layer) having a thickness of 100 Å.

On the light emitting auxiliary layer, a host mixture, a sensitizer, and a dopant were co-deposited at a weight ratio of 85:14:1 to form an emission layer having a thickness of 200 Å. When the emission layer is formed, materials as described in Table 1 and Table 2 were used as a host (and the sensitizer) and the dopant, and the host mixture includes an HT host and an ET host at a weight ratio of 5:5.

The light emitting elements of Examples 1-1 to 1-6 described in Table 1 and the light emitting elements of Examples 2-1 to 2-6 described in Table 2 differ from each other in that whether or not a sensitizer is included. The light emitting elements of Examples 2-1 to 2-6 each do not provide a sensitizer when forming an emission layer, but provide a host mixture and a dopant at a weight ratio of 99:1.

TSPO1 was deposited on the emission layer to form a hole blocking layer having a thickness of 200 Å, and TPBi was deposited on the hole blocking layer to form an electron transport layer having a thickness of 300 Å. LiF was deposited on the electron transport layer to form an electron injection layer having a thickness of 10 Å. Al was deposited on the electron injection layer to form a second electrode (cathode) having a thickness of 3000 Å, and Compound P4 was deposited on the second electrode to form a capping layer having a thickness of 700 Å, thereby manufacturing a light emitting element.

### Materials Used in Manufacturing Light Emitting Elements

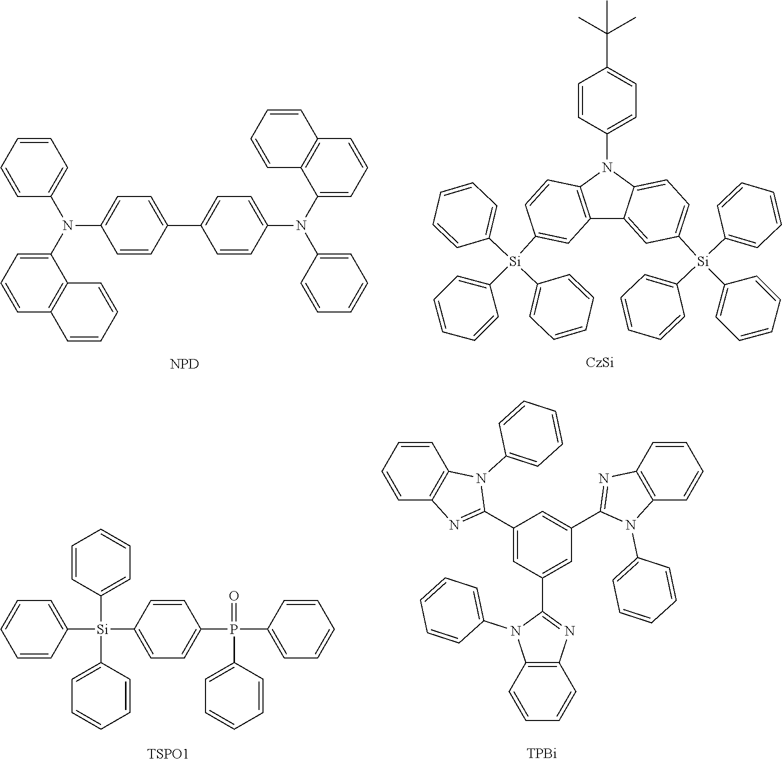

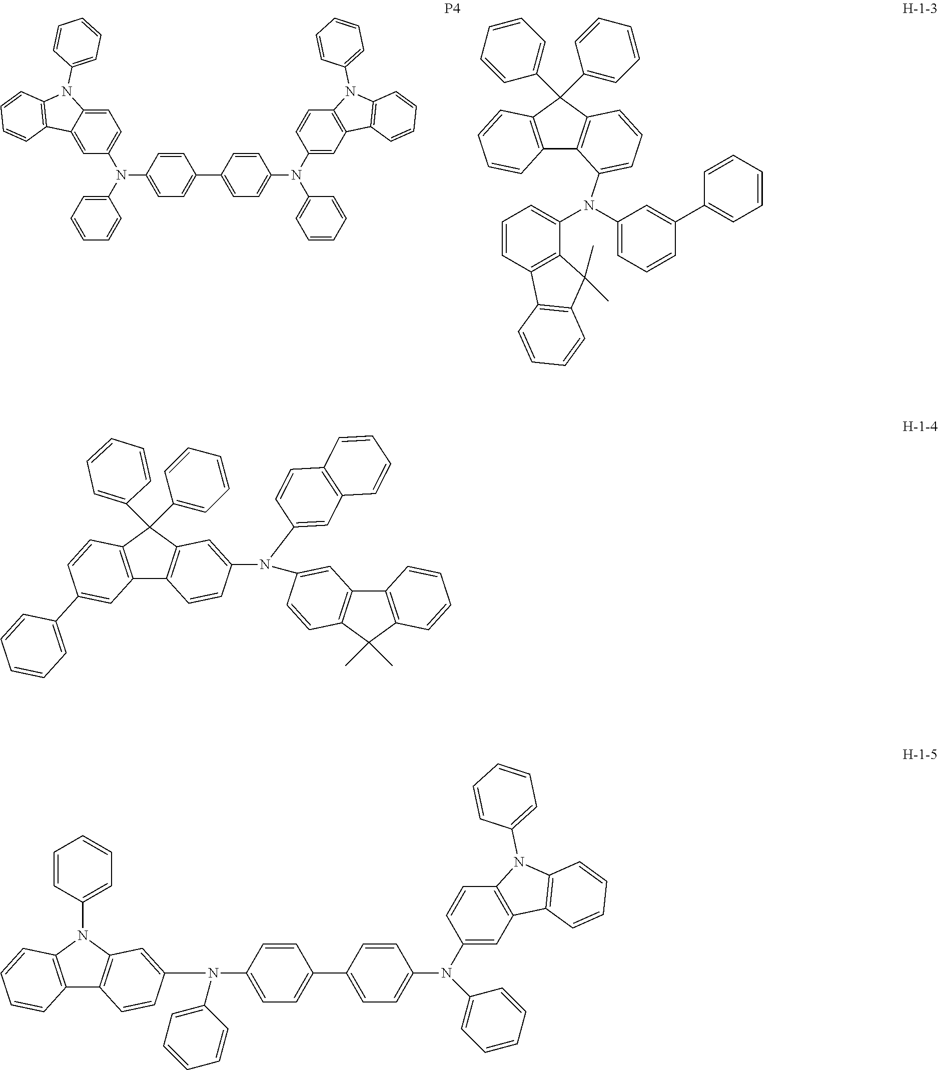 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

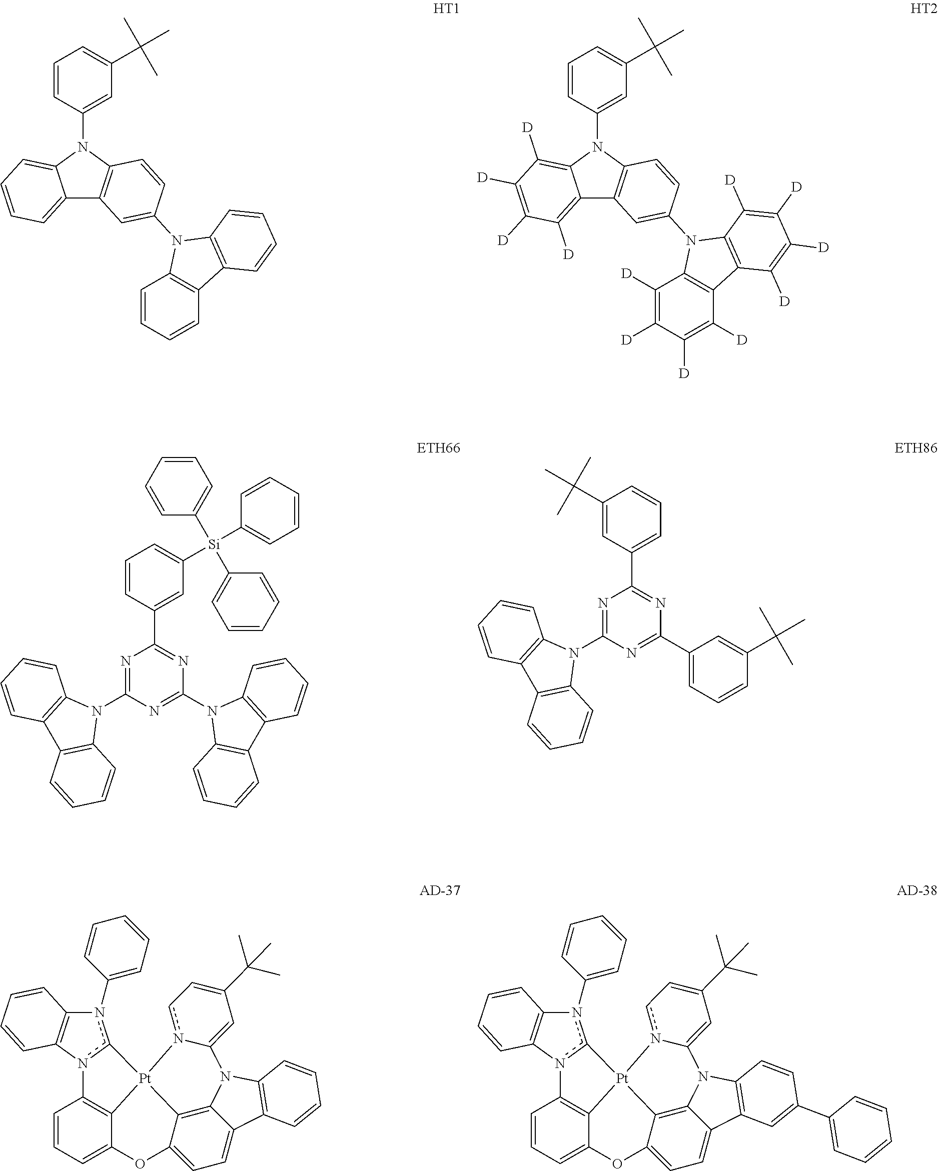

### Example Compounds

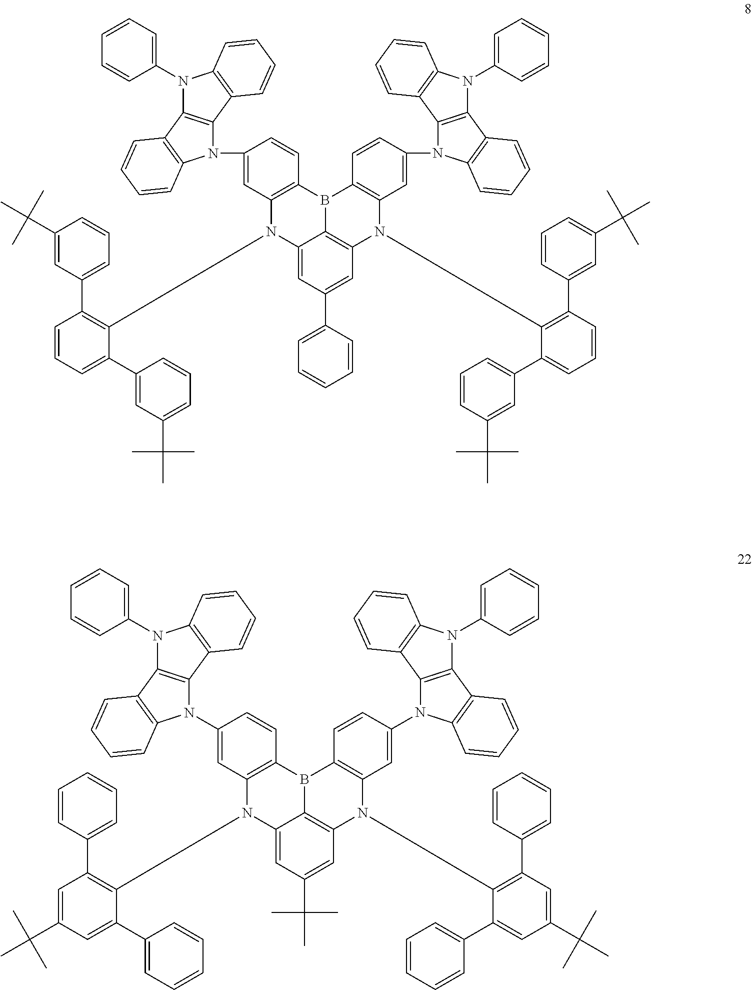

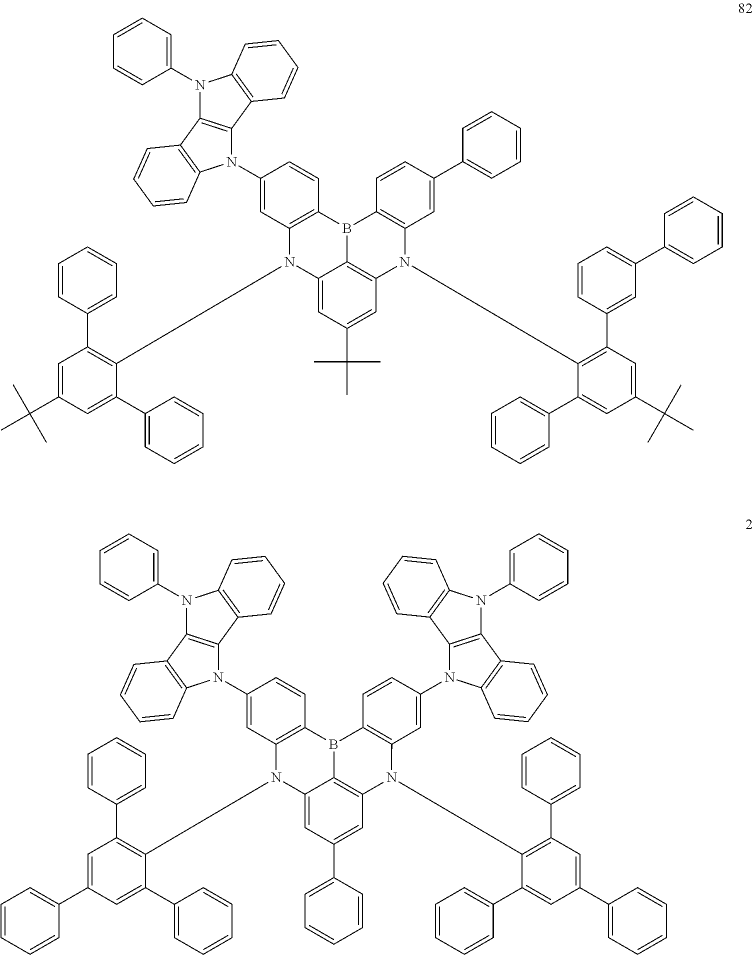 [SMILES: CC(C)(C)c1cc(-c2ccccc2)c(N2c3cc(-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1 ; c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cc(-c6ccccc6)cc5-c5ccccc5)c5cc(-c6ccccc6)cc3c54)c(-c3ccccc3)c2)cc1]

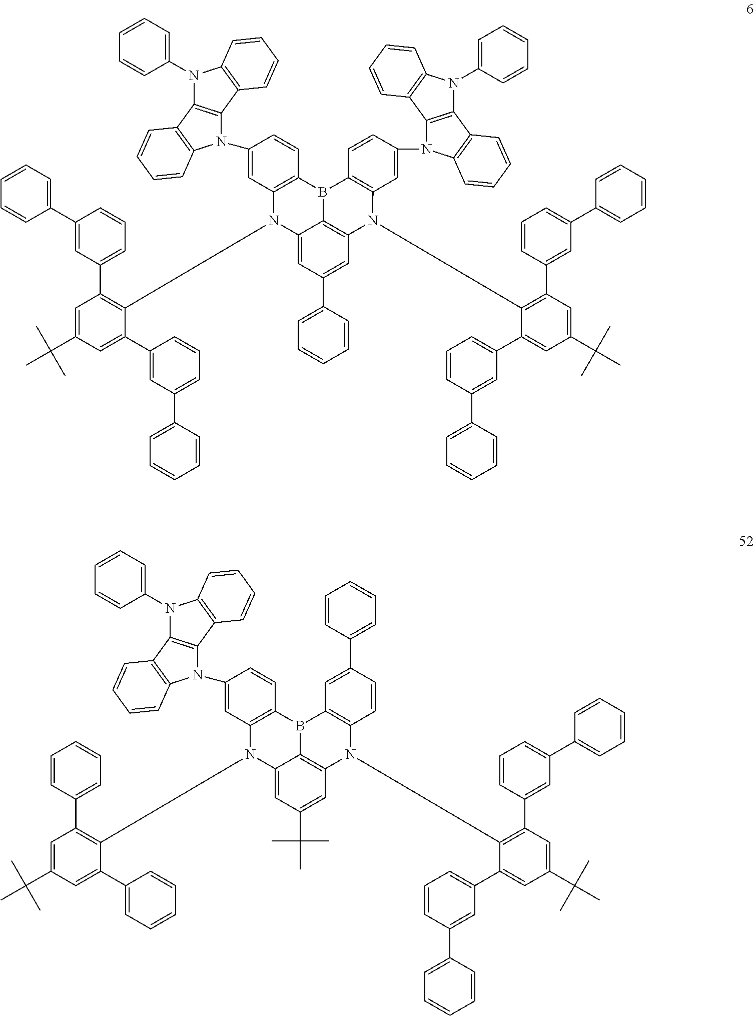 [SMILES: CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1 ; CC(C)(C)c1cc(-c2cccc(-c3ccccc3)c2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1]

### Comparative Example Compounds

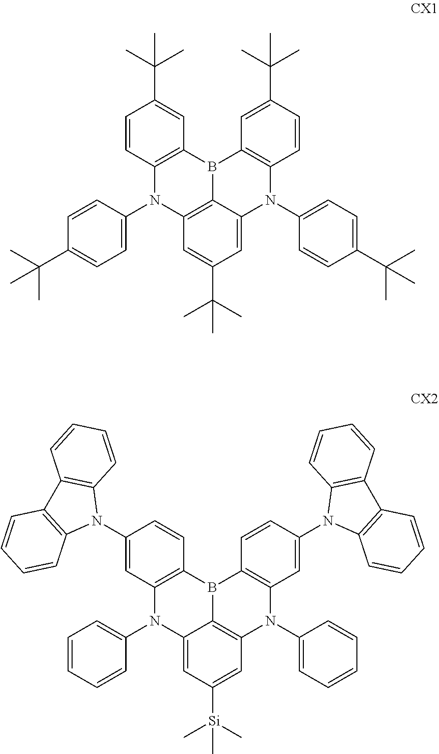 [SMILES: CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1 ; C[Si](C)(C)c1cc2c3c(c1)N(c1ccccc1)c1cc(-n4c5ccccc5c5ccccc54)ccc1B3c1ccc(-n3c4ccccc4c4ccccc43)cc1N2c1ccccc1]

### 2) Evaluation of Light Emitting Elements

Table 1 and Table 2 show the evaluation of light emitting elements of Comparative Examples and Examples. Table 1 and/or Table 2 show the results of measuring the driving voltage, luminous efficiency, maximum external quantum efficiency, lifetime, and luminous color at a luminance 1000 cd/m² by using Keithley MU 236 and a luminance meter PR650. Lifespan (T95) shows the result of measuring the time required for an luminance decreasing from its initial luminance to 95% of the initial luminance, and then calculating relative lifespan based on (e.g., with respect to) Comparative Example 1-1 whose lifespan (T95) sets as 100.

TABLE 1

| | | | | | | | Maximum | | |
|---|---|---|---|---|---|---|---|---|---|
| | Hole | | | | | | external | | |
| | transport | | | | Driving | Luminous | quantum | | |
| | layer | Host | | | voltage | efficiency | efficiency | Lifespan | Luminous |
| | host | (HT:ET = 5:5) | Sensitizer | Dopant | (V) | (cd/A) | (%) | (T95) | color |
| Example 1-1 | H-1-3 | HT1/ETH66 | AD-38 | Compound 8 | 4.2 | 25.7 | 24.6 | 215 | Blue |
| Example 1-2 | H-1-5 | HT2/ETH86 | AD-38 | Compound 22 | 4.3 | 23.5 | 22.3 | 210 | Blue |
| Example 1-3 | H-1-4 | HT2/ETH86 | AD-37 | Compound 82 | 4.2 | 27.1 | 26.2 | 230 | Blue |
| Example 1-4 | H-1-3 | HT2/ETH86 | AD-38 | Compound 2 | 4.3 | 24.5 | 23.7 | 213 | Blue |
| Example 1-5 | H-1-3 | HT2/ETH66 | AD-38 | Compound 6 | 4.2 | 22.8 | 21.9 | 205 | Blue |
| Example 1-6 | H-1-5 | HT2/ETH86 | AD-37 | Compound 52 | 4.3 | 26.1 | 25.3 | 220 | Blue |
| Comparative | H-1-3 | HT2/ETH66 | AD-37 | Comparative | 4.4 | 13.4 | 12.3 | 100 | Blue |
| Example 1-1 | | | | Example | | | | | |
| | | | | Compound CX1 | | | | | |
| Comparative | H-1-3 | HT2/ETH66 | AD-37 | Comparative | 4.5 | 15.7 | 14.3 | 130 | Blue |
| Example 1-2 | | | | Example | | | | | |
| | | | | Compound CX2 | | | | | |

TABLE 2

| | | | | | Maximum | |
|---|---|---|---|---|---|---|
| | Hole | | | Luminous | external | |
| | transport | Host | | efficiency | quantum | Luminous |
| | layer host | (HT:ET = 5:5) | Dopant | (cd/A) | efficiency (%) | color |
| Example 2-1 | H-1-3 | HT1/ETH66 | Compound 8 | 9.6 | 9.0 | Blue |
| Example 2-2 | H-1-5 | HT2/ETH86 | Compound 22 | 9.1 | 8.9 | Blue |
| Example 2-3 | H-1-4 | HT2/ETH86 | Compound 82 | 10.4 | 9.9 | Blue |
| Example 2-4 | H-1-4 | HT2/ETH86 | Compound 2 | 9.2 | 8.8 | Blue |
| Example 2-5 | H-1-3 | HT2/ETH86 | Compound 6 | 9.3 | 9.0 | Blue |
| Example 2-6 | H-1-3 | HT2/ETH66 | Compound 52 | 10.1 | 9.7 | Blue |
| Comparative | H-1-5 | HT2/ETH86 | Comparative | 4.5 | 4.1 | Blue |
| Example 2-1 | | | Example | | | |
| | | | Compound CX1 | | | |
| Comparative | H-1-3 | HT2/ETH66 | Comparative | 5.3 | 4.9 | Blue |
| Example 2-2 | | | Example | | | |
| | | | Compound CX2 | | | |

Referring to Table 1, it can be seen that each of the light emitting elements of Comparative Example 1-1, Comparative Example 1-2, and Examples 1-1 to 1-6 emits blue light. Compared to the light emitting elements of Comparative Example 1-1 and Comparative Example 1-2, it can be seen that each of the light emitting elements of Examples 1-1 to 1-6 exhibits high luminous efficiency and high maximum external quantum efficiency. Compared to the light emitting elements of Comparative Example 1-1 and Comparative Example 1-2, it can be seen that each of the light emitting elements of Examples 1-1 to 1-6 has a low driving voltage and a long lifespan.

Referring to Table 2, it can be seen that each of the light emitting elements of Comparative Example 2-1, Comparative Example 2-2, and Examples 2-1 to 2-6 emits blue light. Compared to the light emitting elements of Comparative Example 2-1 and Comparative Example 2-2, it can be seen that each of the light emitting elements of Examples 2-1 to 2-6 exhibits high luminous efficiency and high maximum external quantum efficiency.

The light emitting elements of Examples 1-1 to 1-6 and 2-1 to 2-6 respectively include Compounds 8, 22, 82, 2, 6, and 52, wherein Compounds 8, 22, 82, 2, 6, and 52 are each the fused polycyclic compound of one or more embodiments. Compounds 8, 22, 82, 2, 6, and 52 each include an indoloindole moiety and a biphenyl moiety bonded to a central structure. The central structure is a 5-ring fused ring including two nitrogen atoms and one boron atom as ring forming atoms. It can be seen that Compounds 8, 22, 82, 2, 6, and 52 each including the indoloindole moiety, which is a bulky substituent, improve the efficiency and lifespan of a light emitting element by preventing or reducing intermolecular interactions and Dexter energy transfer. Therefore, it can be seen that the fused polycyclic compound of one or more embodiments improves the efficiency and lifespan of the light emitting element.

The light emitting elements of Comparative Examples 1-1 and 2-1 each include Comparative Example Compound CX1. Comparative Example Compound CX1 includes a 5-ring fused ring as the central structure, but does not include an indoloindole moiety and a biphenyl moiety. In Comparative Example Compound CX1, a t-butyl group is bonded to the 5-ring fused ring. Accordingly, the light emitting element of Comparative Example 2-1 exhibits relatively low luminous efficiency and low maximum external quantum efficiency, and the light emitting element of Comparative Example 1-1 exhibits relatively low luminous efficiency, low maximum external quantum efficiency, a high driving voltage, and a short lifespan.

The light emitting elements of Comparative Examples 1-2 and 2-2 each include Comparative Example Compound CX2. Comparative Example Compound CX2 includes a 5-ring fused ring as the central structure, but does not include an indoloindole moiety and a biphenyl moiety. In Comparative Example Compound CX2, carbazole groups are bonded to the 5-ring fused ring. Accordingly, the light emitting element of Comparative Example 2-2 exhibits relatively low luminous efficiency and low maximum external quantum efficiency, and the light emitting element of Comparative Example 1-2 exhibits relatively low luminous efficiency, low maximum external quantum efficiency, a high driving voltage, and a short lifespan.

The display device of one or more embodiments may include the light emitting element of one or more embodiments, and the light emitting element of one or more embodiments may include a fused polycyclic compound of one or more embodiments. The fused polycyclic compound of one or more embodiments may include, as a central structure, a 5-ring fused ring including two nitrogen atoms and one boron atom as ring-forming atoms, and may include an indoloindole moiety and a biphenyl moiety bonded to the central structure. Accordingly, the fused polycyclic compound of one or more embodiments may prevent or reduce intermolecular interactions and Dexter energy transfer, and may thus improve luminous efficiency of the light emitting element.

The light emitting element of one or more embodiments and the display device including the light emitting element include a fused polycyclic compound of one or more embodiments, and thus, may exhibit properties of high luminous efficiency and long lifespan.

The fused polycyclic compound of one or more embodiments may contribute to the high luminous efficiency of the light emitting element and the display device of the present disclosure.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the electronic apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although disclosure has been described with reference to example embodiments of disclosure, it will be understood by those skilled in the art that one or more suitable modifications and changes in form and details may be made therein without departing from the spirit and scope of disclosure as set forth in the appended claims and equivalents thereof.

Accordingly, the technical scope of the disclosure is not intended to be limited to the contents set forth in the detailed description of the disclosure, but is intended to be defined by the appended claims and equivalents thereof.

What is claimed is:

1. A light emitting element comprising:
a first electrode;
a second electrode on the first electrode; and
an emission layer between the first electrode and the second electrode and comprising a first compound represented by Formula 1: 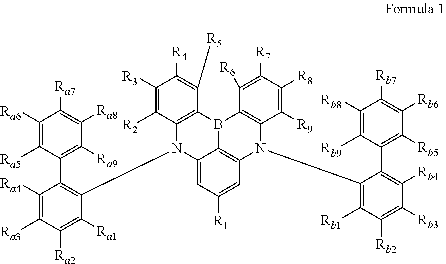
wherein in Formula 1,
at least one selected from among R₁ to R₉, Rₐ₁ to Rₐ₉, and R_{b1} to R_{b9} is represented by Formula 2, and the rest thereof are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group: 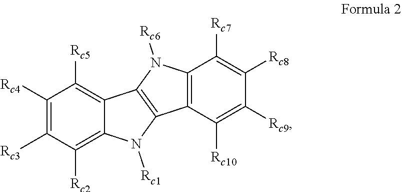
and
wherein in Formula 2,
any one selected from among R_{c1} to R_{c10} is a position bonded to Formula 1, and the remaining R_{c1} to R_{c10} other than the one selected are each independently hydrogen, deuterium, or a substituted or unsubstituted aryl group having 6 to 30 ring-forming carbon atoms.

2. The light emitting element of claim 1, wherein the emission layer further comprises at least one of a second compound represented by Formula HT-1, a third compound represented by Formula ET-1, or a fourth compound represented by Formula D-1: 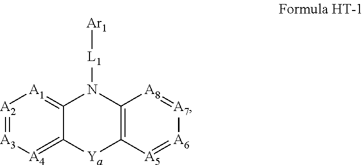
wherein in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or form a ring by being bonded to an adjacent group; 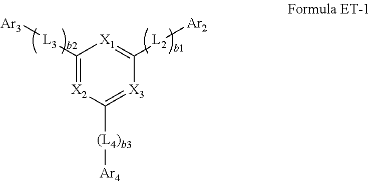
wherein in Formula ET-1,
at least one selected from among X₁ to X₃ is N, and the rest thereof are CR₅₆,
R₅₆ is hydrogen, deuterium, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently hydrogen, deuterium, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; and 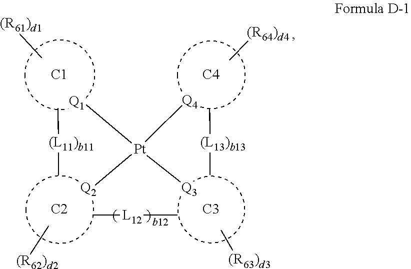
wherein in Formula D-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted hetero ring having 2 to 30 ring-forming carbon atoms,
L₁₁ to L₁₃ may each independently be a direct linkage, *—O—*, *—S—*, 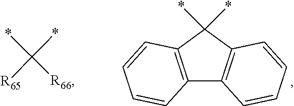
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

3. The light emitting element of claim 1, wherein Formula 2 is represented by Formula 2-A: 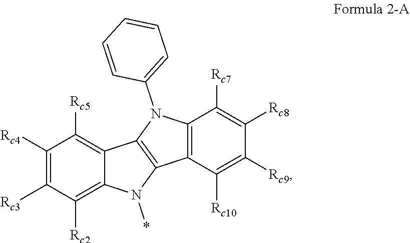
in Formula 2-A,
R_{c2} to R_{c5} and R_{c7} to R_{c10} each being the same as defined in Formula 2.

4. The light emitting element of claim 1, wherein the first compound represented by Formula 1 is represented by Formula 1-A or Formula 1-B: 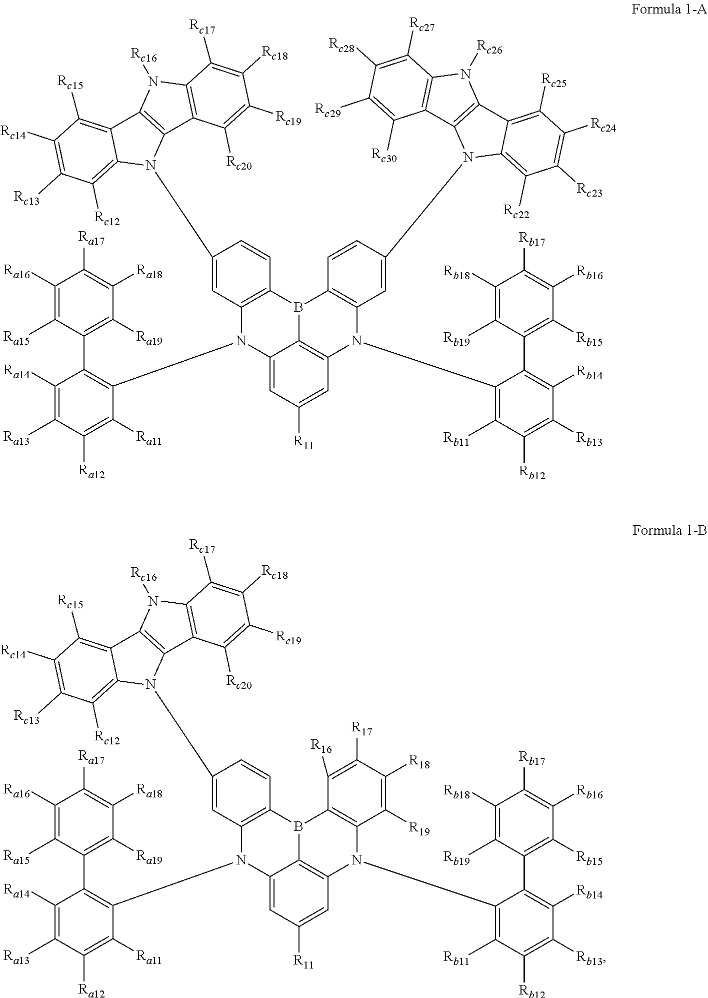
wherein in Formula 1-A,
R_{c22} to R_{c30} are each independently hydrogen, deuterium, or a substituted or unsubstituted aryl group having 6 to 30 ring-forming carbon atoms,
wherein in Formula 1-B,
R₁₆ to R₁₉ are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group, and
wherein in Formula 1-A and Formula 1-B,
R₁₁, Rₐ₁₁ to Rₐ₁₉, and R_{b1}1 to R_{b19} are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group, and
R_{c12} to R_{c20} are each independently hydrogen, deuterium, or a substituted or unsubstituted aryl group having 6 to 30 ring-forming carbon atoms.

5. The light emitting element of claim 4, wherein the first compound represented by Formula 1-A is represented by Formula 1-A1: 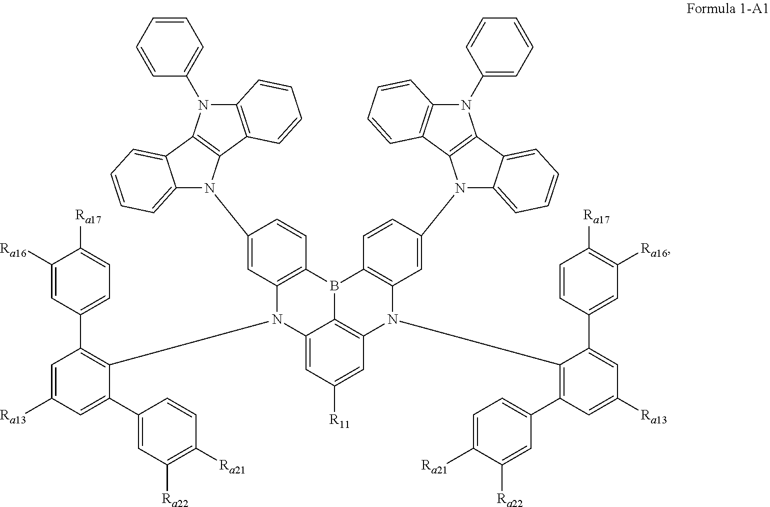
in Formula 1-A1,
Rₐ₂₁, Rₐ₂₂, R_{b21}, and R_{b22} being each independently hydrogen, deuterium, a substituted or unsubstituted alkyl group having 1 to 30 carbon atoms, or a substituted or unsubstituted aryl group having 6 to 30 ring-forming carbon atoms, and
R₁₁, Rₐ₁₃, Rₐ₁₆, Rₐ₁₇, R_{b13}, R_{b16}, and R_{b17} each being the same as defined in Formula 1-A.

6. The light emitting element of claim 5, wherein in Formula 1-A1, Rₐ₂₁, Rₐ₂₂, R_{b21}, and R_{b22} are each independently hydrogen, a substituted or unsubstituted t-butyl group, or a substituted or unsubstituted phenyl group.

7. The light emitting element of claim 4, wherein the first compound represented by Formula 1-B is represented by Formula 1-B1 or Formula 1-B2: 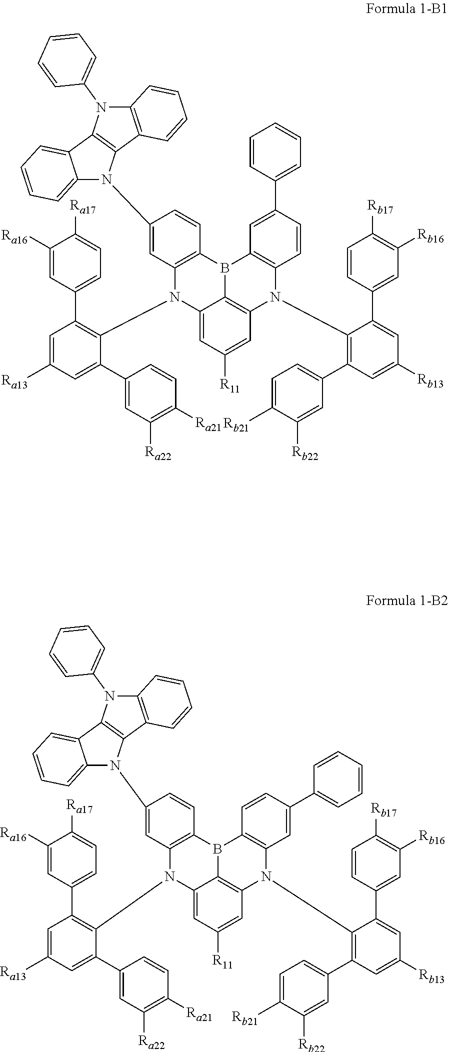
in Formula 1-B1 and Formula 1-B2,
Rₐ₂₁, Rₐ₂₂, R_{b21}, and R_{b22} being each independently hydrogen, deuterium, a substituted or unsubstituted alkyl group having 1 to 30 carbon atoms, or a substituted or unsubstituted aryl group having 6 to 30 ring-forming carbon atoms, and
R₁₁, Rₐ₁₃, Rₐ₁₆, Rₐ₁₇, R_{b13}, R_{b16}, and R_{b17} each being the same as defined in Formula 1-B.

8. The light emitting element of claim 1, wherein in Formula 1, a first biphenyl group comprising Rₐ₁ to Rₐ₉ and a second biphenyl group comprising R_{b1} to R_{b9} are each independently represented by any one selected from among AB-1 to AB-12:

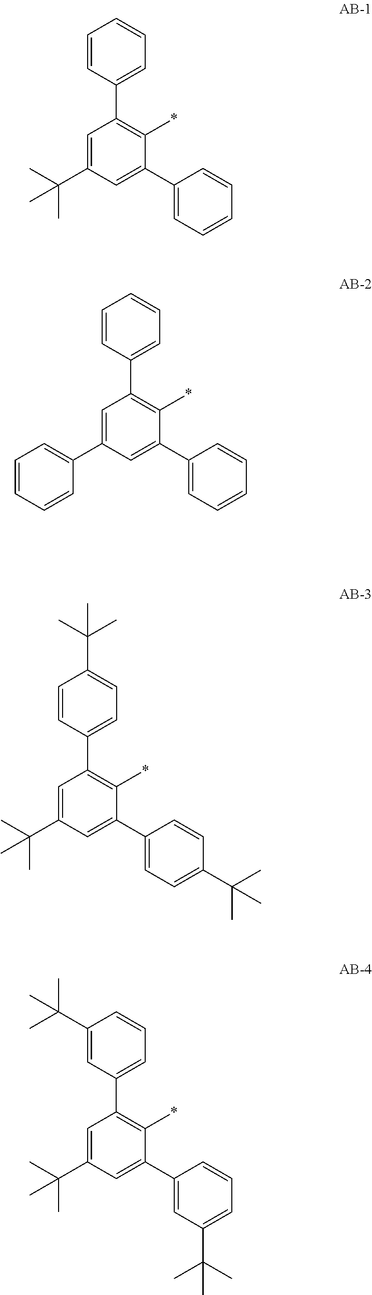

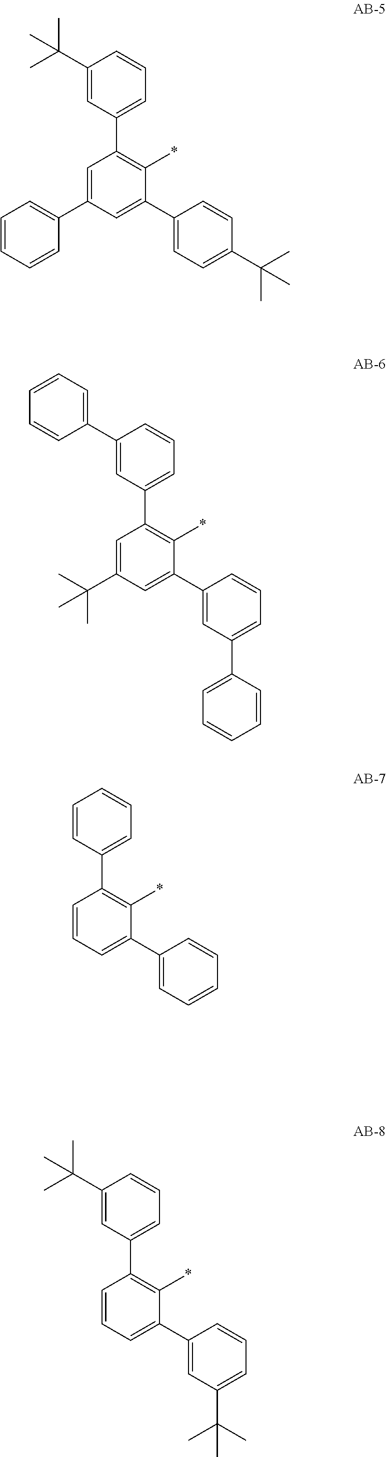

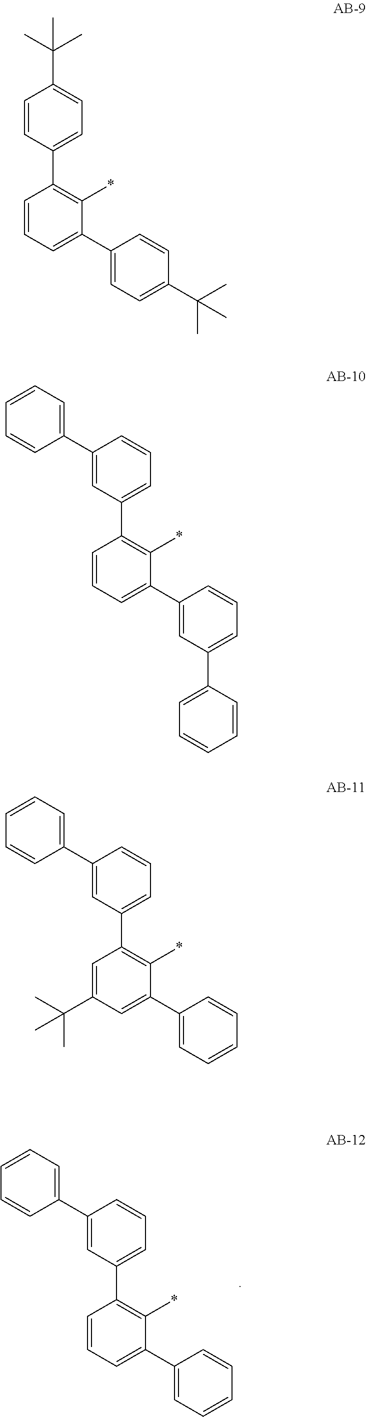 [SMILES: *c1c(-c2ccc(C(C)(C)C)cc2)cccc1-c1ccc(C(C)(C)C)cc1 ; *c1c(-c2cccc(-c3ccccc3)c2)cccc1-c1cccc(-c2ccccc2)c1 ; *c1c(-c2ccccc2)cc(C(C)(C)C)cc1-c1cccc(-c2ccccc2)c1 ; *c1c(-c2ccccc2)cccc1-c1cccc(-c2ccccc2)c1]

9. The light emitting element of claim 1, wherein in Formula 1, R₁ is a substituted or unsubstituted t-butyl group or a substituted or unsubstituted phenyl group.

10. The light emitting element of claim 1, wherein the first compound is any one selected from among compounds of Compound Group 1:

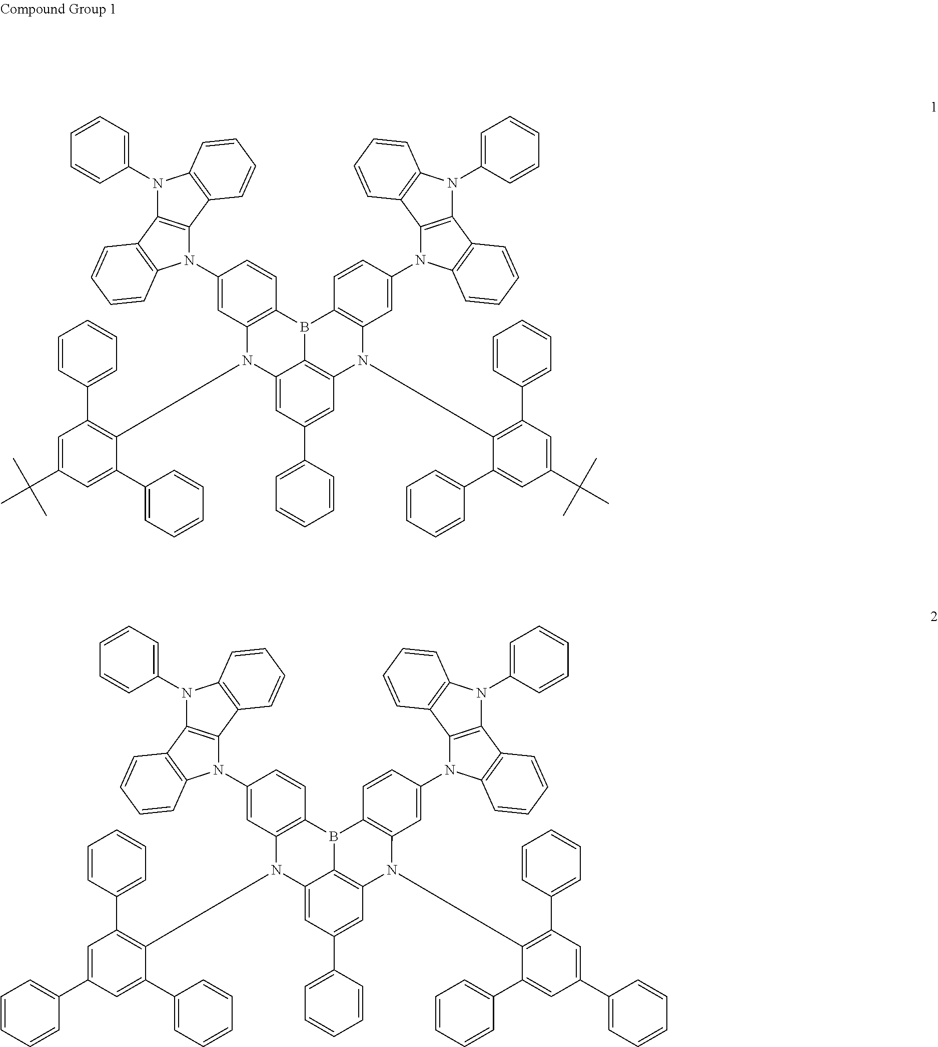 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(-c5ccccc5)cc2c43)c(-c2ccccc2)c1 ; c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cc(-c6ccccc6)cc5-c5ccccc5)c5cc(-c6ccccc6)cc3c54)c(-c3ccccc3)c2)cc1]

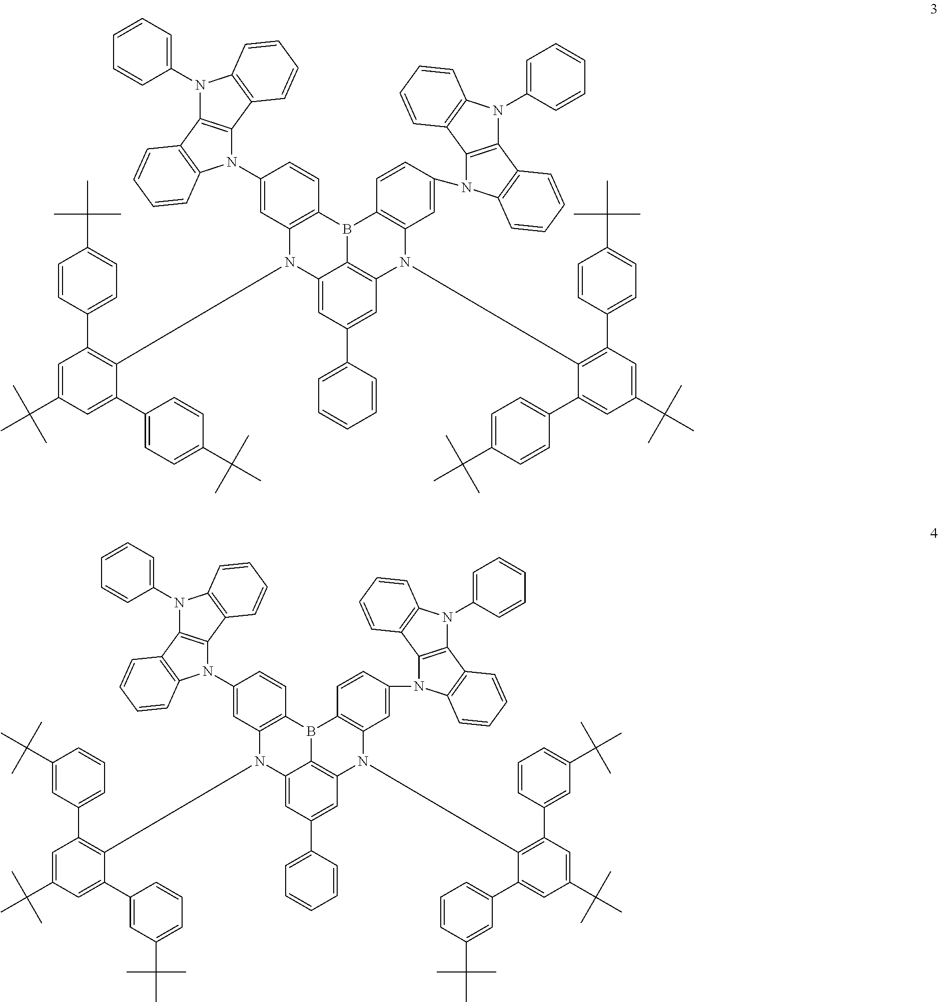

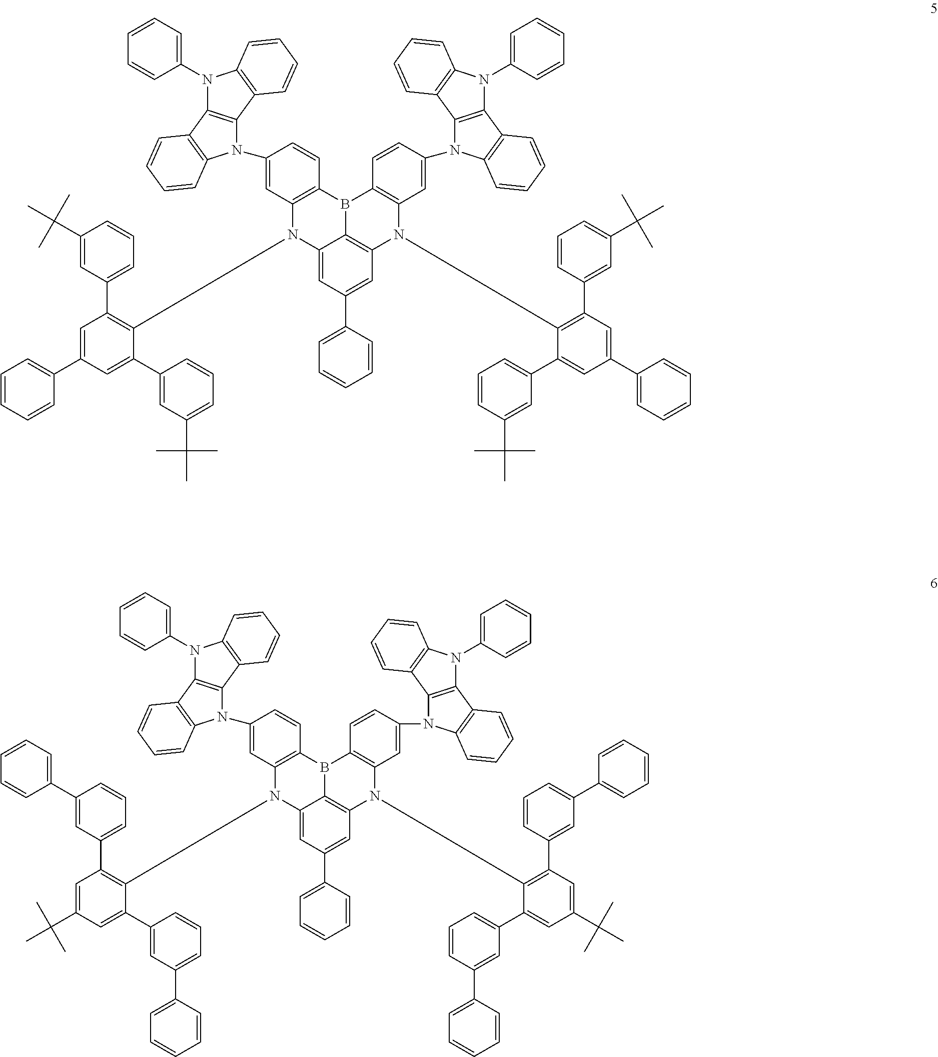 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(-c5ccccc5)cc2c43)c1 ; CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1]

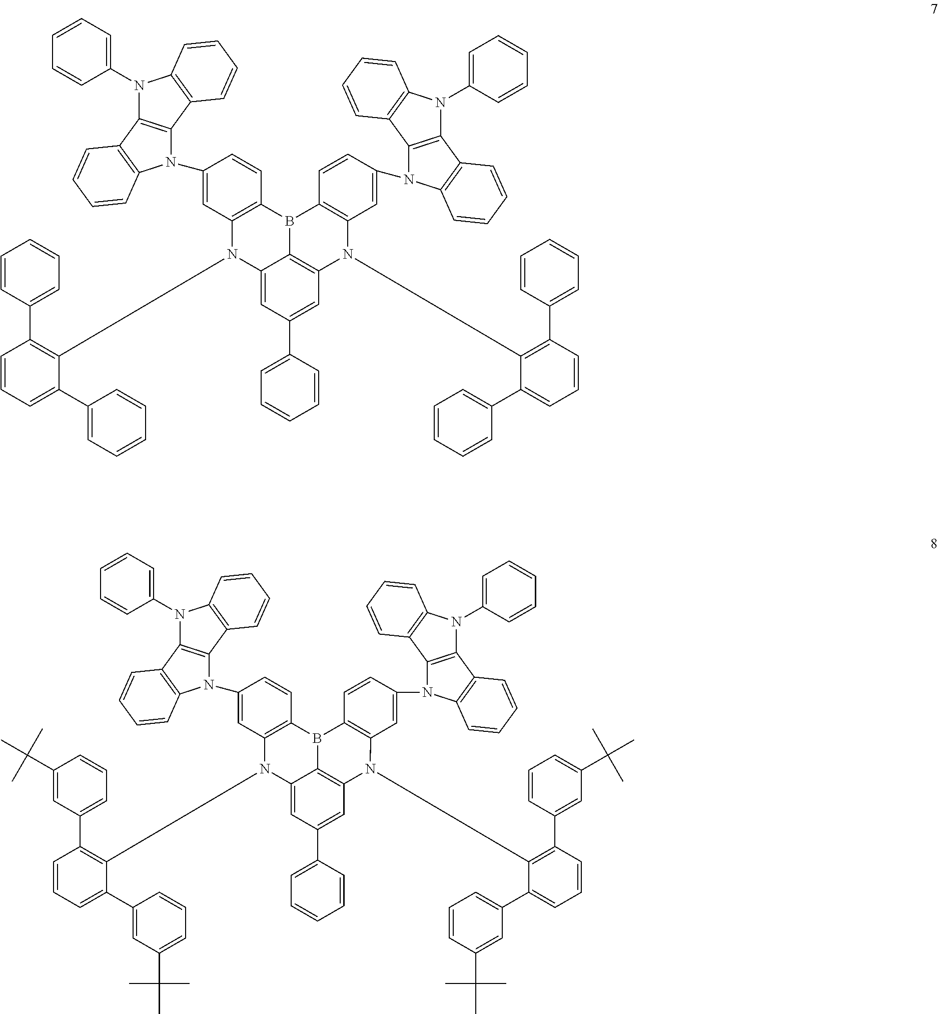 [SMILES: c1ccc(-c2cc3c4c(c2)N(c2c(-c5ccccc5)cccc2-c2ccccc2)c2cc(-n5c6ccccc6c6c5c5ccccc5n6-c5ccccc5)ccc2B4c2ccc(-n4c5ccccc5c5c4c4ccccc4n5-c4ccccc4)cc2N3c2c(-c3ccccc3)cccc2-c2ccccc2)cc1 ; CC(C)(C)c1cccc(-c2cccc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cccc4-c4cccc(C(C)(C)C)c4)c4cc(-c5ccccc5)cc2c43)c1]

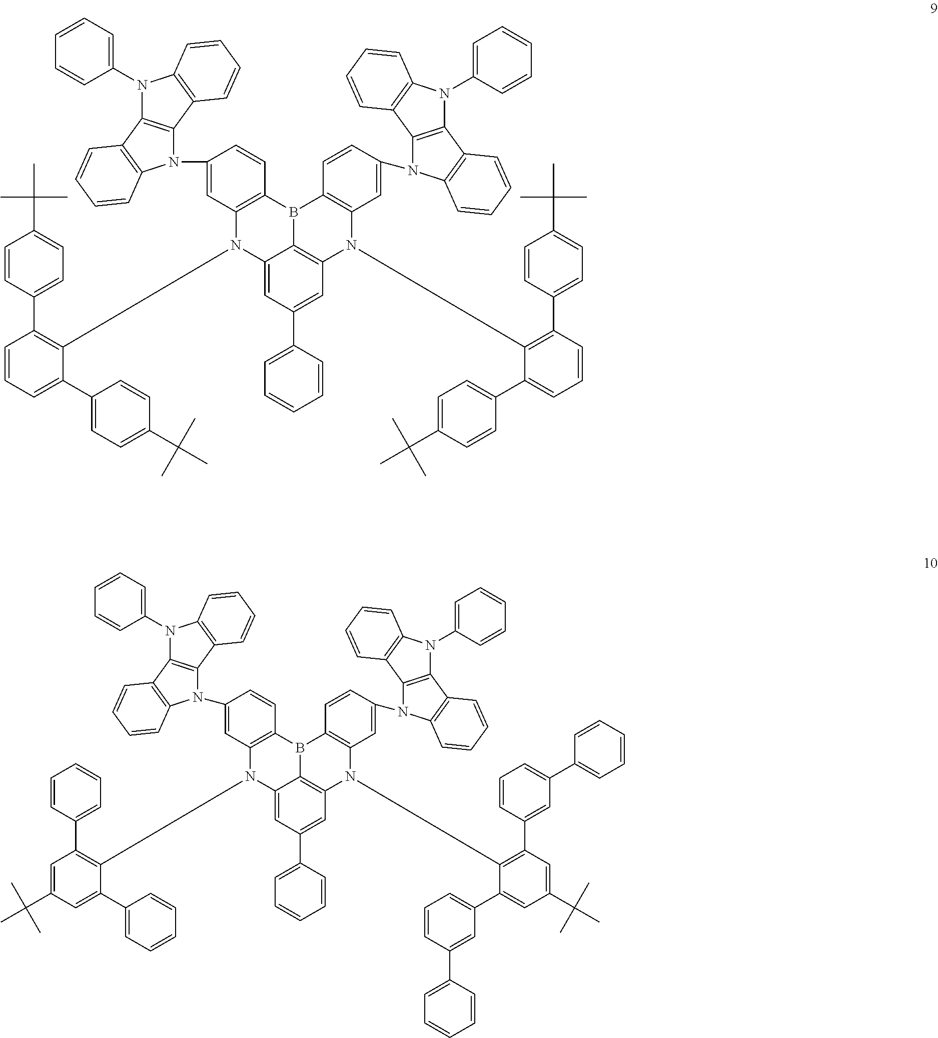

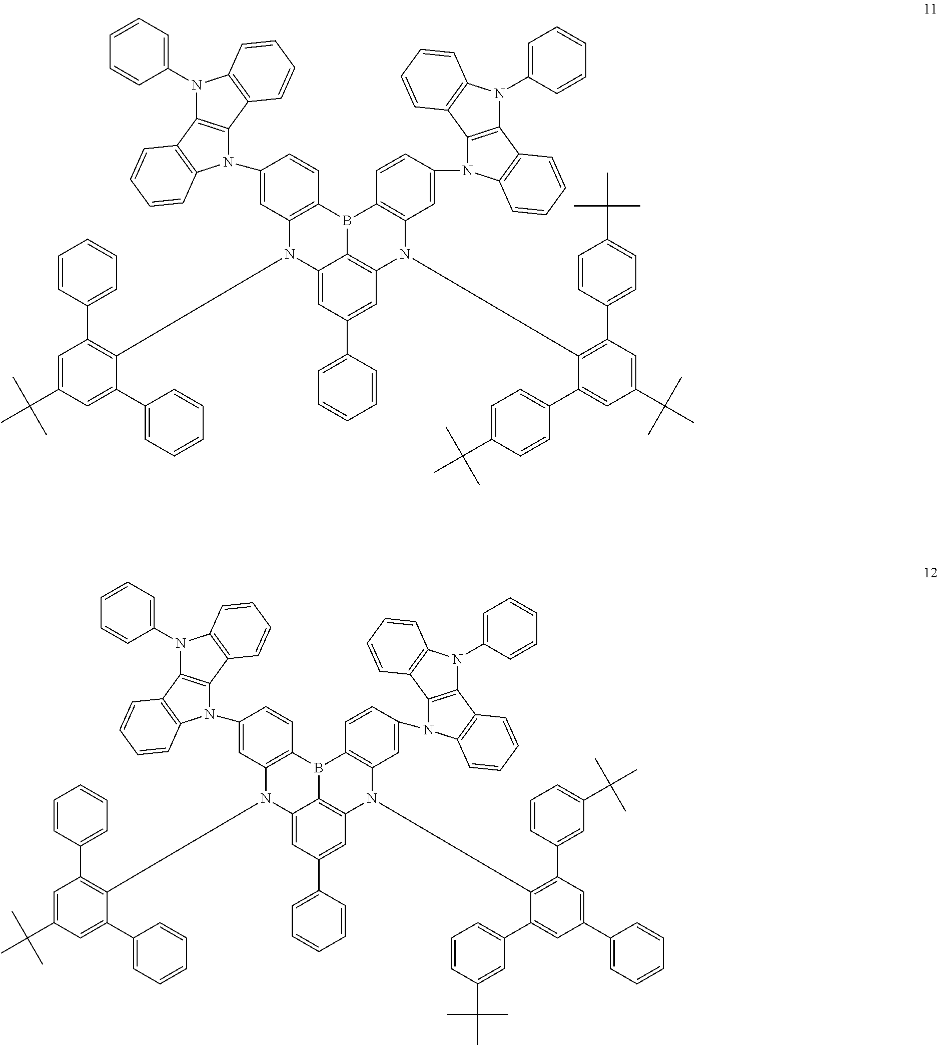

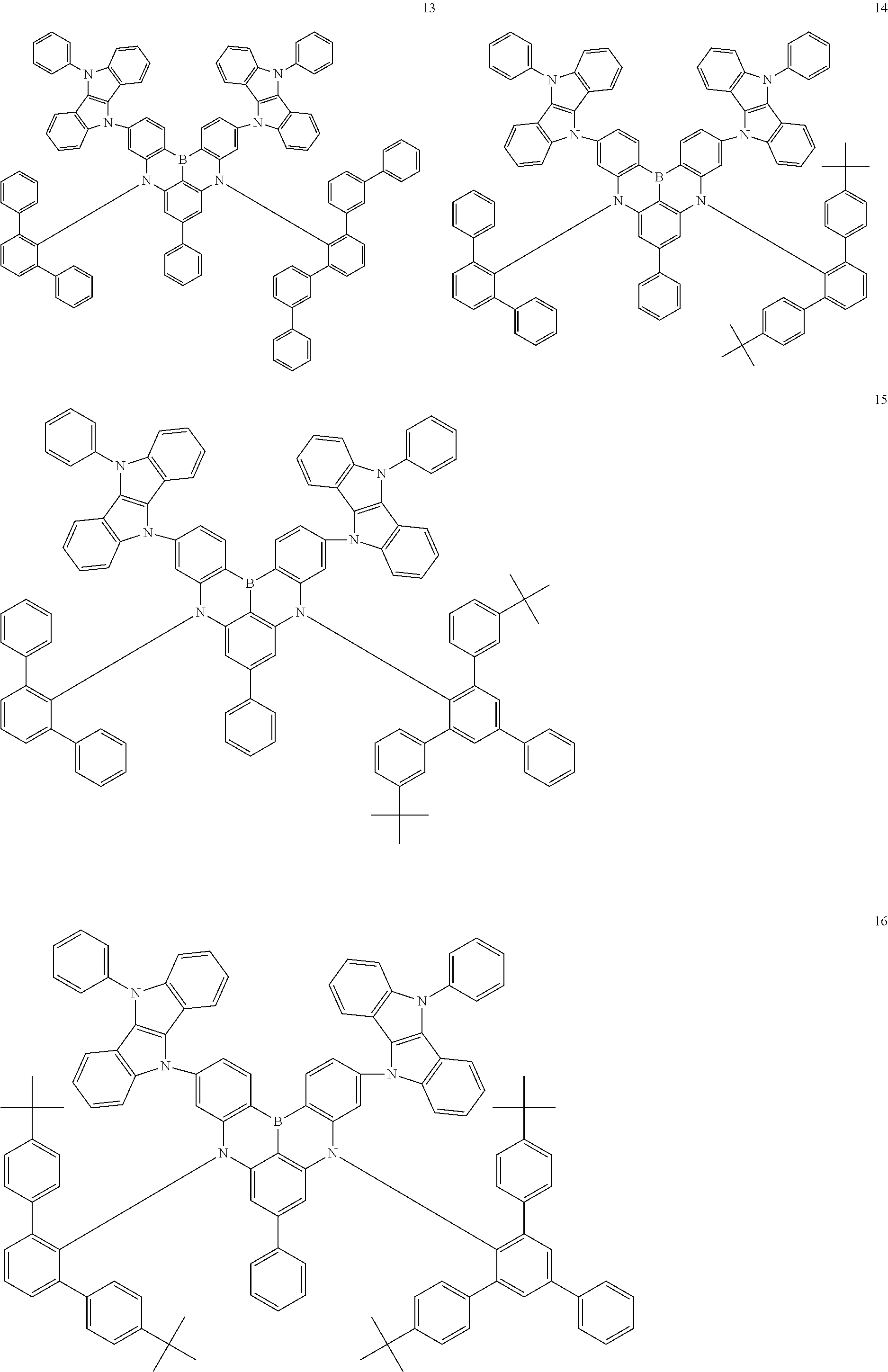

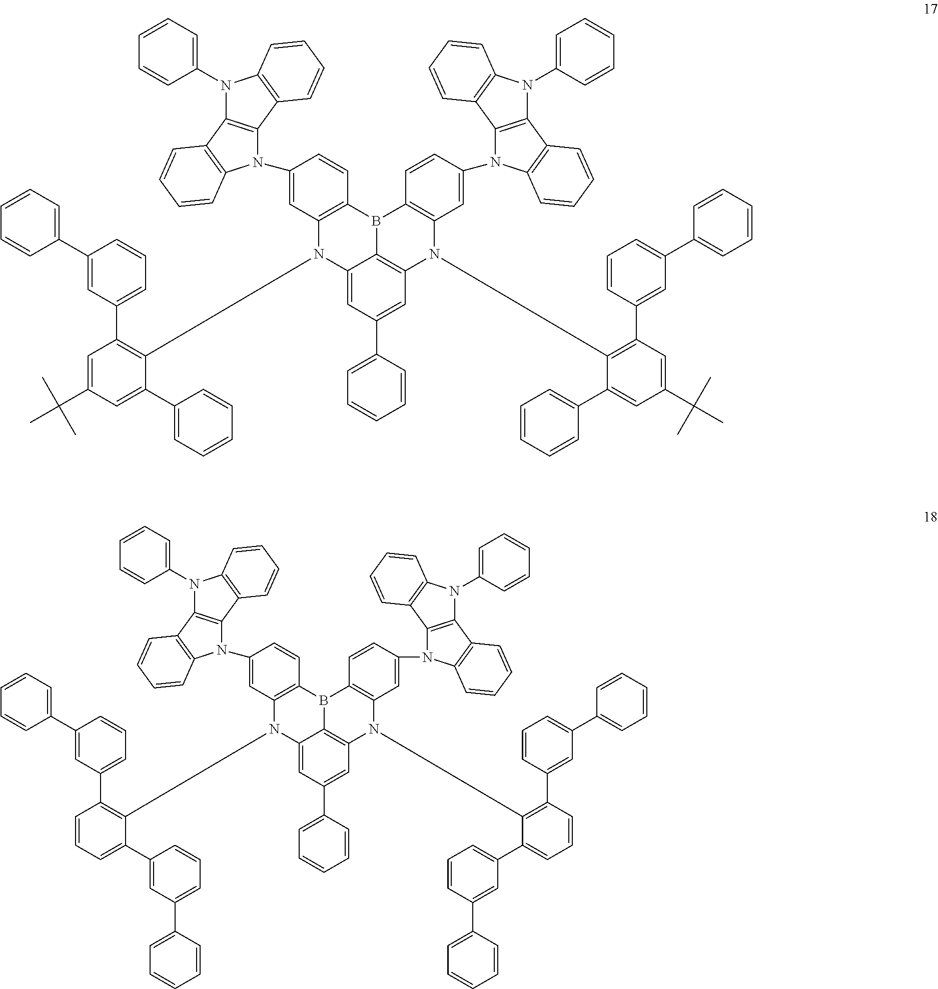 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(-c5ccccc5)cc2c43)c(-c2cccc(-c3ccccc3)c2)c1 ; c1ccc(-c2cccc(-c3cccc(-c4cccc(-c5ccccc5)c4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6cccc(-c7ccccc7)c6)cccc5-c5cccc(-c6ccccc6)c5)c5cc(-c6ccccc6)cc3c54)c2)cc1]

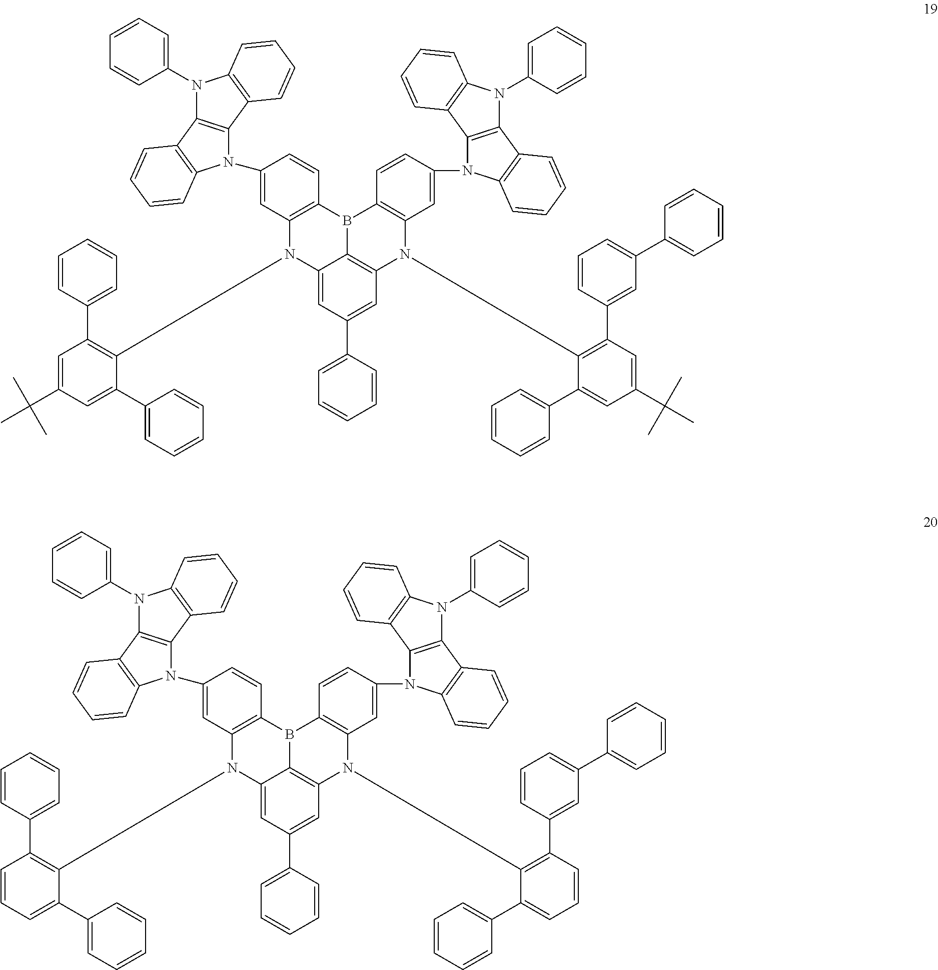 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(-c5ccccc5)cc2c43)c(-c2ccccc2)c1 ; c1ccc(-c2cccc(-c3cccc(-c4ccccc4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c2)cc1]

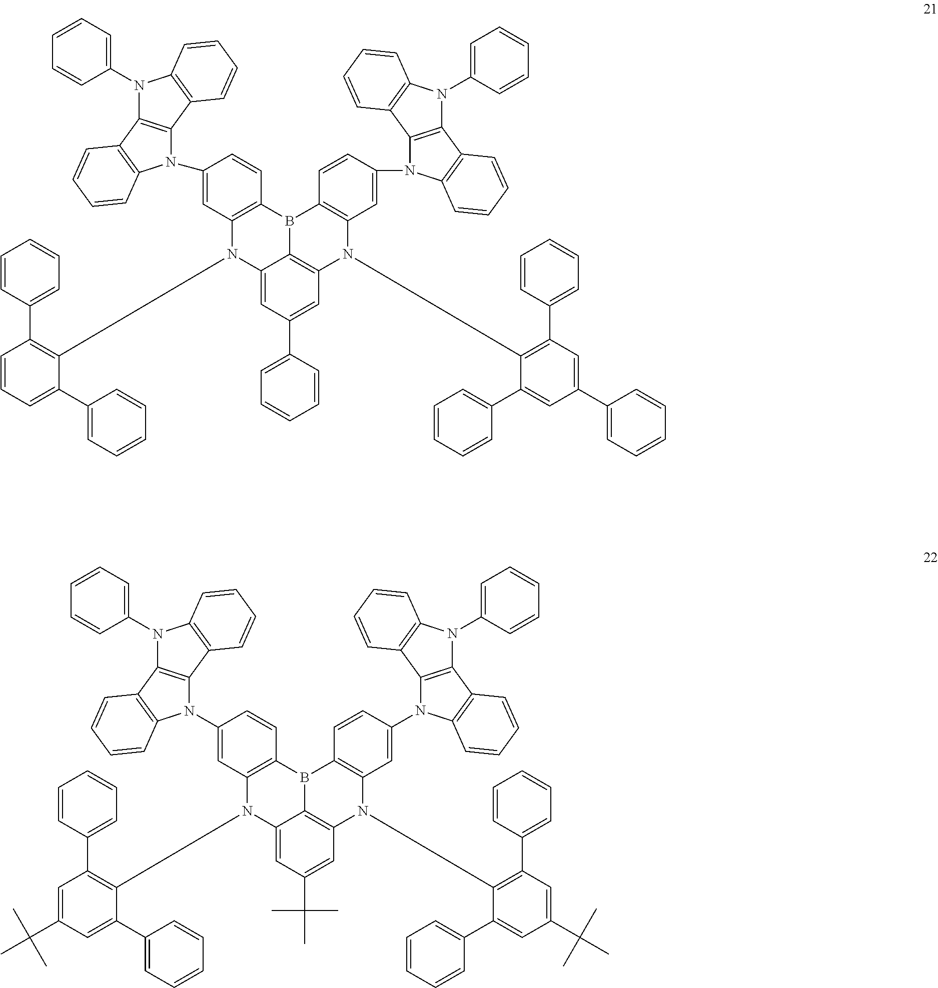 [SMILES: c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c(-c3ccccc3)c2)cc1 ; CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2ccccc2)c1]

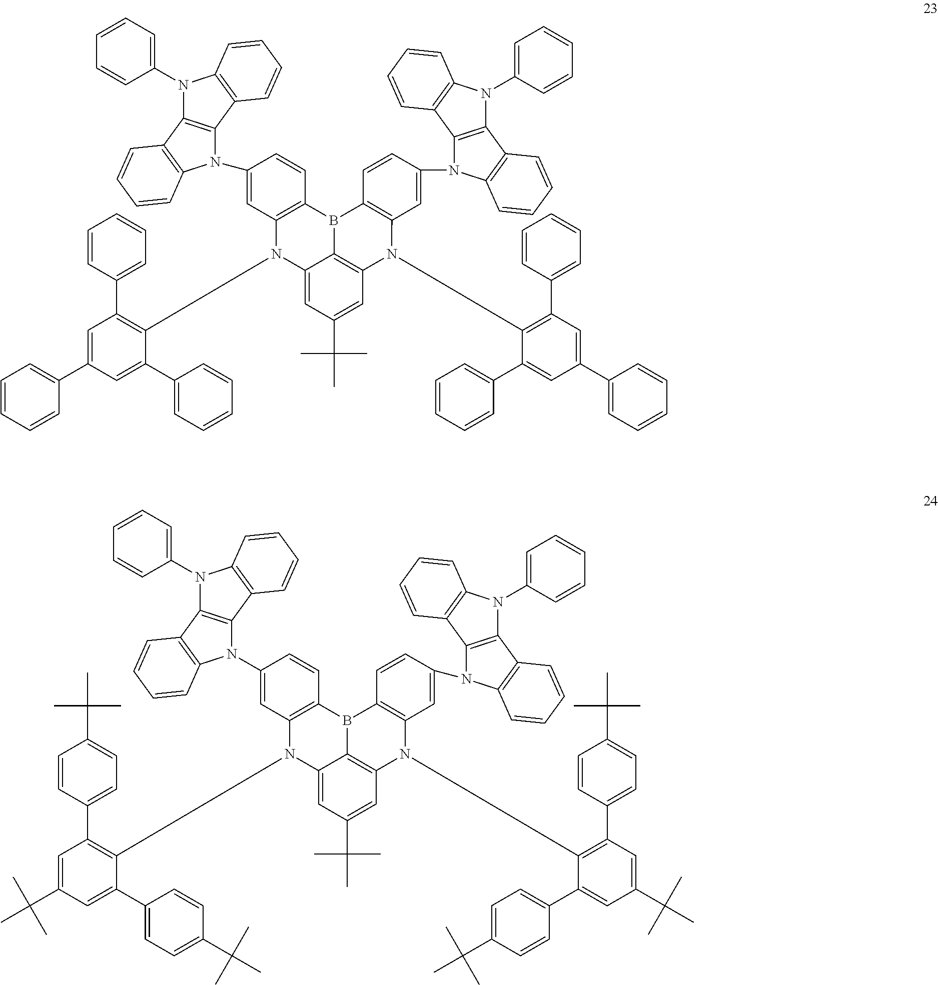 [SMILES: CC(C)(C)c1cc2c3c(c1)N(c1c(-c4ccccc4)cc(-c4ccccc4)cc1-c1ccccc1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

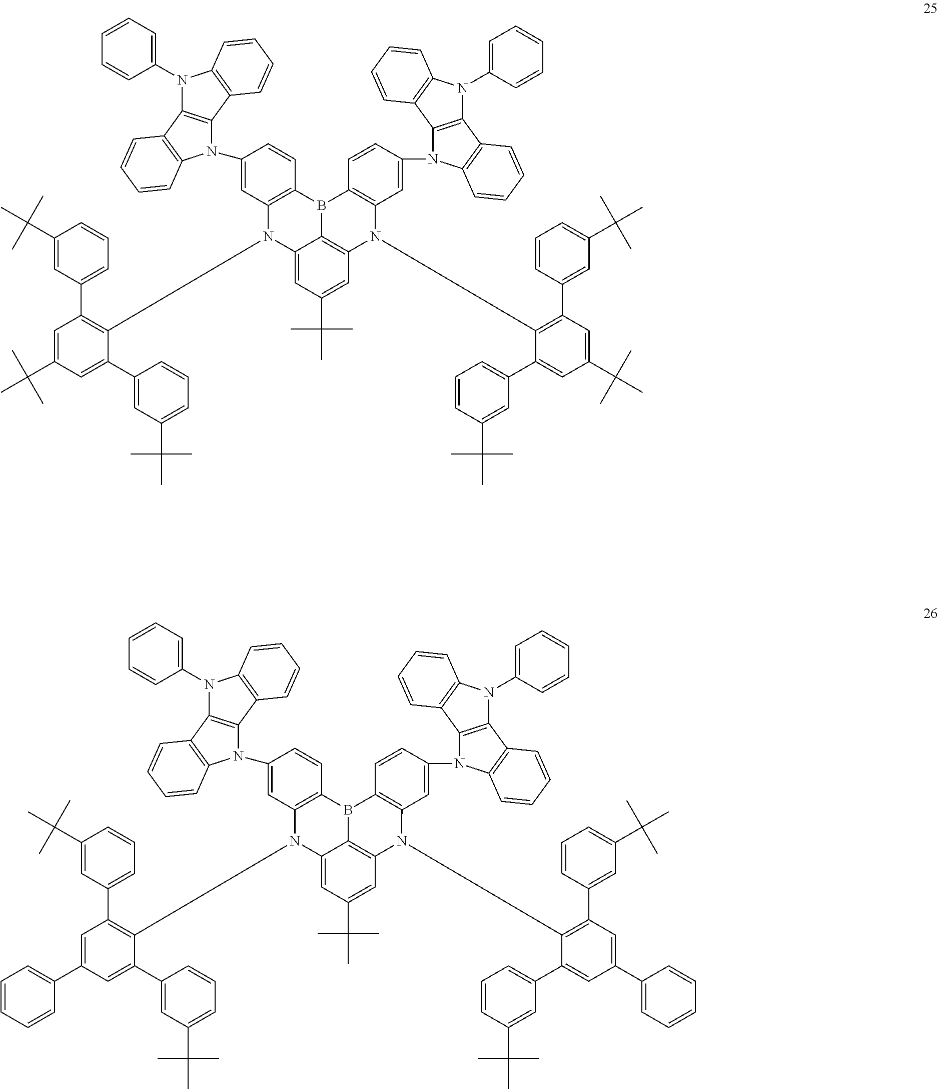 [SMILES: CC(C)(C)c1cccc(-c2cc(C(C)(C)C)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1]

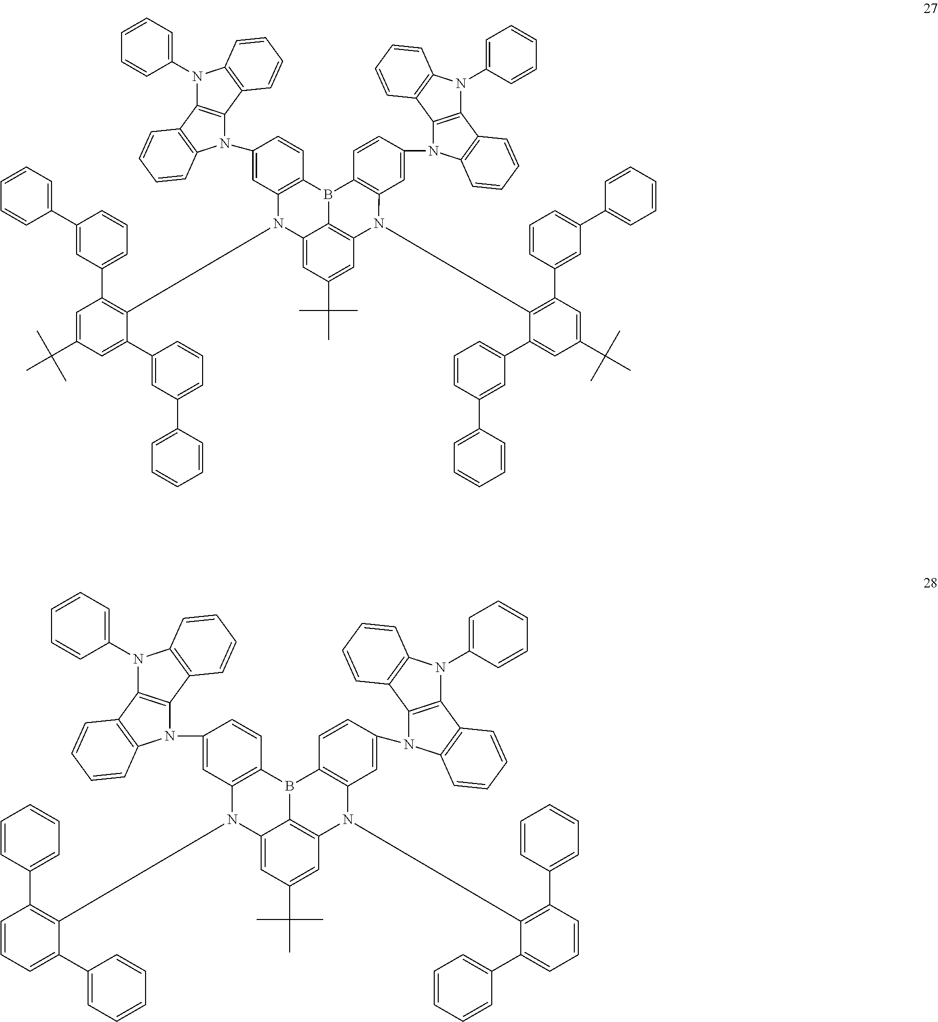 [SMILES: CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cccc1-c1ccccc1]

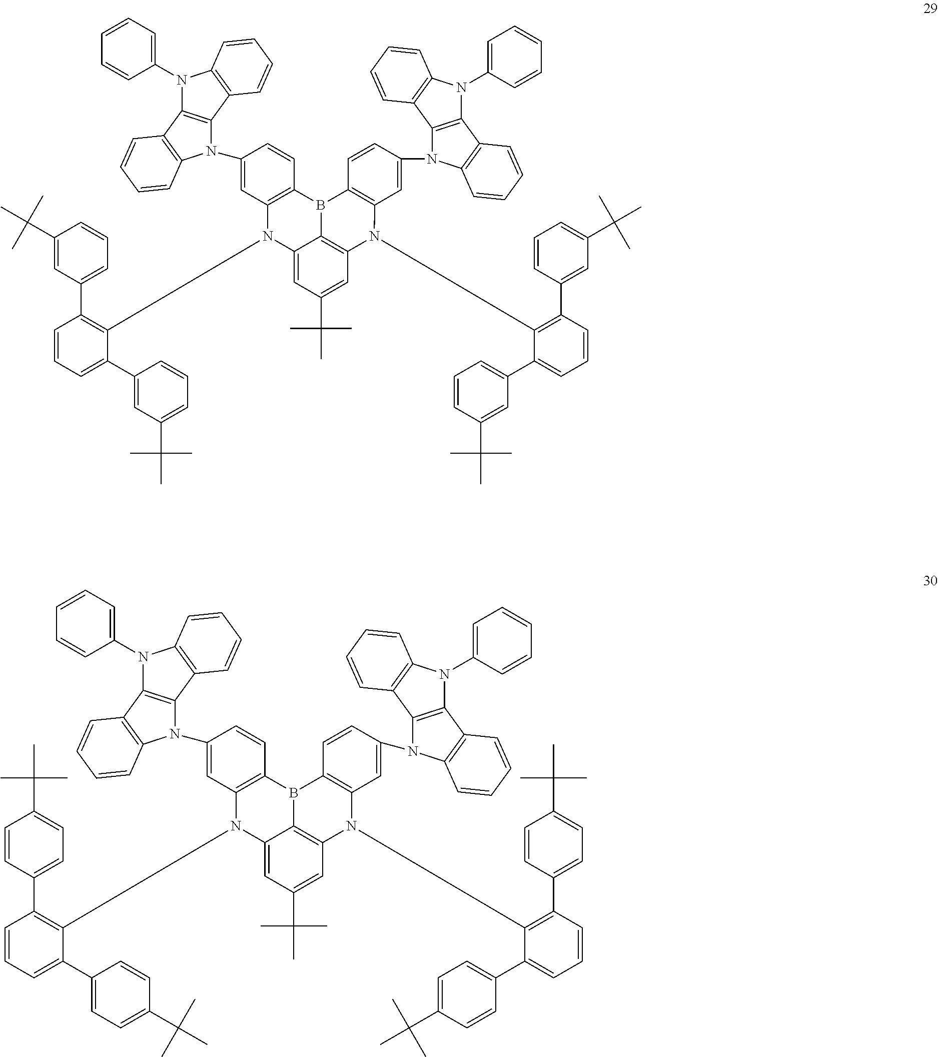

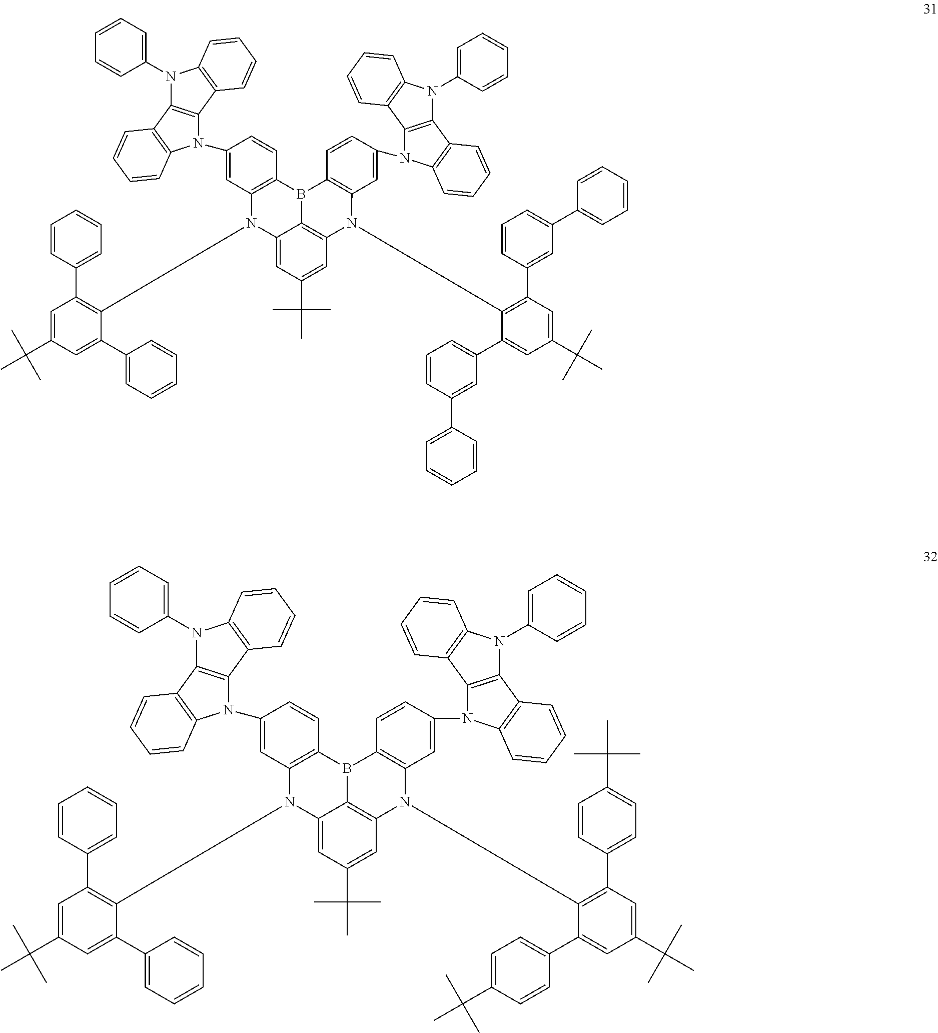 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2ccccc2)c1 ; CC(C)(C)c1ccc(-c2cc(C(C)(C)C)cc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)cc1]

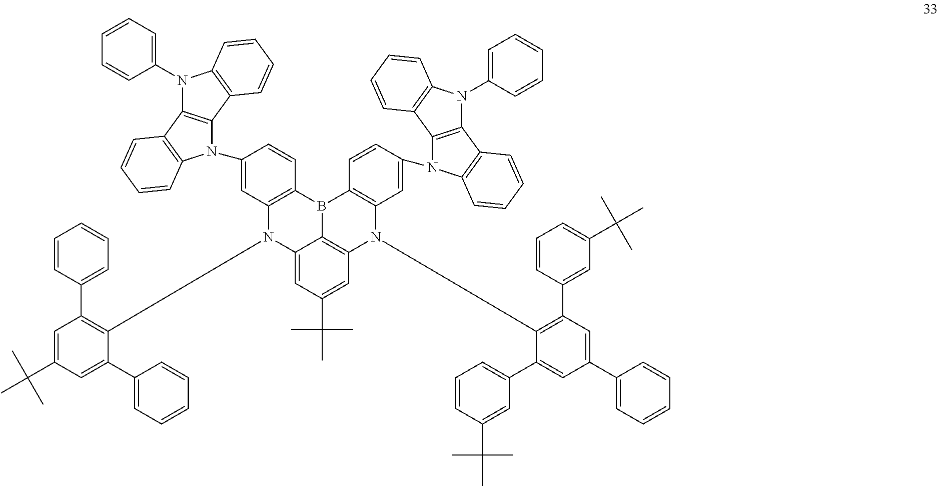 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c1]

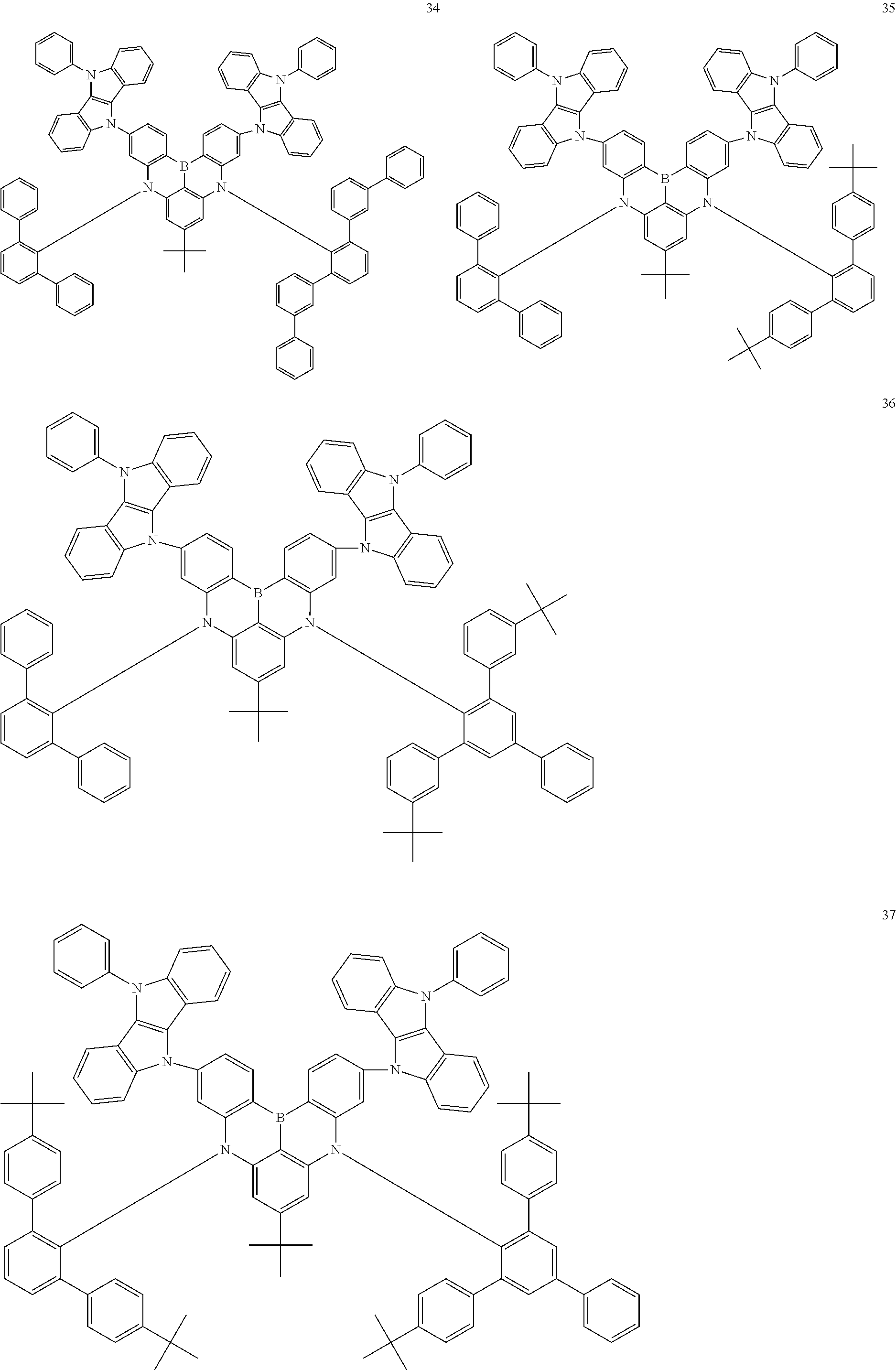

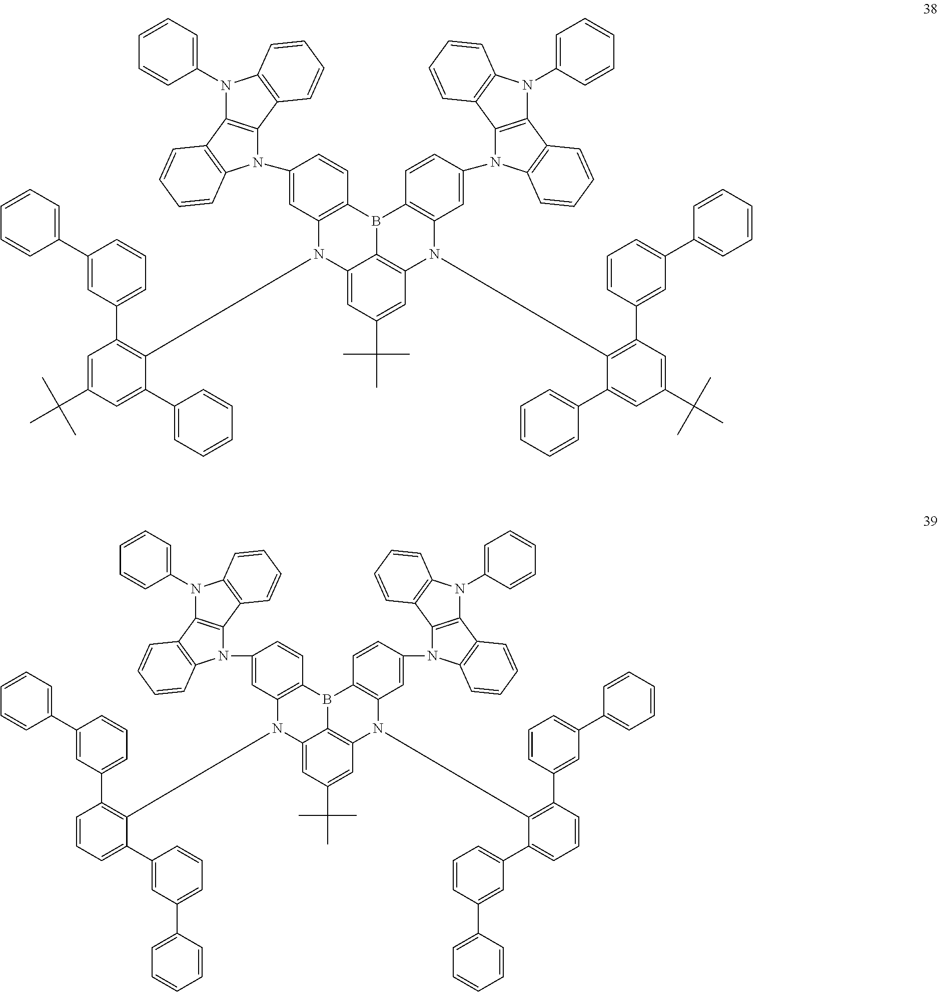 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2cccc(-c3ccccc3)c2)cccc1-c1cccc(-c2ccccc2)c1]

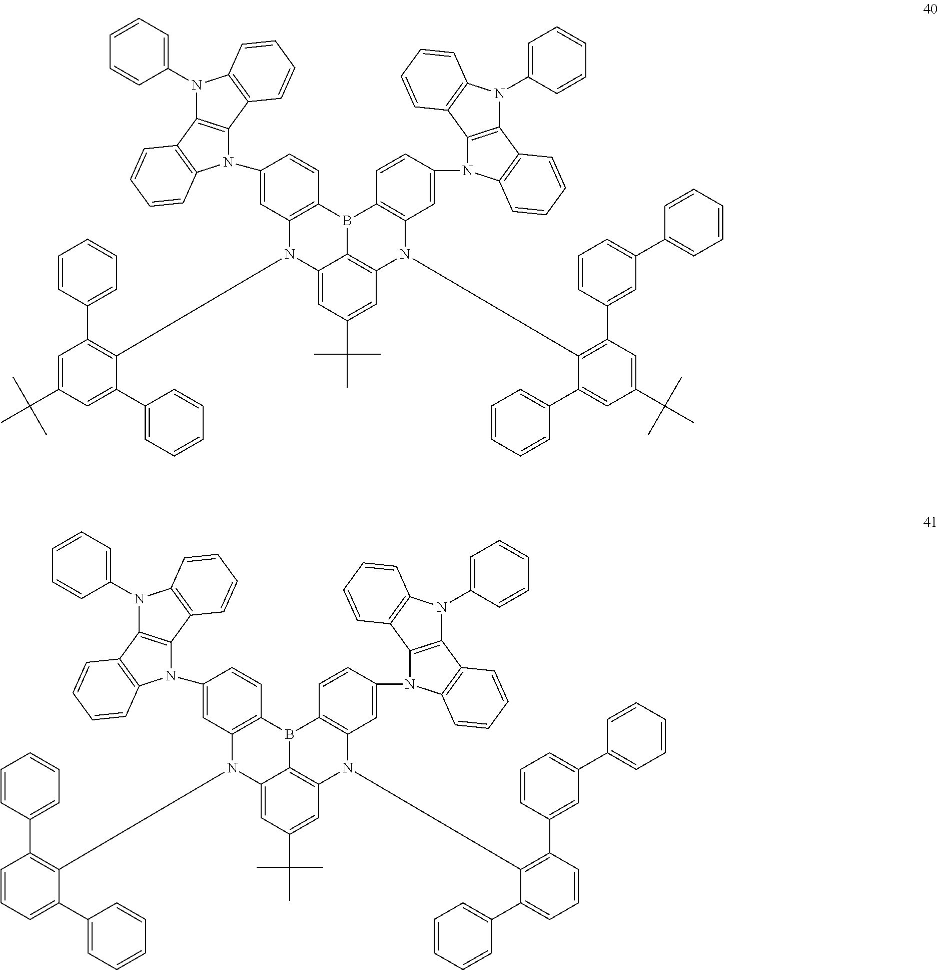 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2ccccc2)c1 ; CC(C)(C)c1cc2c3c(c1)N(c1c(-c4ccccc4)cccc1-c1cccc(-c4ccccc4)c1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cccc1-c1ccccc1]

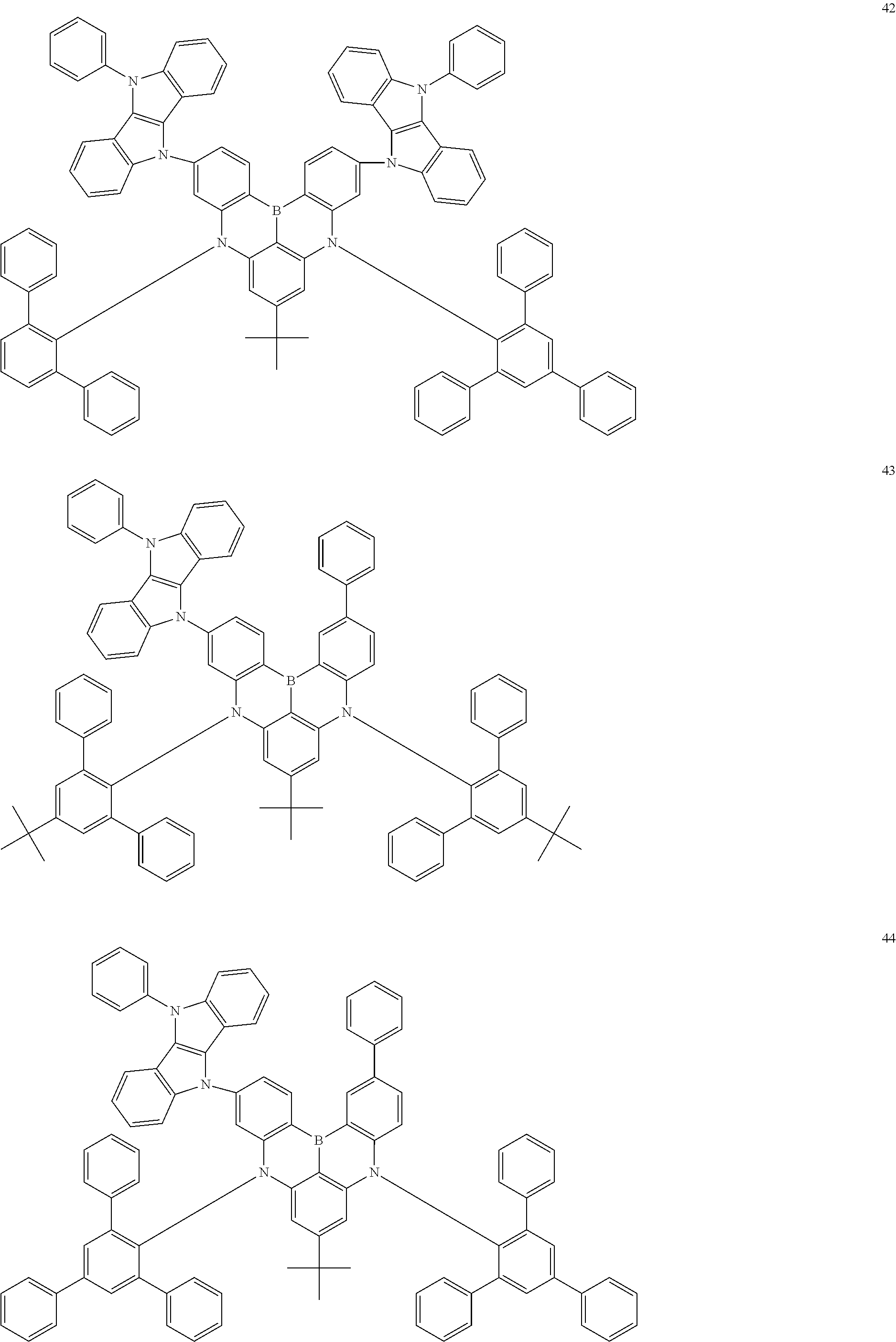

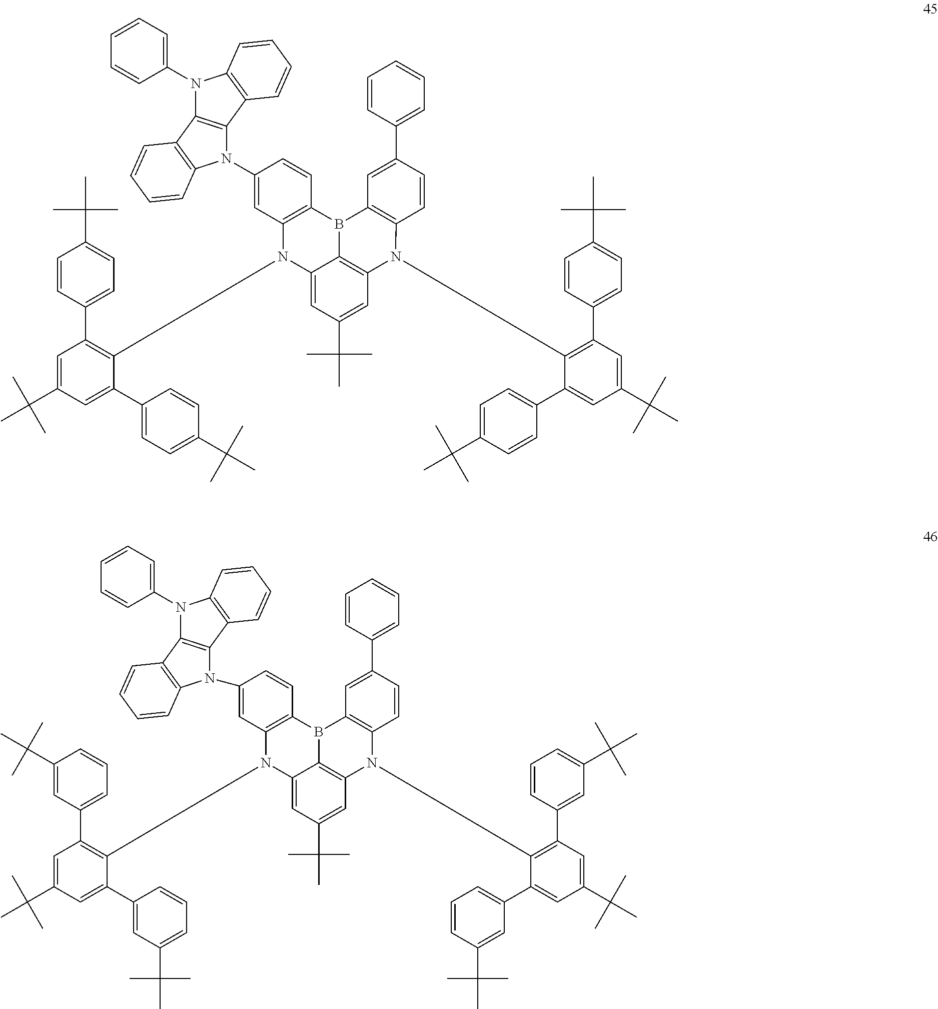

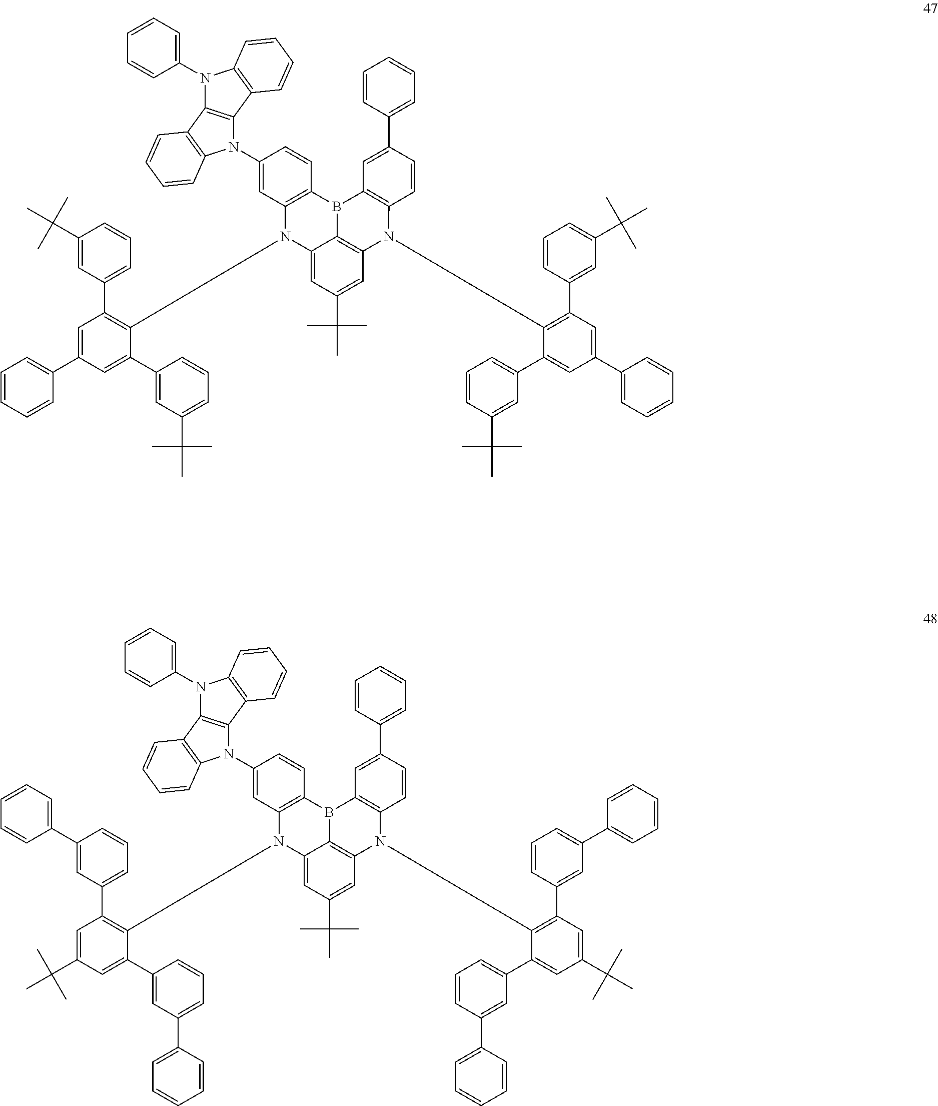 [SMILES: CC(C)(C)c1cccc(-c2cc(-c3ccccc3)cc(-c3cccc(C(C)(C)C)c3)c2N2c3ccc(-c4ccccc4)cc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3ccc(-c4ccccc4)cc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

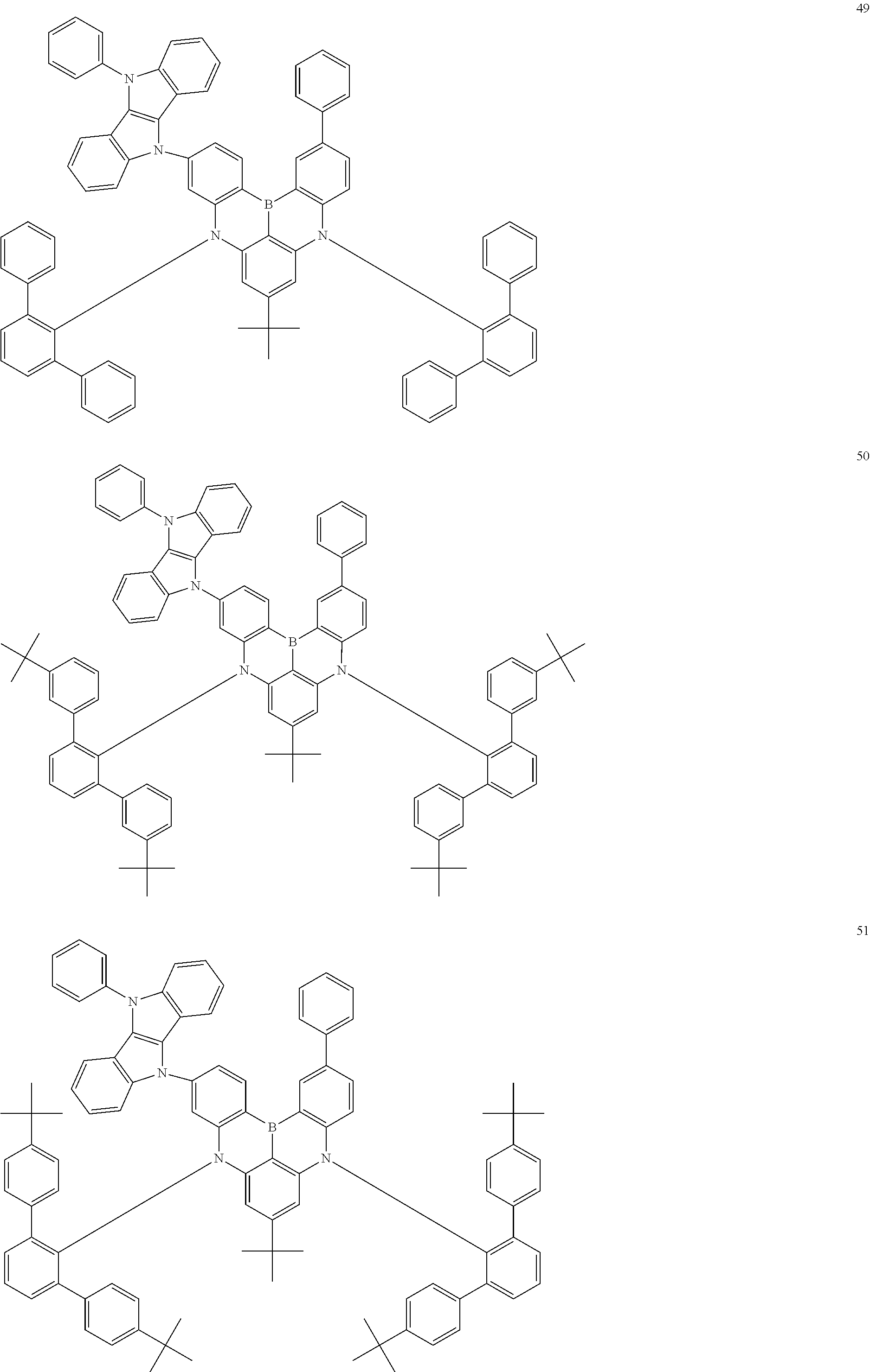

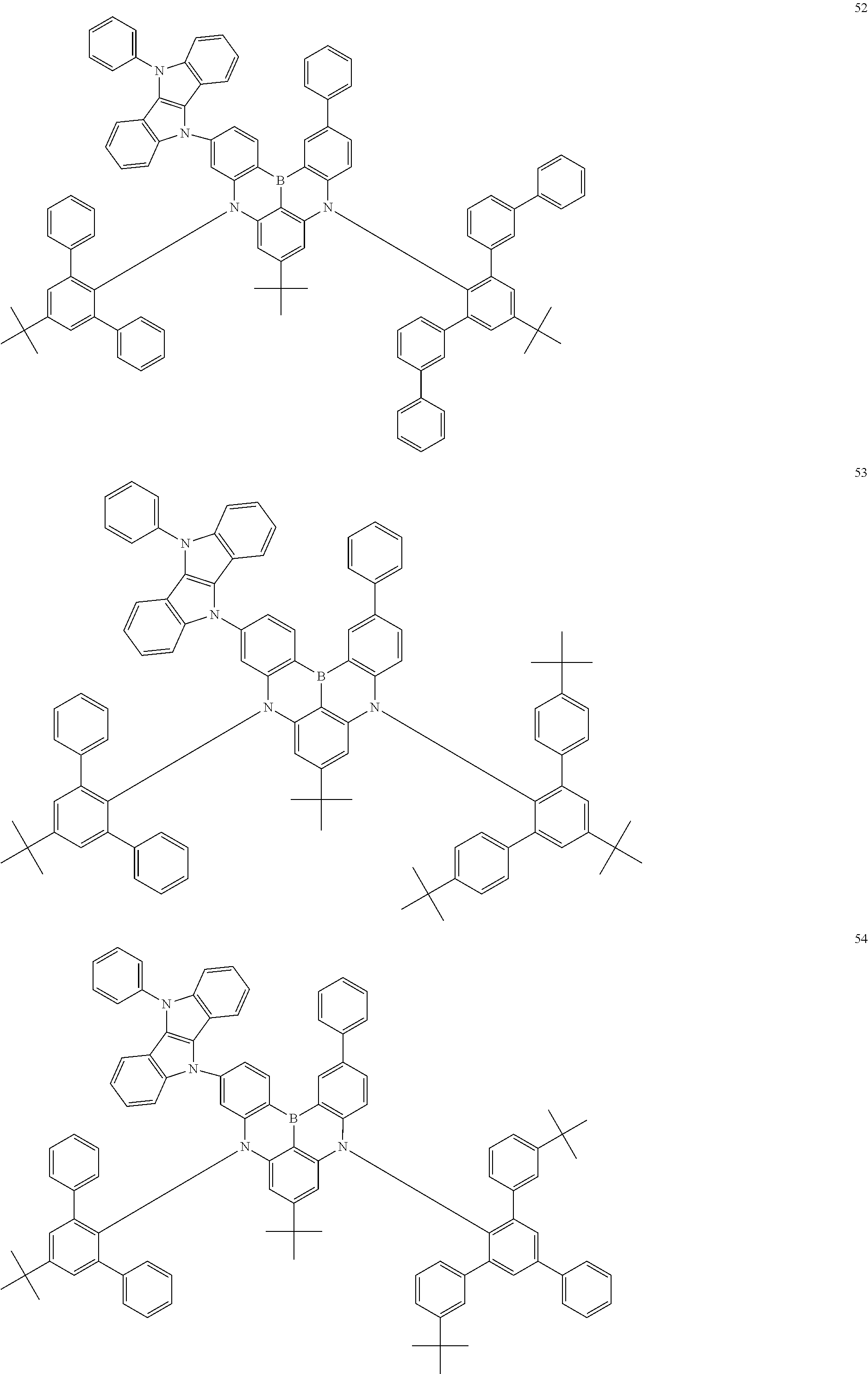

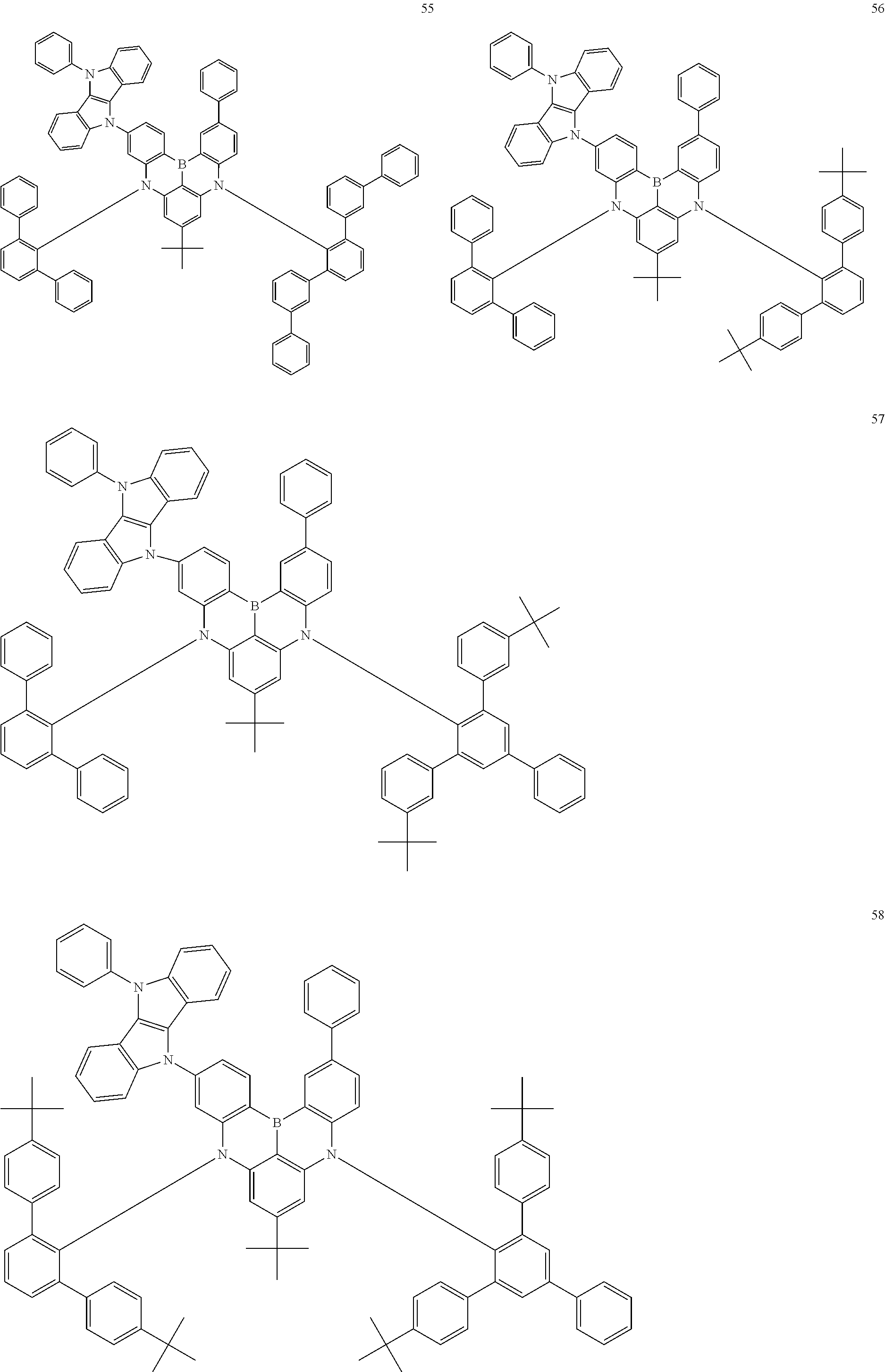

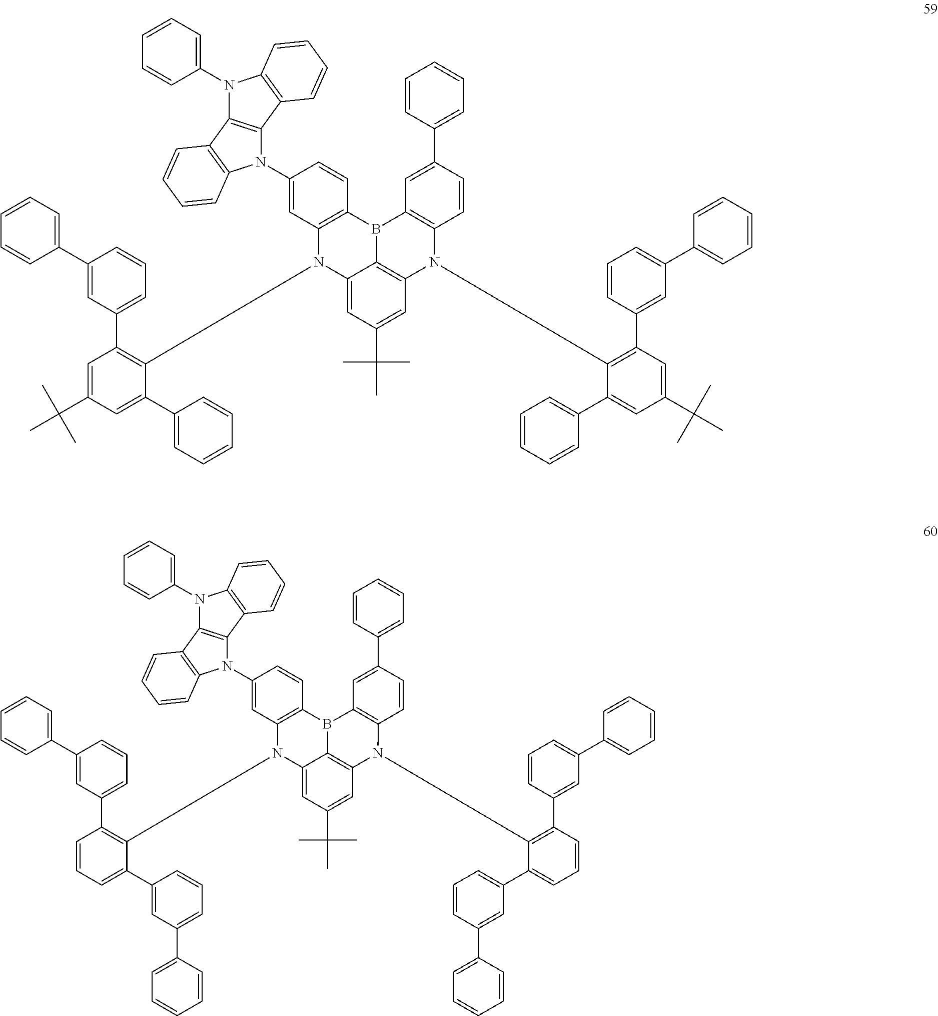 [SMILES: CC(C)(C)c1cc(-c2ccccc2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1cc(-c3ccccc3)ccc1N2c1c(-c2cccc(-c3ccccc3)c2)cccc1-c1cccc(-c2ccccc2)c1]

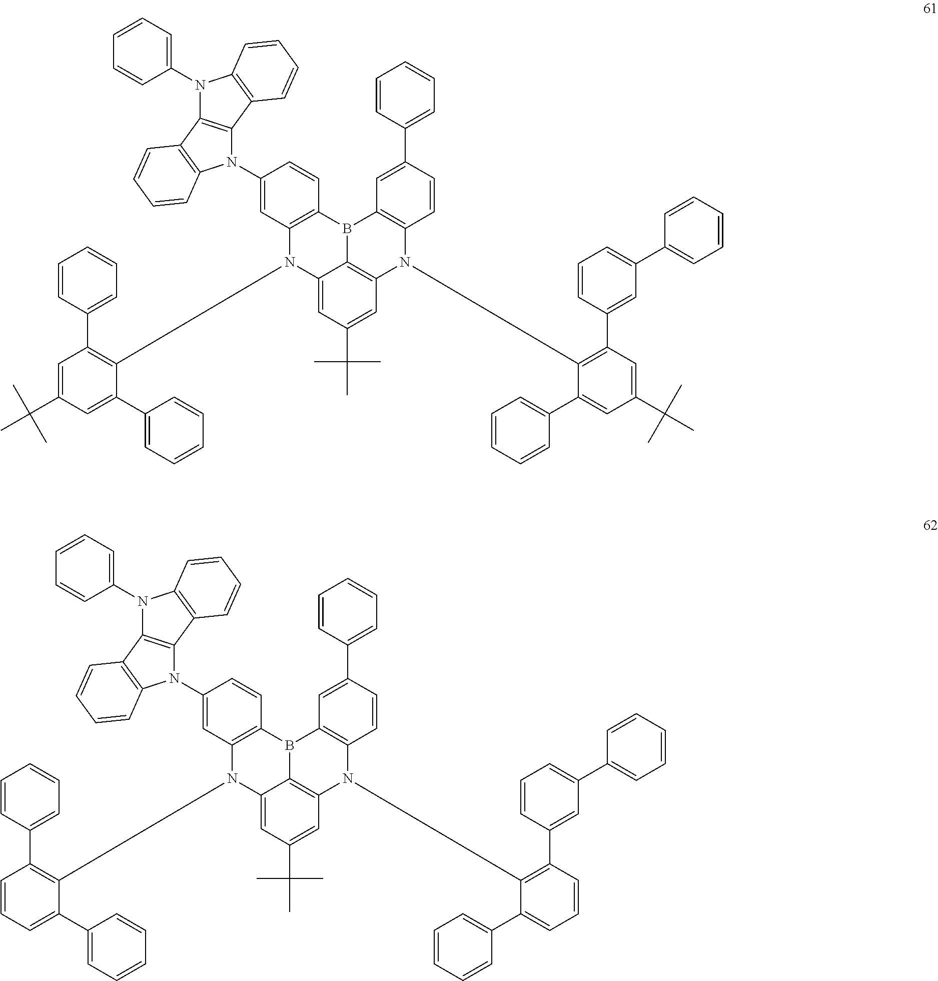 [SMILES: CC(C)(C)c1cc(-c2ccccc2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1cc(-c3ccccc3)ccc1N2c1c(-c2ccccc2)cccc1-c1cccc(-c2ccccc2)c1]

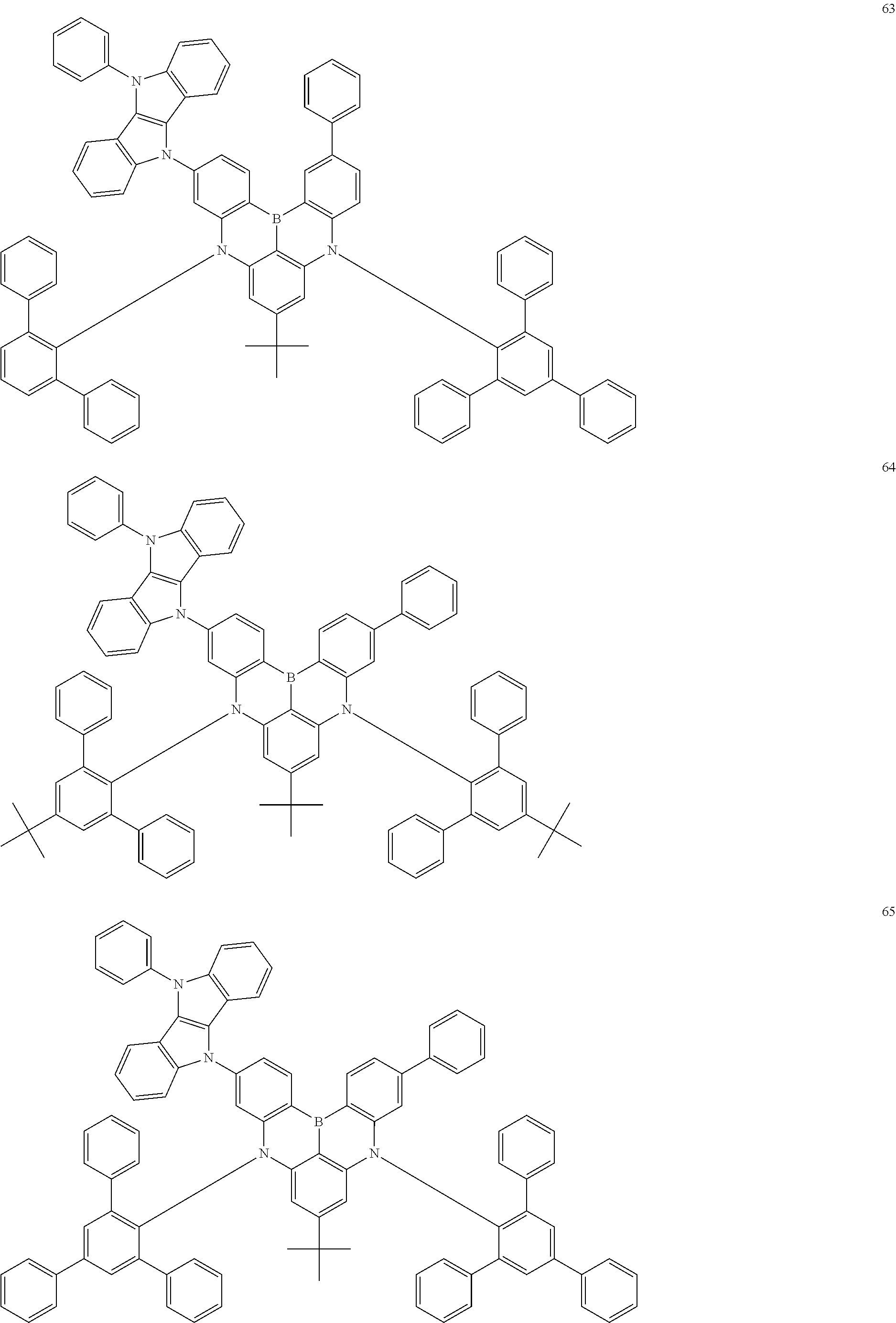

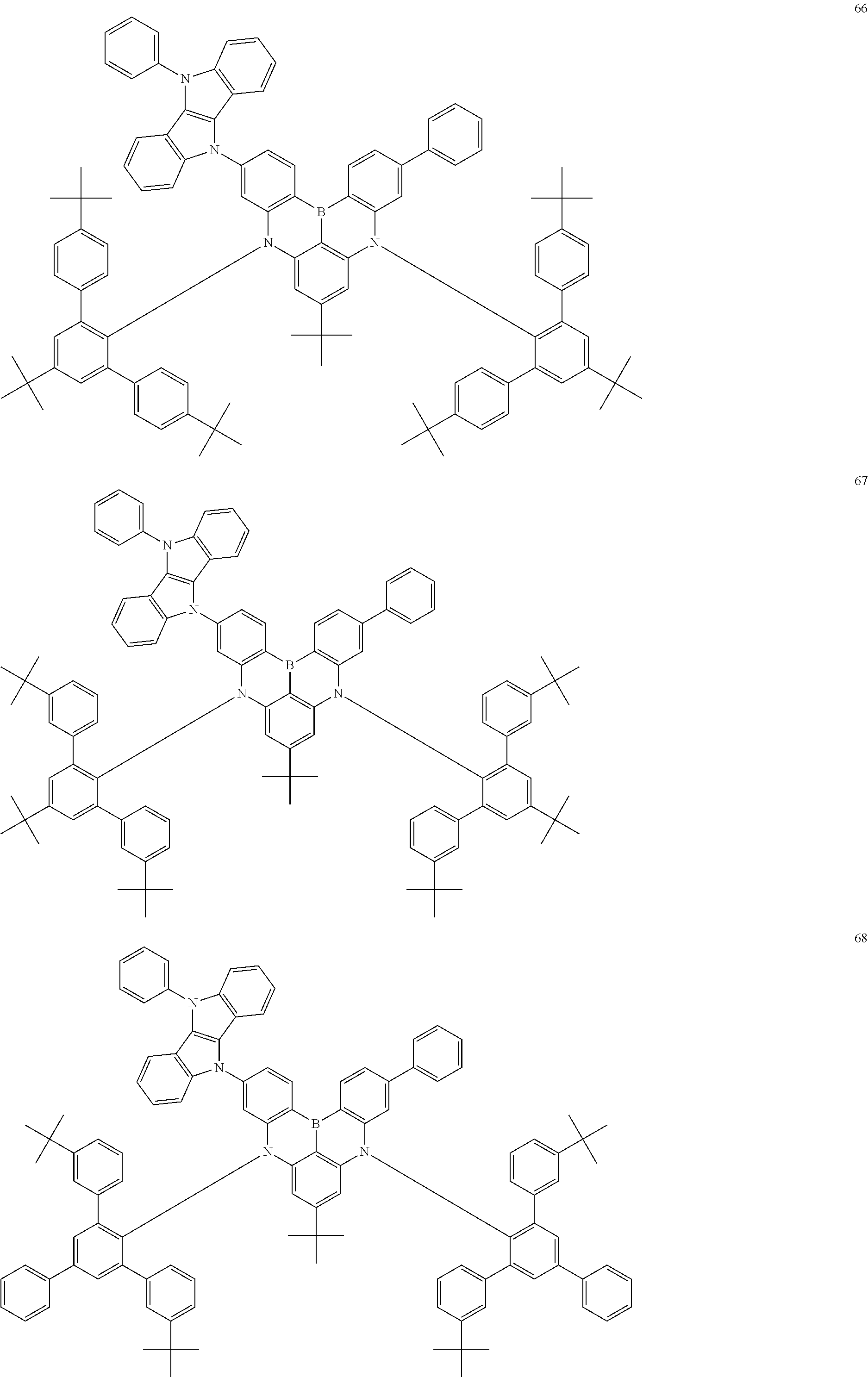

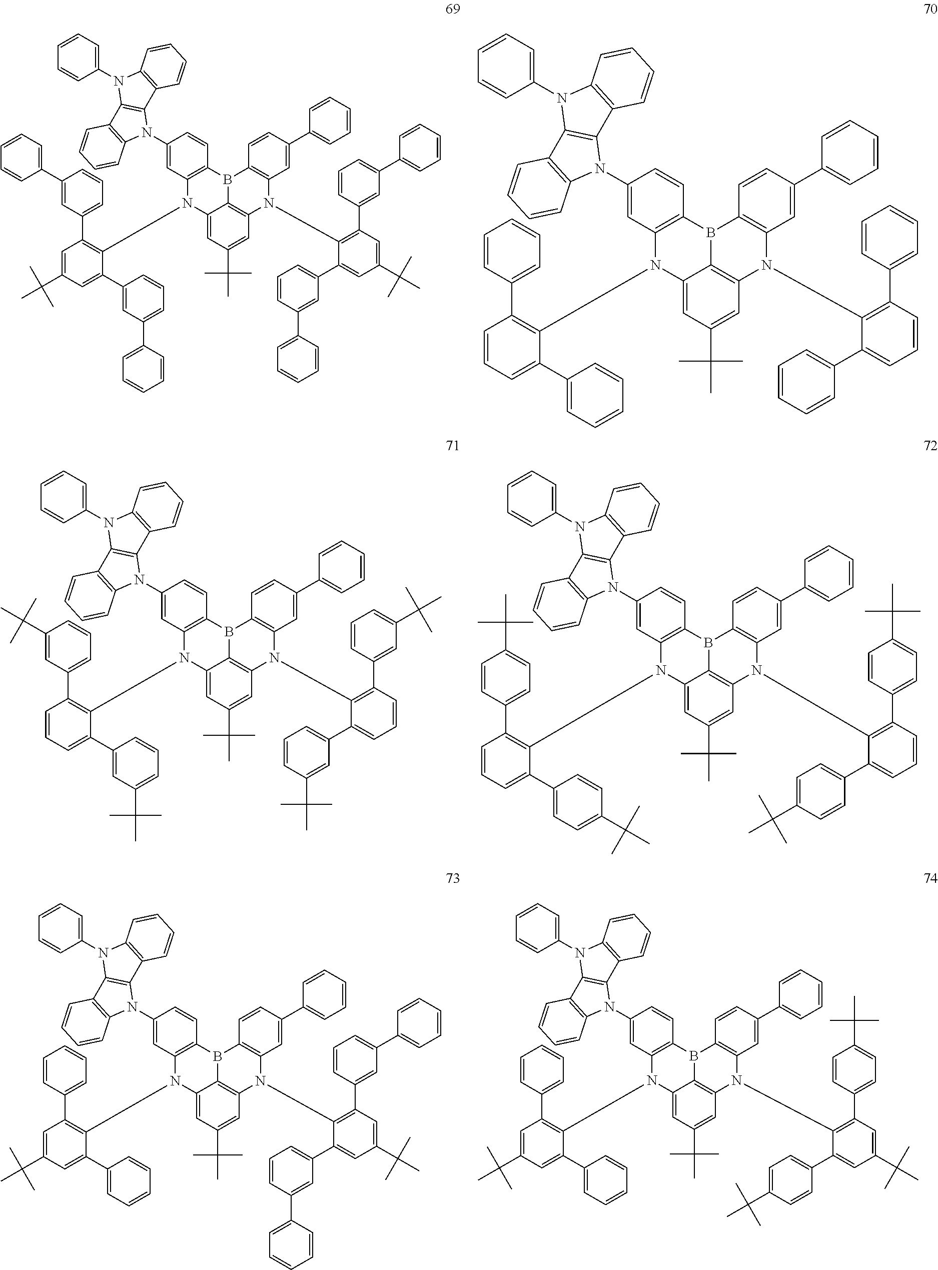

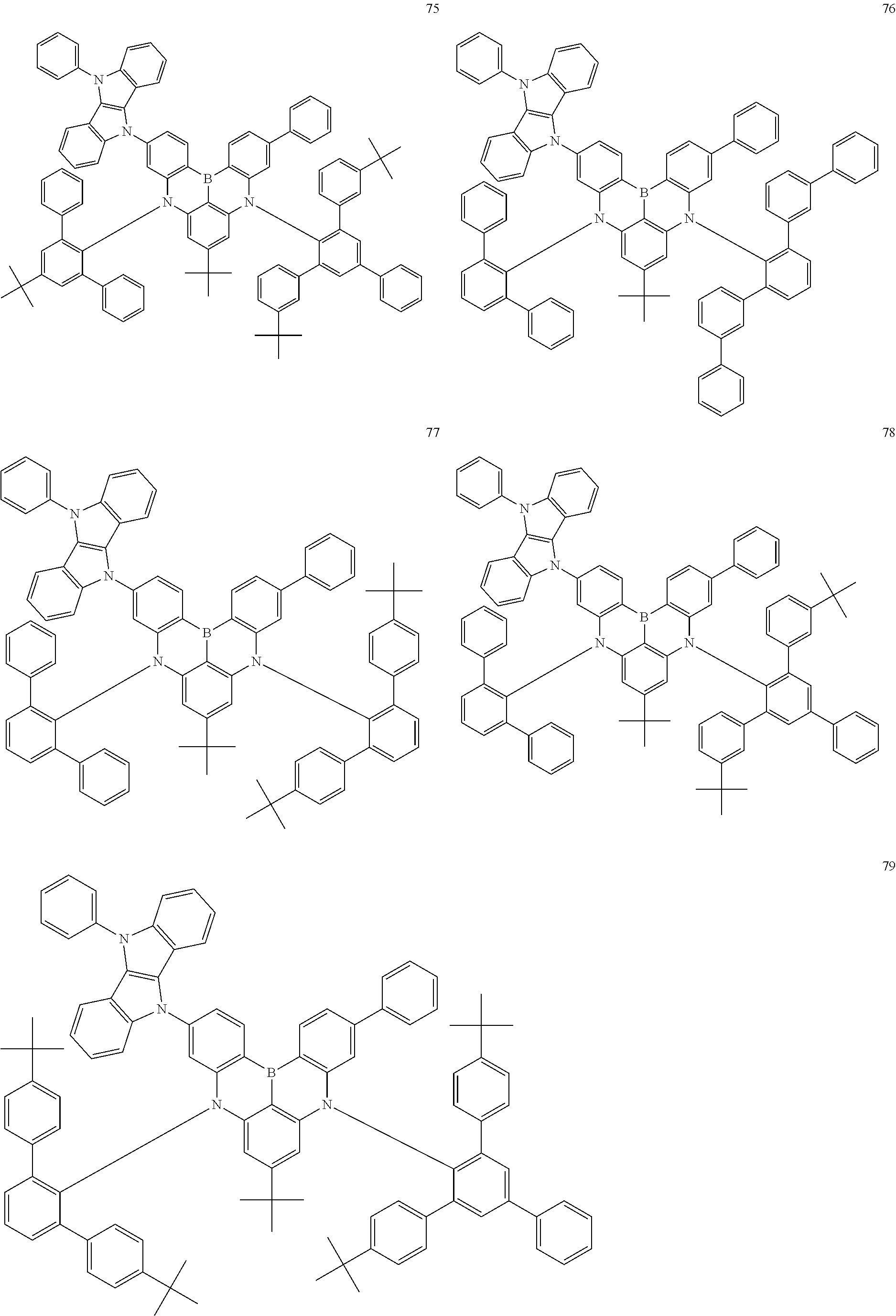

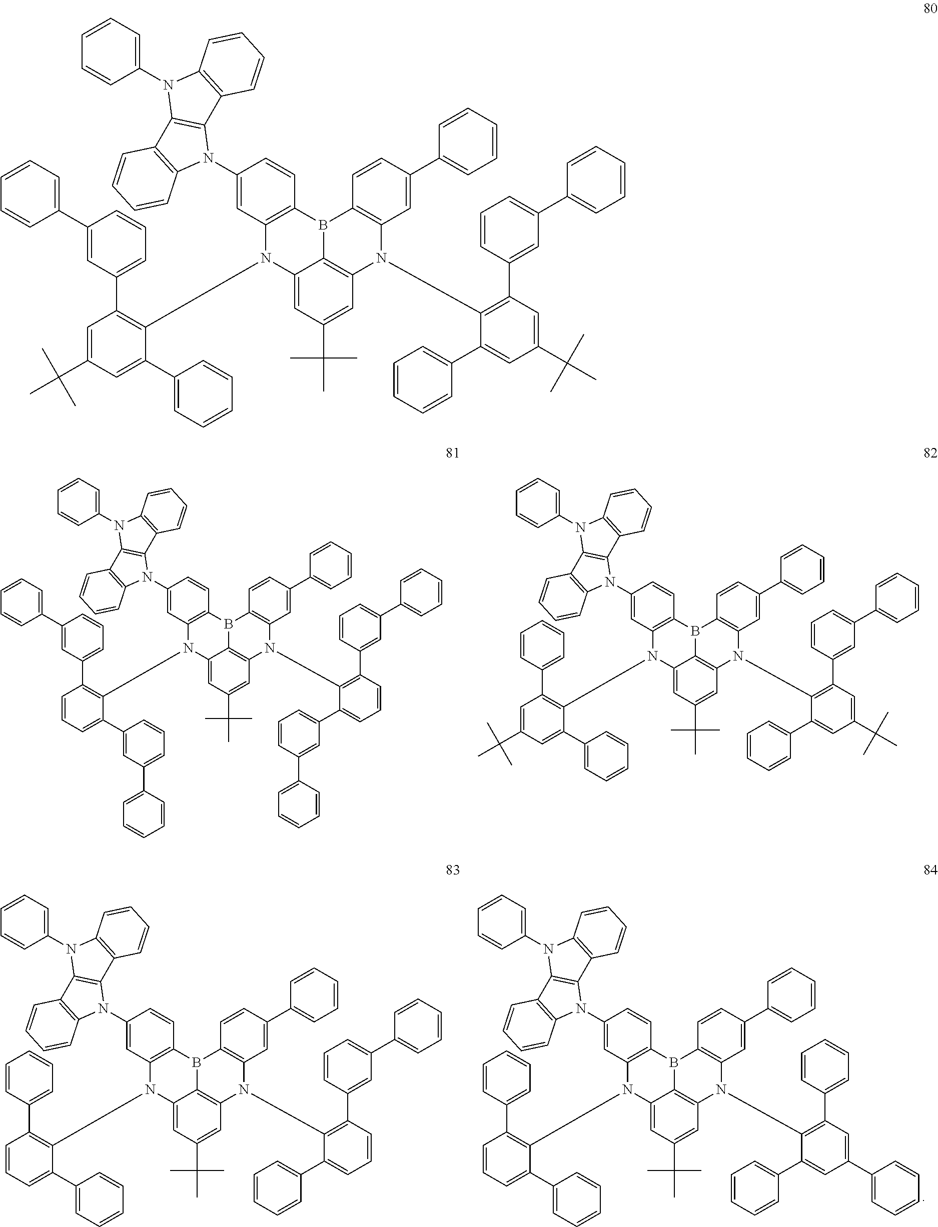

11. A fused polycyclic compound represented by Formula 1: 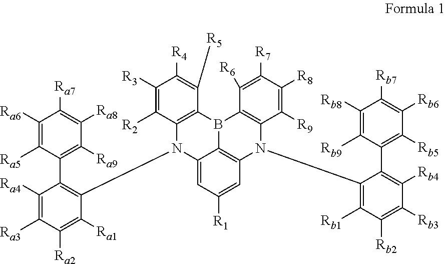
wherein in Formula 1,
at least one selected from among R₁ to R₉, Rₐ₁ to Rₐ₉, and R_{b1} to R_{b9} is represented by Formula 2, and the rest thereof are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group: 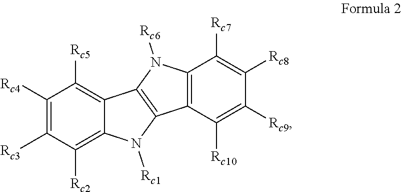
wherein in Formula 2,
any one selected from among R_{c1} to R_{c10} is a position bonded to Formula 1, and the rest thereof are each independently hydrogen, deuterium, or a substituted or unsubstituted aryl group having 6 to 30 ring-forming carbon atoms.

12. The fused polycyclic compound of claim 11, wherein Formula 2 is represented by Formula 2-A: 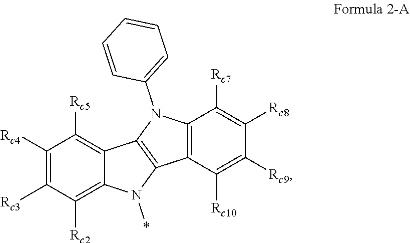
in Formula 2-A,
R_{c2} to R_{c5} and R_{c7} to R_{c10} each being the same as defined in Formula 2.

13. The fused polycyclic compound of claim 11, wherein the fused polycyclic compound represented by Formula 1 is represented by Formula 1-A or Formula 1-B: 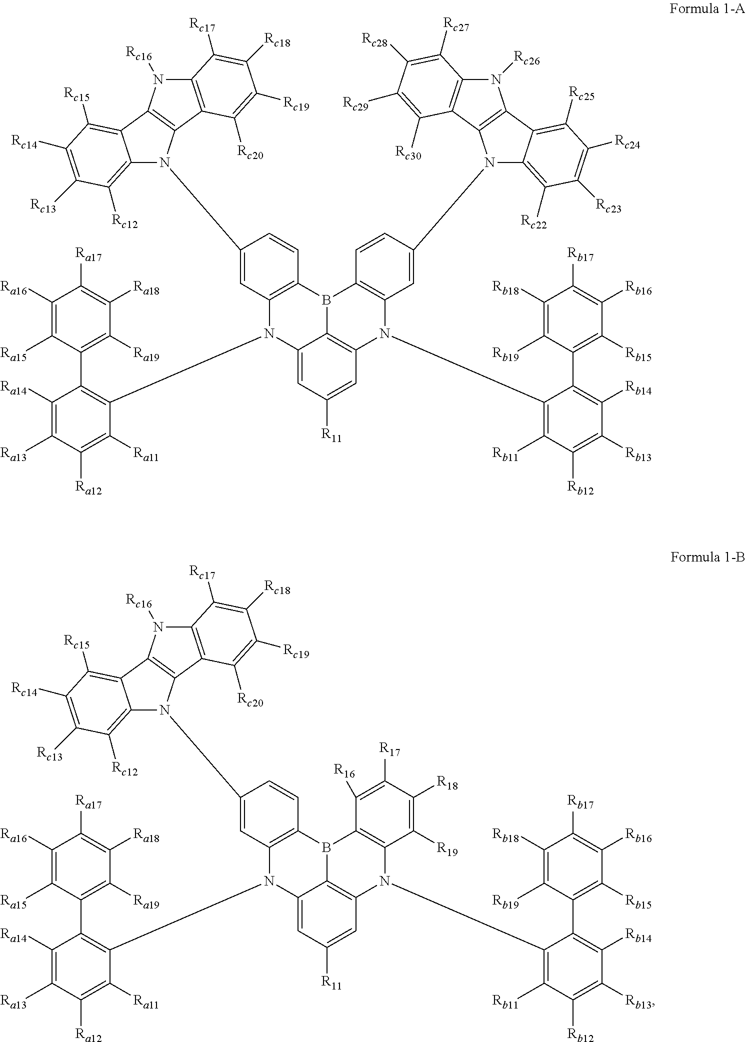
wherein in Formula 1-A,
R_{c22} to R_{c30} are each independently hydrogen, deuterium, or a substituted or unsubstituted aryl group having 6 to 30 ring-forming carbon atoms,
wherein in Formula 1-B,
R₁₆ to R₁₉ are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group, and
wherein in Formula 1-A and Formula 1-B,
R₁₁, Rₐ₁₁ to Rₐ₁₉, and R_{b11} to R_{b19} are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group, and
R_{c12} to R_{c20} are each independently hydrogen, deuterium, or a substituted or unsubstituted aryl group having 6 to 30 ring-forming carbon atoms.

14. The fused polycyclic compound of claim 13, wherein the fused polycyclic compound represented by Formula 1-A is represented by Formula 1-A1: 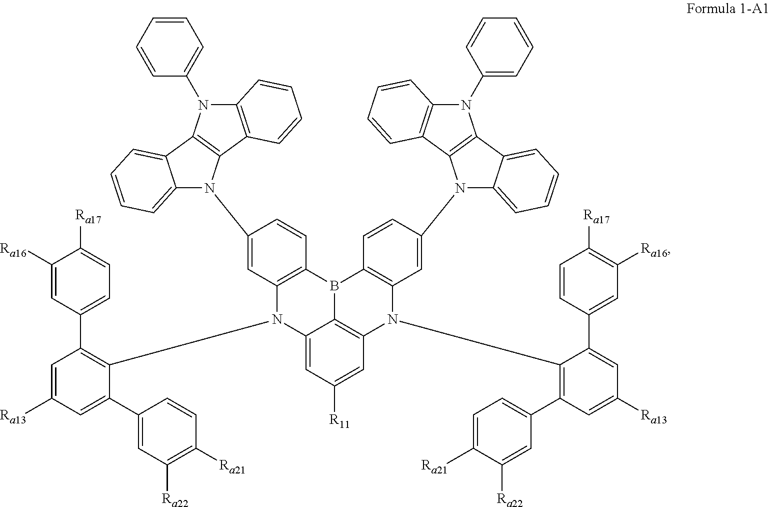
in Formula 1-A1,
Rₐ₂₁, Rₐ₂₂, R_{b21}, and R_{b22} being each independently hydrogen, deuterium, a substituted or unsubstituted alkyl group having 1 to 30 carbon atoms, or a substituted or unsubstituted aryl group having 6 to 30 ring-forming carbon atoms, and
R₁₁, Rₐ₁₃, Rₐ₁₆, Rₐ₁₇, R_{b13}, R_{b16}, and R_{b17} each being the same as defined in Formula 1-A.

15. The fused polycyclic compound of claim 14, wherein in Formula 1-A1, Rₐ₂₁, Rₐ₂₂, R_{b21}, and R_{b22} are each independently hydrogen, a substituted or unsubstituted t-butyl group, or a substituted or unsubstituted phenyl group.

16. The fused polycyclic compound of claim 13, wherein the fused polycyclic compound represented by Formula 1-B is represented by Formula 1-B1 or Formula 1-B2: 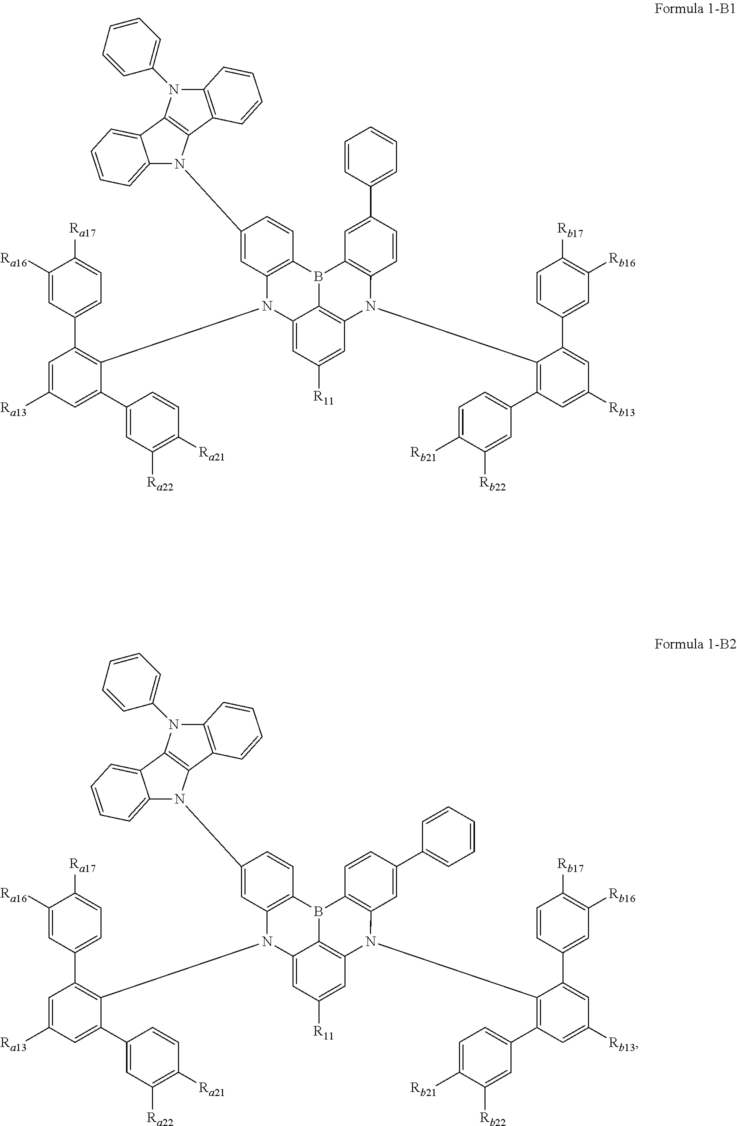
in Formula 1-B1 and Formula 1-B2,
Rₐ₂₁, Rₐ₂₂, R_{b21}, and R_{b22} being each independently hydrogen, deuterium, a substituted or unsubstituted alkyl group having 1 to 30 carbon atoms, or a substituted or unsubstituted aryl group having 6 to 30 ring-forming carbon atoms, and
R₁₁, Rₐ₁₃, Rₐ₁₆, Rₐ₁₇, R_{b13}, R_{b16}, and R_{b17} each being the same as defined in Formula 1-B.

17. The fused polycyclic compound of claim 11, wherein in Formula 1, a first biphenyl group comprising Rₐ₁ to Rₐ₉ and a second biphenyl group comprising R_{b1} to R_{b9} are each independently represented by any one selected from among AB-1 to AB-12:

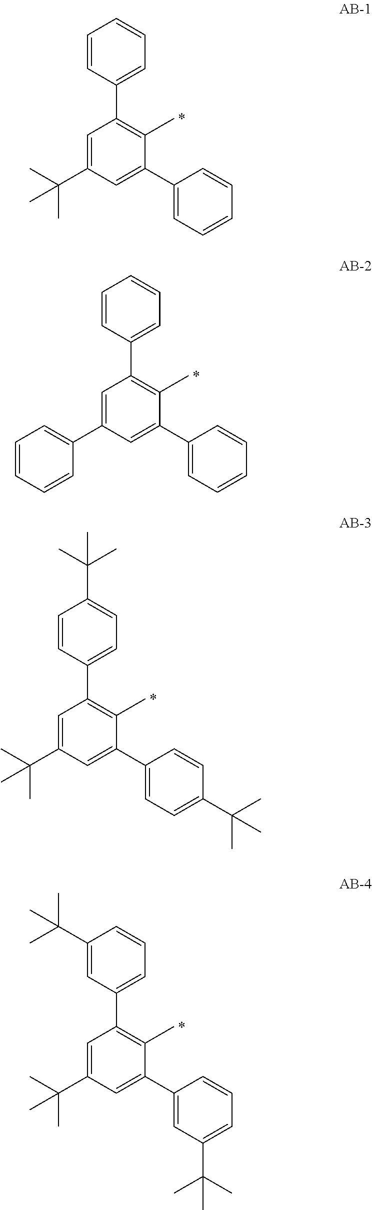

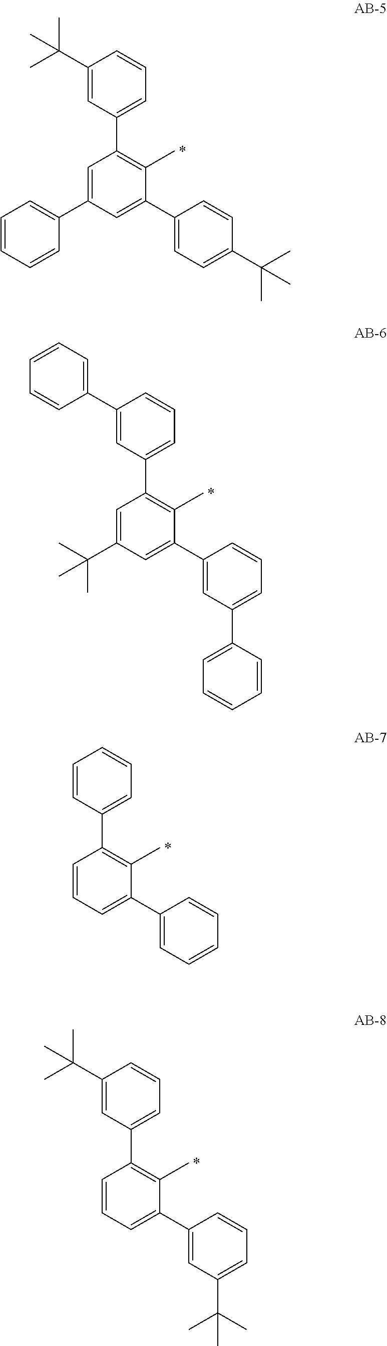

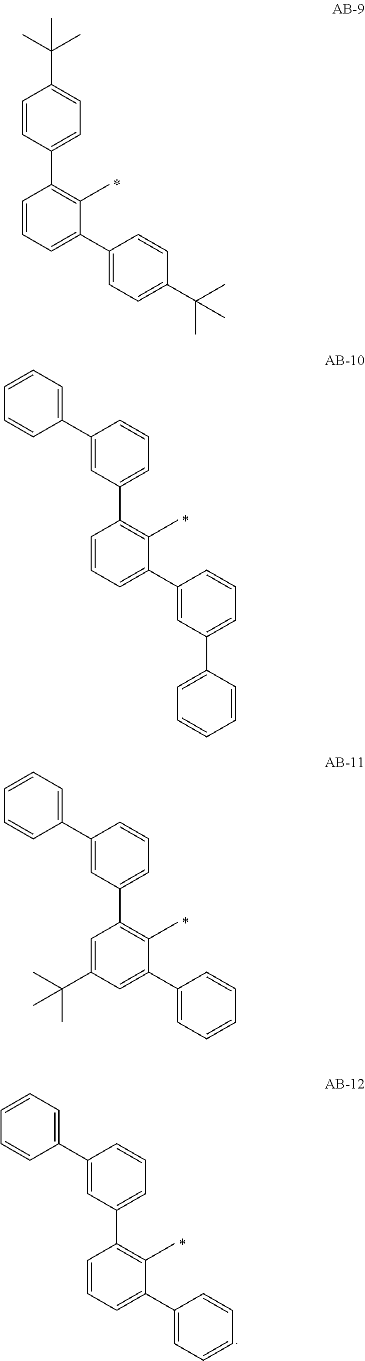

18. The fused polycyclic compound of claim 11, wherein in Formula 1, R₁ is a substituted or unsubstituted t-butyl group or a substituted or unsubstituted phenyl group.

19. The fused polycyclic compound of claim 11, wherein the fused polycyclic compound represented by Formula 1 is any one selected from among compounds of Compound Group 1:

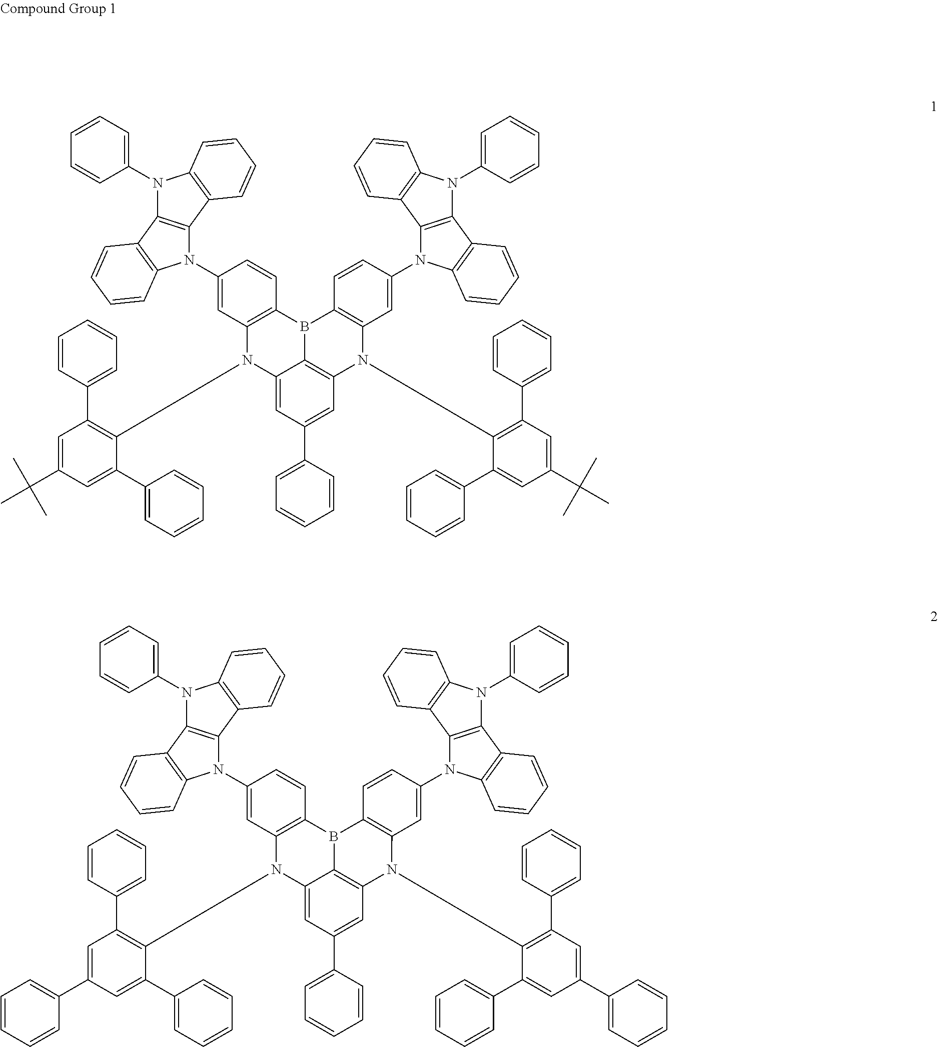 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(-c5ccccc5)cc2c43)c(-c2ccccc2)c1 ; c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cc(-c6ccccc6)cc5-c5ccccc5)c5cc(-c6ccccc6)cc3c54)c(-c3ccccc3)c2)cc1]

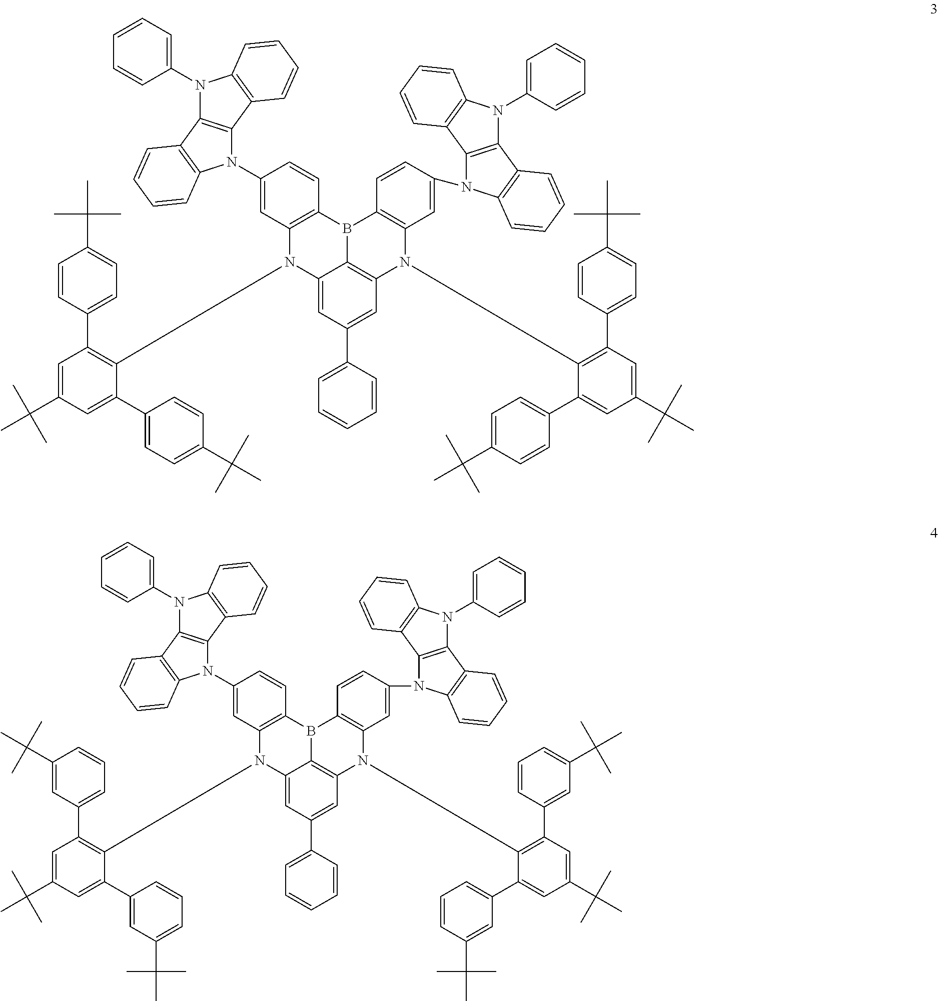

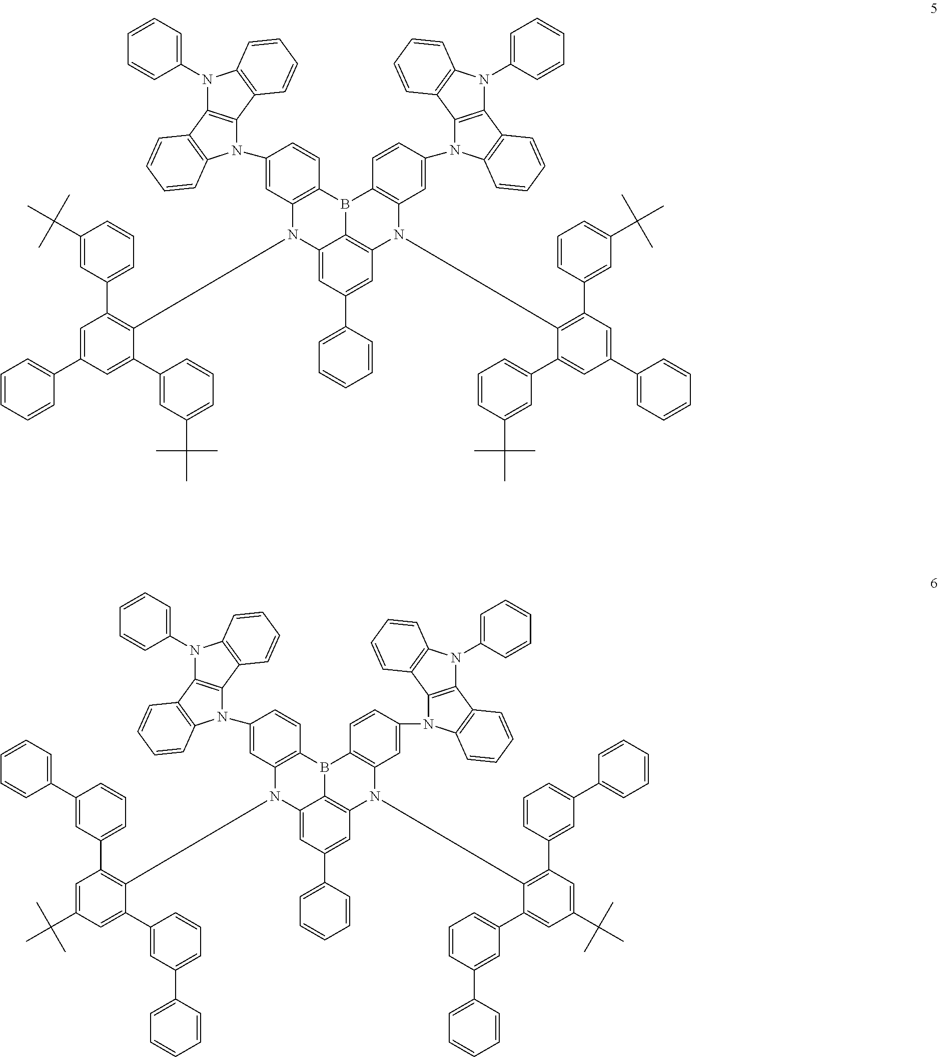 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(-c5ccccc5)cc2c43)c1 ; CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1]

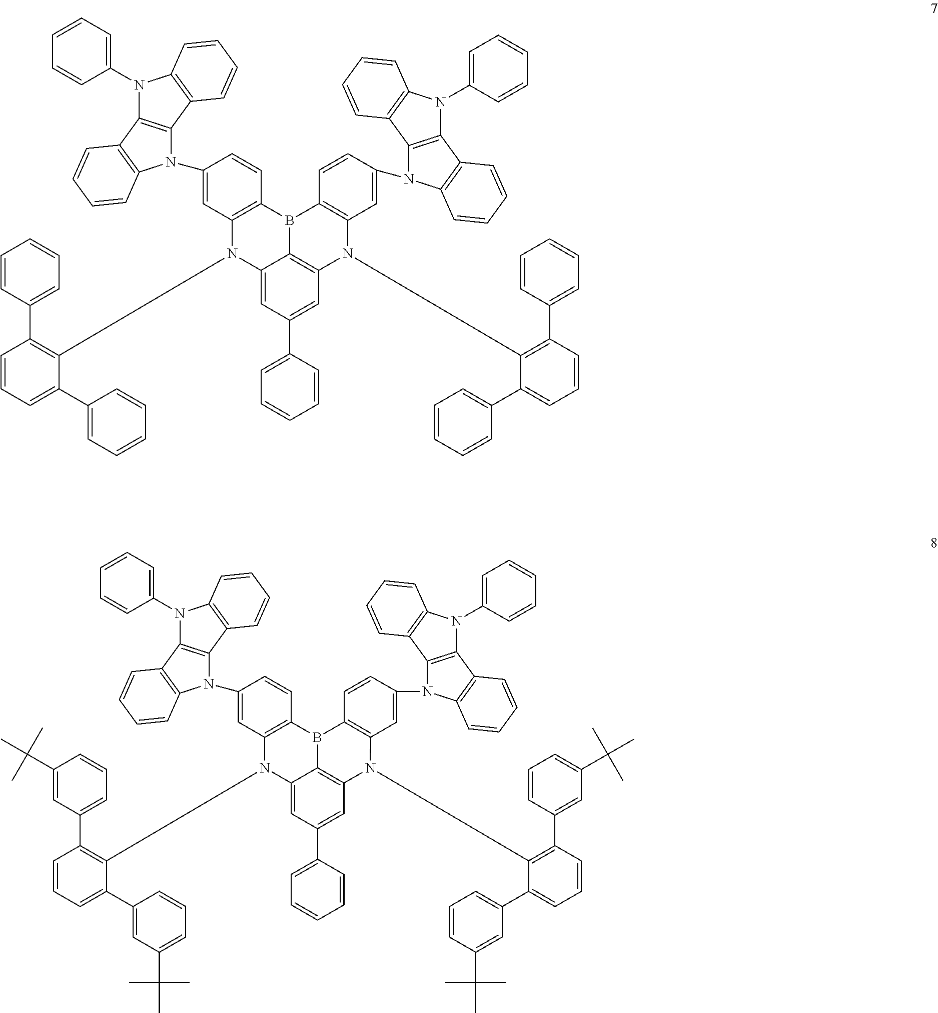 [SMILES: c1ccc(-c2cc3c4c(c2)N(c2c(-c5ccccc5)cccc2-c2ccccc2)c2cc(-n5c6ccccc6c6c5c5ccccc5n6-c5ccccc5)ccc2B4c2ccc(-n4c5ccccc5c5c4c4ccccc4n5-c4ccccc4)cc2N3c2c(-c3ccccc3)cccc2-c2ccccc2)cc1 ; CC(C)(C)c1cccc(-c2cccc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cccc4-c4cccc(C(C)(C)C)c4)c4cc(-c5ccccc5)cc2c43)c1]

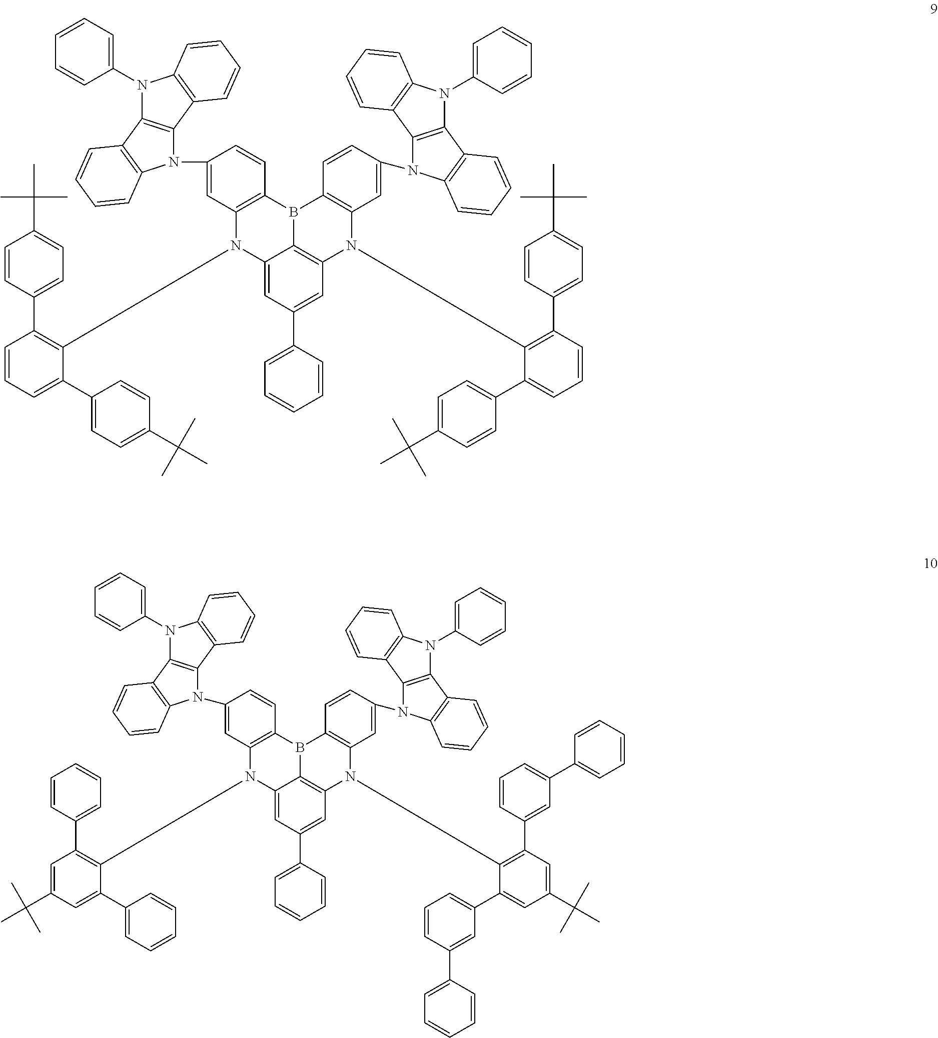

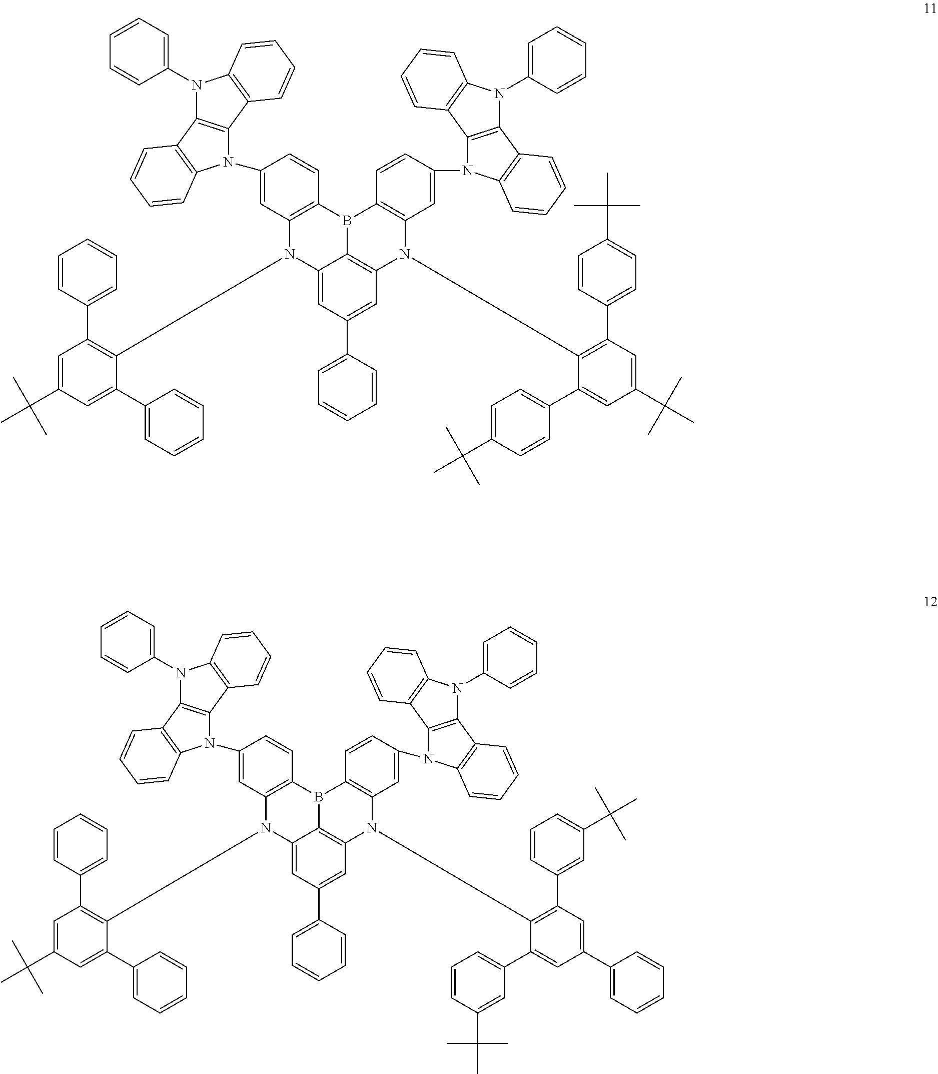

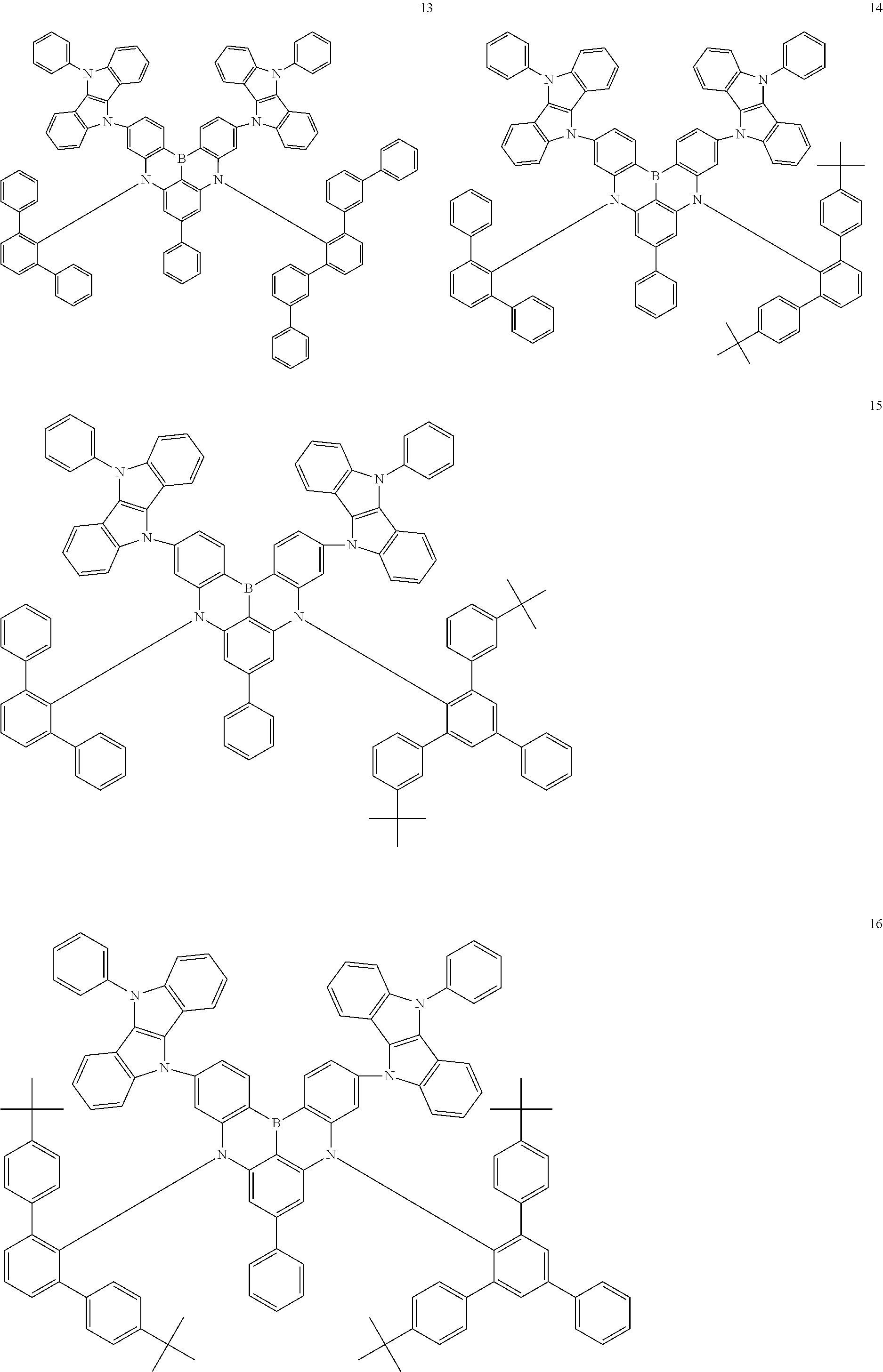

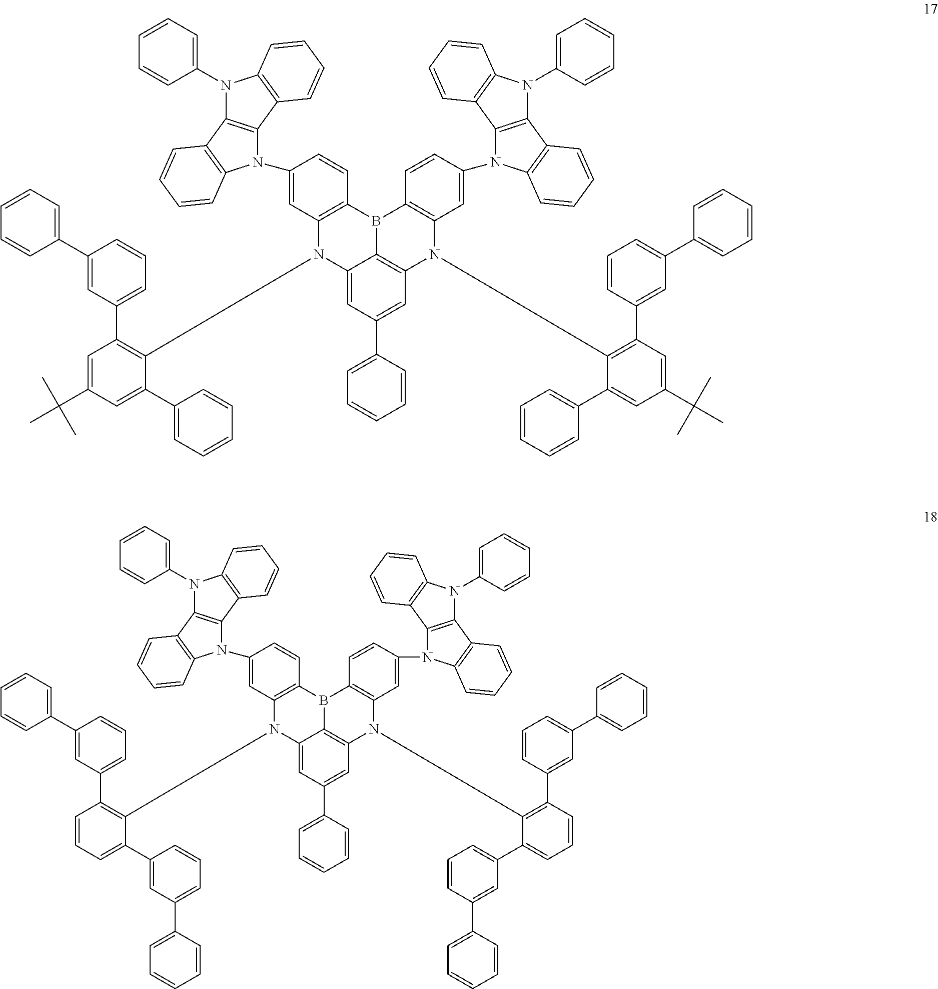 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(-c5ccccc5)cc2c43)c(-c2cccc(-c3ccccc3)c2)c1 ; c1ccc(-c2cccc(-c3cccc(-c4cccc(-c5ccccc5)c4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6cccc(-c7ccccc7)c6)cccc5-c5cccc(-c6ccccc6)c5)c5cc(-c6ccccc6)cc3c54)c2)cc1]

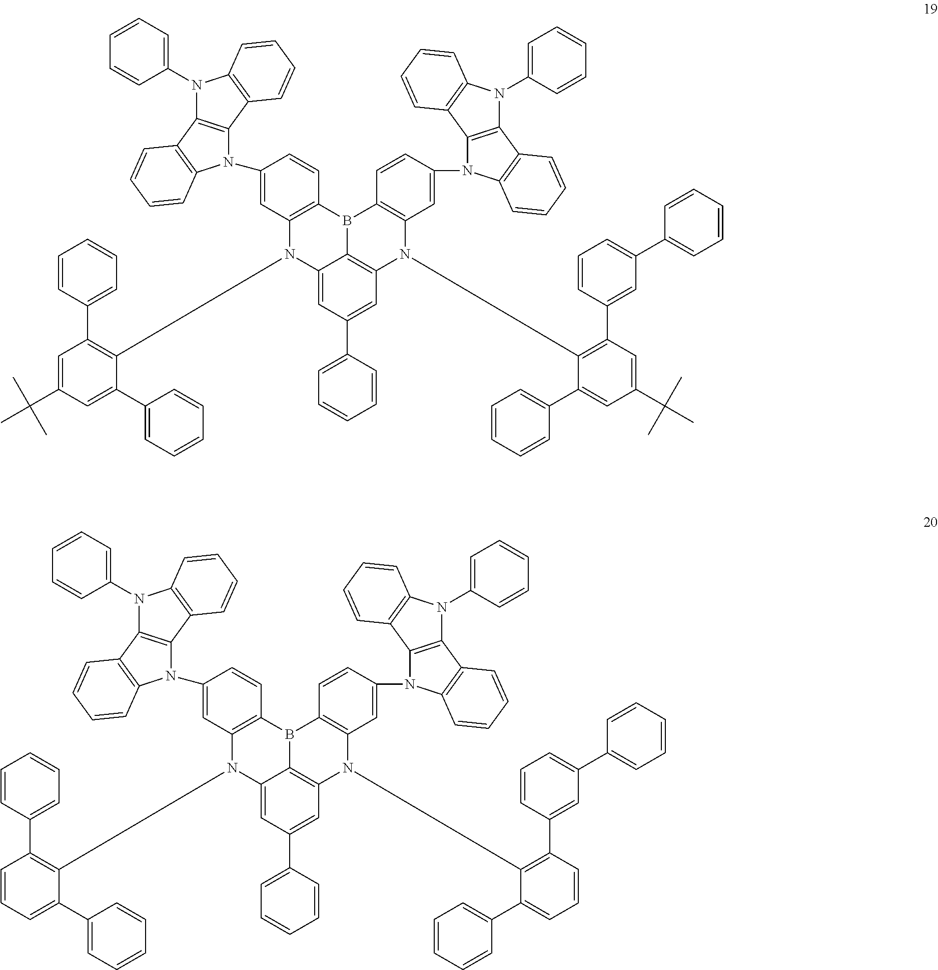 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(-c5ccccc5)cc2c43)c(-c2ccccc2)c1 ; c1ccc(-c2cccc(-c3cccc(-c4ccccc4)c3N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c2)cc1]

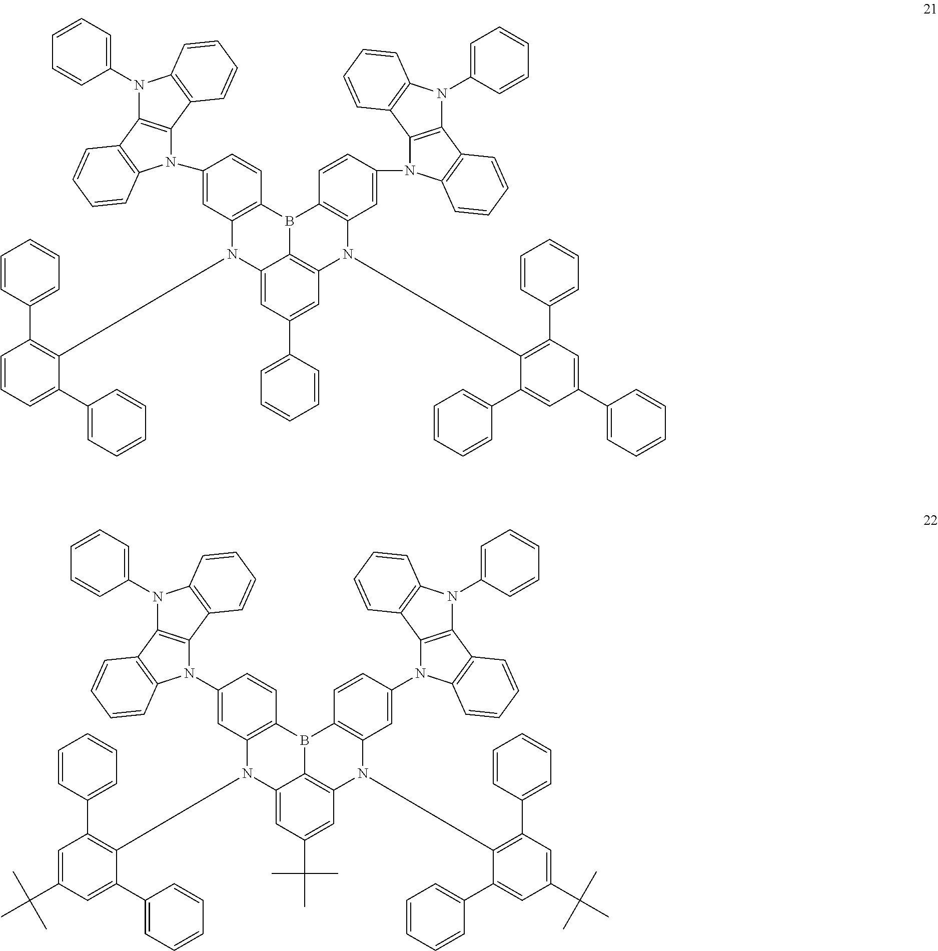 [SMILES: c1ccc(-c2cc(-c3ccccc3)c(N3c4cc(-n5c6ccccc6c6c5c5ccccc5n6-c5ccccc5)ccc4B4c5ccc(-n6c7ccccc7c7c6c6ccccc6n7-c6ccccc6)cc5N(c5c(-c6ccccc6)cccc5-c5ccccc5)c5cc(-c6ccccc6)cc3c54)c(-c3ccccc3)c2)cc1 ; CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2ccccc2)c1]

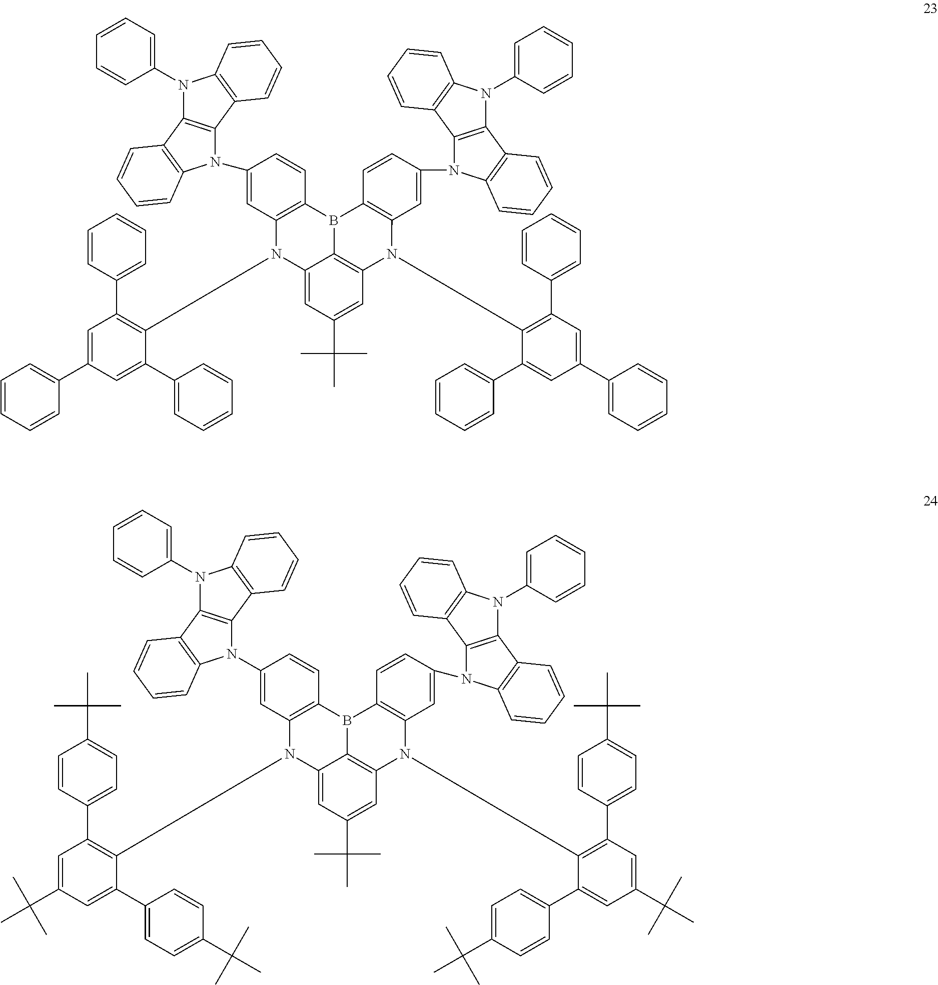 [SMILES: CC(C)(C)c1cc2c3c(c1)N(c1c(-c4ccccc4)cc(-c4ccccc4)cc1-c1ccccc1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

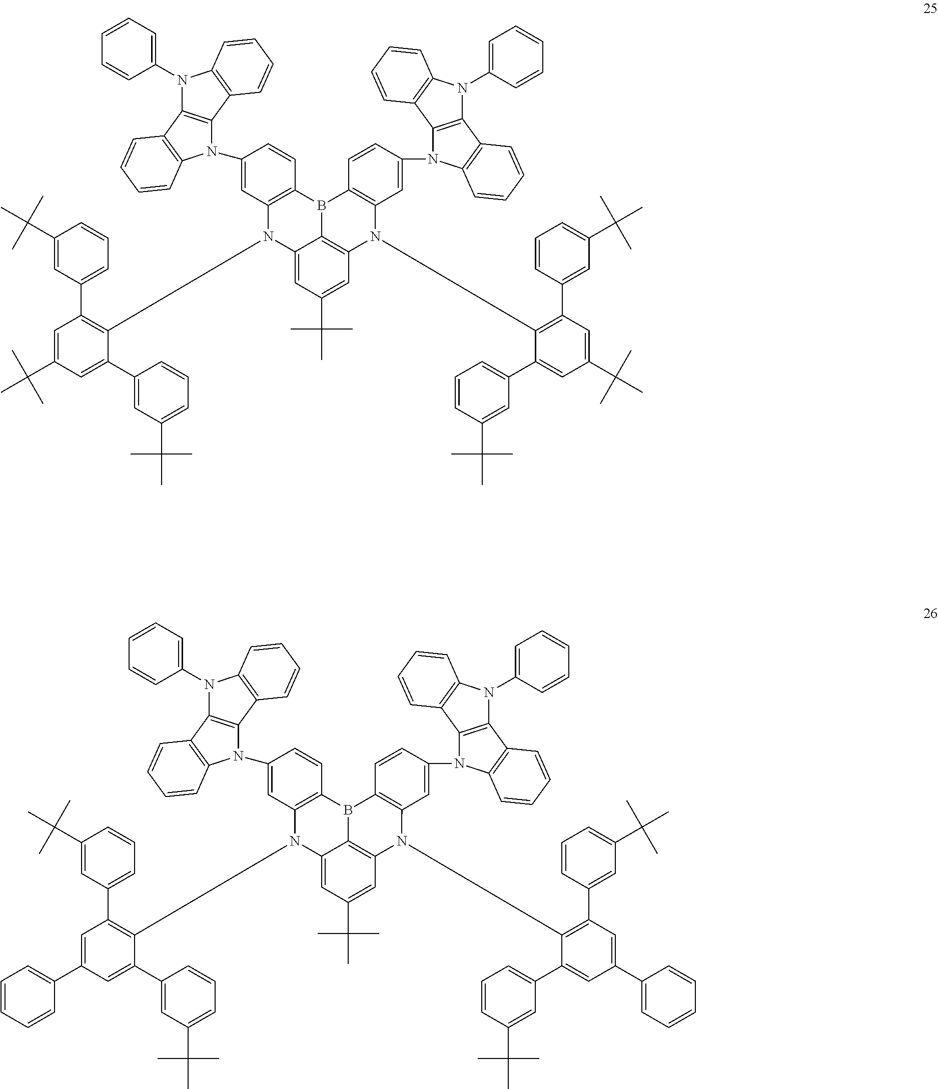 [SMILES: CC(C)(C)c1cccc(-c2cc(C(C)(C)C)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1]

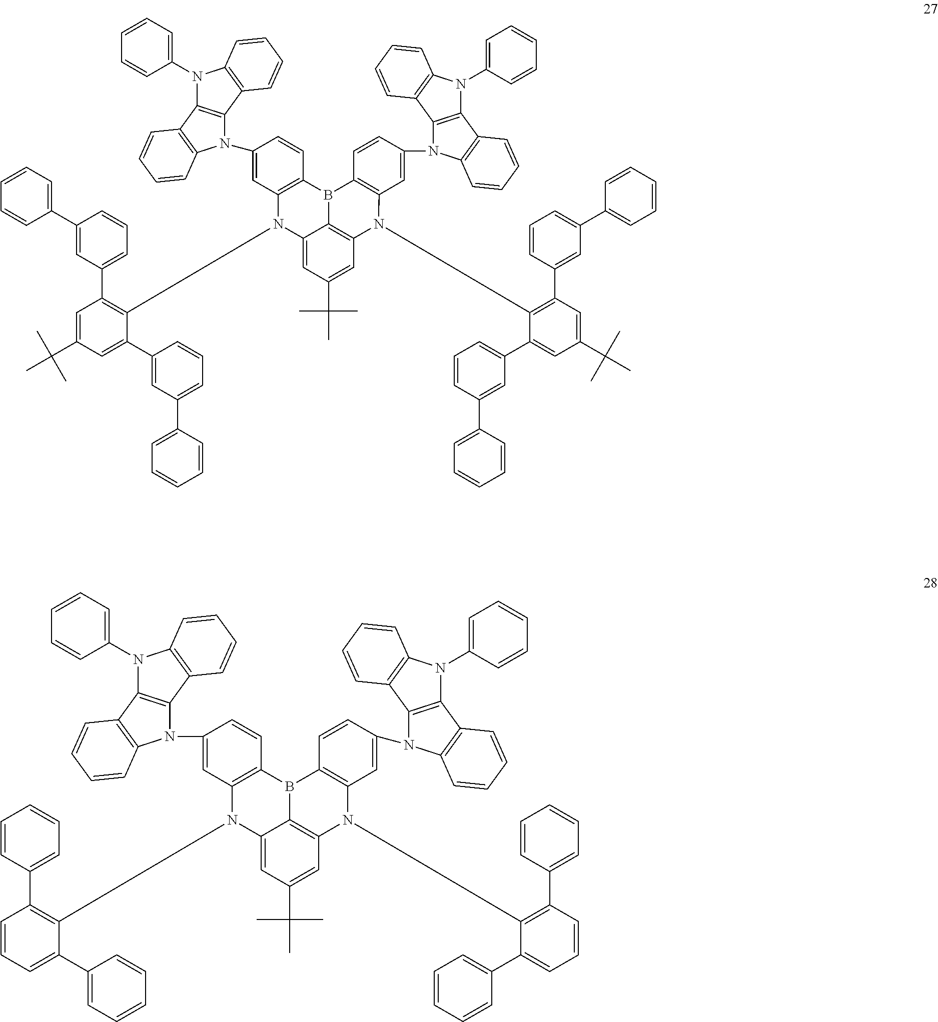 [SMILES: CC(C)(C)c1cc(-c2cccc(-c3ccccc3)c2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cccc1-c1ccccc1]

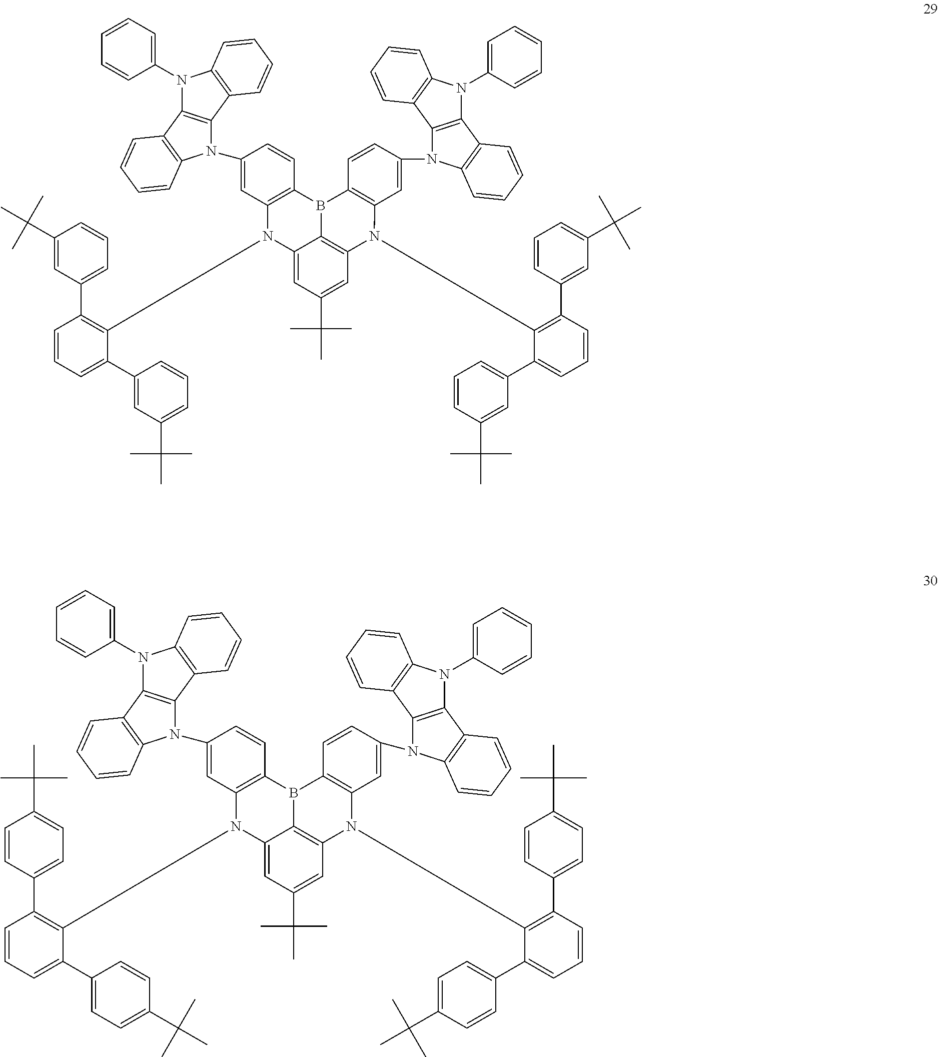

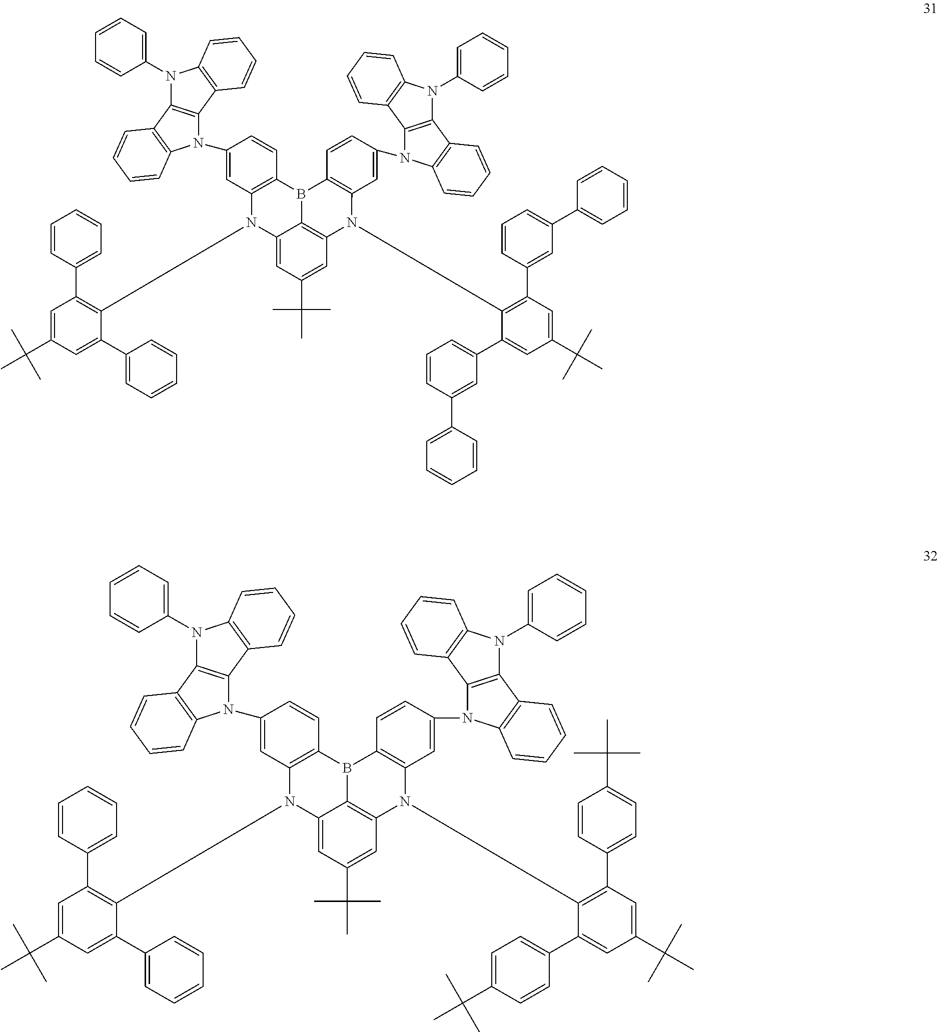 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2ccccc2)c1 ; CC(C)(C)c1ccc(-c2cc(C(C)(C)C)cc(-c3ccc(C(C)(C)C)cc3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)cc1]

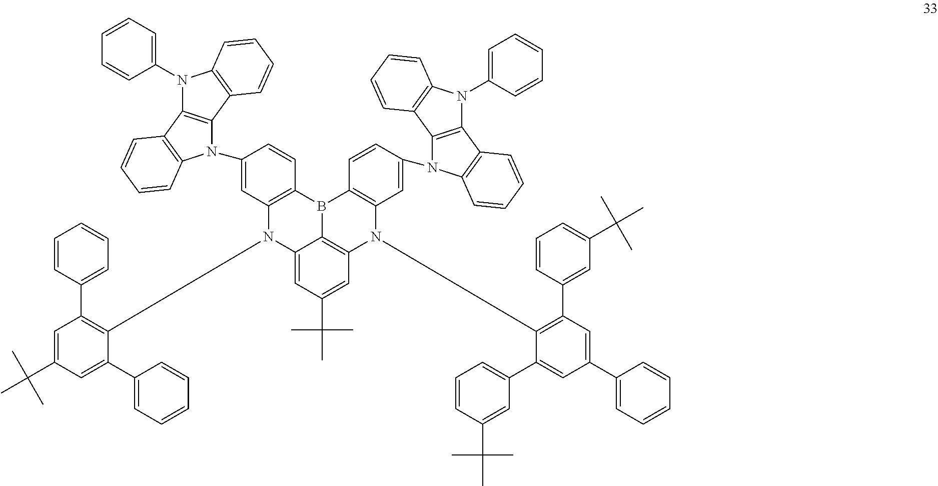 [SMILES: CC(C)(C)c1cccc(-c2cc(-c3ccccc3)cc(-c3cccc(C(C)(C)C)c3)c2N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c1]

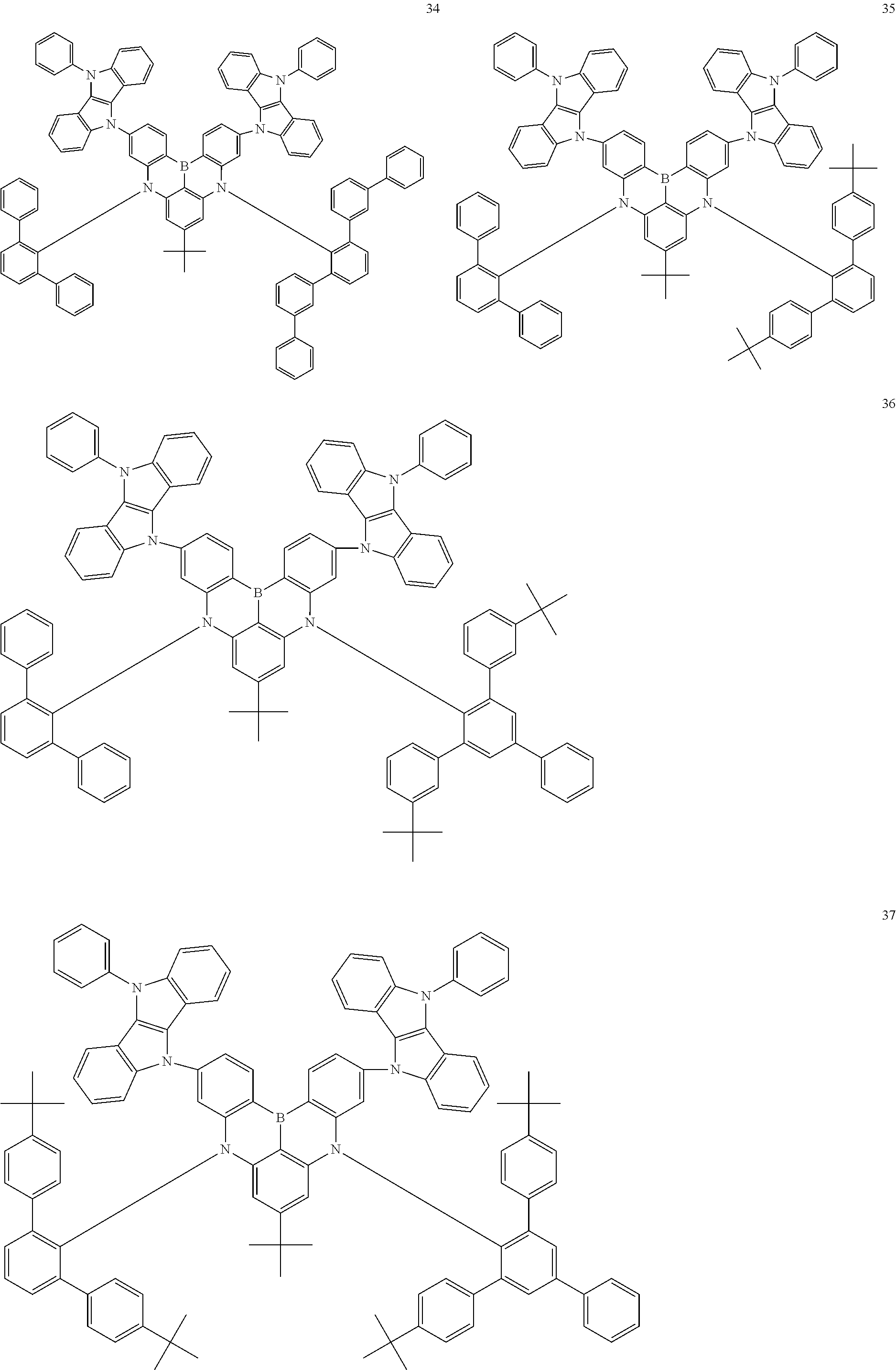

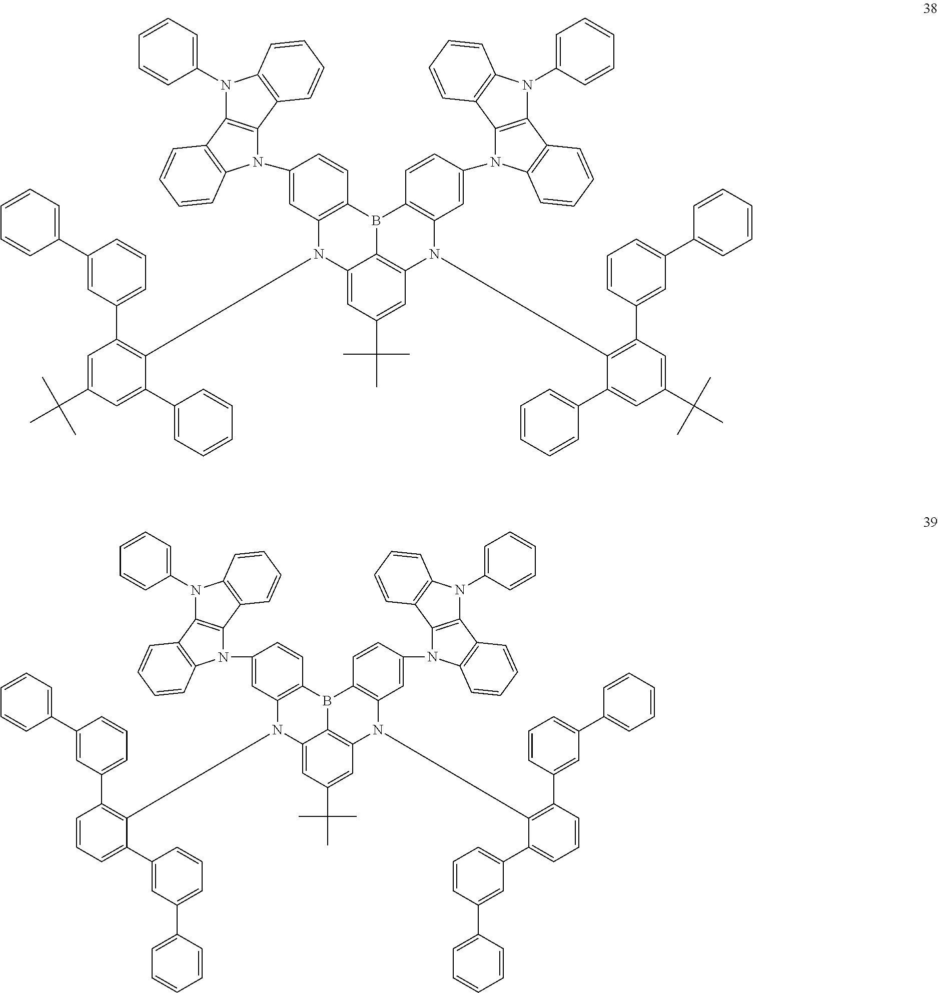 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2cccc(-c3ccccc3)c2)cccc1-c1cccc(-c2ccccc2)c1]

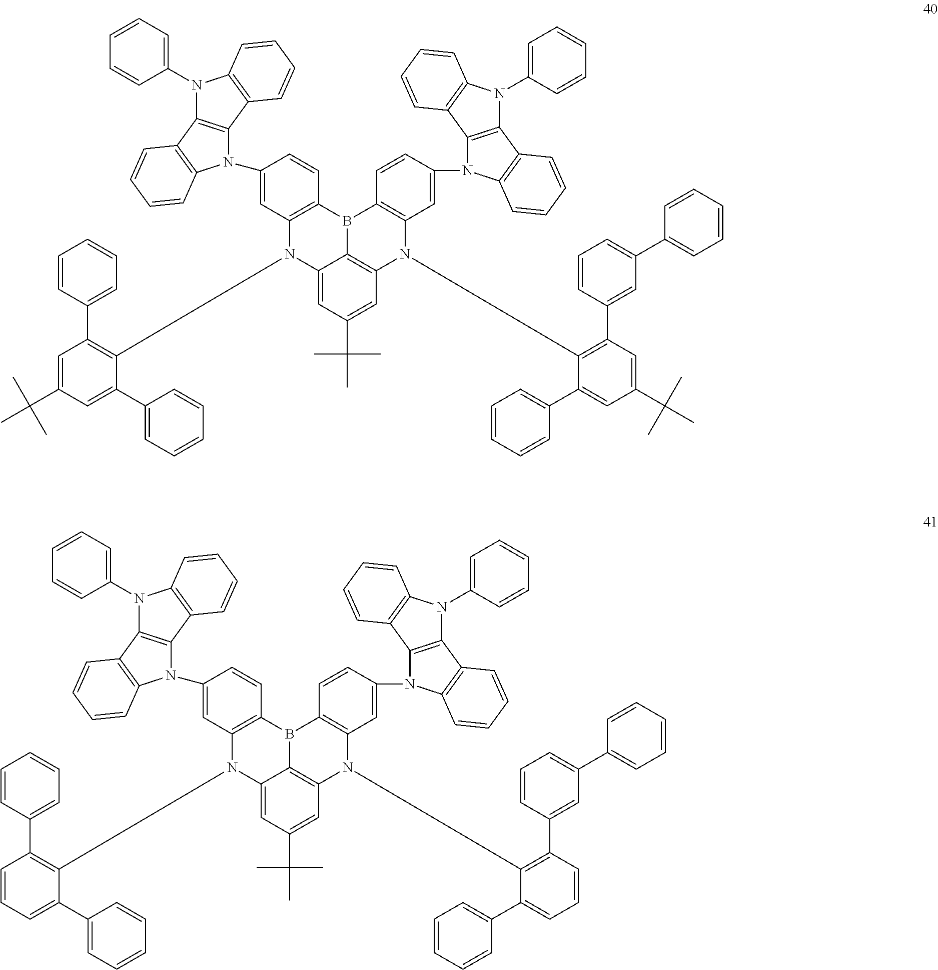 [SMILES: CC(C)(C)c1cc(-c2ccccc2)c(N2c3cc(-n4c5ccccc5c5c4c4ccccc4n5-c4ccccc4)ccc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2ccccc2)c1 ; CC(C)(C)c1cc2c3c(c1)N(c1c(-c4ccccc4)cccc1-c1cccc(-c4ccccc4)c1)c1cc(-n4c5ccccc5c5c4c4ccccc4n5-c4ccccc4)ccc1B3c1ccc(-n3c4ccccc4c4c3c3ccccc3n4-c3ccccc3)cc1N2c1c(-c2ccccc2)cccc1-c1ccccc1]

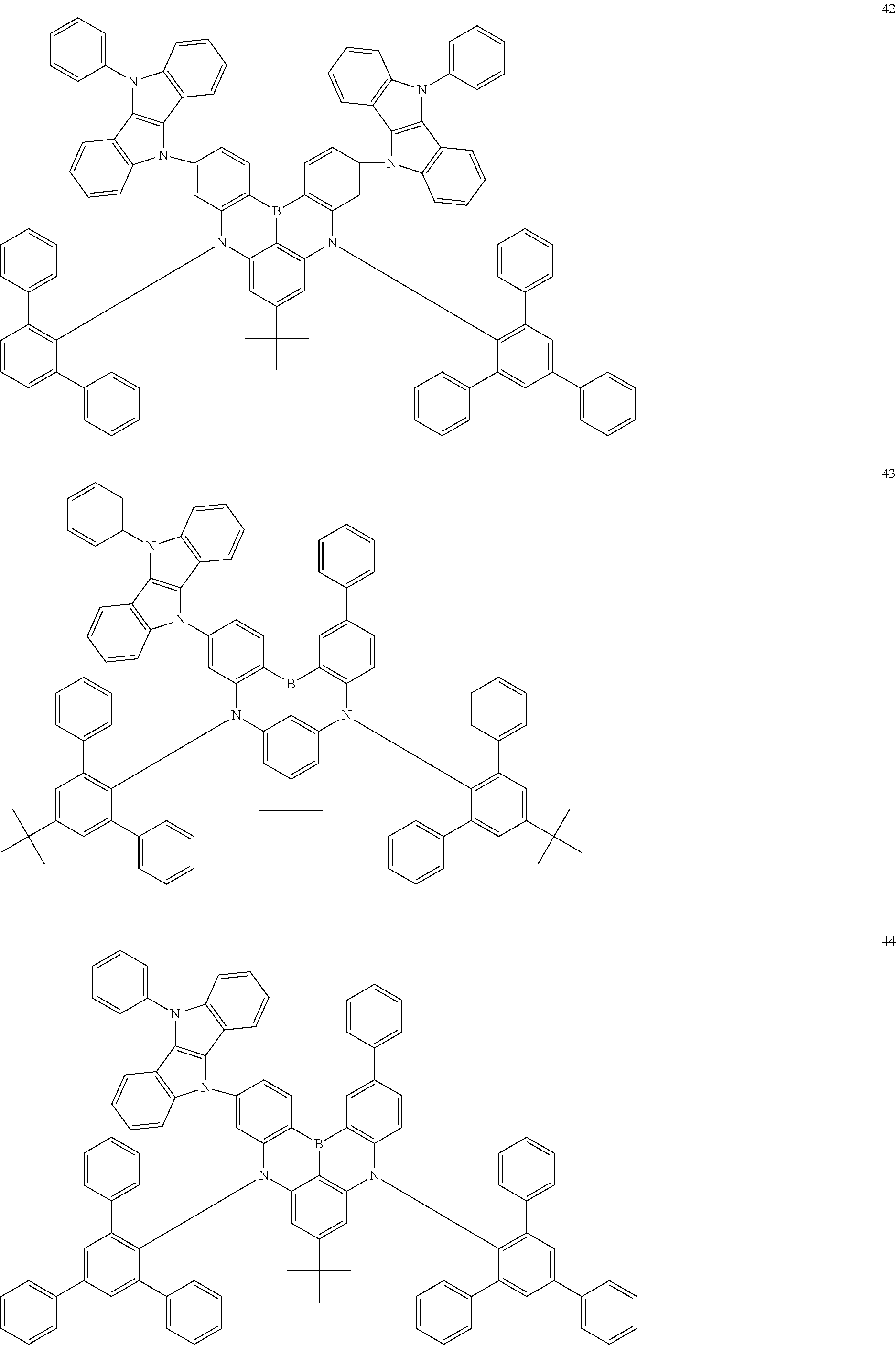

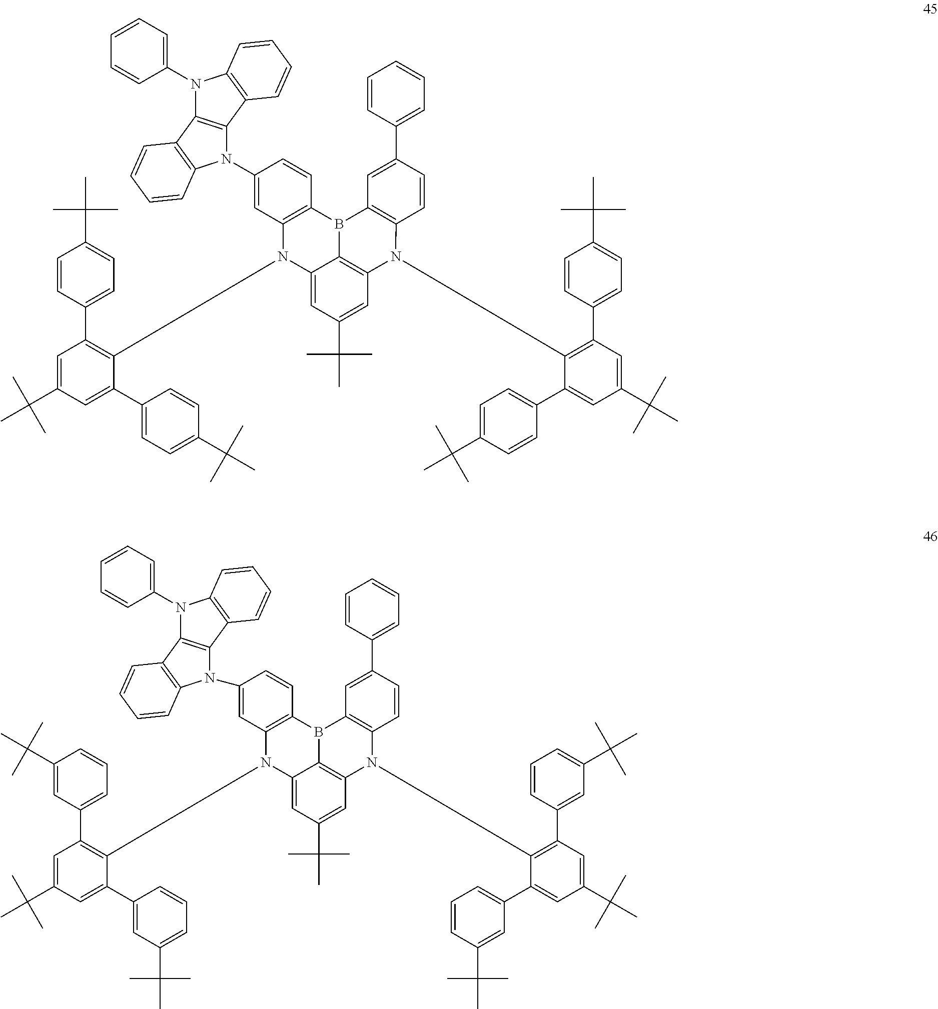

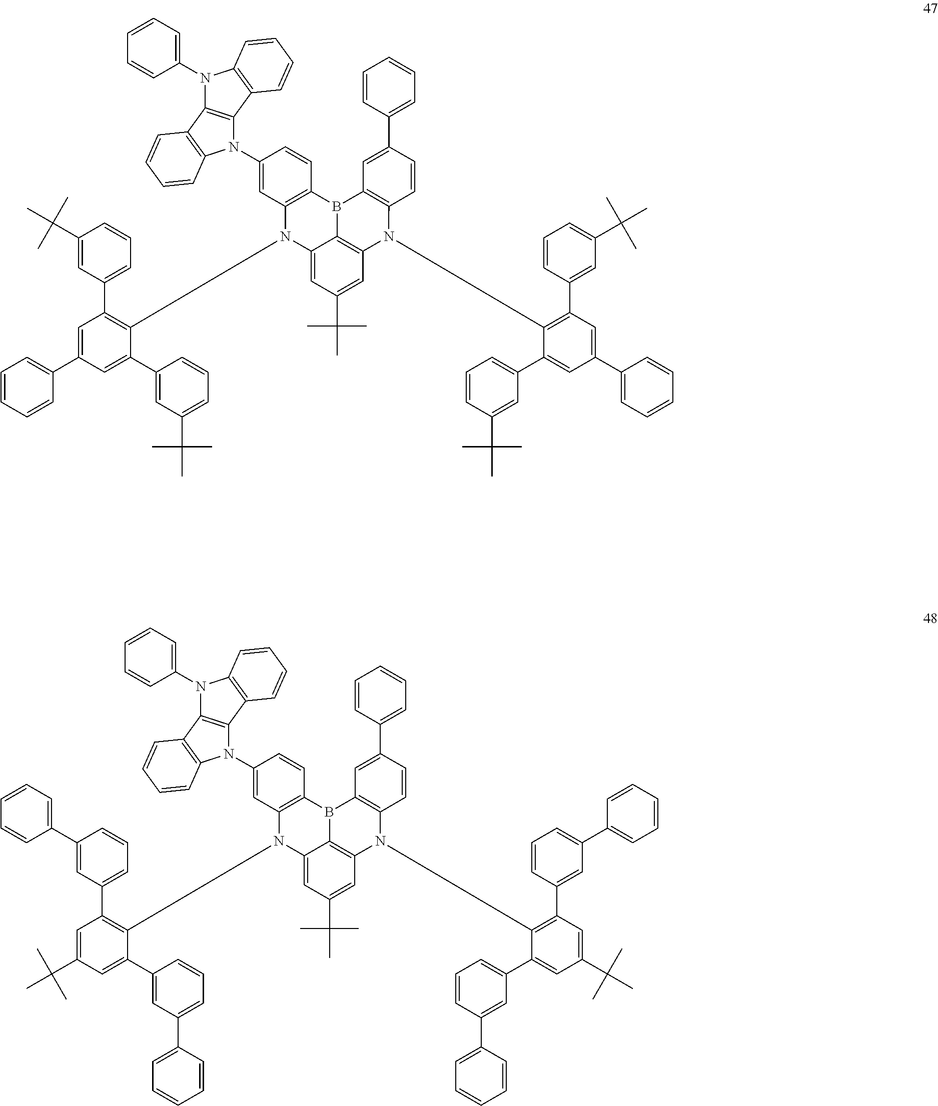 [SMILES: CC(C)(C)c1cccc(-c2cc(-c3ccccc3)cc(-c3cccc(C(C)(C)C)c3)c2N2c3ccc(-c4ccccc4)cc3B3c4ccc(-n5c6ccccc6c6c5c5ccccc5n6-c5ccccc5)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3ccc(-c4ccccc4)cc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

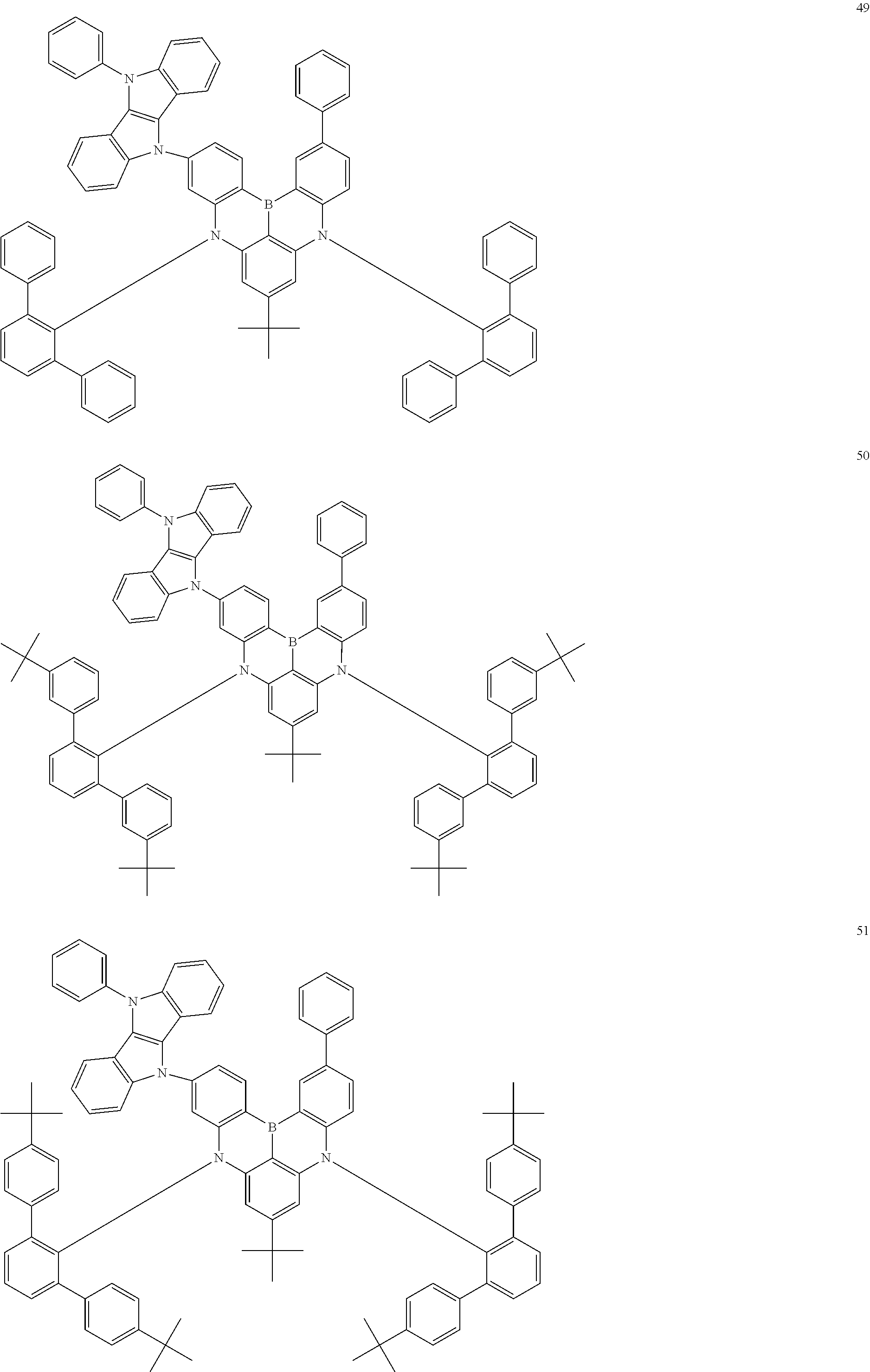

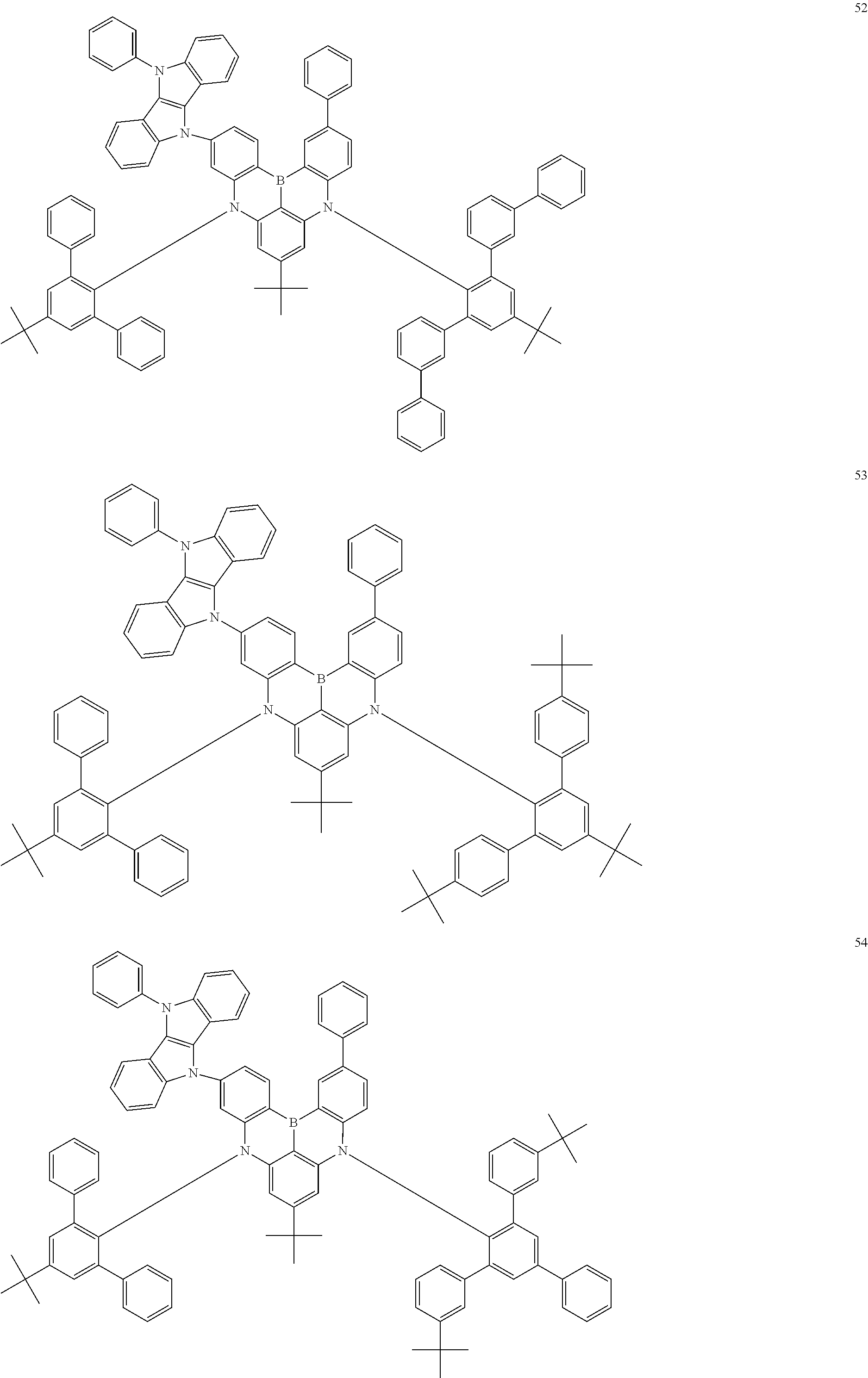

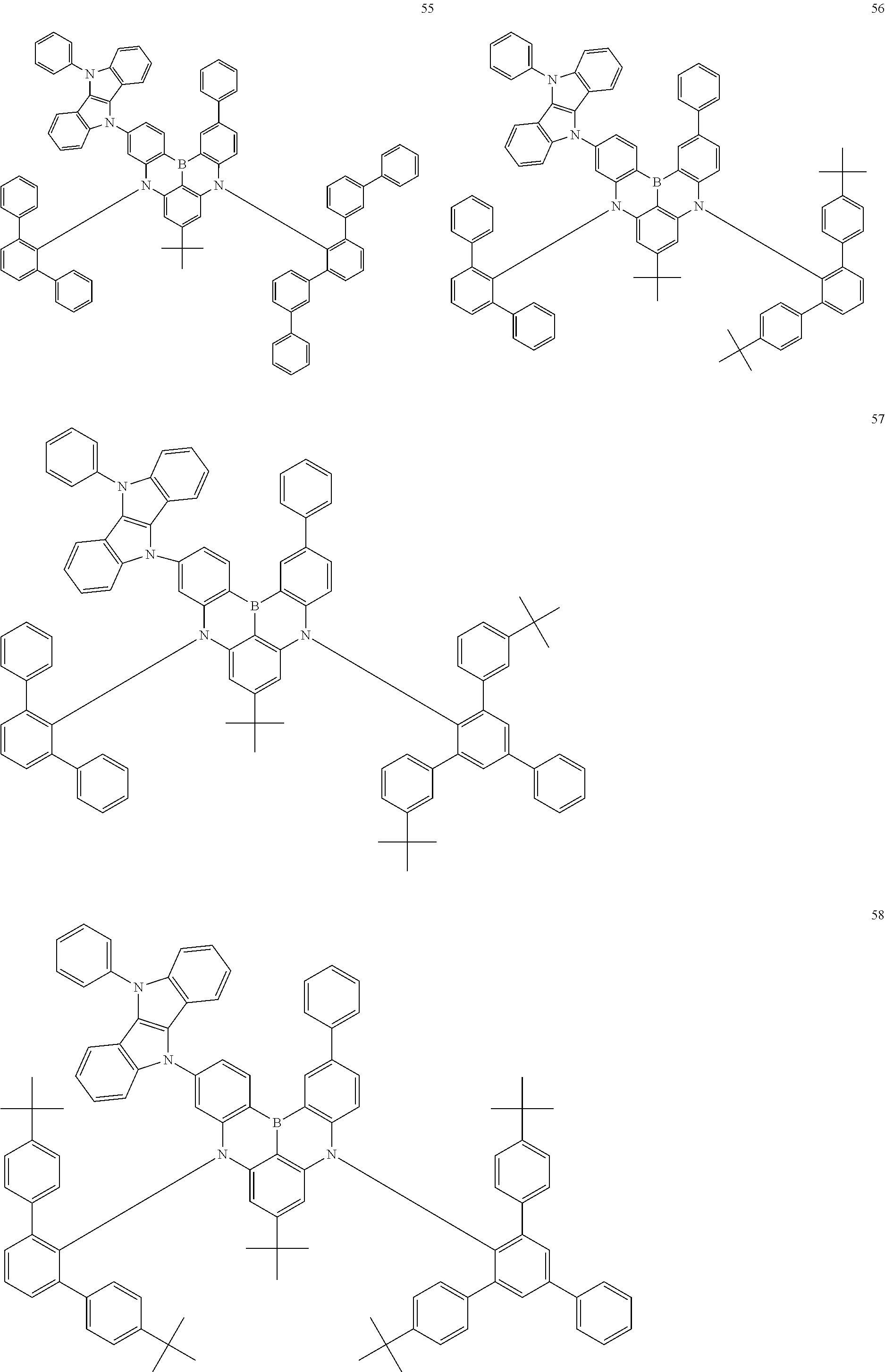

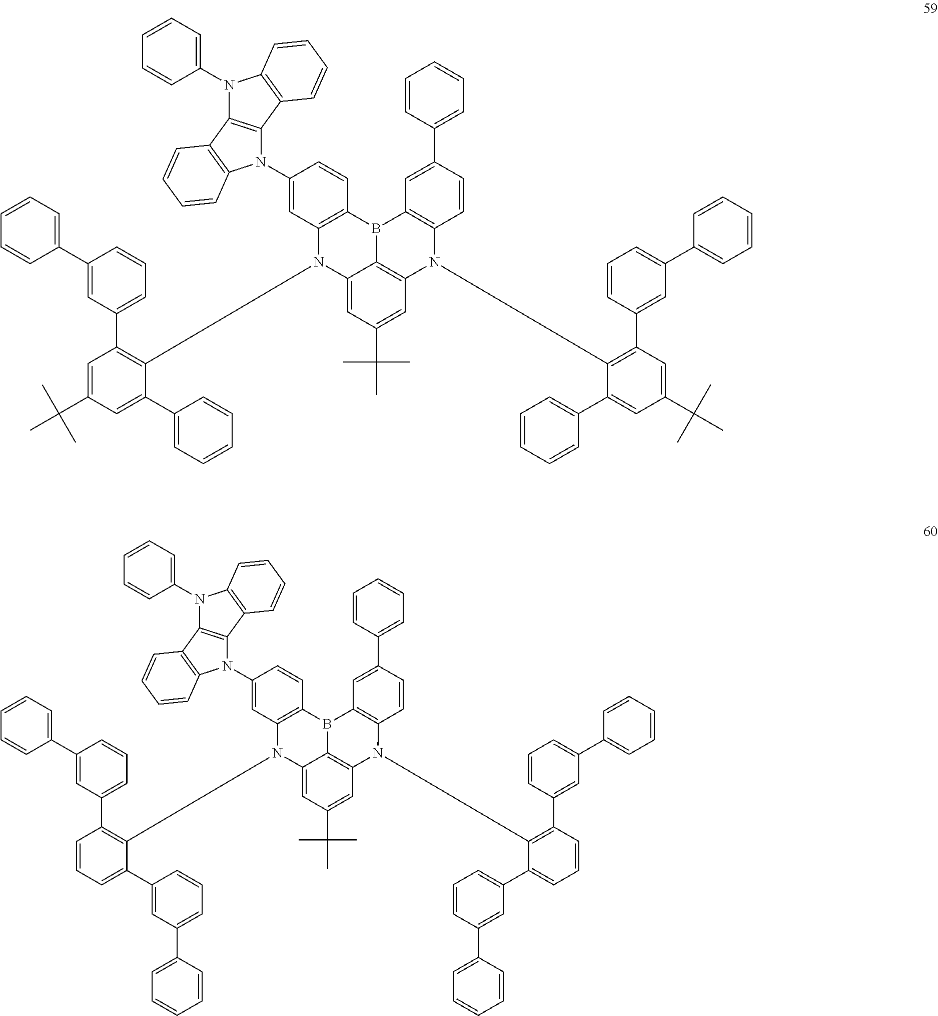 [SMILES: CC(C)(C)c1cc(-c2ccccc2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccccc5c5c4c4ccccc4n5-c4ccccc4)ccc1B3c1cc(-c3ccccc3)ccc1N2c1c(-c2cccc(-c3ccccc3)c2)cccc1-c1cccc(-c2ccccc2)c1]

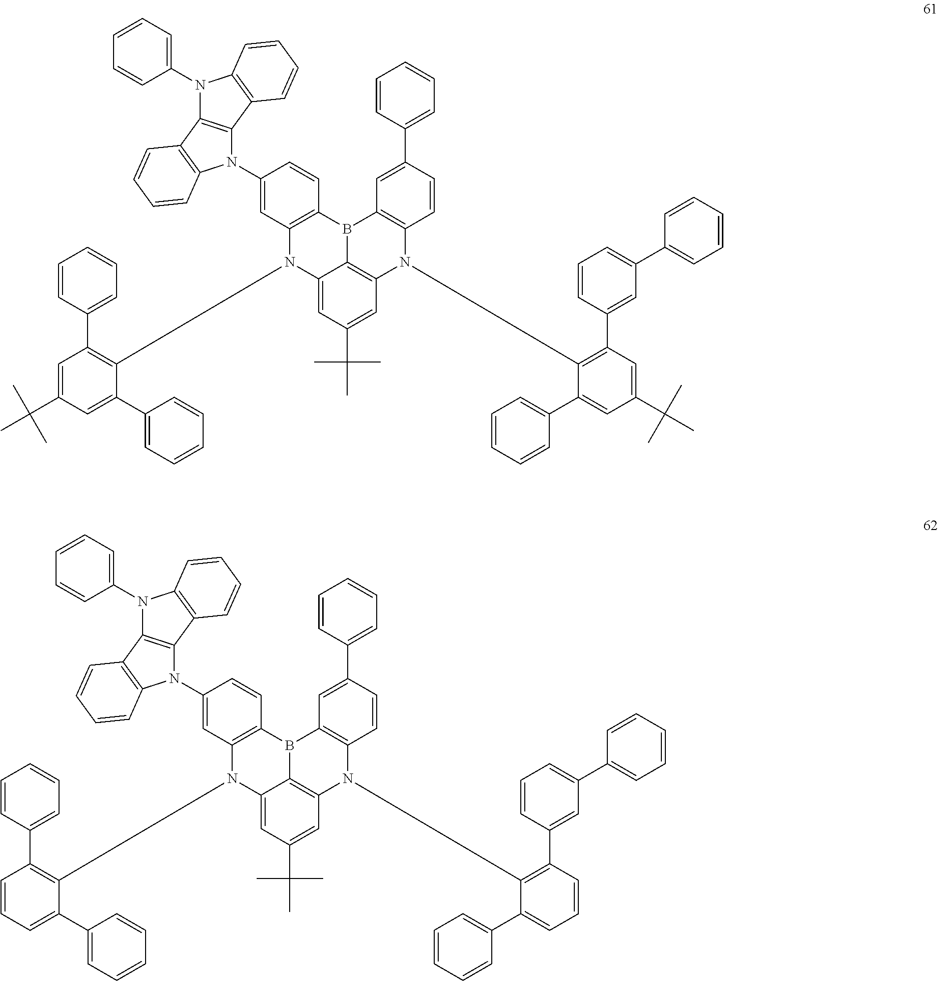 [SMILES: CC(C)(C)c1cc(-c2ccccc2)c(N2c3ccc(-c4ccccc4)cc3B3c4ccc(-n5c6ccccc6c6c5c5ccccc5n6-c5ccccc5)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1cc(-c3ccccc3)ccc1N2c1c(-c2ccccc2)cccc1-c1cccc(-c2ccccc2)c1]

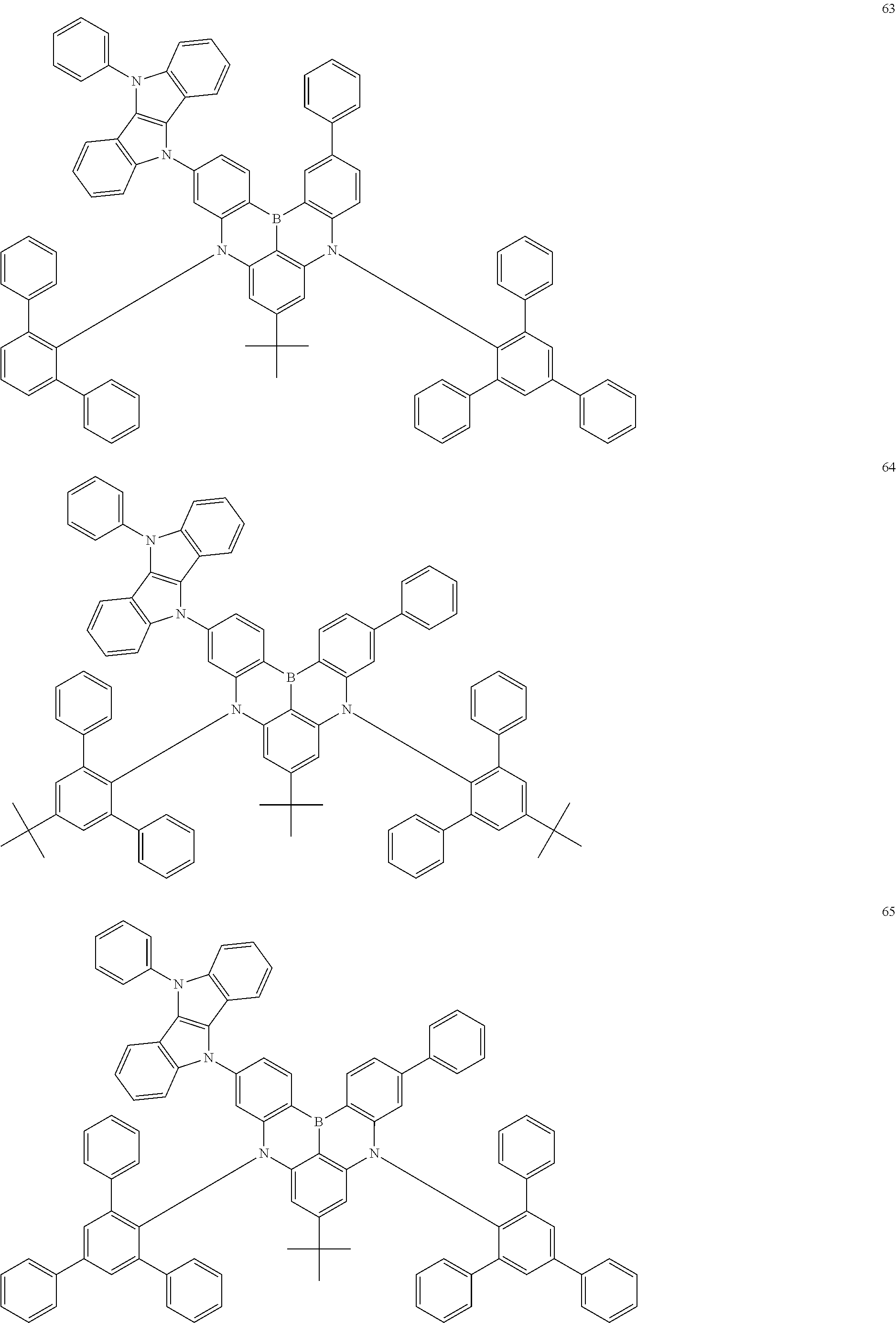

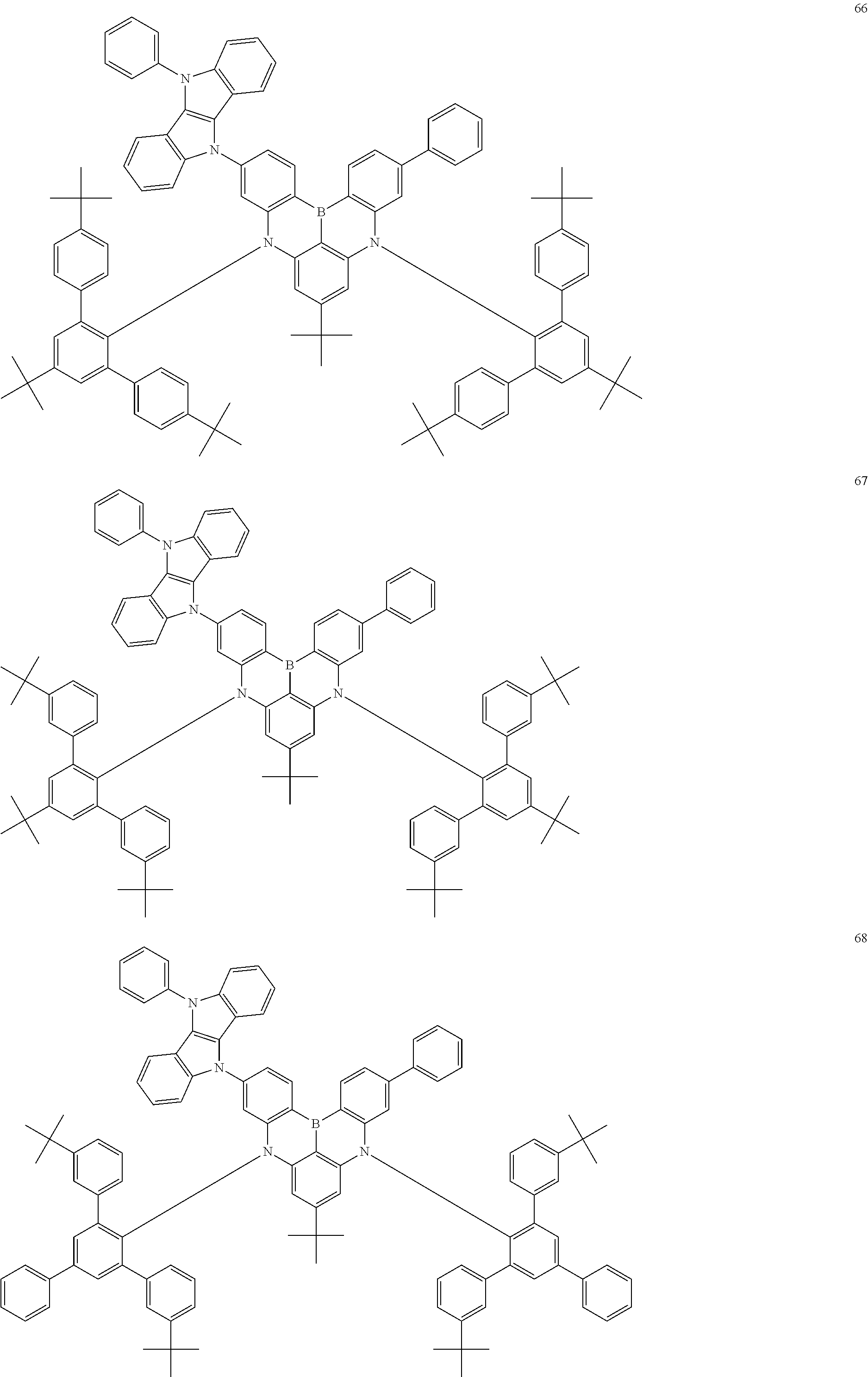

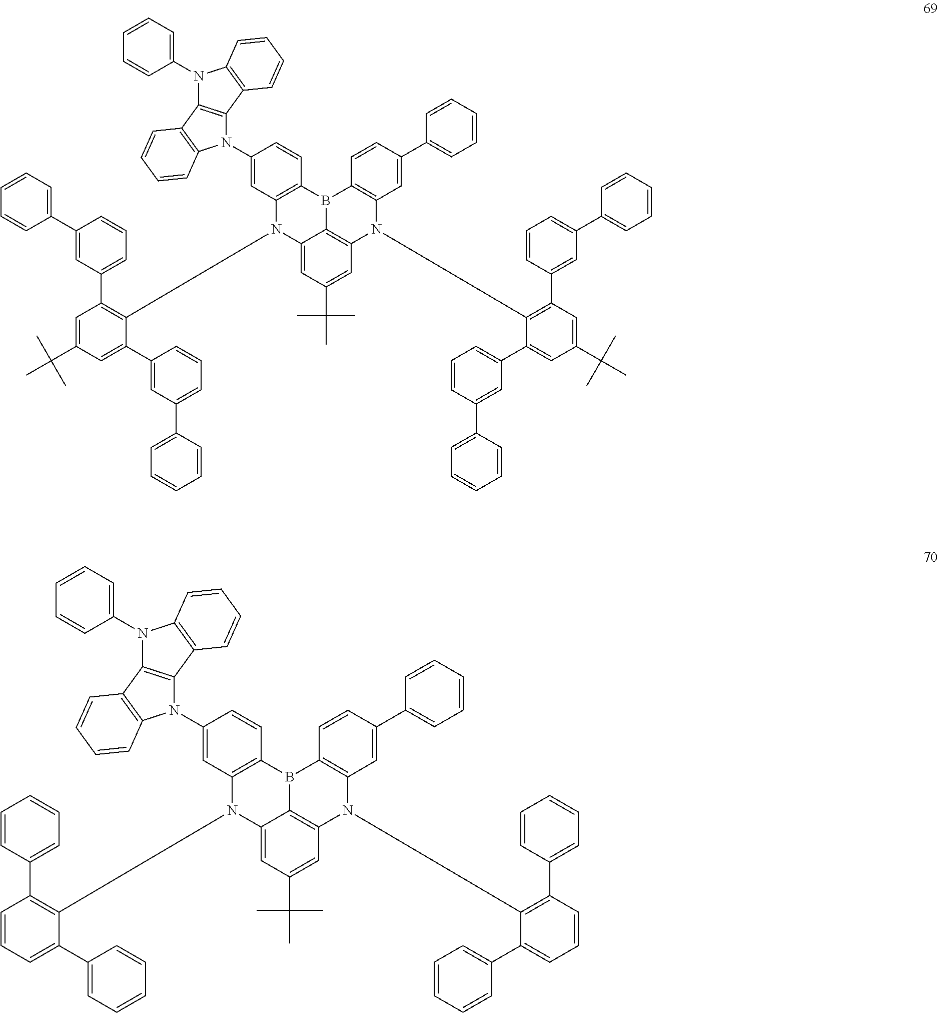 [SMILES: CC(C)(C)c1cc(-c2cccc(-c3ccccc3)c2)c(N2c3cc(-c4ccccc4)ccc3B3c4ccc(-n5c6ccccc6c6c5c5ccccc5n6-c5ccccc5)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-c3ccccc3)cc1N2c1c(-c2ccccc2)cccc1-c1ccccc1]

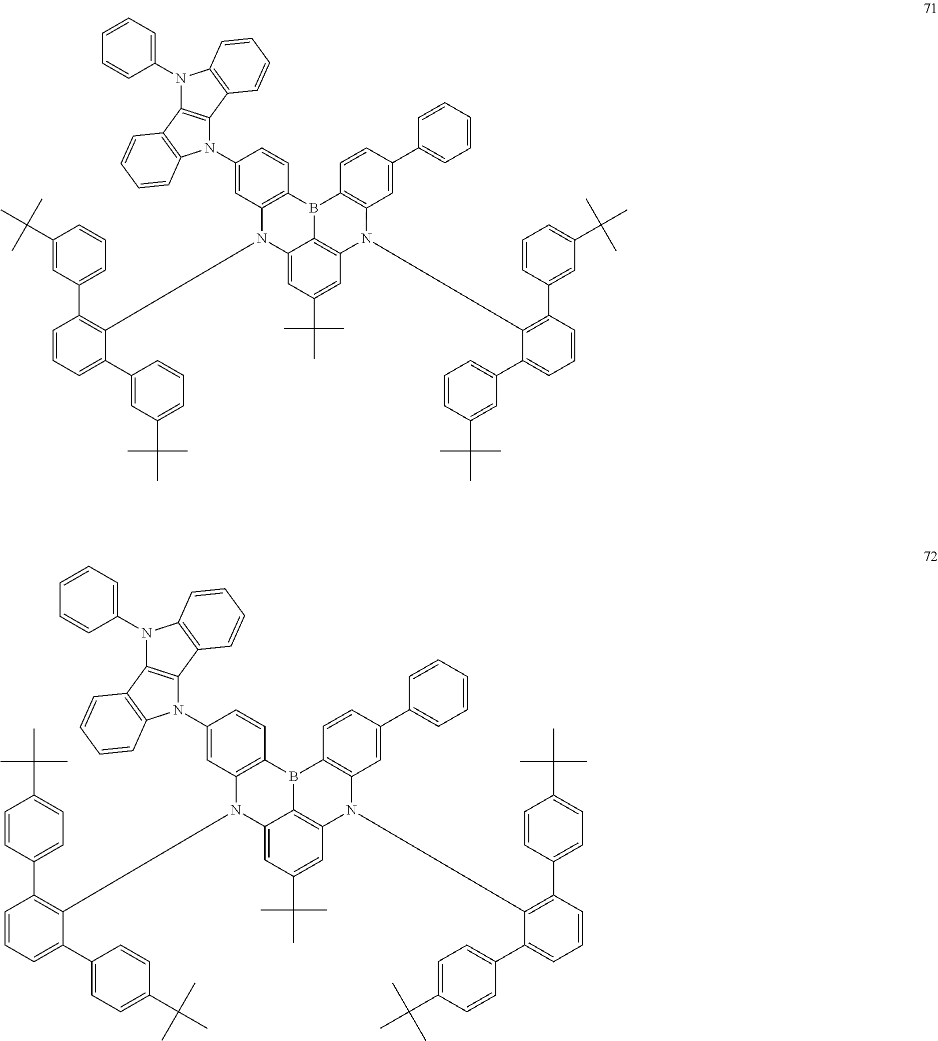

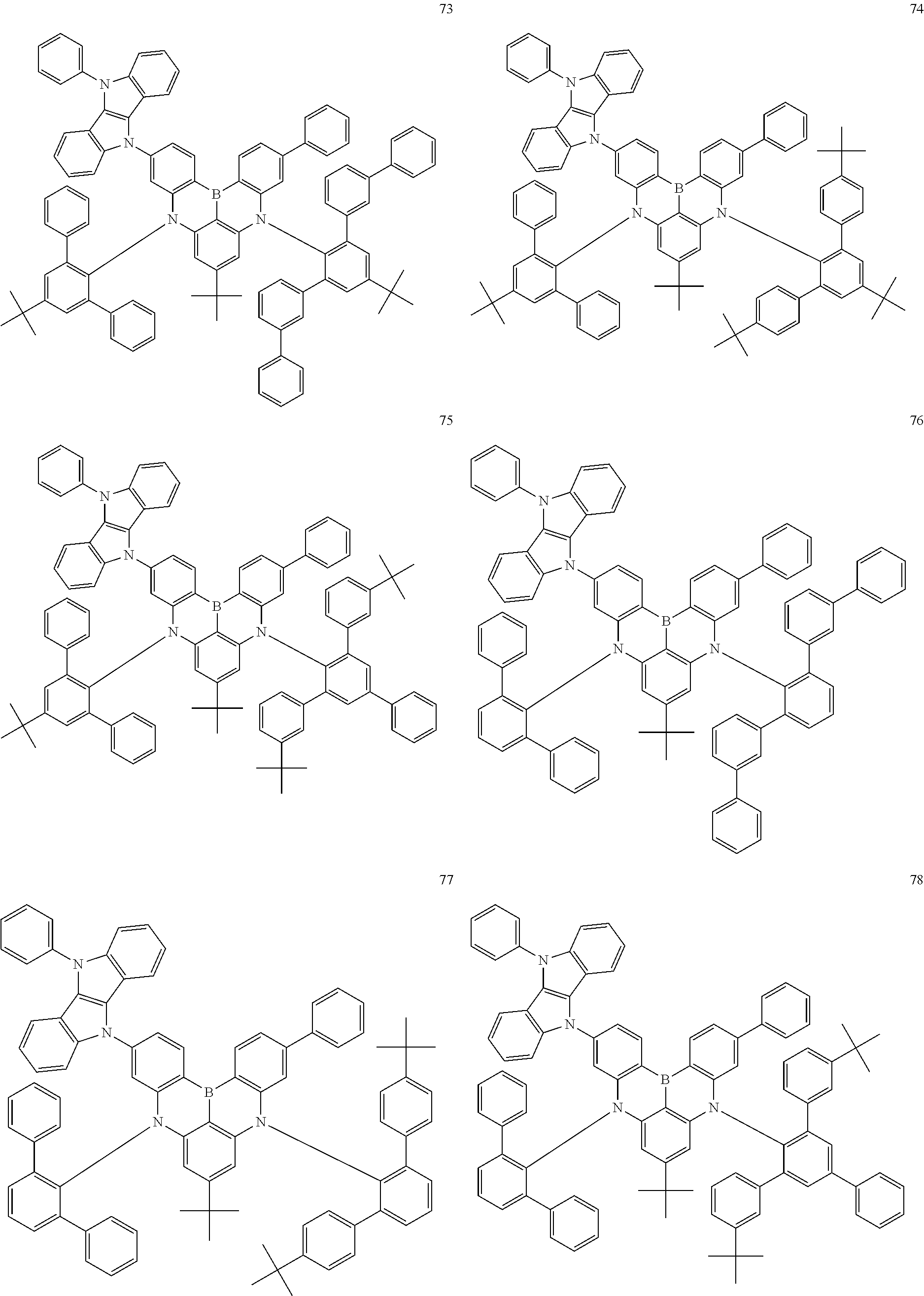

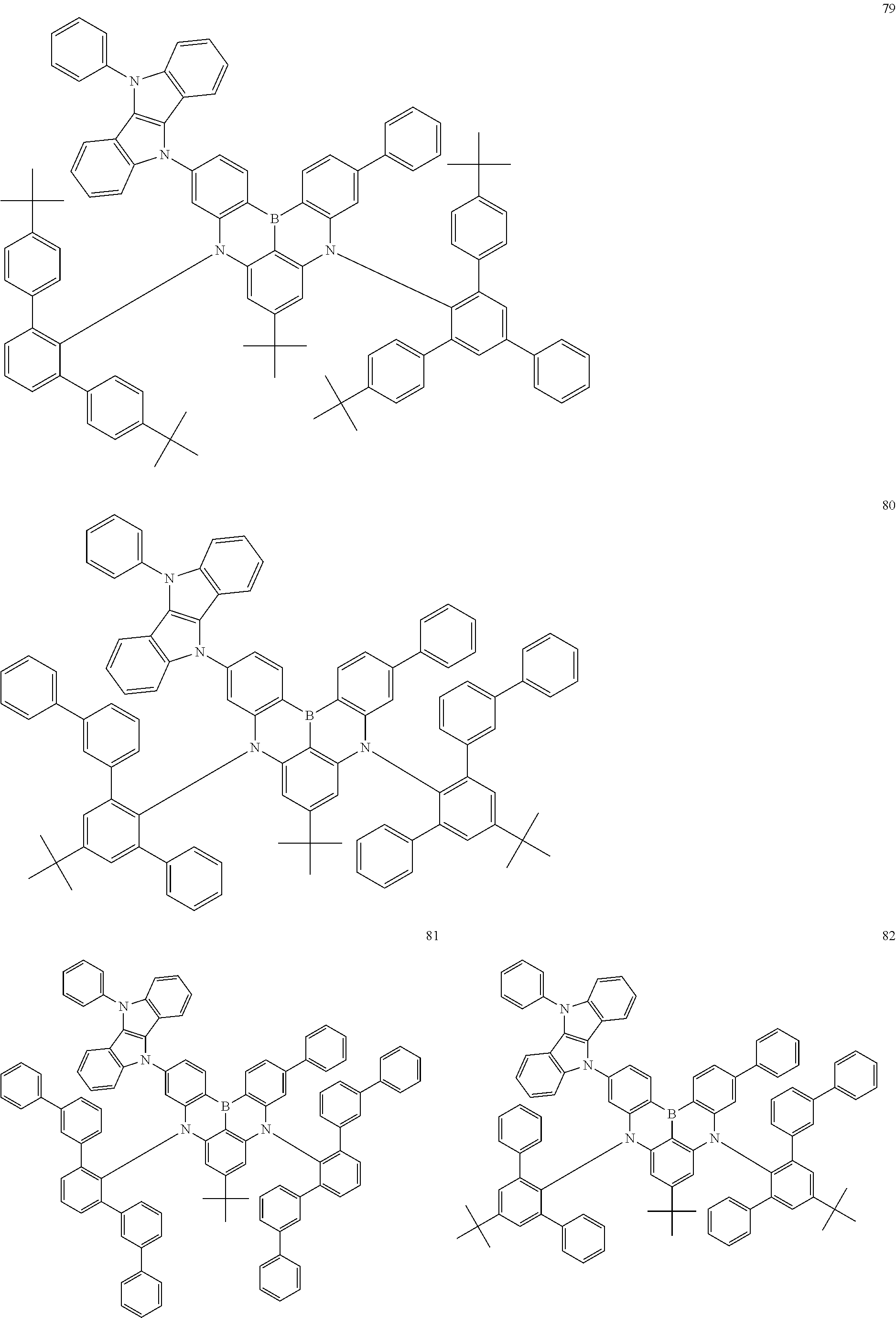

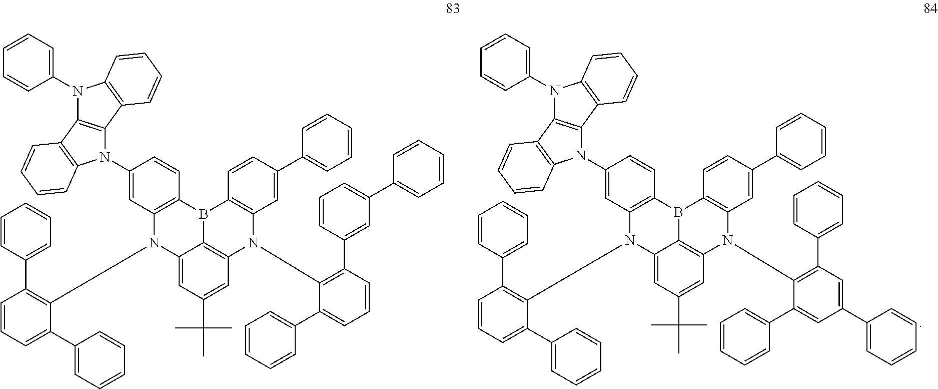 [SMILES: CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-c3ccccc3)cc1N2c1c(-c2ccccc2)cccc1-c1cccc(-c2ccccc2)c1 ; CC(C)(C)c1cc2c3c(c1)N(c1c(-c4ccccc4)cccc1-c1ccccc1)c1cc(-n4c5ccccc5c5c4c4ccccc4n5-c4ccccc4)ccc1B3c1ccc(-c3ccccc3)cc1N2c1c(-c2ccccc2)cc(-c2ccccc2)cc1-c1ccccc1]

20. An electronic device comprising:
a base layer;
a circuit layer on the base layer;
a display element layer on the circuit layer and comprising a light emitting element; and
a light control layer on the display element layer and comprising a quantum dot,
wherein the light emitting element comprises a first light emitting element configured to emit red light, a second light emitting element configured to emit green light, and a third light emitting element configured to emit blue light,
wherein the third light emitting element comprises a first electrode, a second electrode on the first electrode, and an emission layer between the first electrode and the second electrode and comprising a fused polycyclic compound represented by Formula 1: 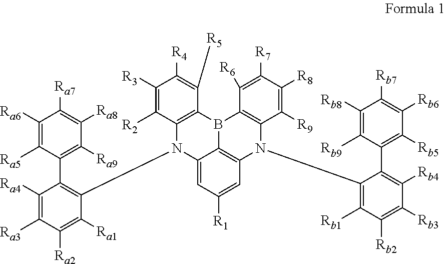
wherein in Formula 1,
at least one selected from among R₁ to R₉, Rₐ₁ to Rₐ₉, and R_{b1} to R_{b9} is represented by Formula 2, and the rest thereof are each independently hydrogen, deuterium, a halogen, a cyano group, a nitro group, a substituted or unsubstituted silyl group, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being bonded to an adjacent group: 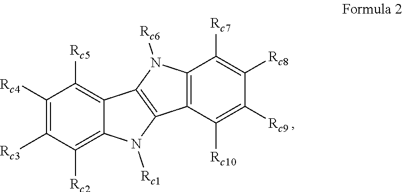
and
wherein in Formula 2,
any one selected from among R_{c1} to R_{c10} is a position bonded to Formula 1, and the rest thereof are each independently hydrogen, deuterium, or a substituted or unsubstituted aryl group having 6 to 30 ring-forming carbon atoms.
